(19) United States
(12) Patent Application Publication
(10) Pub. No.: US 2019/0337973 A1
(43) Pub. Date: Nov. 7, 2019

(54) TETRADENTATE CYCLOMETALATED PLATINUM COMPLEX COMPRISING TRISUBSTITUTED PYRAZOLE, PREPARATION AND USE THEREOF

(71) Applicants: Zhejiang University of Technology, Hangzhou (CN); AAC Microtech (Changzhou) Co., Ltd., Changzhou (CN)

(72) Inventors: Guijie Li, Shenzhen (CN); Jianxin Dai, Shenzhen (CN); Xiangdong Zhao, Shenzhen (CN); Yuanbin She, Shenzhen (CN); Shaohai Chen, Shenzhen (CN)

(21) Appl. No.: 16/112,892

(22) Filed: Aug. 27, 2018

(30) Foreign Application Priority Data
May 7, 2018 (CN) 201810428224.0

(51) Int. Cl. C07F 15/00; H01L 51/00

(52) U.S. Cl. CPC C07F 15/006; H01L 51/5016; H01L 51/0084

(57) ABSTRACT

The present disclosure relates to the field of luminescent materials of blue phosphorescent tetradentate cyclopalladated palladium complexes, and discloses a trisubstituted pyrazole based blue phosphorescent tetradentate cyclopalladated palladium complex, preparation and use thereof. The complex may be a delayed fluorescent and/or phosphorescent emitter, has a high thermal decomposition temperature, can perform blue luminescent, and has strong light emitting, and thus has a great application prospect in the field of blue light, and especially deep blue phosphorescent materials.

### CROSS-REFERENCE TO RELATED APPLICATIONS

This application claims the priority benefit of Chinese Patent Applications Ser. No. 201810428224.0 filed on May 7, 2018, the entire content of which is incorporated herein by reference.

### FIELD OF THE PRESENT DISCLOSURE

The present disclosure relates to the field of luminescent materials of blue phosphorescent tetradentate cyclometalated palladium complexes, and more particularly to a trisubstituted pyrazole based luminescent material of blue phosphorescent tetradentate cyclometalated palladium complex.

### DESCRIPTION OF RELATED ART

Compounds capable of absorbing and/or emitting light can be ideally suited for use in a wide variety of optical and electroluminescent devices, including, for example, light absorbing devices such as solar-sensitive and photo-sensitive devices, organic light emitting diodes (OLEDs), light emitting devices, or devices capable of both light absorption and emission and as markers for bio-applications. Many studies have been devoted to the discovery and optimization of organic and organometallic materials for using in optical and electroluminescent devices. Generally, studies in this area aim to accomplish a number of goals, including improvements in absorption and emission efficiency and improvements in processing ability.

Despite significant advances in studies devoted to optical and electro-optical materials (e.g., red and green phosphorescent organometallic materials are commercially available and have been used as phosphorescence materials in OLEDs, lighting equipment, and advanced displays), the currently available materials still have a number of defects, including poor machining ability, inefficient emission or absorption, and unsatisfactory stability.

Moreover, good blue light emitting materials are particularly scarce, and one challenge is the poor stability of a blue light device. Meanwhile, the choice of host materials has an impact on the stability and the efficiency of the devices. The lowest triplet state energy level of a blue phosphorescent material is very high compared with that of red and green phosphorescent materials, which means that the lowest triplet state energy level of the host material in the blue light device should be even higher. Therefore, the limitation of the host material in the blue light device is another important issue for the development of the blue light device.

Generally, a chemical structural change will affect the electronic structure of the complex, which thereby affects the optical properties of the complex (e.g., emission and absorption spectrum). Thus, the complex described in the present disclosure can be tailored or tuned to a particular emission or absorption energy. In some aspects, the optical properties of the complex disclosed in the present disclosure can be tuned by varying the structure of the ligand surrounding the metal center. For example, complexes having a ligand with electron donating substituents or electron withdrawing substituents generally exhibit different optical properties, including different emission and absorption spectrum.

Since the phosphorescent multidentate palladium metal complexes can simultaneously utilize the electro-excited singlet and triplet exciton to obtain 100% of internal quantum efficiency, these complexes can be used as alternative luminescent materials for OLEDs. Generally, multidentate palladium metal complex ligands include luminescent groups and ancillary groups. If conjugated groups, such as aromatic ring substituents or heteroatom substituents, are introduced into the luminescent part, the energy levels of the highest occupied molecular orbital (HOMO) and lowest unoccupied molecular orbital (LOMO) of the luminescent materials are changed. Meanwhile, further tuning the energy level gap between the HOMO orbit and the LOMO orbit can tune the emission spectrum properties of the phosphorescent multidentate palladium metal complex, such as making the emission spectrum wider or narrower, or resulting in red shift or blue shift of the emission spectrum.

### SUMMARY

The present disclosure aims at providing a trisubstituted pyrazole based blue phosphorescent tetradentate cyclopalladated palladium complex and use thereof.

The tetradentate cyclopalladated palladium complex comprising trisubstituted pyrazole provided by the embodiments of the present disclosure has a structure of formula (I):

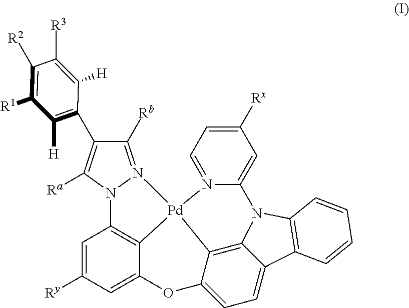

R^{a} and R^{b} each are alkyl, alkoxy, cycloalkyl, ether, heterocyclyl, hydroxy, aryl, heteroaryl, aryloxy, monoalkylamino or dialkylamino, monoarylamino or diarylamino, halogen, sulfydryl, cyano, independently, or combination thereof;

R^{x} is alkyl, alkoxy, cycloalkyl, heterocyclyl, ether, monoalkylamino or dialkylamino, monoarylamino or diarylamino, halogen, or combination thereof;

R^{y} is hydrogen, deuterium, alkyl, alkoxy, cycloalkyl, heterocyclyl, ether, monoalkylamino or dialkylamino, monoarylamino or diarylamino, halogen or combination thereof, and

R¹, R² and R³ each are hydrogen, deuterium, alkyl, alkoxy, ether, cycloalkyl, heterocyclyl, hydroxy, aryl, heteroaryl, aryloxy, monoalkylamino or dialkylamino, monoarylamino or diarylamino, halogen, sulfydryl, haloalkyl, independently, or combination thereof.

Preferably, according to the tetradentate cyclopalladated palladium complex comprising trisubstituted pyrazole provided by the embodiments of the present disclosure, the

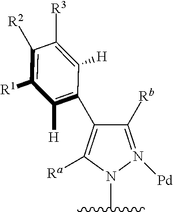

has a structure selected from one of the following:

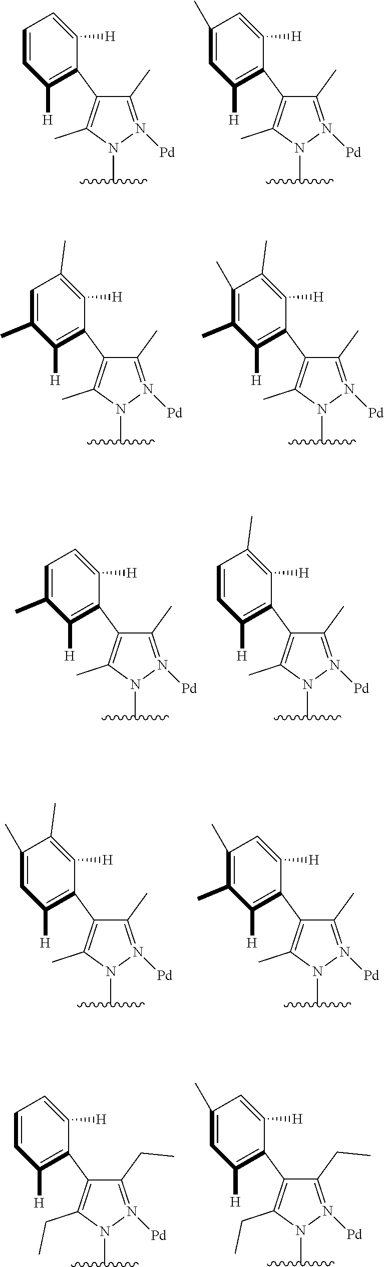

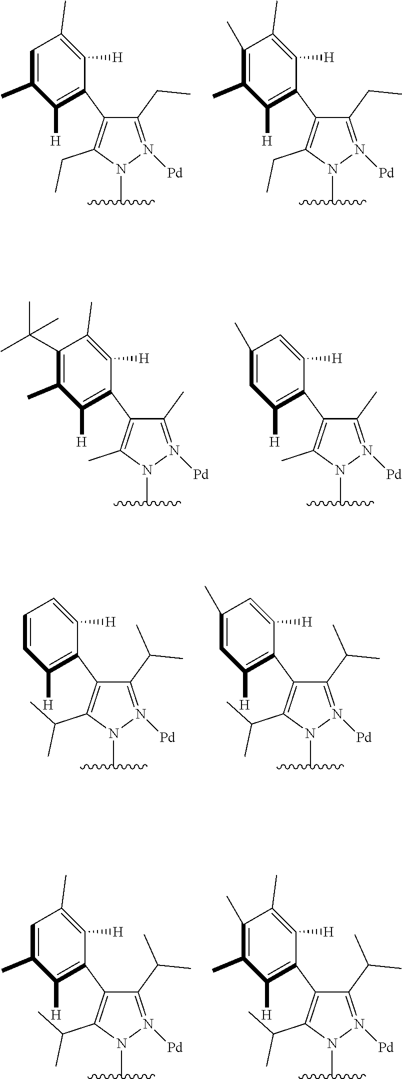

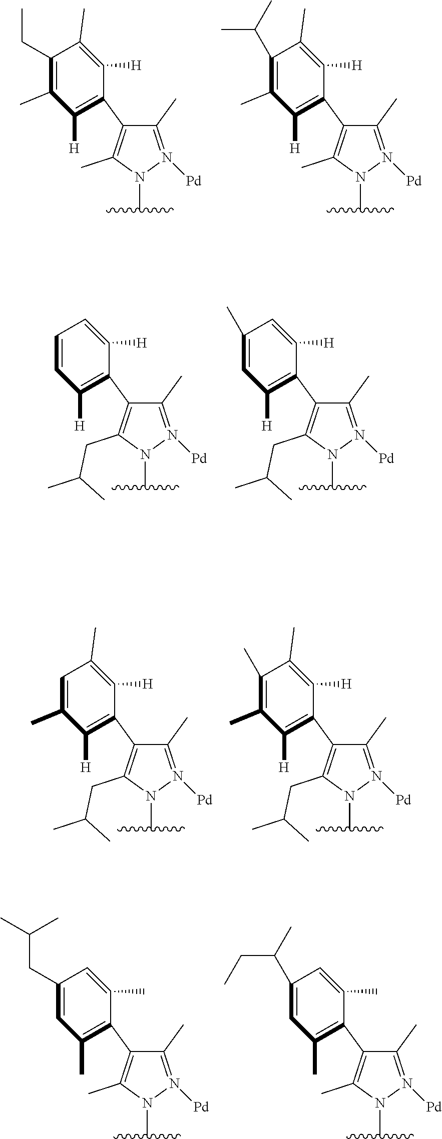

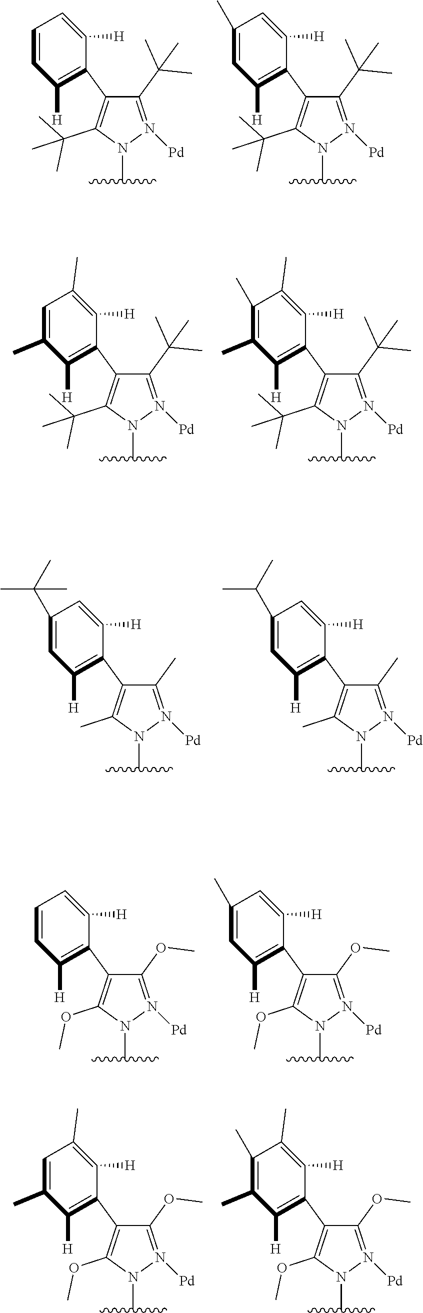

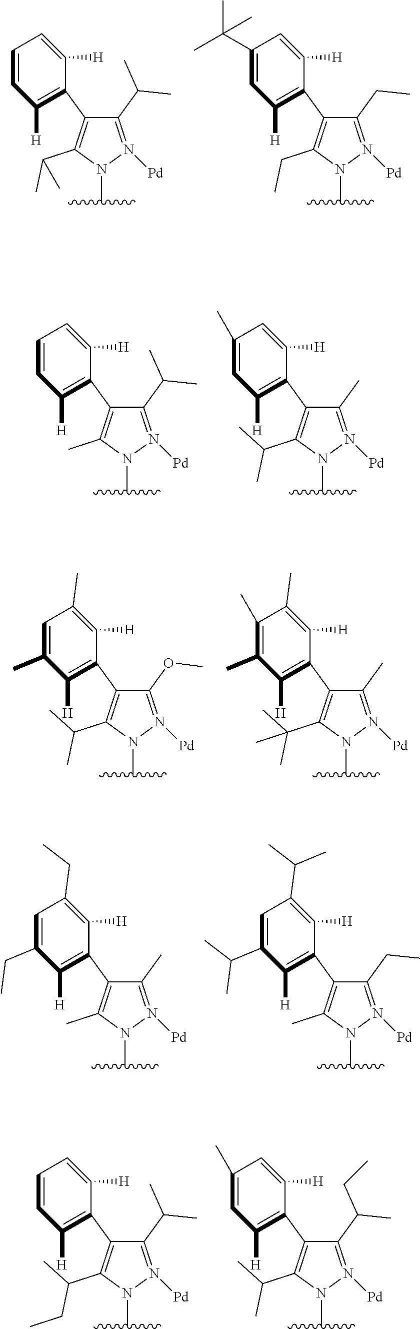

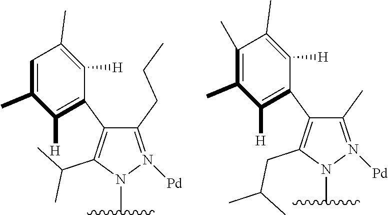

Preferably, the tetradentate cyclopalladated palladium complex comprising trisubstituted pyrazole provided by the embodiments of the present disclosure has a structure selected from one of Pd1 to Pd256:

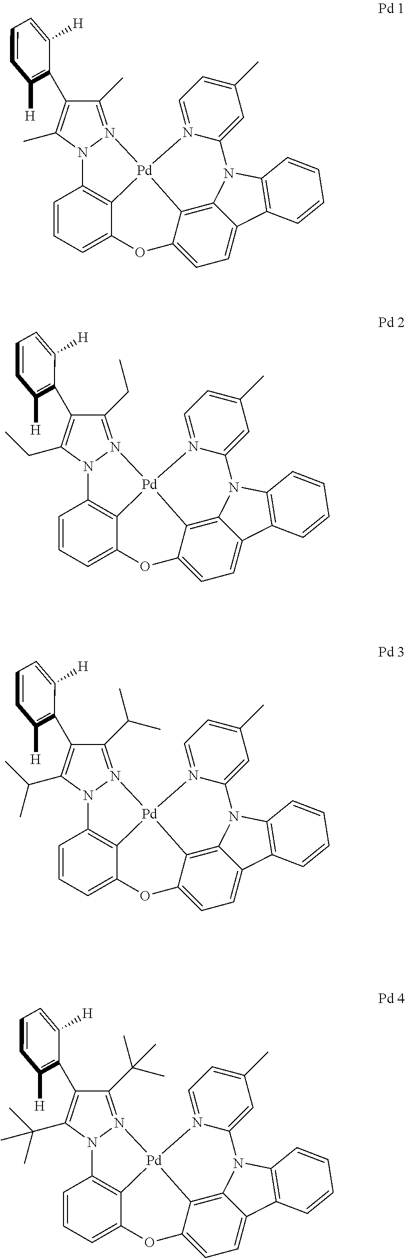

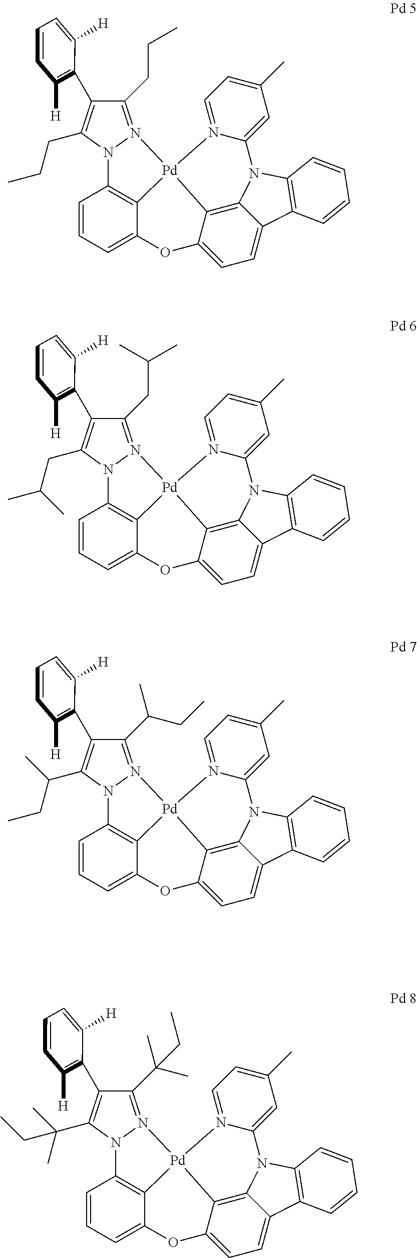

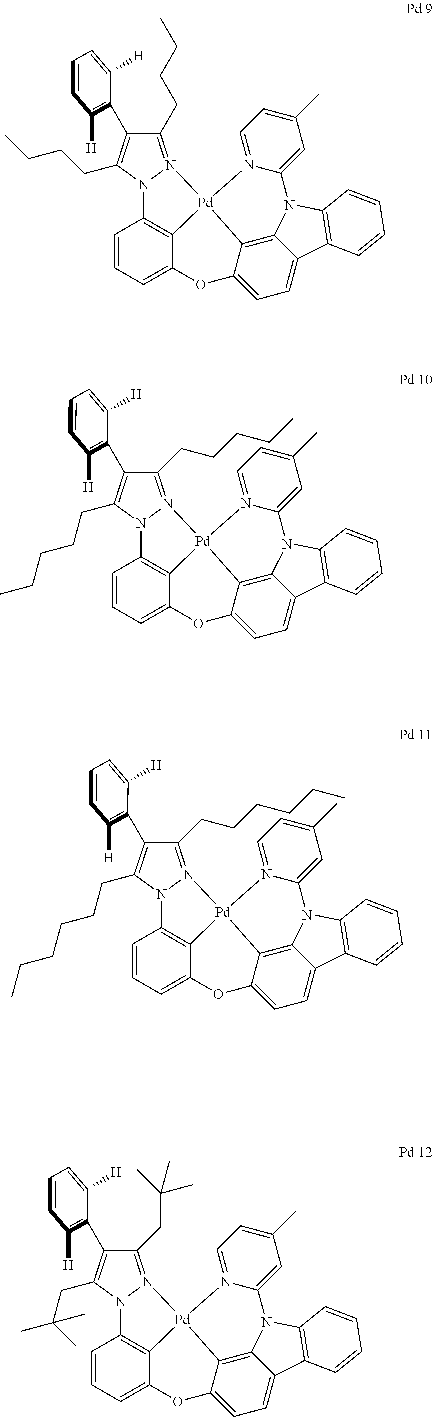

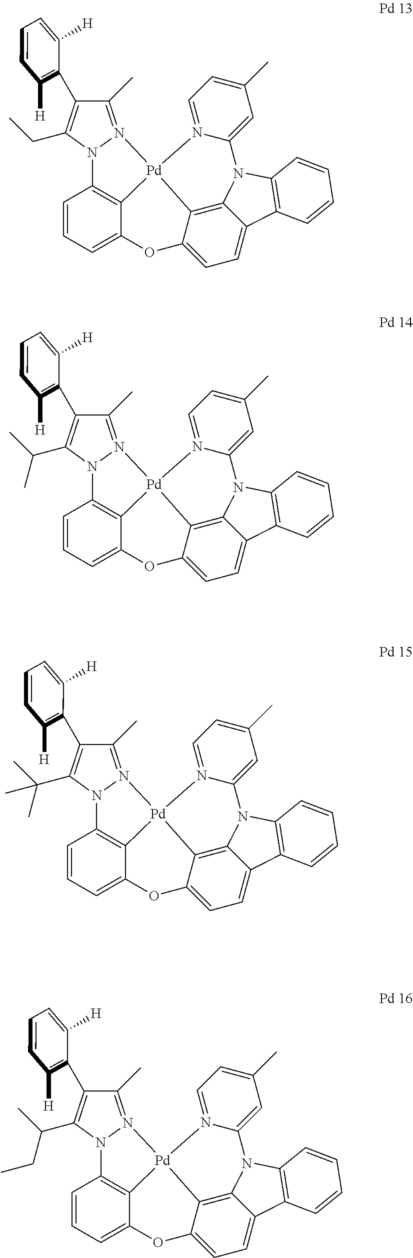

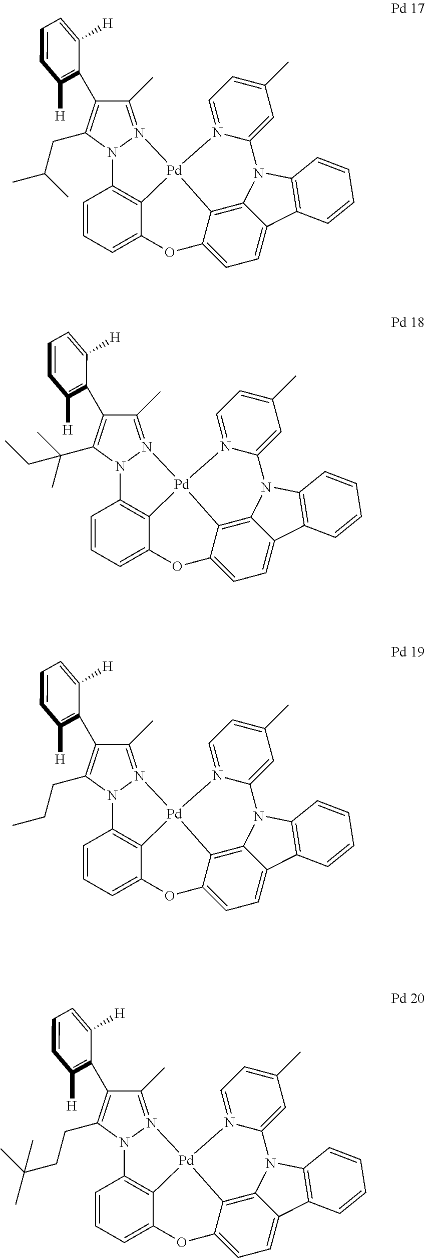

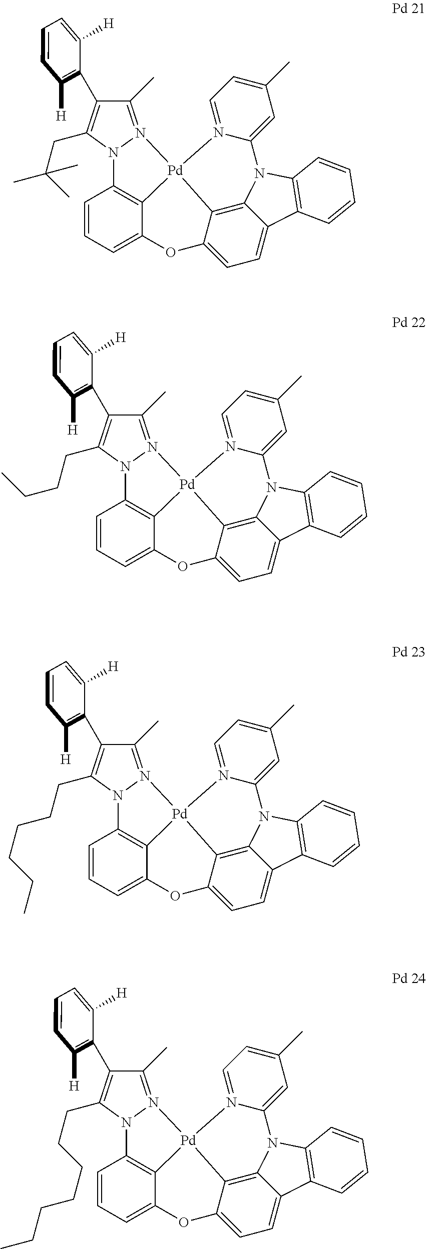

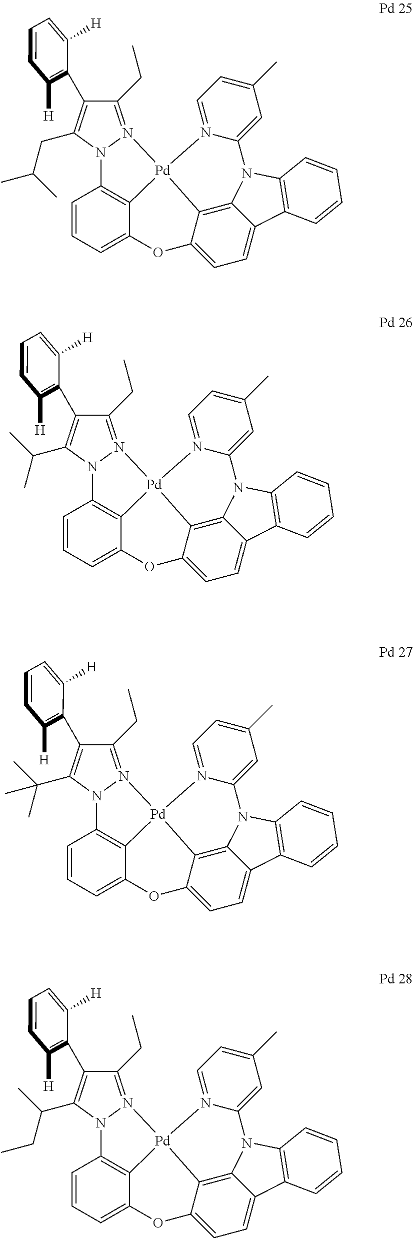

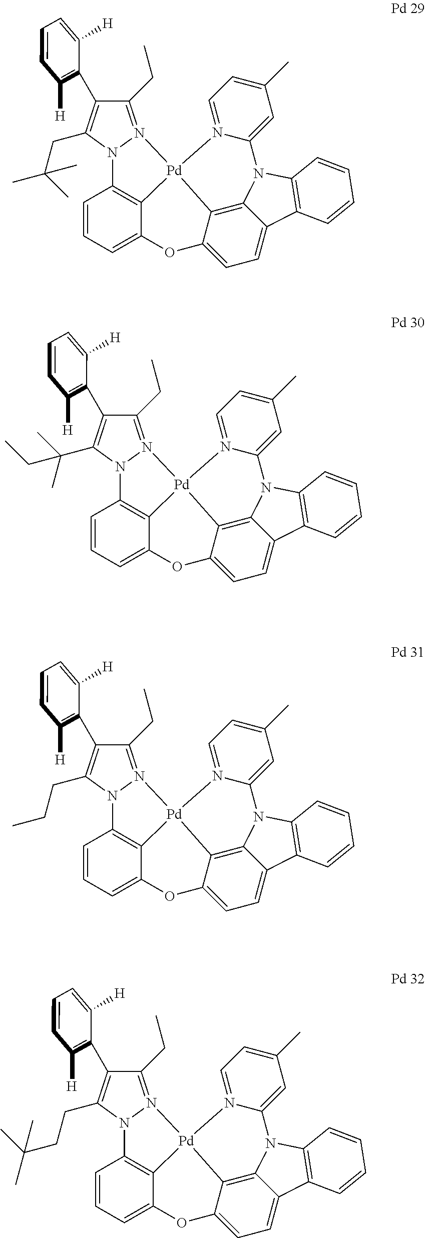

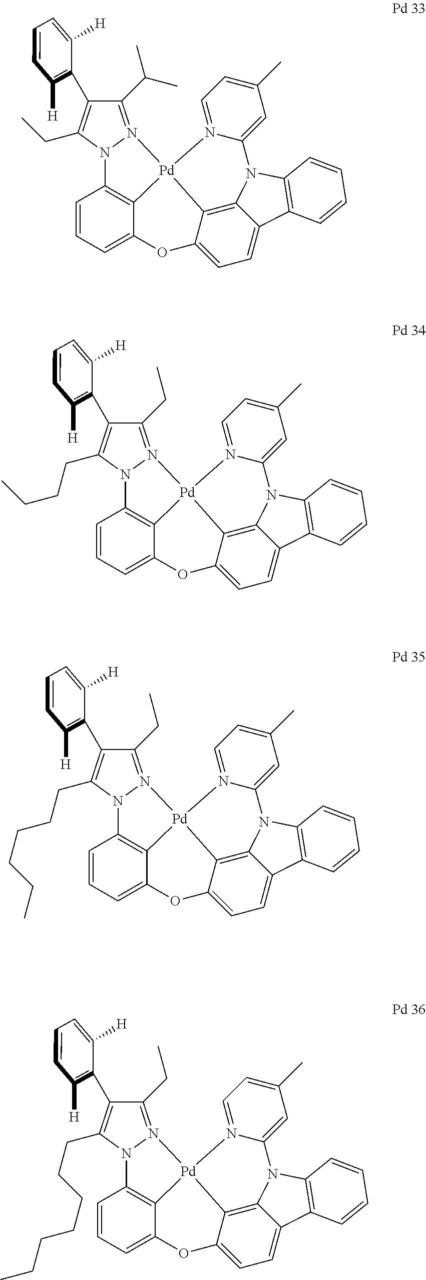

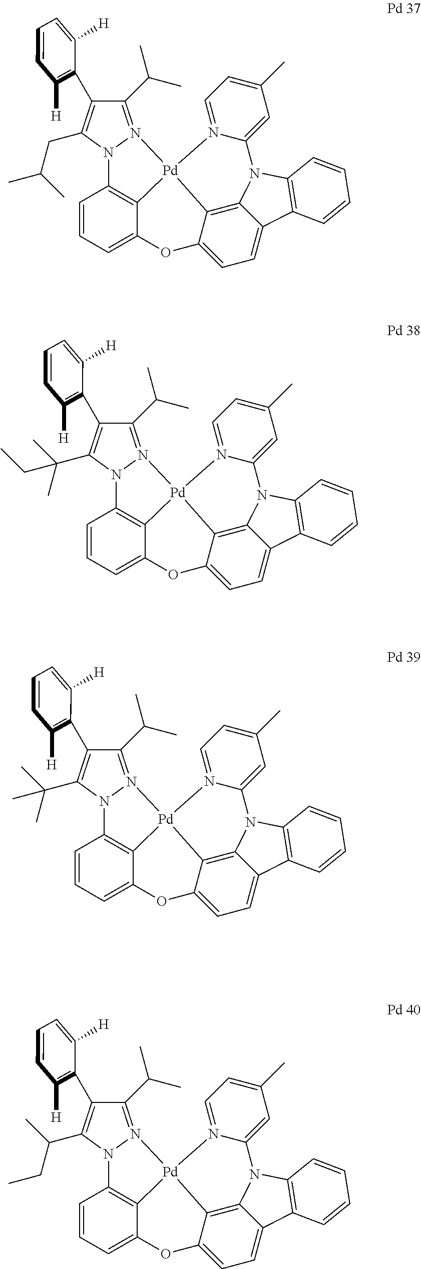

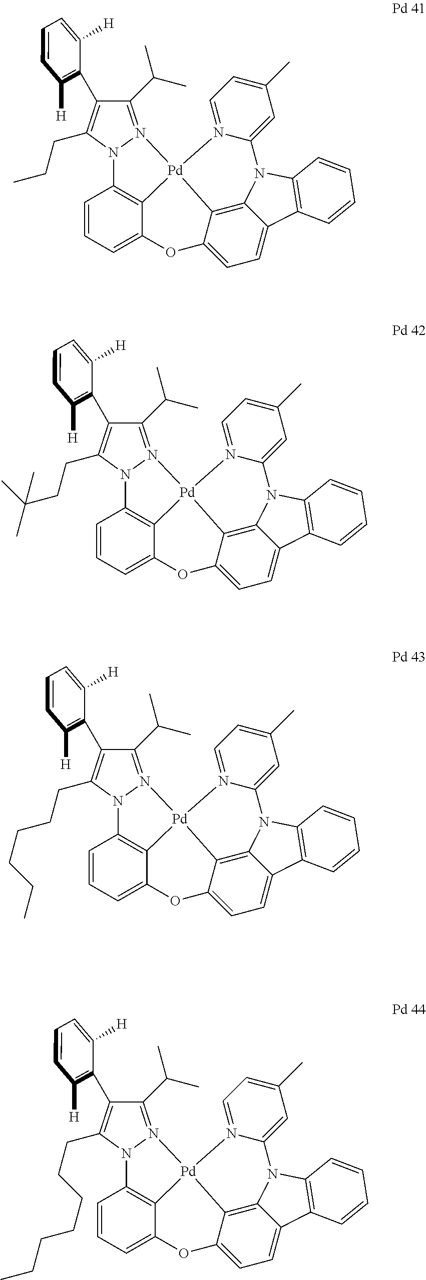

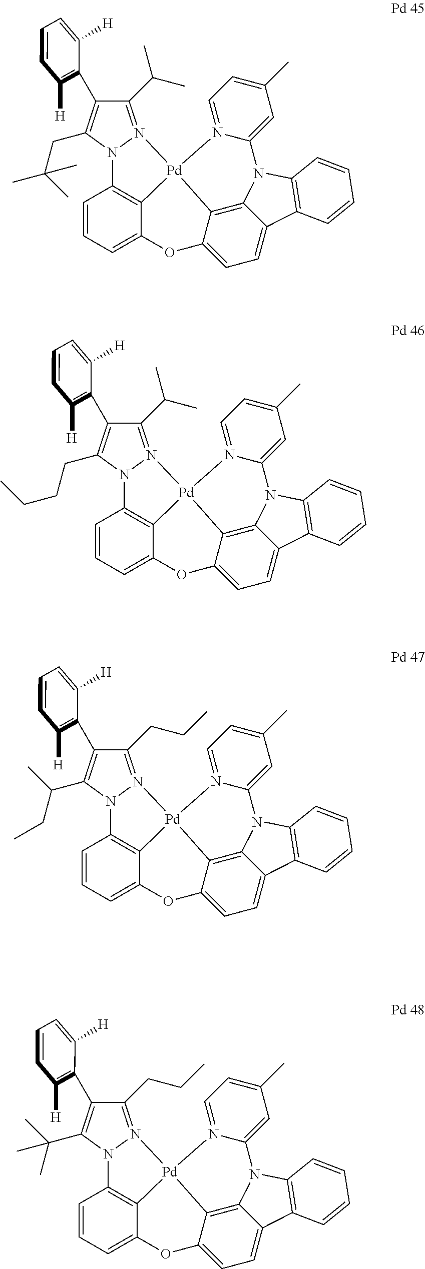

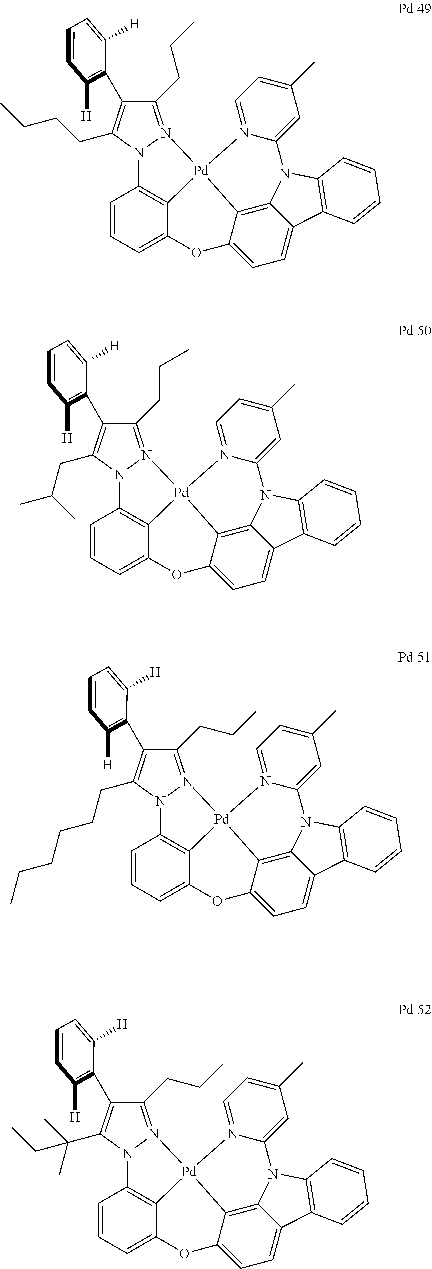

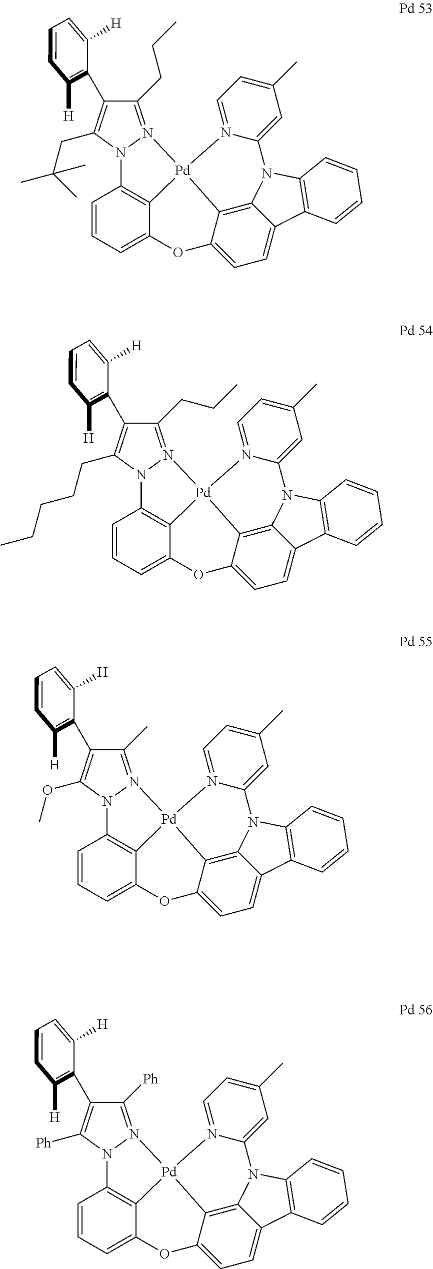

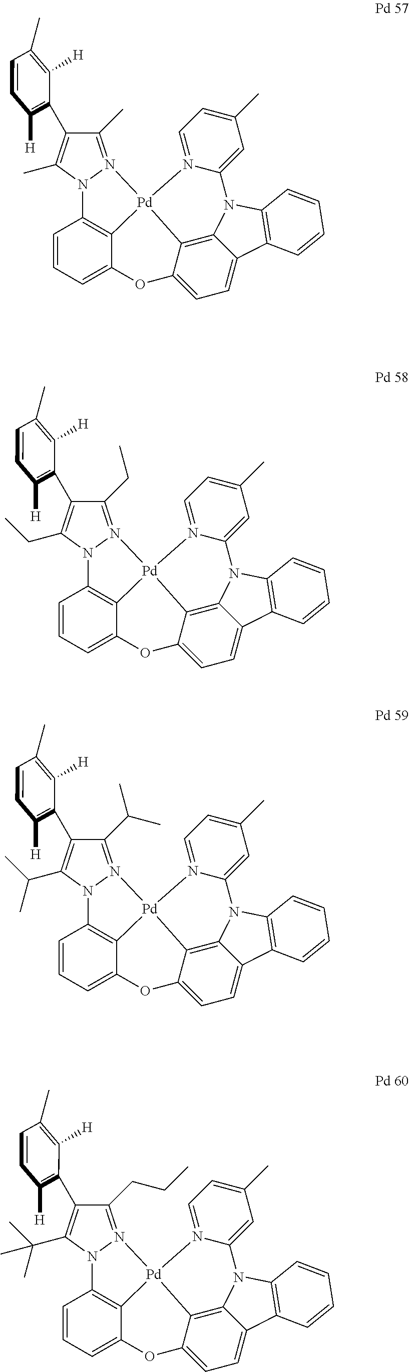

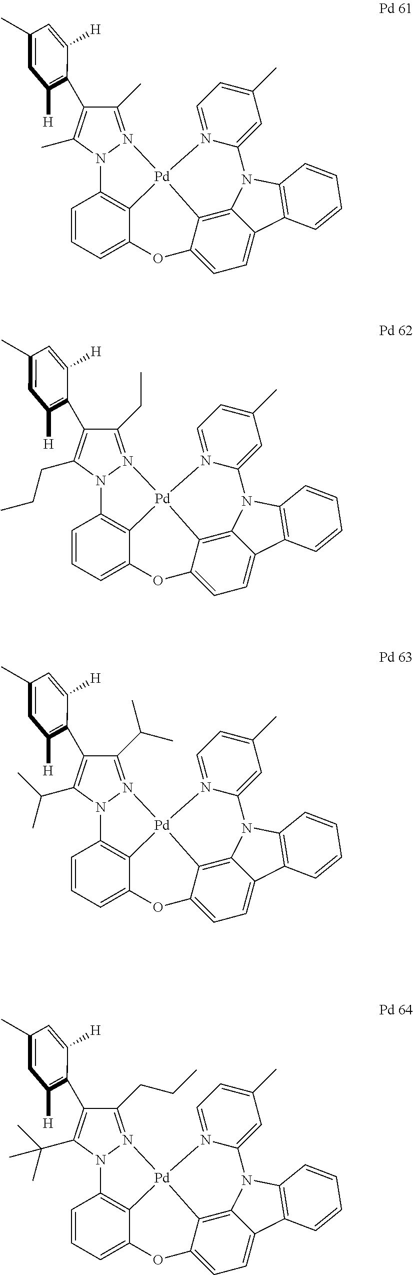

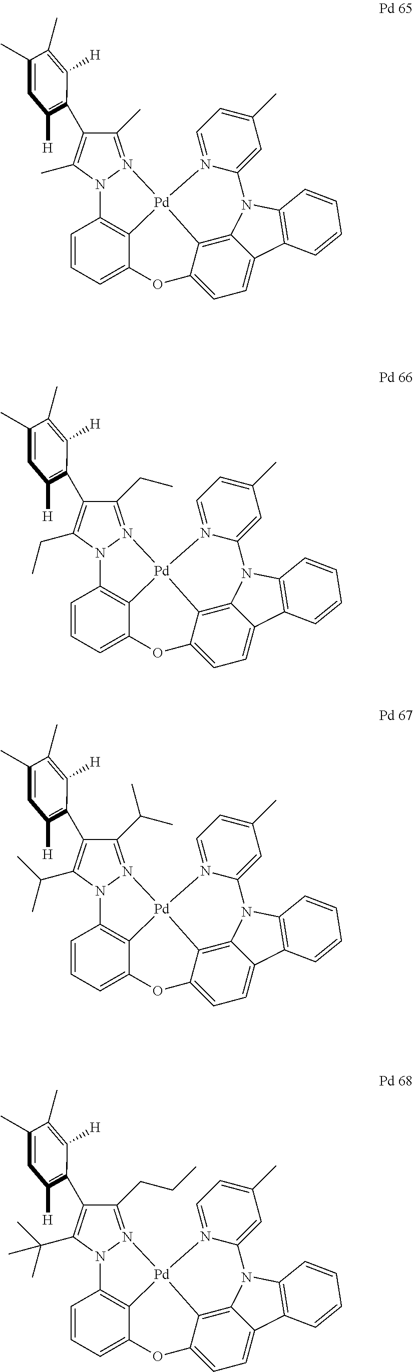

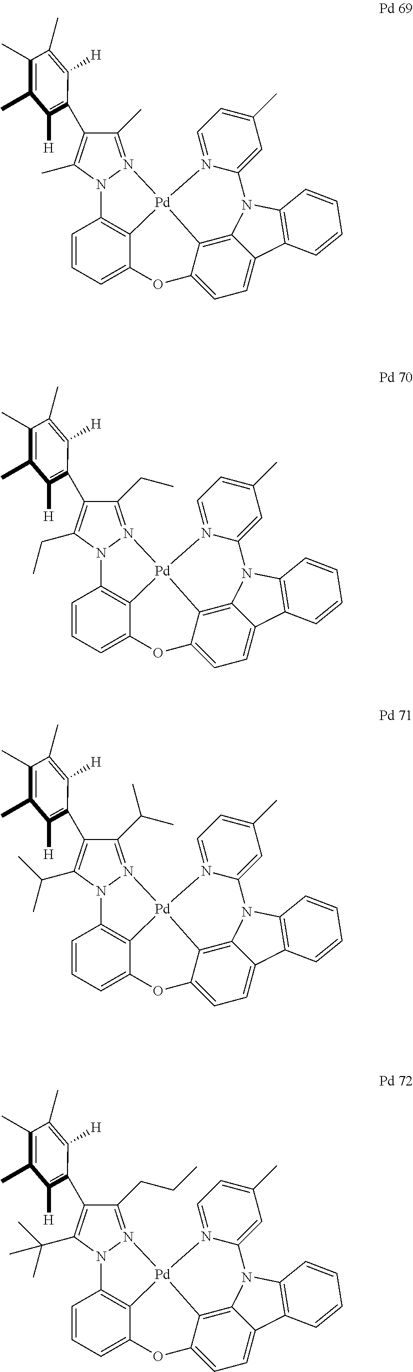

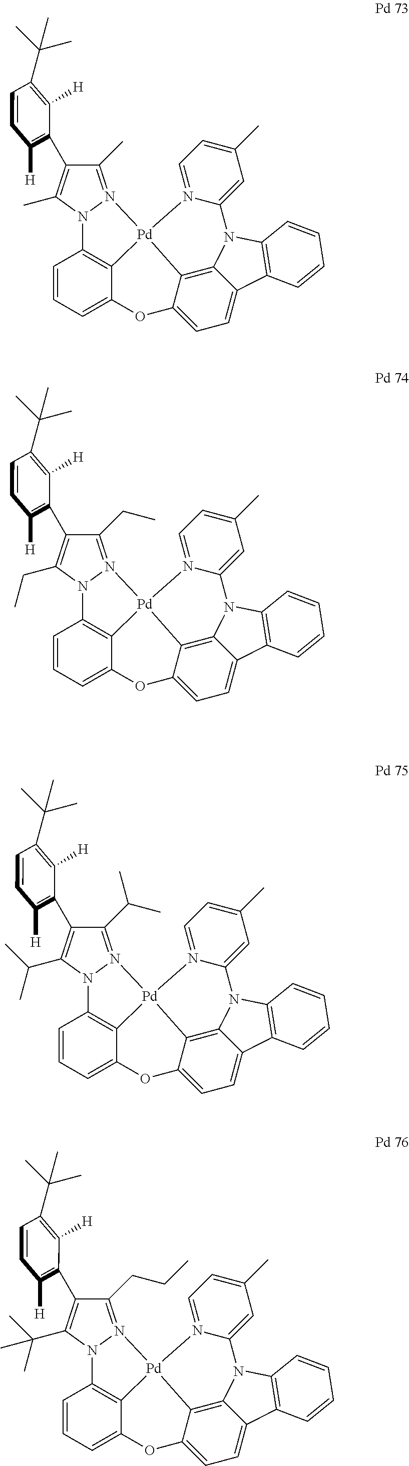

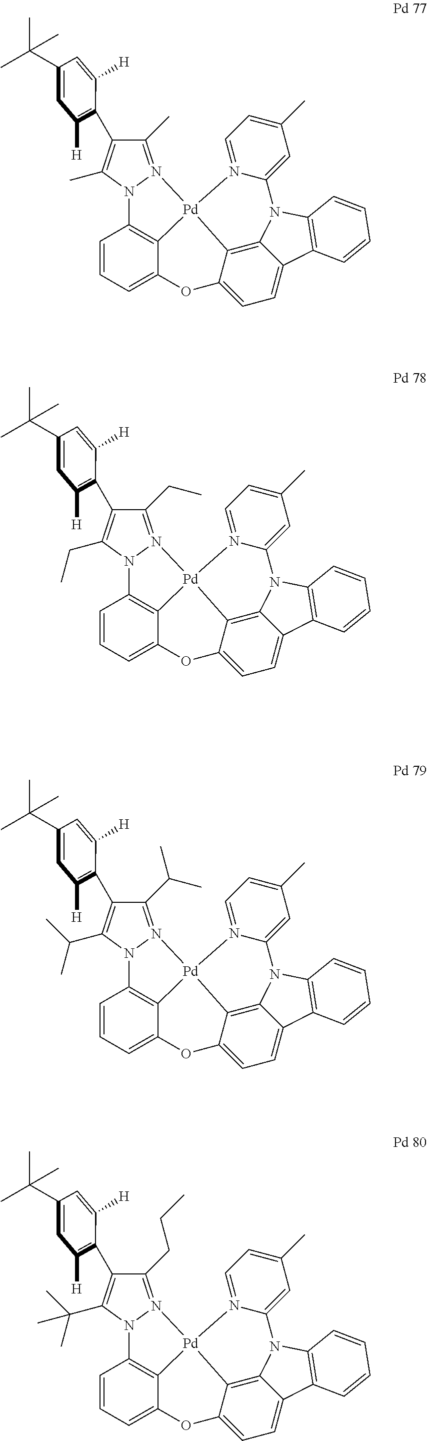

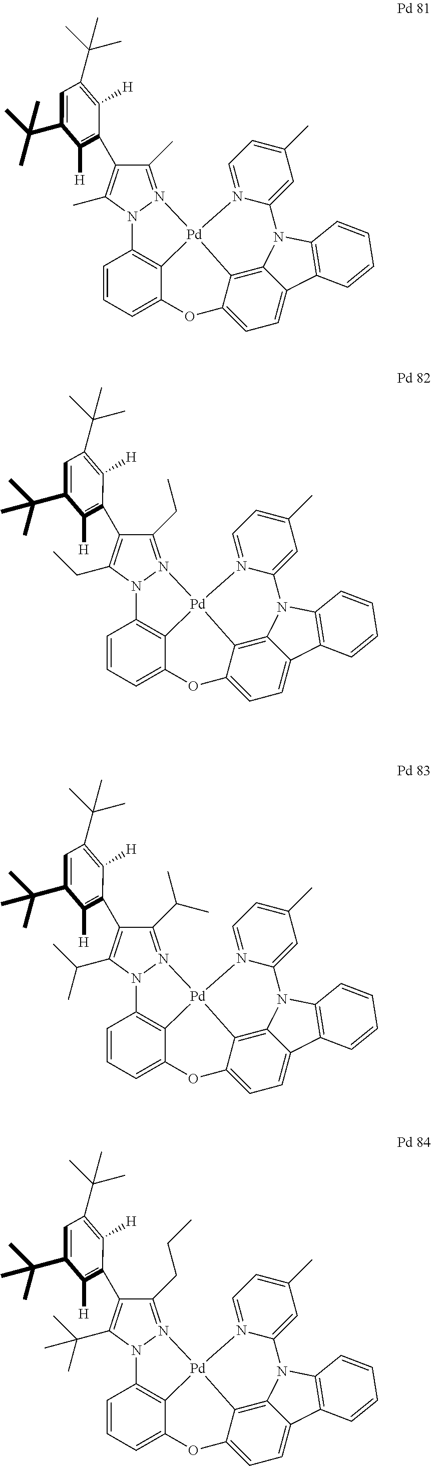

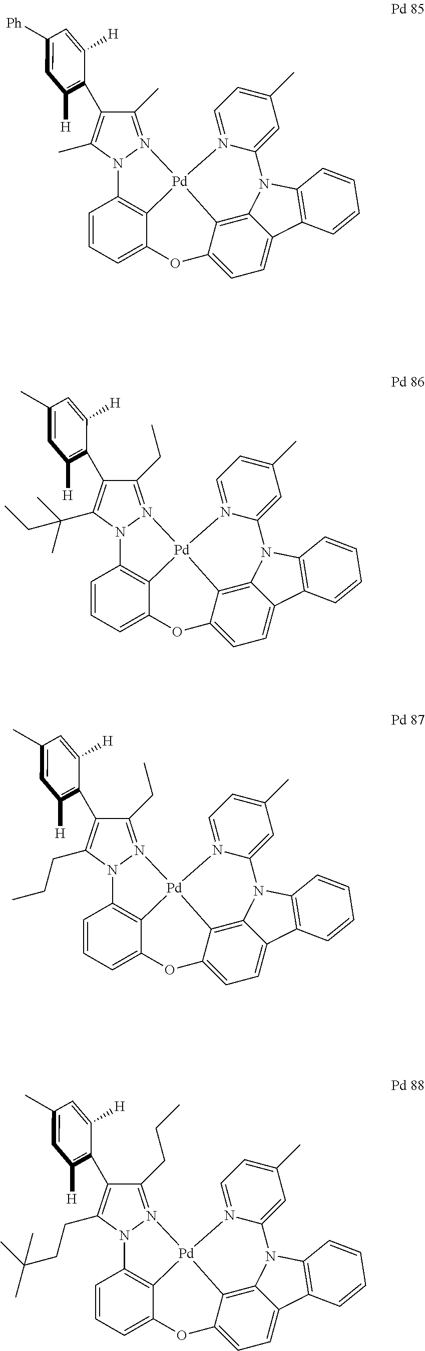

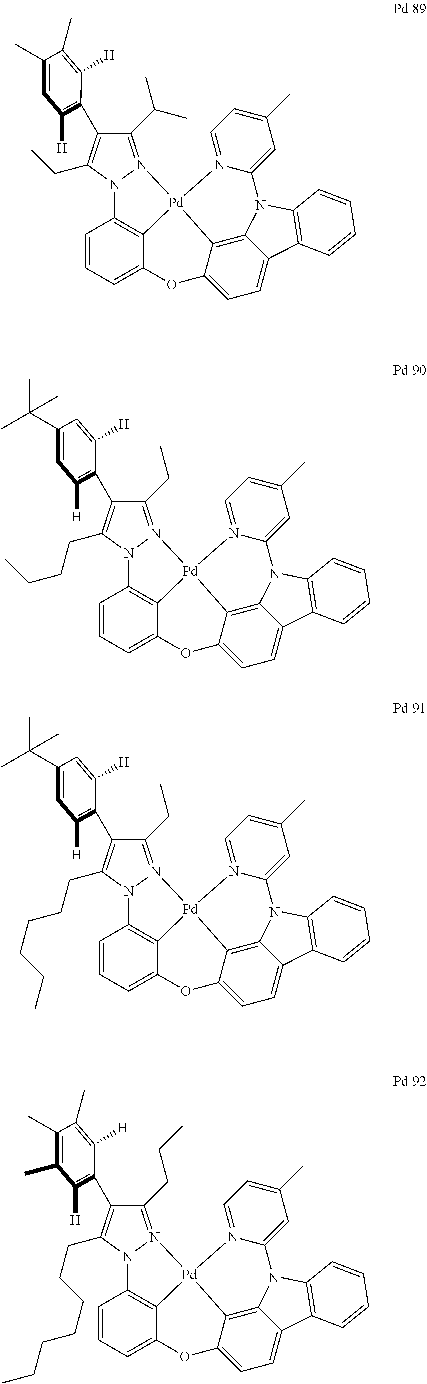

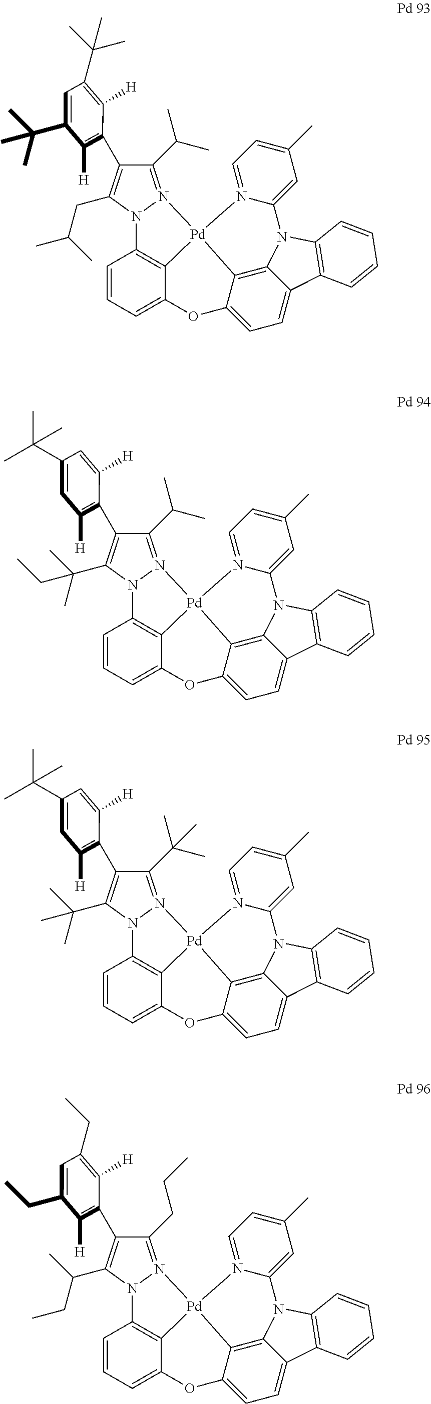

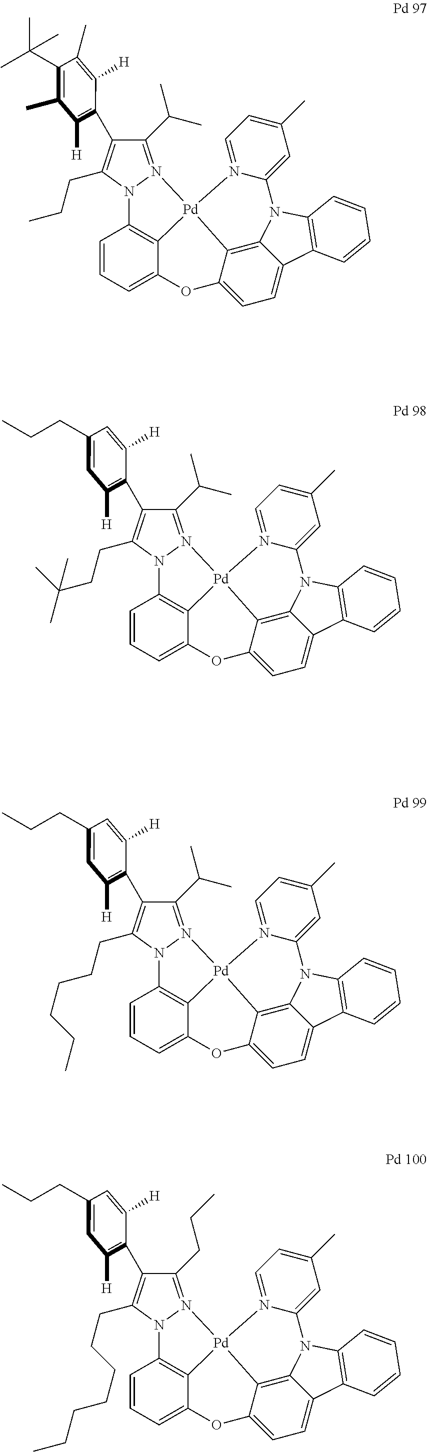

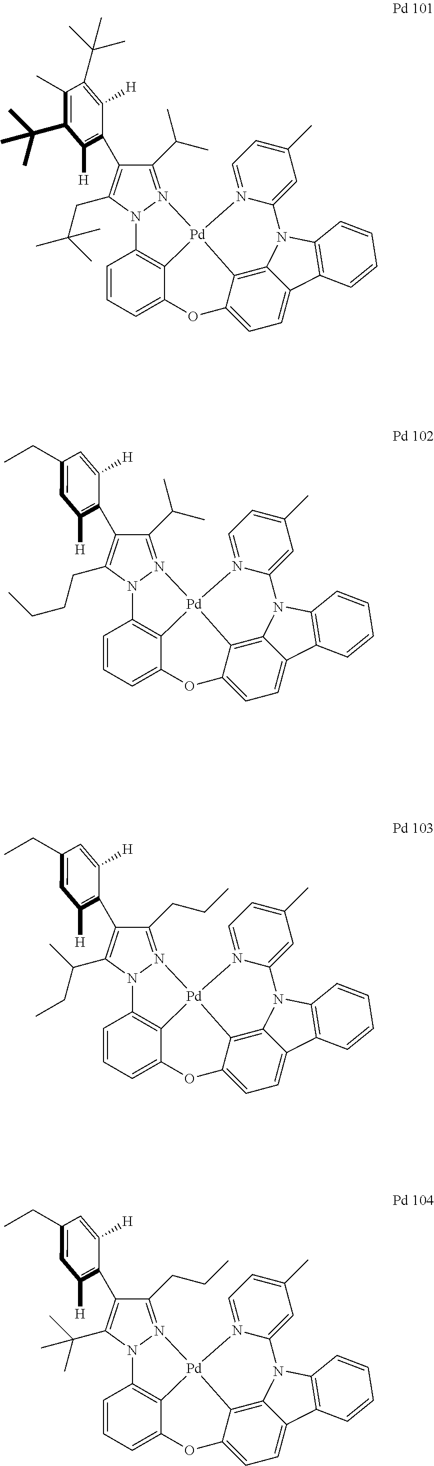

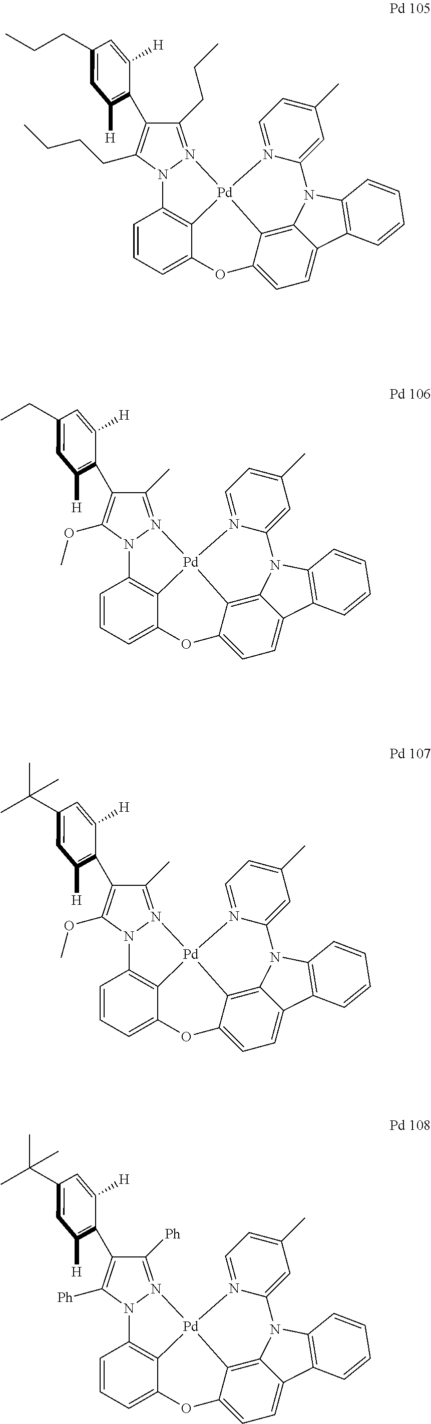

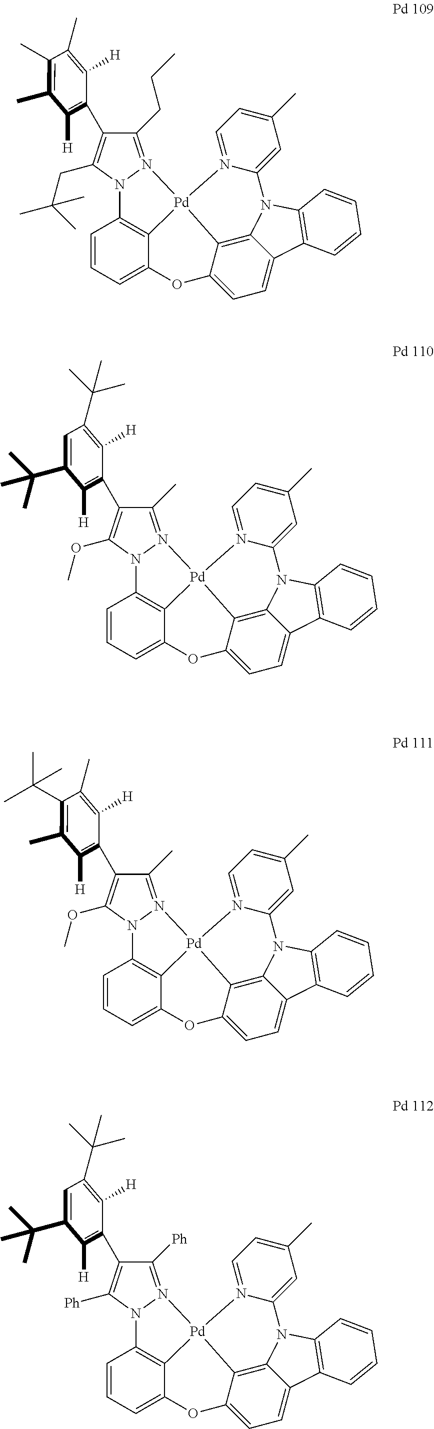

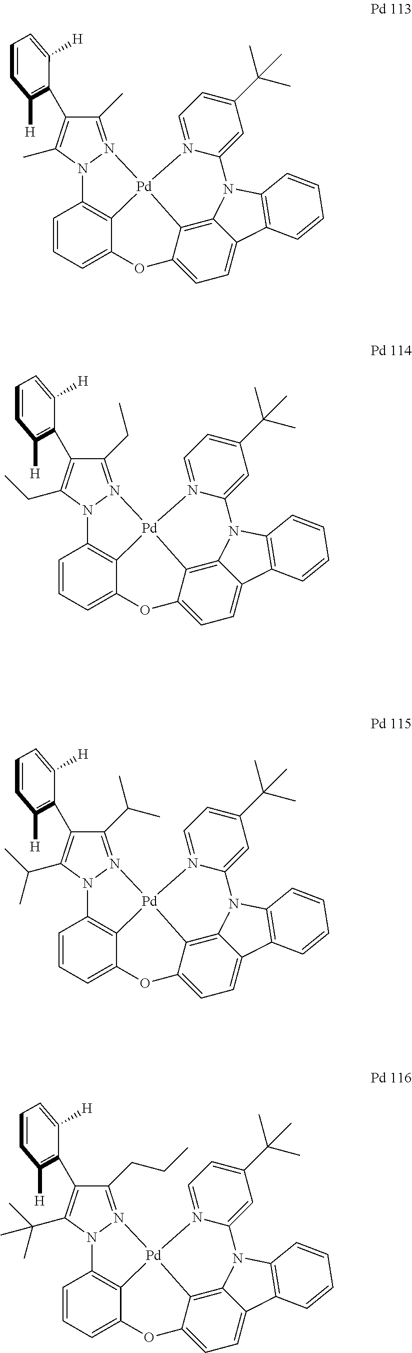

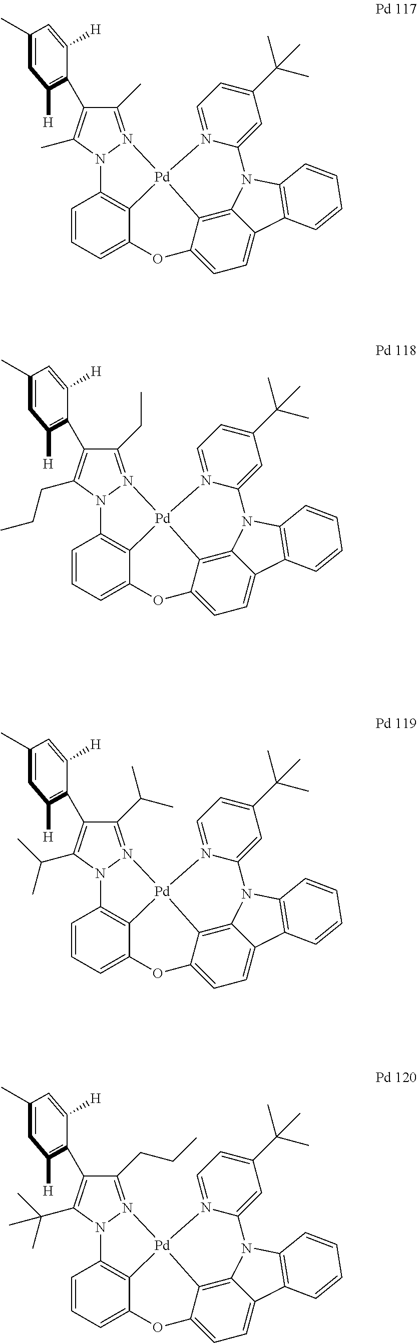

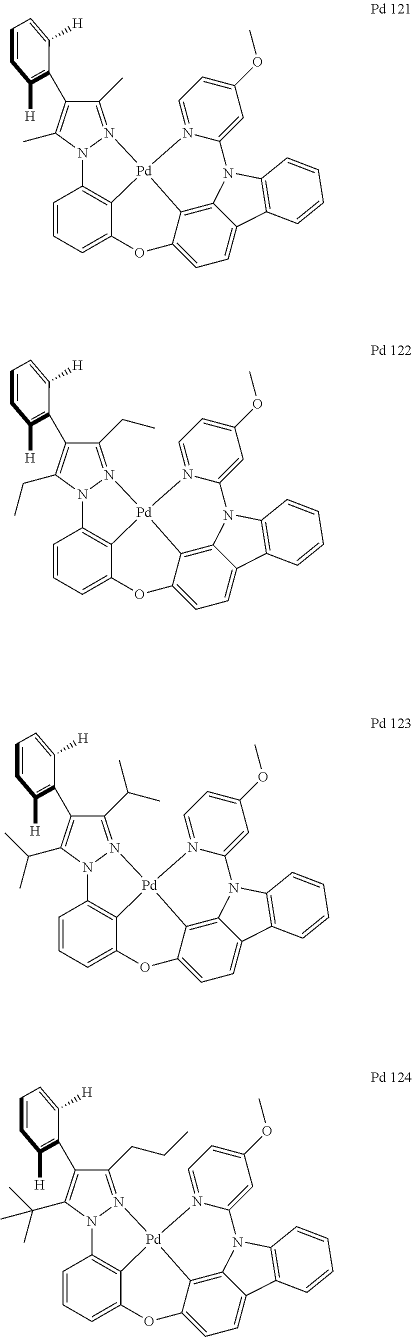

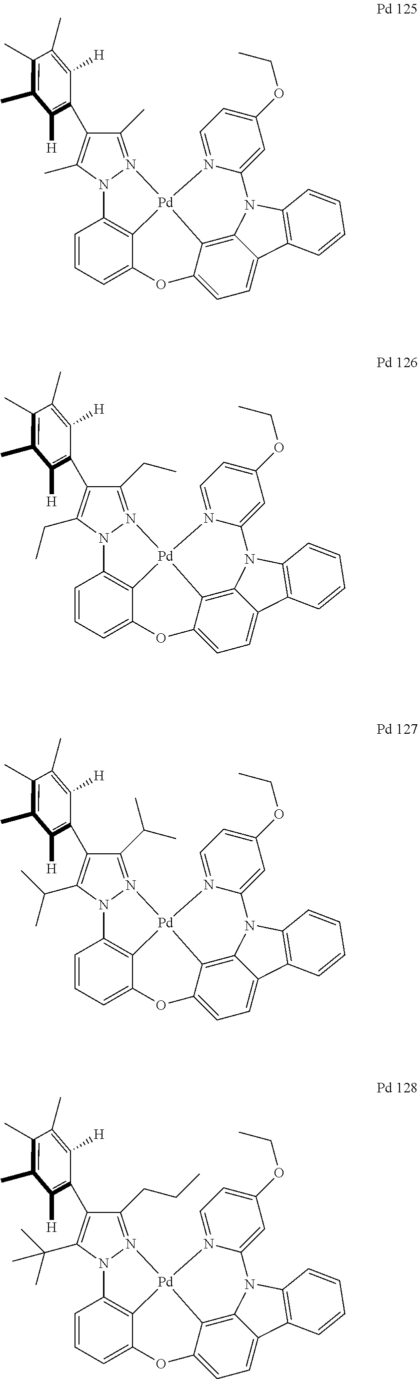

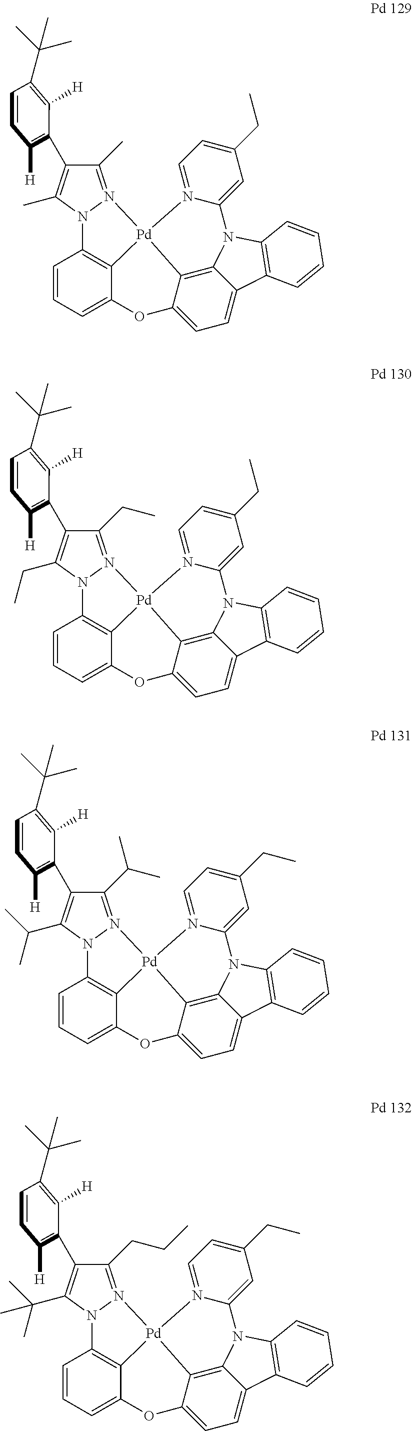

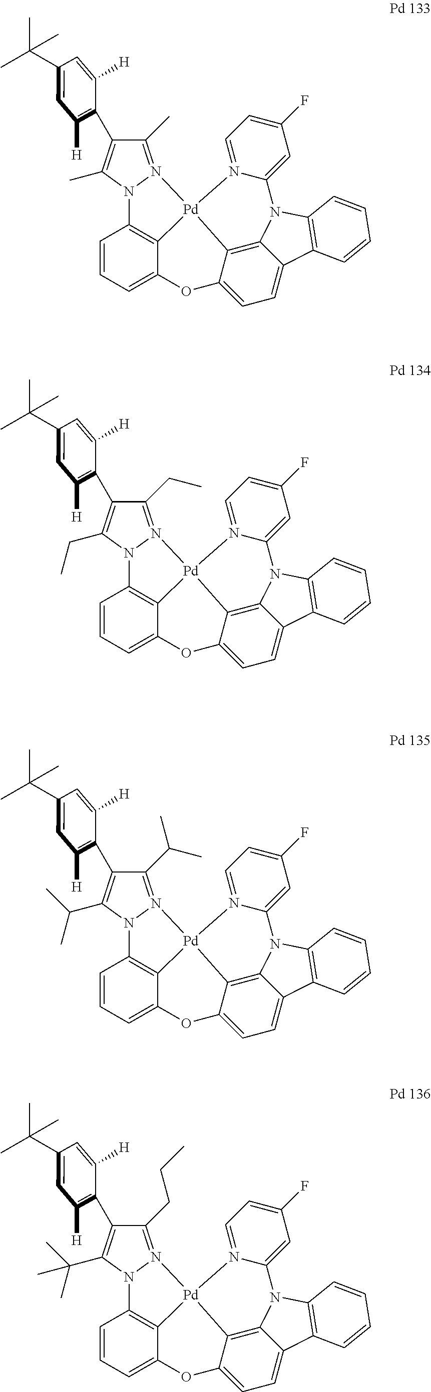

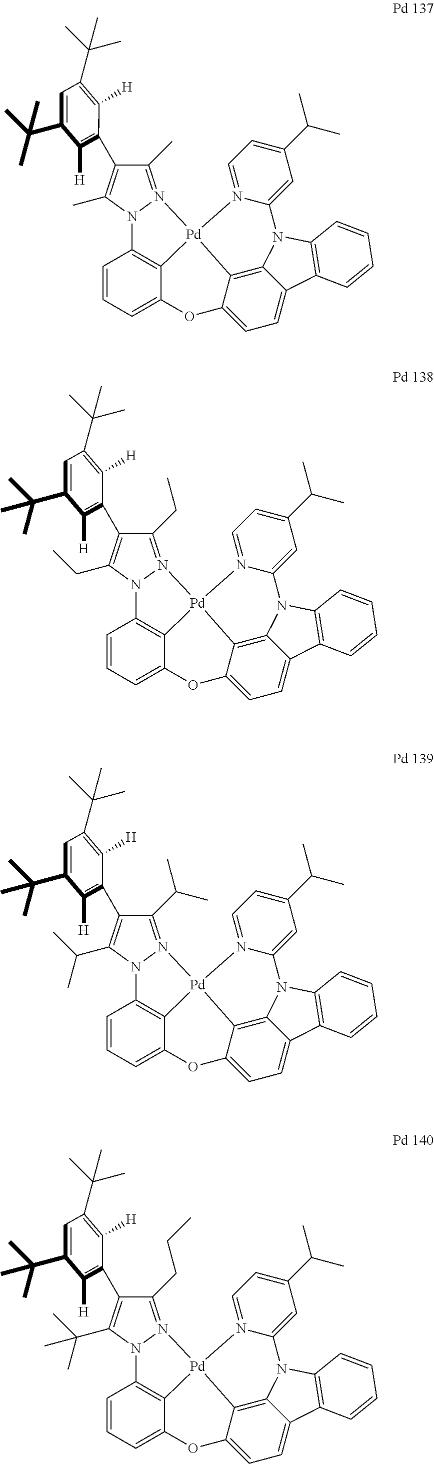

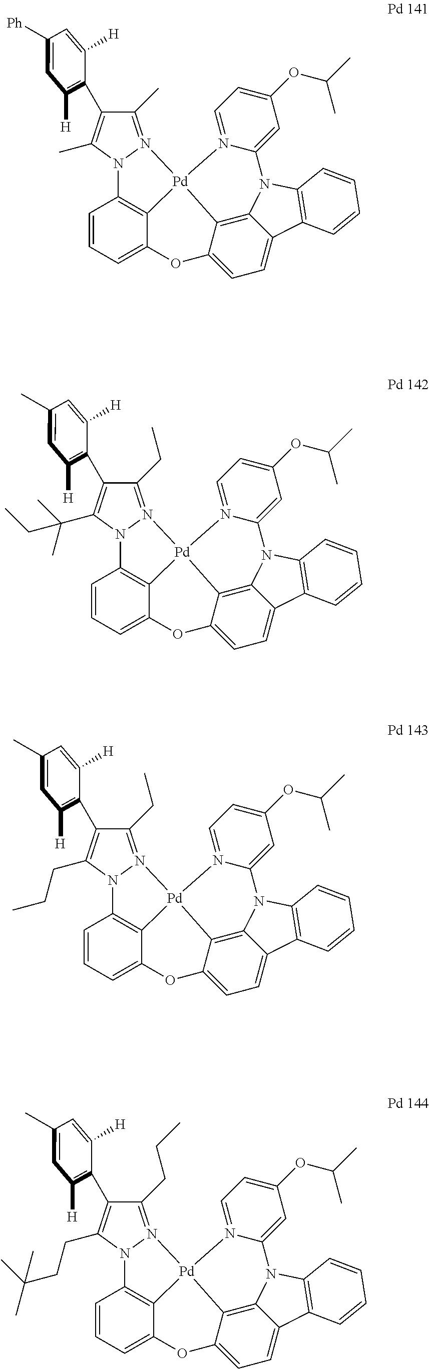

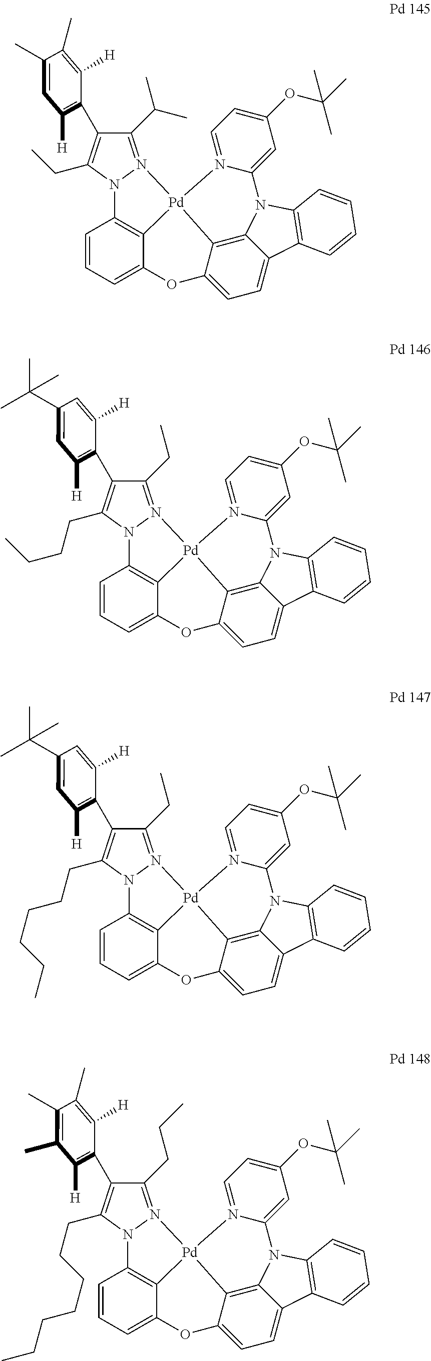

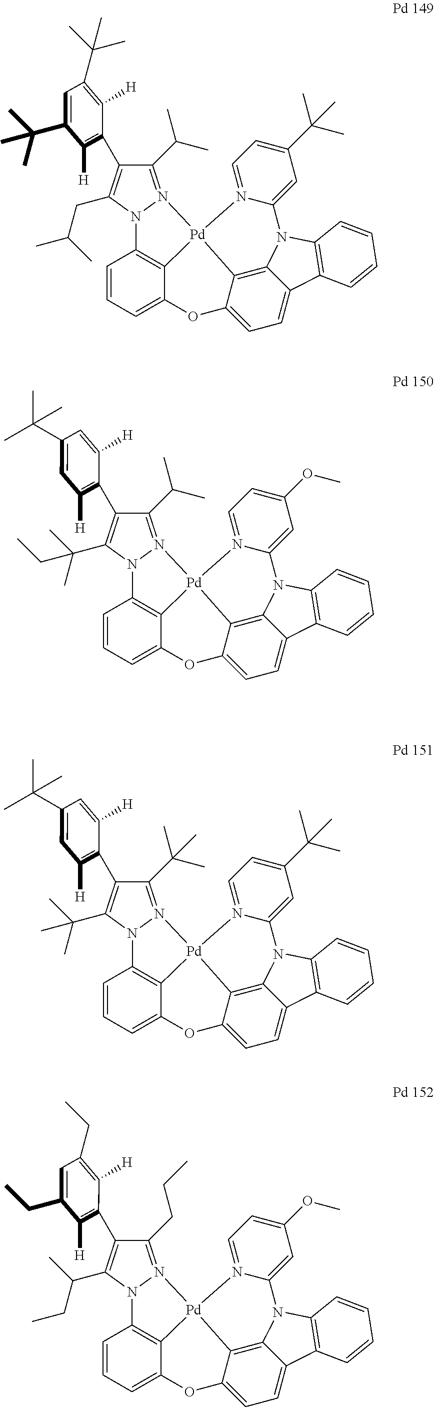

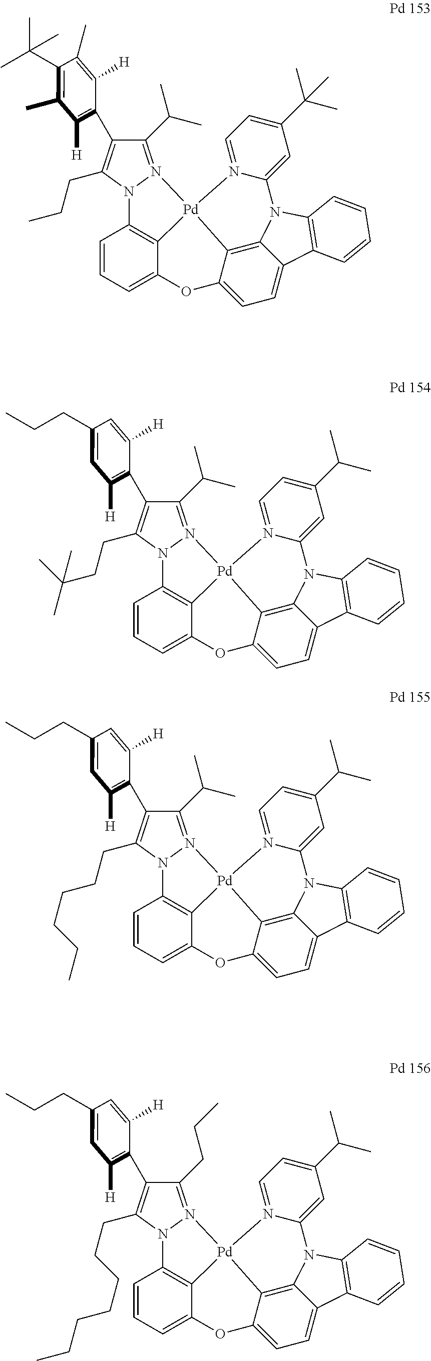

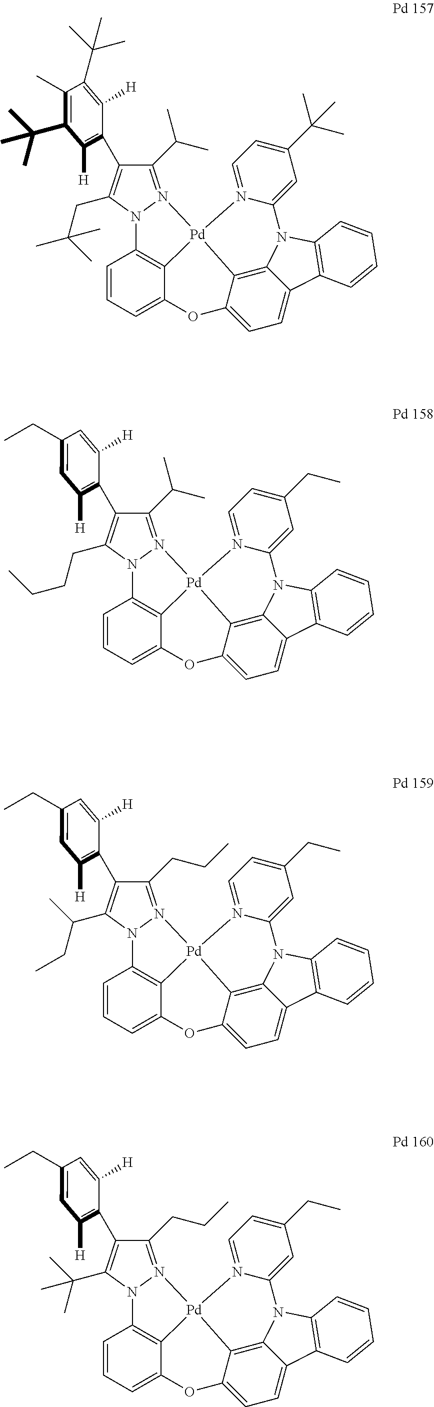

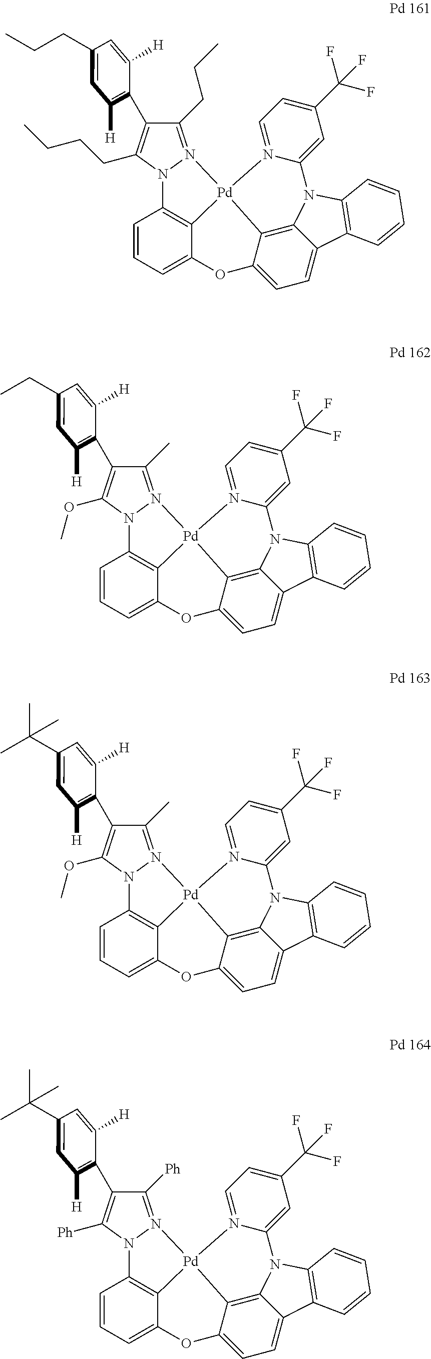

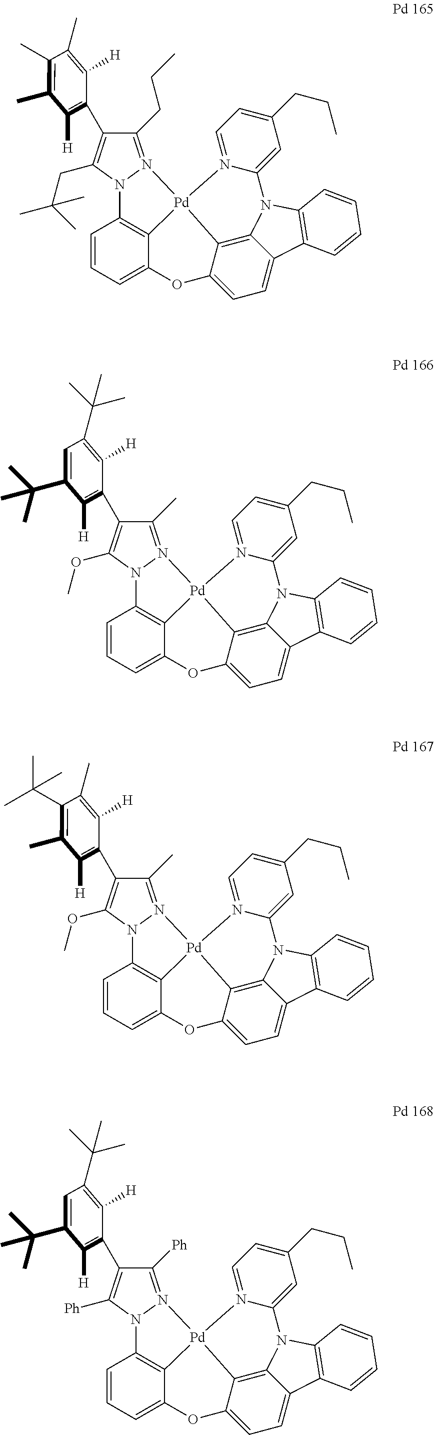

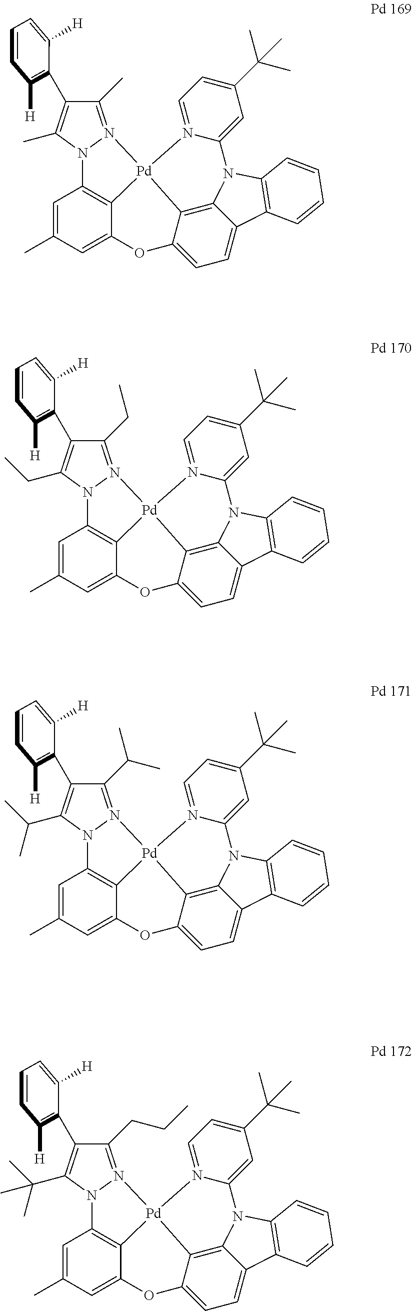

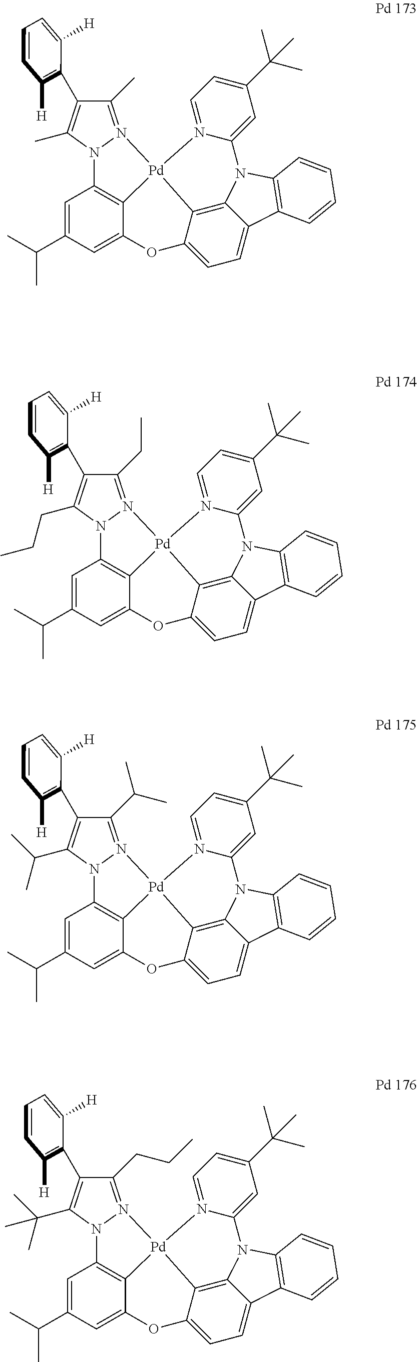

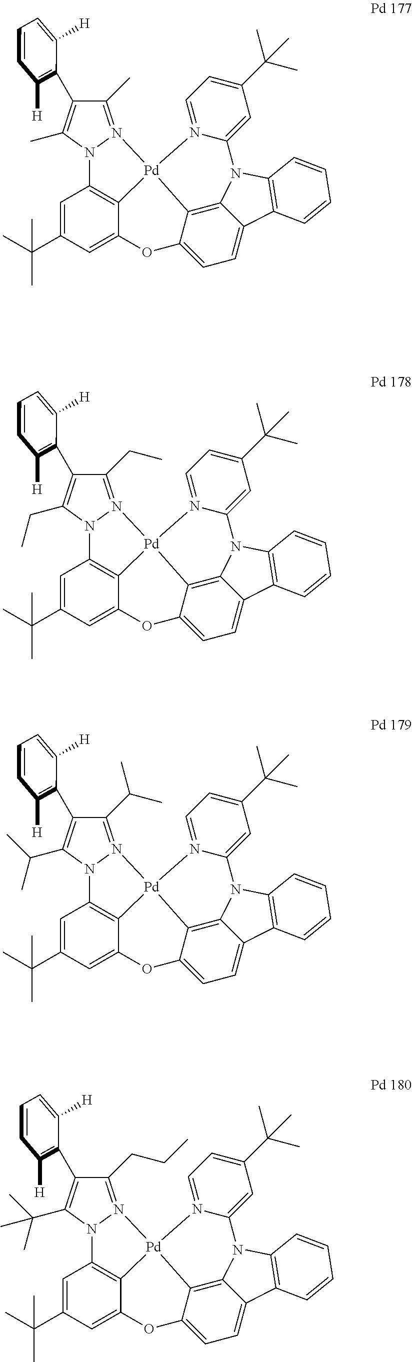

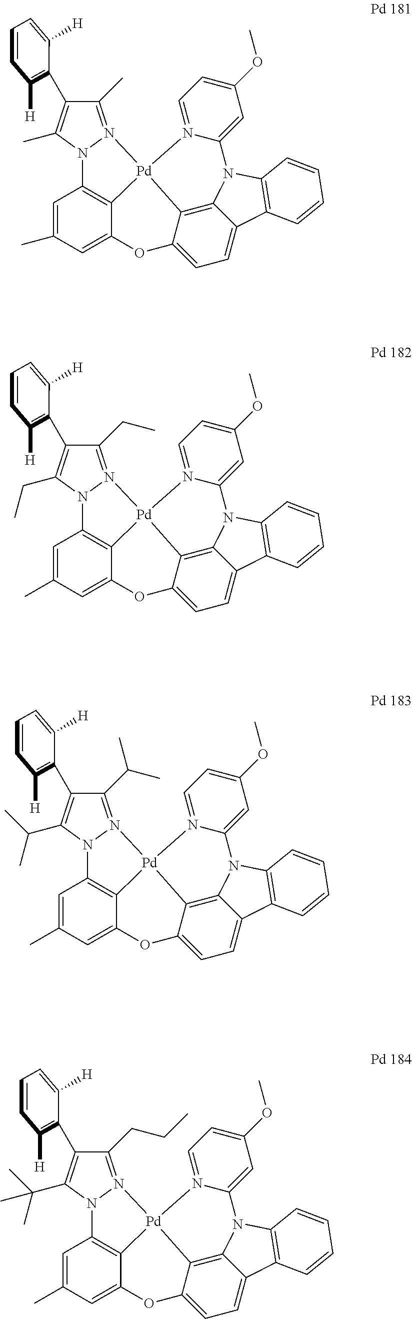

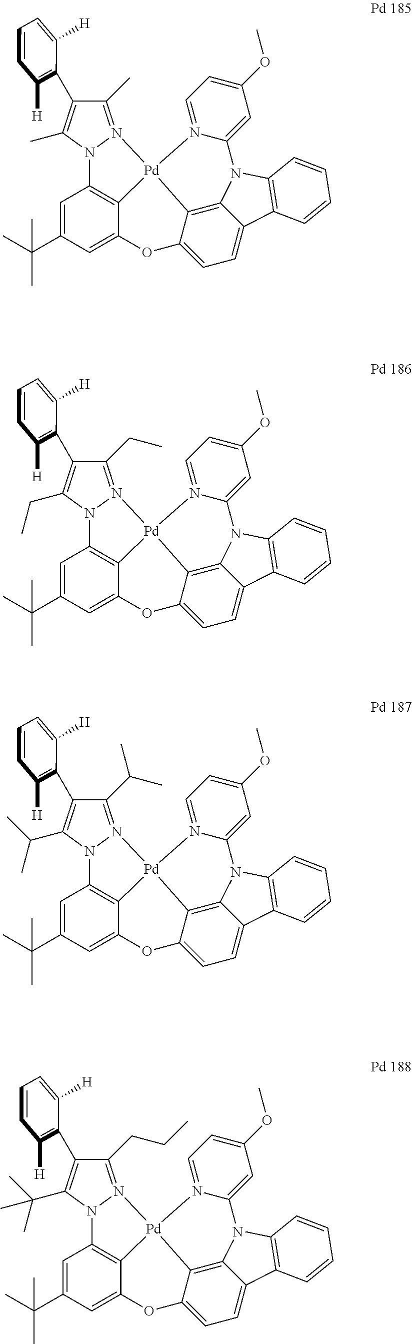

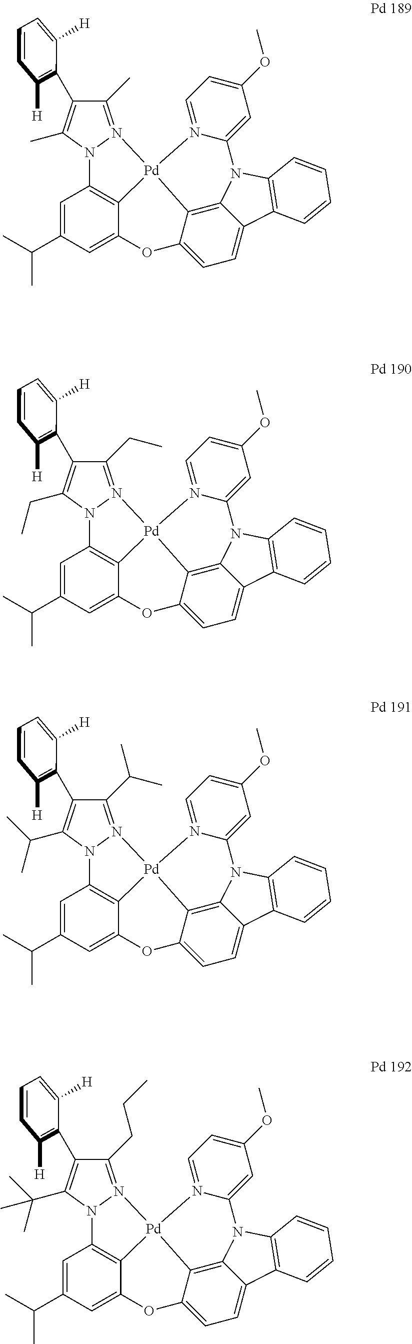

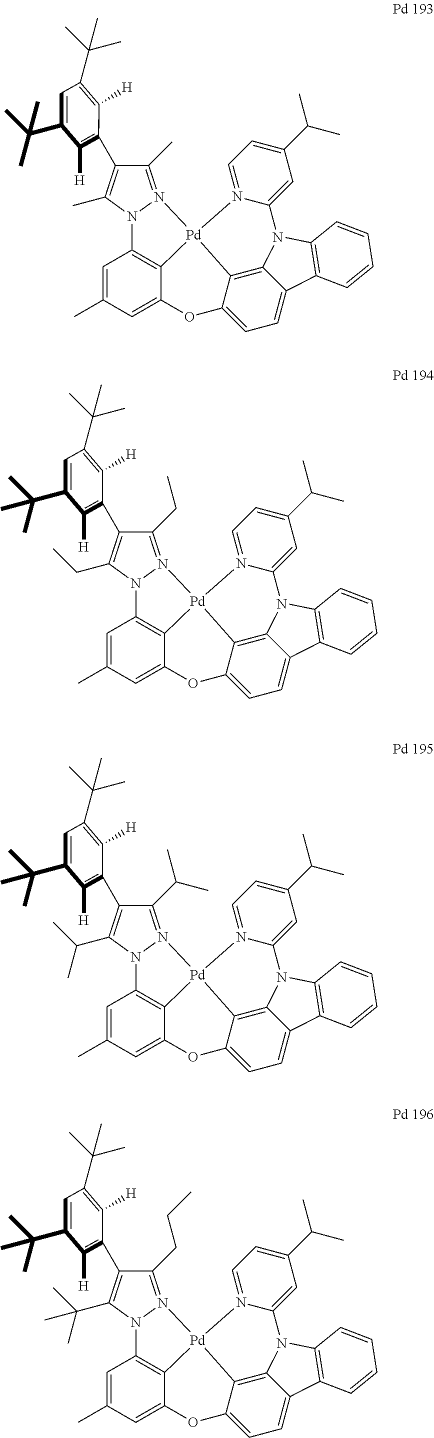

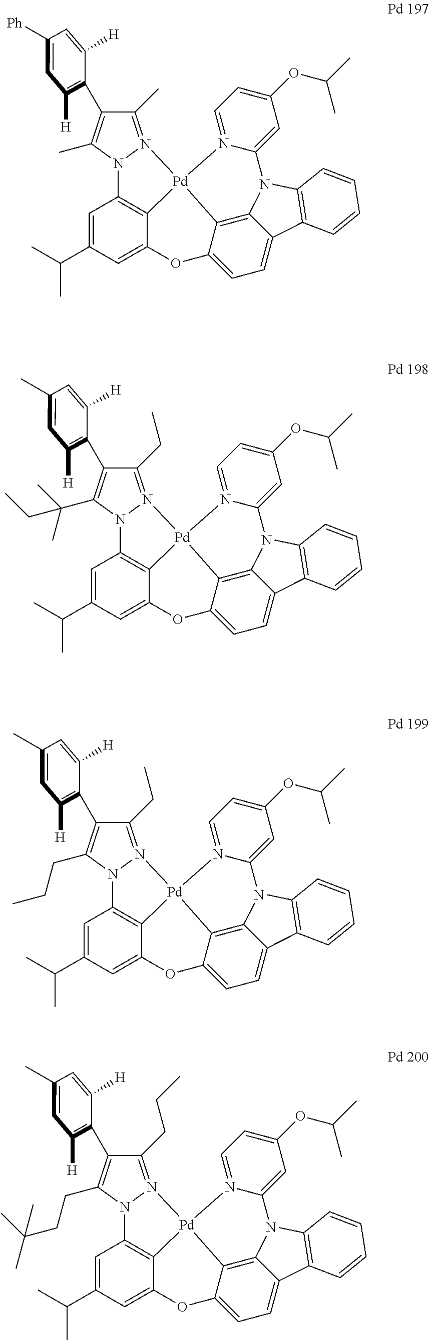

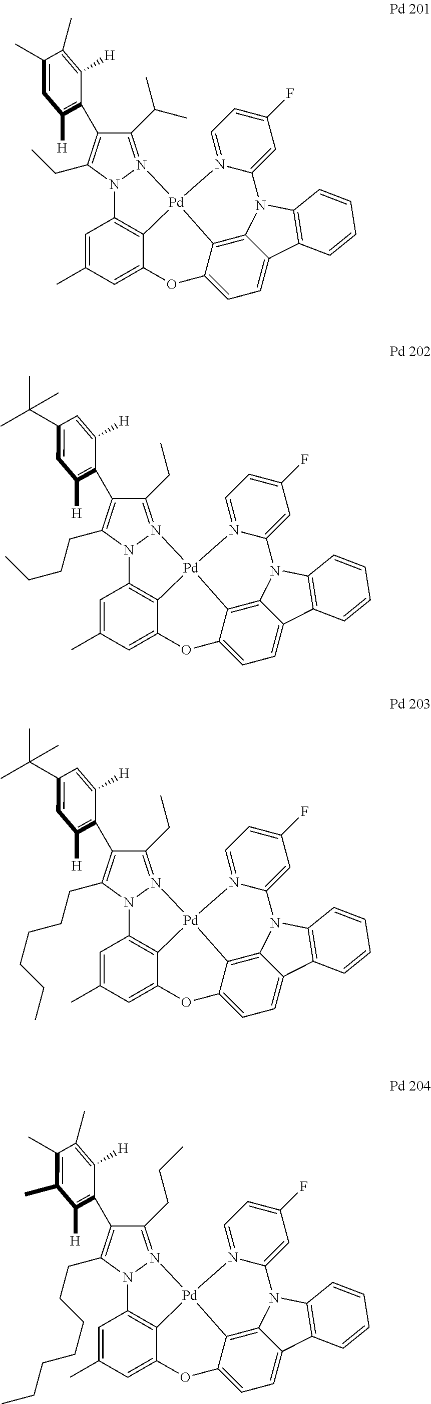

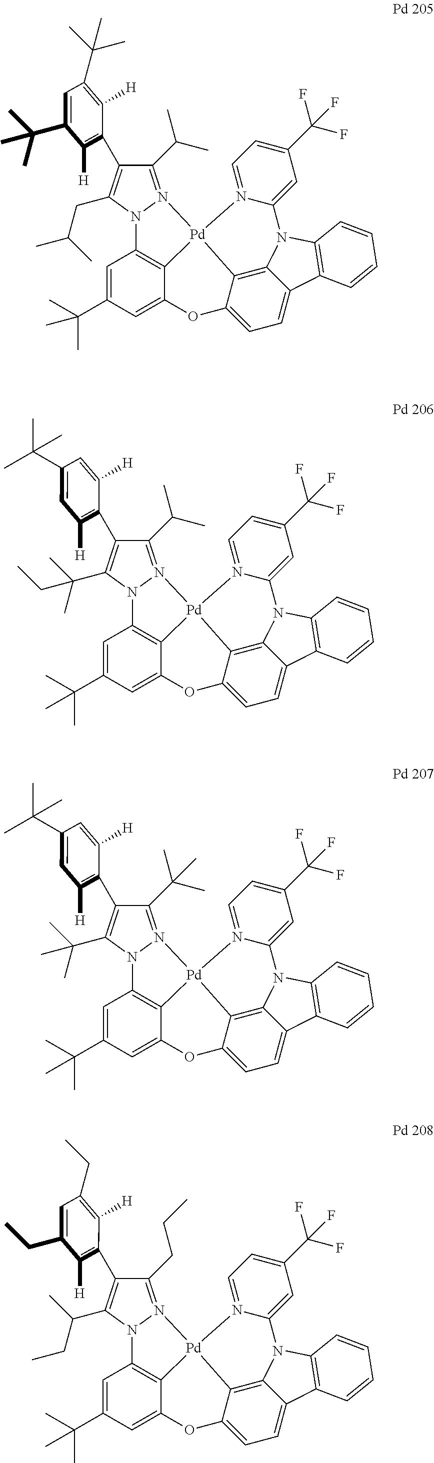

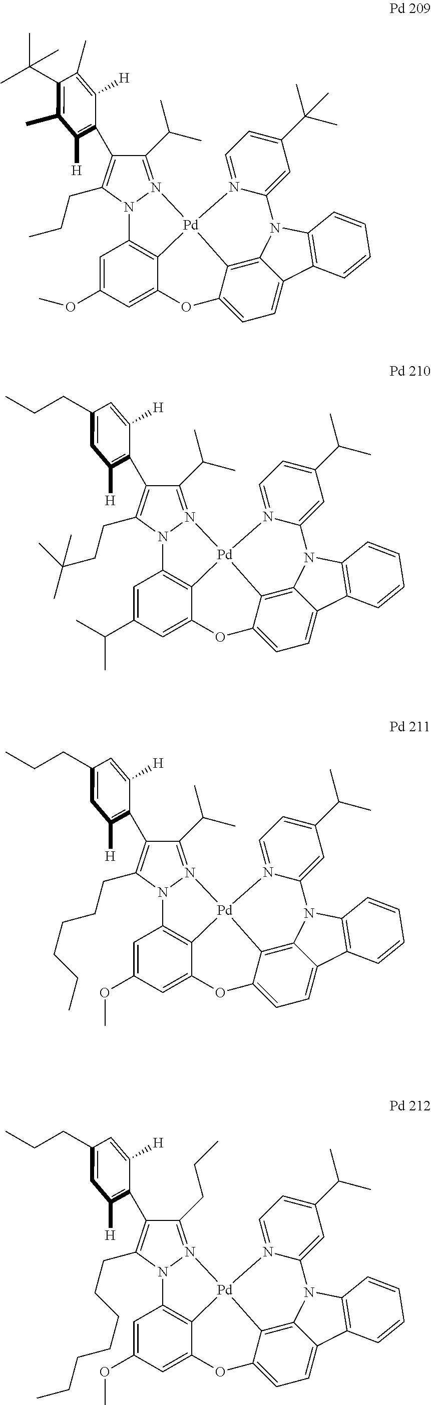

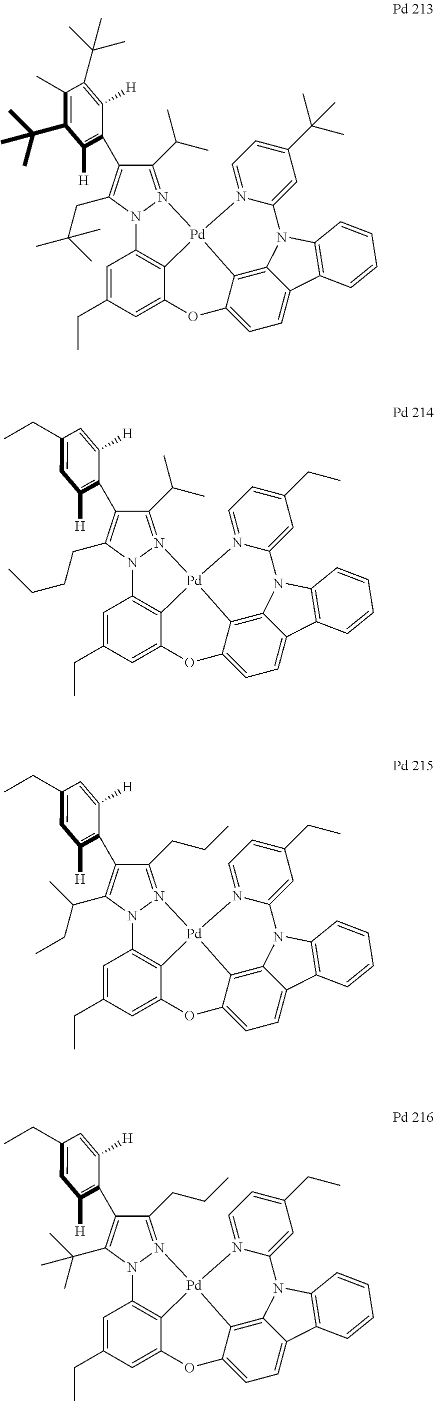

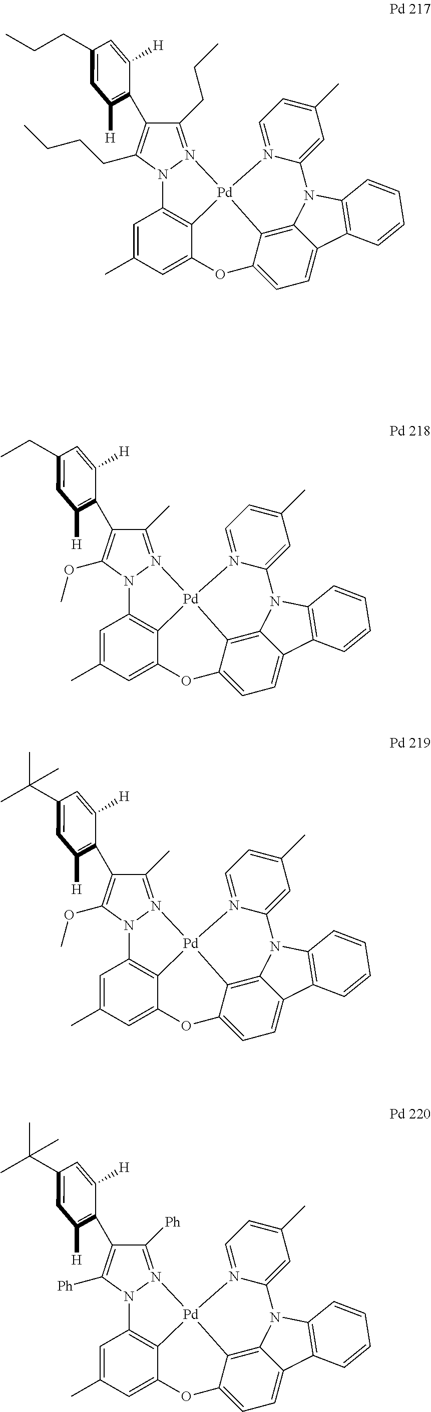

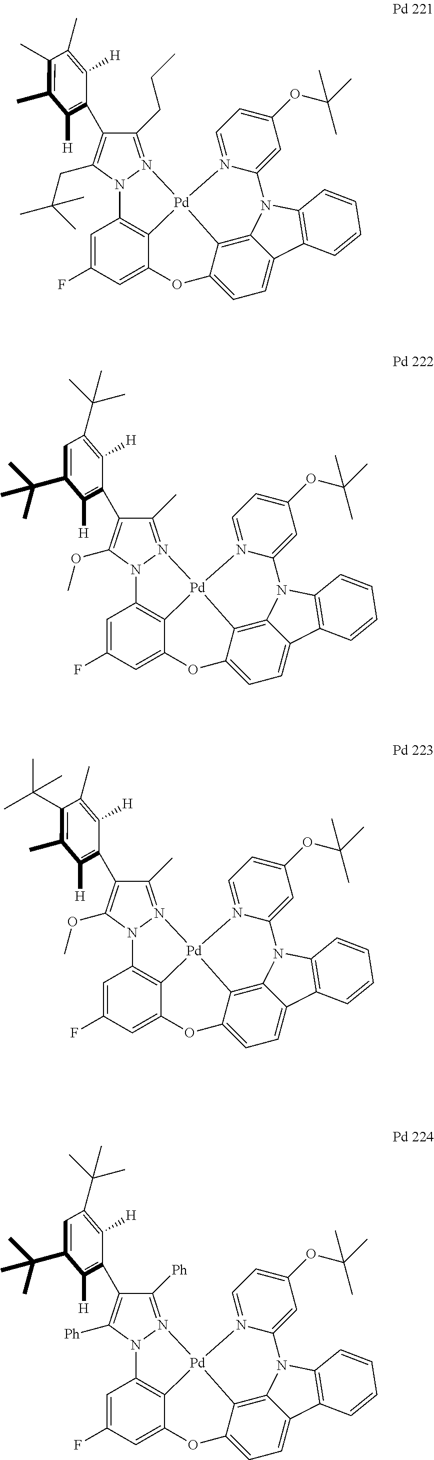

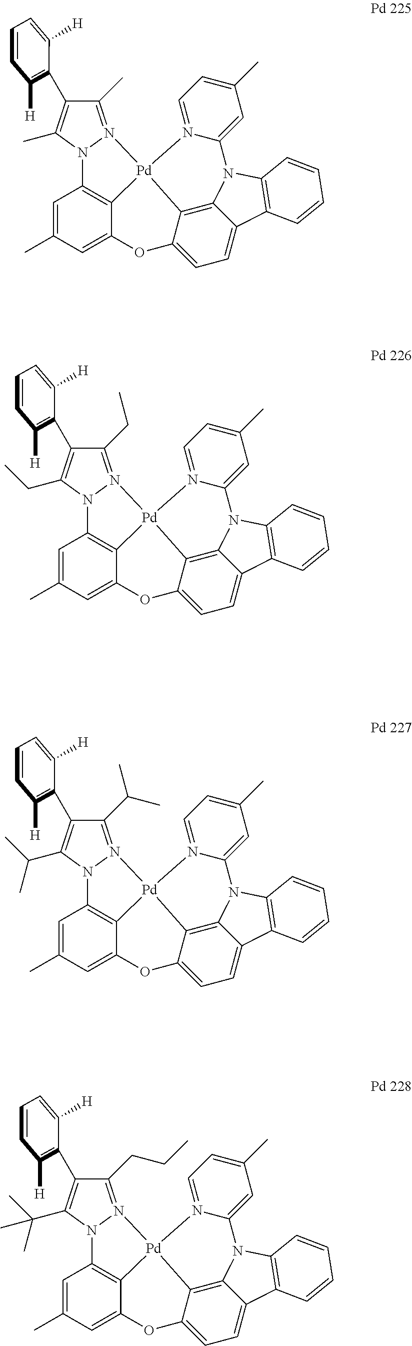

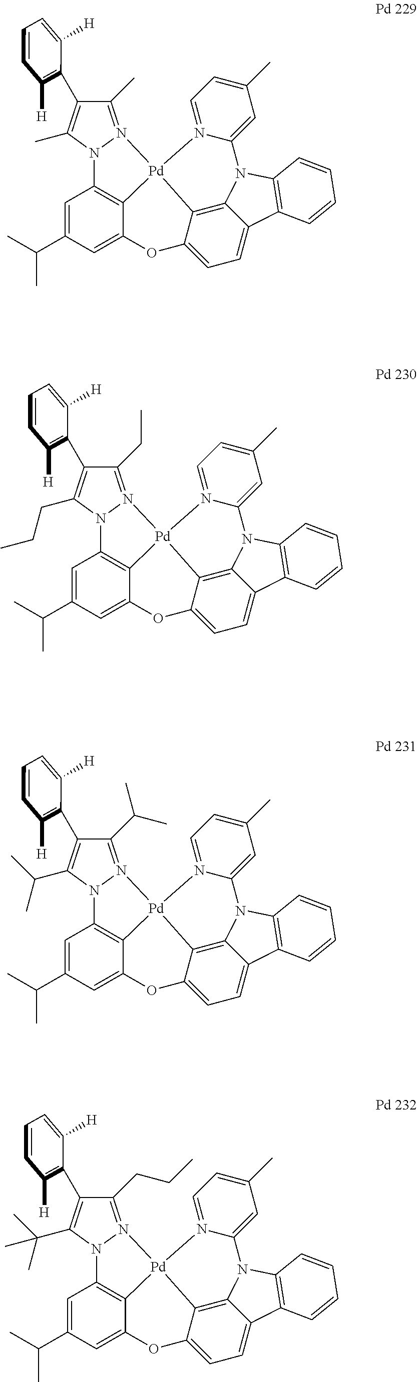

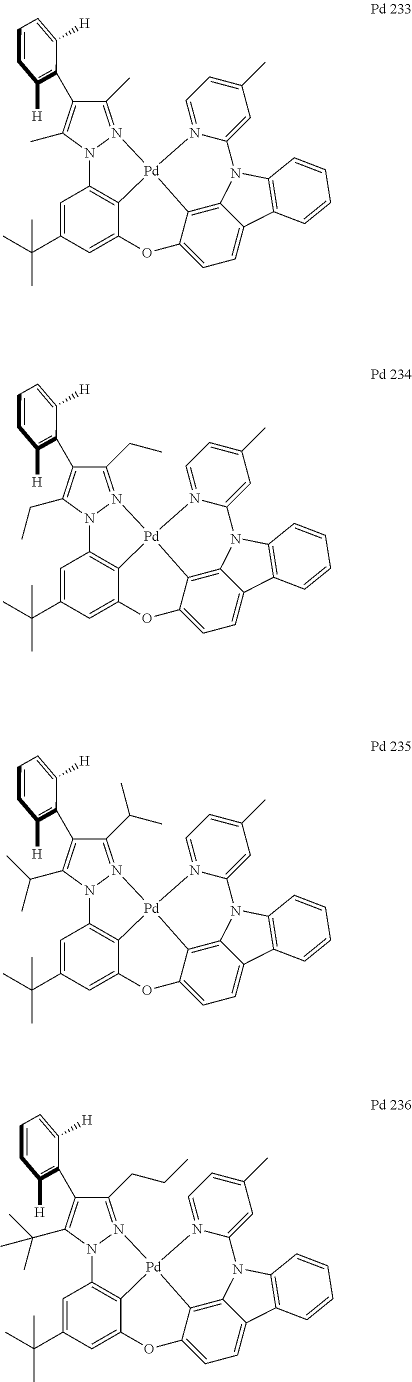

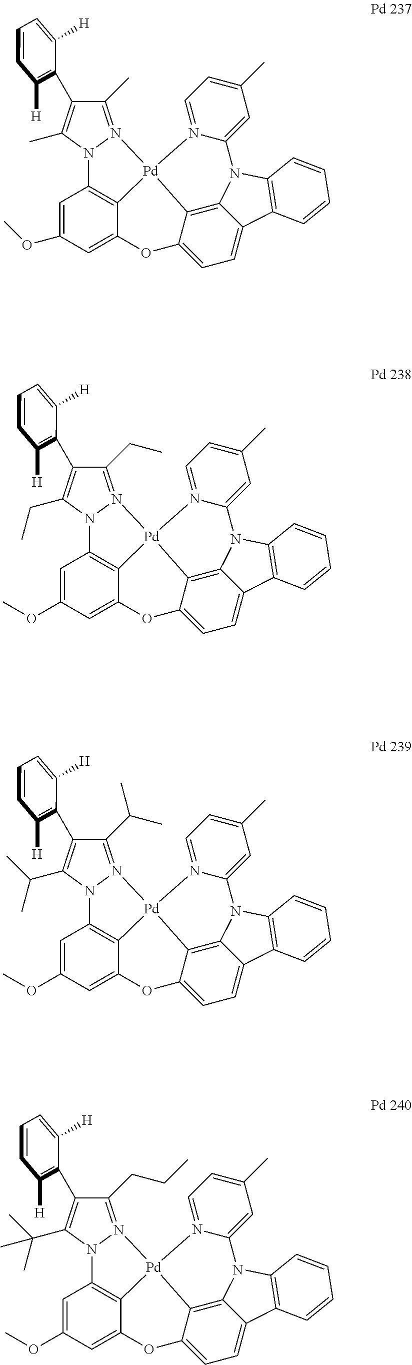

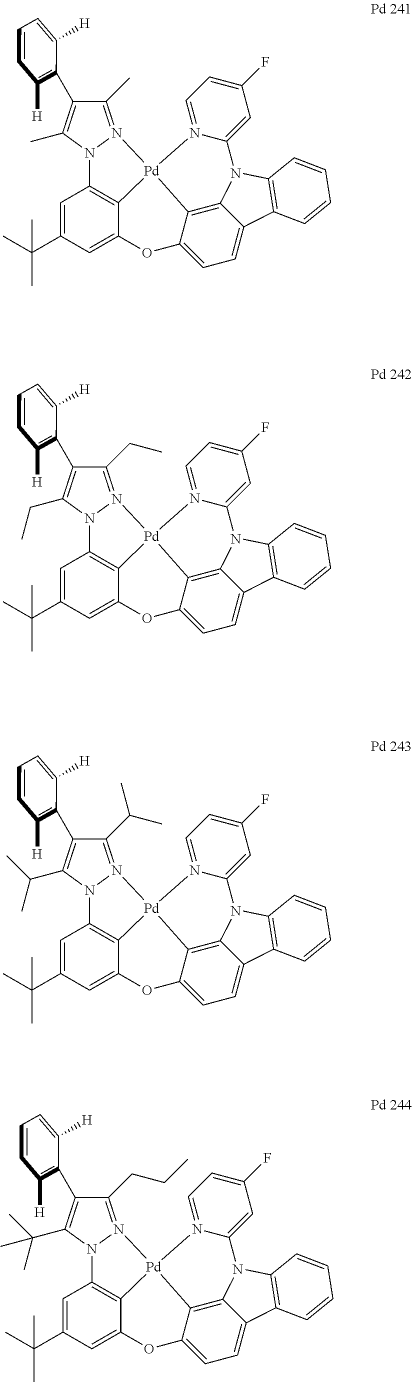

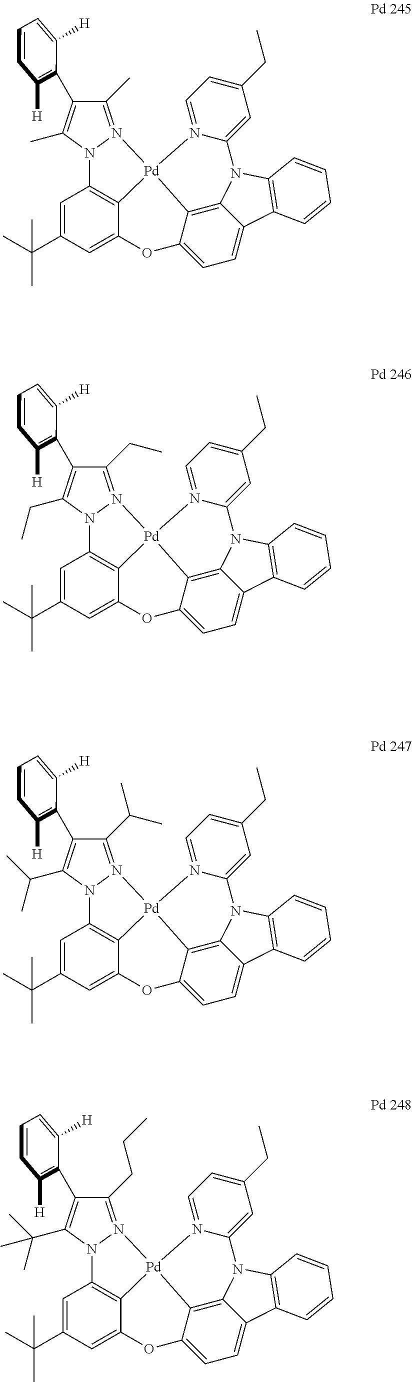

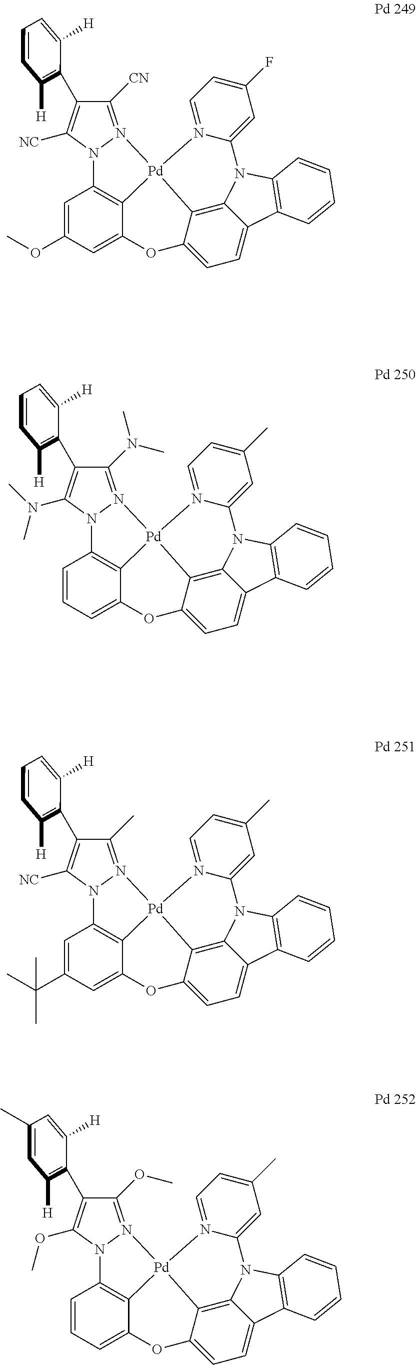

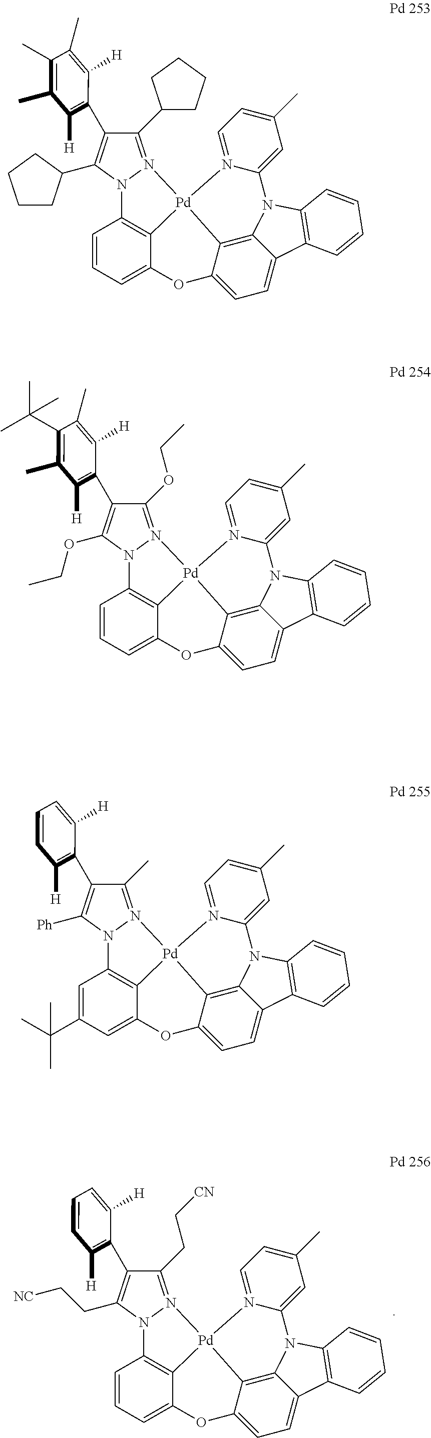

Preferably, the tetradentate cyclopalladated palladium complex comprising trisubstituted pyrazole provided by the embodiments of the present disclosure is electric neutrality.

The embodiments of the present disclosure further provide a method for preparing the tetradentate cyclopalladated palladium complex comprising trisubstituted pyrazole, wherein the complex is synthesized by the following chemical reaction steps:

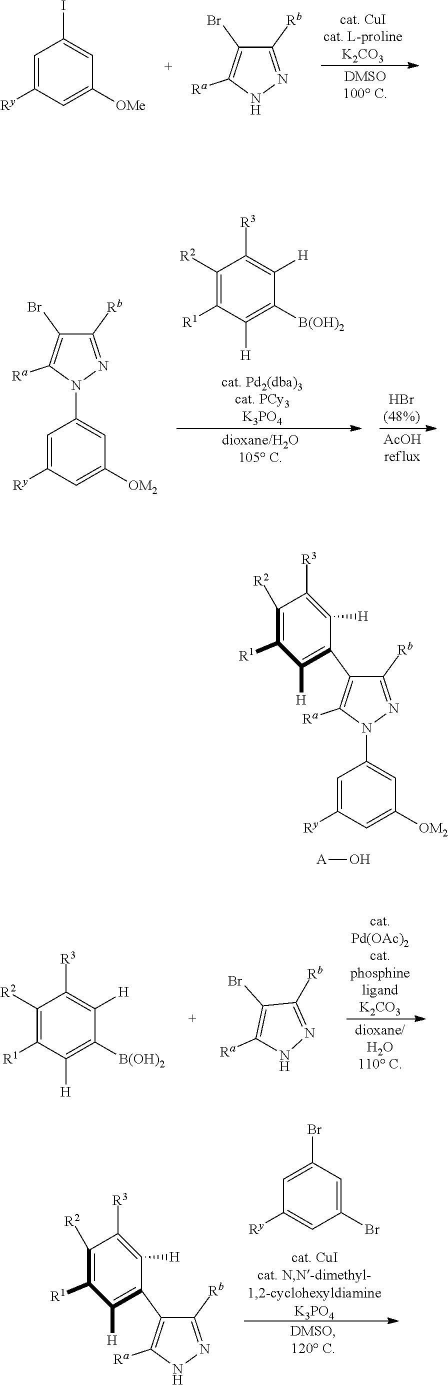

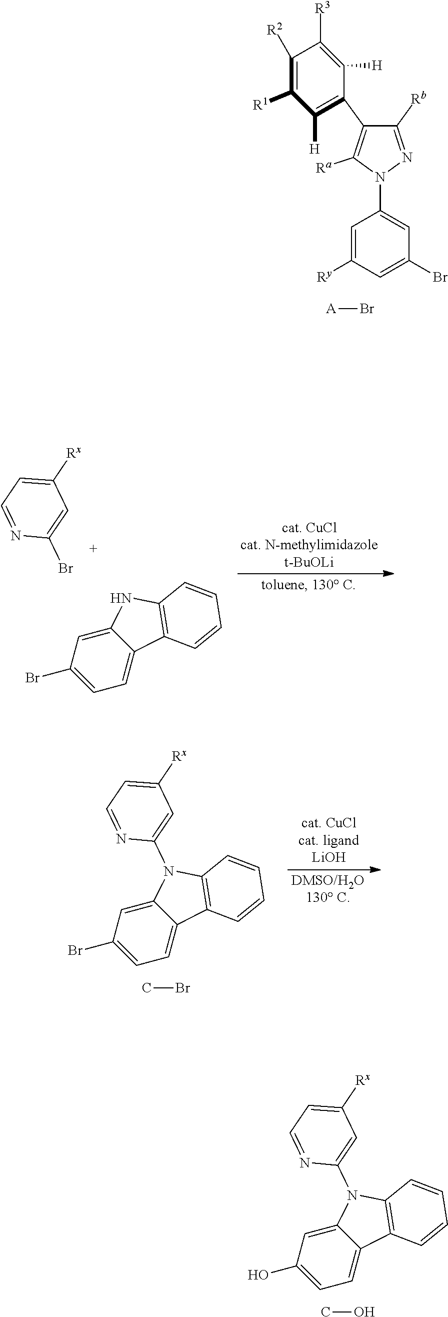

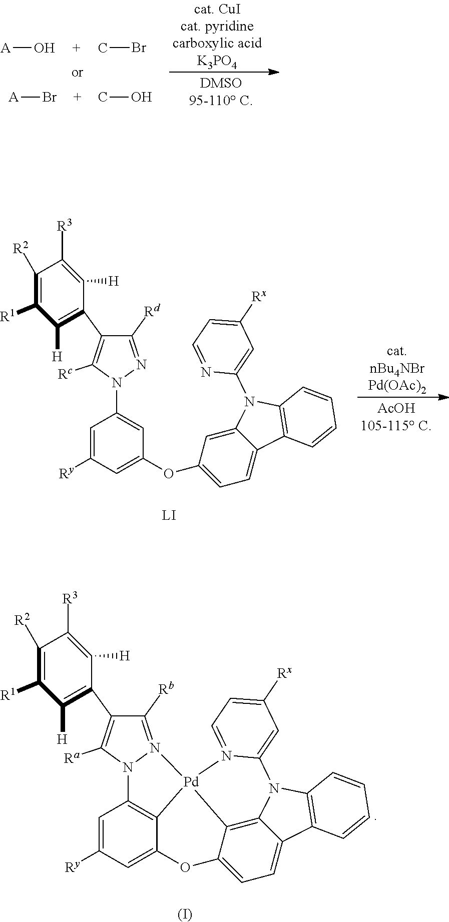

The embodiments of the present disclosure further provide use of the above-mentioned tetradentate cyclopalladated palladium complex comprising trisubstituted pyrazole in an organic electroluminescent material.

The embodiments of the present disclosure further provide an optical or electro-optical device which comprises one or more of the above-mentioned tetradentate cyclopalladated palladium complex comprising trisubstituted pyrazole.

Preferably, the optical or electro-optical device provided by the embodiment of the present disclosure comprises a light absorbing device (such as a solar device or a photosensitive device), an organic light emitting diode (OLED), a light emitting device, or a device capable of both light absorption and emission.

Preferably, the above-mentioned tetradentate cyclopalladated palladium complex comprising trisubstituted pyrazole has 100% of internal quantum efficiency in the optical or electro-optical device provided by the embodiments of the present disclosure.

The embodiments of the present disclosure further provide an OLED device, and a luminescent material or a host material in the OLED device comprises one or more of the above-mentioned tetradentate cyclopalladated palladium complex comprising trisubstituted pyrazole. The complex provided by the embodiments of the present disclosure can either be used as the host material of the OLED device, for example, applied to a full-color display; or applied to luminescent materials for the OLED device, such as a light emitting device and a display, etc.

Compared with the prior art, the present disclosure provides a series of trisubstituted pyrazole based blue phosphorescent materials of tetradentate cyclopalladated palladium complexes, and the materials may be a delayed fluorescent and/or phosphorescent emitter. The complex provided by the embodiments of the present disclosure has the following characteristics: firstly, the thermal stability the molecule is greatly improved by introducing phenyl in the 4-position of the pyrazole, and the thermal decomposition temperature is above 330° C., which is much higher than the thermal evaporation temperature of the material during the device manufacturing (generally not higher than 300° C.), and is conducive to the commercial application of the material; secondly, by introducing a larger steric hindrance substituent other than a hydrogen atom in the 3,5-position of pyrazole, the conjugate between a pyrazole ring and a 4-position benzene ring thereof can be effectively reduced, so that the whole luminescent molecule has a higher lowest triplet excited state energy, which makes it have blue light emission; at the same time, the rigidity of the molecule can be enhanced, which can effectively reduce the energy consumed by the vibration of the molecule, and the quantum efficiency of the luminescent material can be improved; and thirdly, by controlling the positions and types of substituents on the pyridine ring, the emitted light has a narrow emission spectrum, and the maximum wavelength of the emitted light is between 430 and 450 nm, and the complex is a deep blue phosphorescent luminescent material. Therefore, such phosphorescent materials have great application prospects in the field of blue light, and especially deep blue phosphorescent materials. This design provides a new way for the development of blue and deep blue phosphorescent materials, and is of great significance for the development and application of the deep blue phosphorescent materials.

### BRIEF DESCRIPTION OF THE DRAWINGS

FIG. 1 shows the emission spectrum of the complex Pd1 in dichloromethane solution and at room temperature;

FIG. 2 shows the original spectrum of thermogravimetric analysis (TGA) curve of the complex Pd1;

FIG. 3 shows the emission spectrum of the complex Pd113 in dichloromethane solution and at room temperature;

FIG. 4 shows the original spectrum of thermogravimetric analysis (TGA) curve of the complex Pd113;

FIG. 5 shows the emission spectrum of the complex Pd229 in dichloromethane solution and at room temperature;

FIG. 6 shows the original spectrum of thermogravimetric analysis (TGA) curve of the complex Pd229;

FIG. 7 shows the emission spectrum of the complex Pd233 in dichloromethane solution and at room temperature;

FIG. 8 shows the original spectrum of thermogravimetric analysis (TGA) curve of the complex Pd233.

### DETAILED DESCRIPTION OF THE EXEMPLARY EMBODIMENTS

The present disclosure can be understood more readily by reference to the following detailed description and the examples included therein. Before the complexes, devices, and/or methods of the disclosure are disclosed and described, it is to be understood that they are not limited to specific synthetic methods unless otherwise specified, or to specific reagents unless otherwise specified, as such can, of course, vary. It is also to be understood that the term as used herein is for the purpose of describing particular aspects only and is not intended to be limiting. Although any methods and materials similar or equivalent to those described in the disclosure can be used in practice or testing, example methods and materials are described hereinafter.

As used in the specification and the appended claims, the singular forms “a”, “an”, and “the” of the terms as used herein include plural referents unless the context clearly dictates otherwise. Thus, for example, reference to “a component” includes mixtures of two or more components.

The term “optional” or “optionally” as used herein means that the subsequently described event or circumstance can or cannot occur, and that the description includes instances where said event or circumstance occurs and instances where it does not.

Disclosed are the components to be used to prepare the compositions described in the disclosure as well as the compositions themselves to be used in the methods disclosed in the disclosure. These and other materials are disclosed in the disclosure, and it is to be understood that when combinations, subsets, interactions, groups, etc. of these materials are disclosed that while specific reference of each various individual and collective combinations and permutation of these complexes cannot be explicitly disclosed, each is specifically contemplated and described in the disclosure. For example, if a specific complex is disclosed and discussed and a number of modifications that can be made to a number of molecules including the complexes are discussed, each and every combination and permutation of the complex are specifically contemplated and the modifications may be possibly conducted unless specifically indicated to the contrary. Thus, if a class of molecules A, B, and C are disclosed as well as a class of molecules D, E, and F and an example of a combination molecule A-D is disclosed, then even if each is not individually recited, each of the individually and collectively contemplated meaning combinations A-E, A-F, B-D, B-E, B—F, C-D, C-E, and C—F are considered. Likewise, any subset or combination of these is also disclosed. Thus, for example, sub-groups A-E, B-F, and C-E would be considered to be disclosed. This concept applies to all aspects of the disclosure including, but not limited to, steps in methods of preparing and using the compositions. Thus, if there are a variety of additional steps that can be performed, it is to be understood that each of these additional steps can be performed with any specific embodiment or combination of embodiments of the methods.

A linking atom as used herein can connect two groups, for example, N and C groups. The linking atom can optionally, if valency permits, have other chemical moieties attached. For example, in one aspect, an oxygen would not have any other chemical groups attached as the valency is satisfied once it is bonded to two atoms (e.g., N or C). On contrary, when carbon is the linking atom, two additional chemical moieties can be attached to the carbon atom. Suitable chemical moieties include, but are not limited to, hydrogen, hydroxy, alkyl, alkoxy, ═O, halogen, nitro, amine, amide, thiol, aryl, heteroaryl, cycloalkyl, and heterocyclyl.

The term “cyclic structure” or the like terms as used herein refer to any cyclic chemical structure which includes, but is not limited to, aryl, heteroaryl, cycloalkyl, cycloalkenyl, heterocyclyl, carbene, and N-heterocyclic carbene.

The term “substituted” as used herein is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For the objects of the disclosure, the heteroatoms, such as nitrogen, can have hydrogen substituents and/or any permissible substituents of the organic compounds described in the disclosure which satisfy the valences of the heteroatoms. This disclosure is not intended to be limited in any manner by the permissible substituents of the organic compounds. Likewise, the terms “substitution” or “substituted with” include the implicit proviso that such substitution is in accordance with permitted valence of the substituted atom and the substituent, and that the substitution results in a stable compound, e.g., a compound that does not spontaneously undergo transformation (such as by rearrangement, cyclization, elimination, or the like). It is also contemplated that, in certain aspects, unless expressly indicated to the contrary, individual substituents can be further optionally substituted (i.e., further substituted or unsubstituted).

In defining various terms, “R¹”, “R²”, “R³” and “R⁴” are used as generic symbols to represent various specific substituents in the disclosure. These symbols can be any substituent, not limited to those disclosed in the disclosure, and when they are defined to be certain substituents in one instance, they can, in another instance, be defined as some other substituents.

The term “alkyl” as used herein is a branched or unbranched saturated hydrocarbon of 1 to 24 carbon atoms, such as methyl, ethyl, n-propyl, isopropyl, n-butyl, isobutyl, sec-butyl, tert-butyl, n-pentyl, isopentyl, sec-pentyl, neopentyl, hexyl, heptyl, octyl, nonyl, decyl, dodecyl, tetradecyl, hexadecyl, eicosyl, tetracosyl, and the like. The alkyl can be cyclic or acyclic. The alkyl may be branched or unbranched. The alkyl can also be substituted or unsubstituted. For example, the alkyl can be substituted with one or more groups including, but not limited to, alkyl, cycloalkyl, alkoxy, amino, ether, halogen, hydroxy, nitro, silyl, sulfo-oxo, or thiol, as described herein. A “lower alkyl” group is an alkyl comprising from 1 to 6 (e.g., from one to four) carbon atoms.

Throughout the specification, “alkyl” is generally used to refer to both unsubstituted alkyl and substituted alkyl; however, substituted alkyl is also specifically referred to herein by identifying the specific substituent(s) on the alkyl. For example, the term “halogenated alkyl” or “haloalkyl” specifically refers to an alkyl that is substituted with one or more halogens, e.g., fluorine, chlorine, bromine, or iodine. The term “alkoxyalkyl” specifically refers to an alkyl that is substituted with one or more alkoxys, as described below. The term “alkylamino” specifically refers to an alkyl that is substituted with one or more aminos as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described in the disclosure. That is, while a term such as “cycloalkyl” refers to both unsubstituted and substituted cycloalkyl moieties, the substituted moieties can, in addition, be specifically identified in the disclosure; for example, a specific substituted cycloalkyl can be referred to as, e.g., an “alkylcycloalkyl”. Similarly, a substituted alkoxy can be specifically referred to as, e.g., a “halogenated alkoxy”, and a specific substituted alkenyl can be, e.g., an “enol” and the like. Likewise, the practice of using a general term, such as “cycloalkyl”, and a specific term, such as “alkylcycloalkyl”, is not meant to imply that the general term does not also include the specific term.

The term “cycloalkyl” as used herein is a non-aromatic carbon-based ring composed of at least three carbon atoms. Examples of cycloalkyl include, but are not limited to, cyclopropyl, cyclobutyl, cyclopentyl, cyclohexyl, cyclononyl, and the like. The term “heterocycloalkyl” is a type of cycloalkyl as defined above, and is included within the meaning of the term “cycloalkyl”, where at least one of the carbon atoms of the ring is replaced with a heteroatom such as, but not limited to, nitrogen, oxygen, sulfur, or phosphorus. The cycloalkyl and heterocycloalkyl can be substituted or unsubstituted. The cycloalkyl and heterocycloalkyl can be substituted with one or more groups including, but not limited to, alkyl, cycloalkyl, alkoxy, amino, ether, halide, hydroxy, nitro, silyl, sulfo-oxo, or thiol as described herein.

The terms “alkoxy” and “alkoxyl group” as used herein, to refer to an alkyl or cycloalkyl bonded through an ether linkage; that is, an “alkoxy” can be defined as —OR¹ where R¹ is alkyl or cycloalkyl as defined above. “Alkoxy” also includes polymers of the alkoxy as just described; that is, an alkoxy can be a polyether such as —OR¹—OR² or —OR¹—(OR²)a-OR³, where “a” is an integer of from 1 to 200 and R¹, R², and R³ each are alkyl, cycloalkyl independently, or a combination thereof.

The term “alkenyl” as used herein is a hydrocarbyl of from 2 to 24 carbon atoms with a structural formula containing at least one carbon-carbon double bond. Asymmetric structures such as (R¹R²)C═C(R³R⁴) are intended to include both E and Z isomers. This can be presumed in the structural formulas of the disclosure, an asymmetric alkene is present, or it can be explicitly indicated by the bond symbol C═C. The alkenyl can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bound, i.e., C═C. Examples of cycloalkenyl include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl as defined above, and is included within the meaning of the term “cycloalkenyl”, where at least one of the carbon atoms of the ring is replaced with a heteroatom such as, but not limited to, nitrogen, oxygen, sulfur, or phosphorus. The cycloalkenyl and heterocycloalkenyl can be substituted or unsubstituted. The cycloalkenyl and heterocycloalkenyl can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxy, ketone, azide, nitro, silyl, sulfo-oxo, or thiol, as described herein.

The term “alkynyl” as used herein is a hydrocarbon of 2 to 24 carbon atoms with a structural formula comprising at least one carbon-carbon triple bond. The alkynyl can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl include, but are not limited to, cycloheptynyl, cyclooctynyl, cyclononynyl, and the like. The term “heterocycloalkynyl” is a type of cycloalkenyl as defined above, and is included within the meaning of the term “cycloalkynyl” where at least one of the carbon atoms of the ring is replaced with a heteroatom such as, but not limited to, nitrogen, oxygen, sulfur, or phosphorus. The cycloalkynyl and heterocycloalkynyl can be substituted or unsubstituted. The cycloalkynyl and heterocycloalkynyl can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxy, ketone, azide, nitro, silyl, sulfo-oxo, or thiol, as described herein.

The term “aryl” as used herein is a group that contains any carbon-based aromatic group including, but not limited to, benzene, naphthalene, phenyl, biphenyl, phenoxybenzene, and the like. The term “aryl” also includes “heteroaryl”, which is defined as a group comprising an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl” (which is also included in the term “aryl”) defines a group comprising an aromatic group that does not contain a heteroatom. The aryl can be substituted or unsubstituted. The aryl can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester group, ether group, halogen, hydroxy, ketone group, azide, nitro, silyl, sulfo-oxo, or sulfydryl as described herein. The term “biaryl” is a specific type of aryl and is included in the definition of “aryl”. Biaryl refers to two aryls that are bound together via a fused ring structure, as in naphthalene, or are attached via one or more carbon-carbon bonds, as in biphenyl.

The terms “amine” or “amino” as used herein are represented by the formula —NR¹R², where R¹ and R² can be, independently, hydrogen or alkyl, cycloalkyl, alkenyl, cycloalkenyl, alkynyl, cycloalkynyl, aryl, or heteroaryl.

The term “alkylamino” as used herein is represented by the formula —NH(-alkyl) where alkyl is as described herein. Representative examples include, but are not limited to, methylamino, ethylamino, propylamino, isopropylamino, butylamino, isobutylamino (s-butyl)amino, (t-butyl)amino, pentylamino, isopentylamino, (tert-pentyl)amino, hexylamino, and the like.

The term “dialkylamino” as used herein is represented by the formula —N(-alkyl)₂ where alkyl is as described herein. Representative examples include, but are not limited to, dimethylamino, diethylamino, dipropylamino, diisopropylamino, dibutylamino, diisobutylamino, di(s-butyl)amino, di(t-butyl)amino, dipentylamino group, diisopentylamino, di(tert-pentyl)amino, dihexylamino, N-ethyl-N-methylamino, N-methyl-N-propylamino, N-ethyl-N-propylamino and the like.

The term “ether” as used herein is represented by the formula R¹OR², where R¹ and R² can be, independently, an alkyl, cycloalkyl, alkenyl, cycloalkenyl, alkynyl, cycloalkynyl, aryl, or heteroary described in the disclosure. The term “polyether” as used herein is represented by the formula —(R¹O—R²O)ₐ—, where R¹ and R² can be, independently, an alkyl, cycloalkyl, alkenyl, cycloalkenyl, alkynyl, cycloalkynyl, aryl, or heteroaryl described in the disclosure, and “a” is an integer of from 1 to 500. Examples of polyether groups include polyethylene oxide, polypropylene oxide, and polybutylene oxide.

The term “halogen” as used herein refers to the halogens fluorine, chlorine, bromine, and iodine.

The term “heterocyclyl” as used herein refers to single and multi-cyclic non-aromatic ring systems and “heteroaryl” as used herein refers to single and multi-cyclic aromatic ring systems: in which at least one of the ring members is other than carbon. The terms includes azetidine, dioxane, furan, imidazole, isothiazole, isoxazole, morpholine, oxazole, oxazole including 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine including 1,2,4,5-tetrazine, tetrazole including 1,2,3,4-tetrazole and 1,2,4,5-tetrazole, thiadiazole including 1,2,3-thiadiazole, 1,2,5-thiadiazole and 1,3,4-thiadiazole, thiazole, thiophene, triazine including 1,3,5-triazine and 1,2,4-triazine, triazole including 1,2,3-triazole, 1,3,4-triazole, and the like.

The term “hydroxy” as used herein is represented by the formula —OH.

The term “ketone” as used herein is represented by the formula R¹C(O)R², where R¹ and R² can be, independently, an alkyl, cycloalkyl, alkenyl, cycloalkenyl, alkynyl, cycloalkynyl, aryl, or heteroary described herein.

The term “azide” as used herein is represented by the formula —N₃.

The term “nitro” as used herein is represented by the formula —NO₂.

The term “nitrile” as used herein is represented by the formula —CN.

The term “silyl” as used herein is represented by the formula —SiR¹R²R³, where R¹, R², and R³ can be, independently, hydrogen or an alkyl, cycloalkyl, alkoxy, alkenyl, cycloalkenyl, alkynyl, cycloalkynyl, aryl, or heteroaryl group as described herein.

The term “sulfo-oxo group” as used herein is represented by the formulas —S(O)R¹, —S(O)₂R¹, —OS(O)₂R¹, or —OS(O)₂OR¹, where R¹ can be hydrogen or an alkyl, cycloalkyl, alkenyl, cycloalkenyl, alkynyl, cycloalkynyl, aryl, or heteroaryl group as described herein. Throughout this specification “S(O)” is an abbreviated form for S═O. The term “sulfonyl” as used herein refers to the sulfo-oxo group represented by the formula —S(O)₂R¹, where R¹ can be an alkyl, cycloalkyl, alkenyl, cycloalkenyl, alkynyl, cycloalkynyl, aryl, or heteroaryl. The term “sulfone” as used herein is represented by the formula R¹S(O)₂R², where R¹ and R² can be, independently, an alkyl, cycloalkyl, alkenyl, cycloalkenyl, alkynyl, cycloalkynyl, aryl, or heteroaryl as described herein. The term “sulfoxide” as used herein is represented by the formula R¹S(O)R², where R¹ and R² can be, independently, an alkyl, cycloalkyl, alkenyl, cycloalkenyl, alkynyl, cycloalkynyl, aryl, or heteroaryl as described herein.

The term “sulfydryl” as used herein is represented by the formula —SH.

“R¹”, “R²”, “R³” and “Rⁿ” (n is an integer), as used herein can, independently, possess one or more of the groups listed above. For example, if R¹ is a linear alkyl, one of the hydrogen atoms of the alkyl may be optionally substituted with hydroxy, alkoxy, alkyl, halogen, and the like. Depending upon the groups that are selected, a first group can be incorporated within second group, or alternatively, the first group can be pendant (i.e., attached) to the second group. For example, with the phrase “alkyl comprising an amino”, the amino can be incorporated within the backbone of the alkyl. Alternatively, the amino can be attached to the backbone of the alkyl. The nature of the group that is selected will determine that whether the first group is embedded or attached to the second group.

Compounds described herein may contain “optionally substituted” moieties. In general, the term “substituted” (whether preceded by the term “optionally” or not), means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this disclosure are preferably those that result in the formation of stable or chemically feasible compounds. In is also contemplated that, in certain aspects, unless expressly indicated to the contrary, individual substituents can be further optionally substituted (i.e., further substituted or unsubstituted).

The structure of the complex can be represented by a following formula:

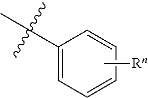

which is understood to be equivalent to a following formula:

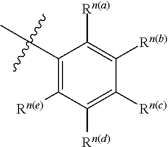

wherein n is typically an integer. That is, Rⁿ is understood to represent five independent substituents R^{n(a)}, R^{n(b)}, R^{n(c)}, R^{n(d)} and R^{n(e)}. The “independent substituent” means that each R substituent can be independently defined. For example, if in one instance R^{n(a)} is halogen, then R^{n(b)} is not necessarily halogen in that instance.

Several references to R¹, R², R³, R⁴, R⁵, R⁶, etc. are made in chemical structures and moieties disclosed and described herein. Unless otherwise indicated, any description of R¹, R², R³, R⁴, R⁵, R⁶, etc. in the specification is applicable to any structure or moiety reciting R¹, R², R³, R⁴, R⁵, R⁶, etc. respectively.

Opto-electronic devices that make use of organic materials are becoming increasingly desirable for a number of reasons. Many of the materials used to make such devices are relatively inexpensive, so organic optoelectronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic light emitting layer emits light may generally be readily tuned with appropriate dopants.

Excitons decay from singlet excited states to ground state to yield prompt luminescence, which is fluorescence. Excitons decay from triplet excited states to ground state to generate luminescence, which is phosphorescence. Because the strong spin-orbit coupling of the heavy metal atom enhances intersystem crossing (ISC) very efficiently between singlet and triplet excited states, phosphorescent metal complexes, such as palladium complexes, have demonstrated their potential to harvest both the singlet and triplet excitons to achieve 100% of internal quantum efficiency. Thus phosphorescent metal complexes are good candidates as dopants in the emissive layer of organic light emitting devices (OLEDs) and a great deal of attention has been received both in the academic and industrial fields. In addition, many achievements have been made in the past decade to lead to the lucrative commercialization of the technology, for example, OLEDs have been used in advanced displays in smart phones, televisions and digital cameras.

However, so far, blue electroluminescent devices remain the most challenging area of this technology, and one of the big issues is the stability of the blue devices. It has been proven that the choice of host materials is a very factor in the stability of the blue devices. However, the lowest energy of the triplet excited state (T₁) of the blue luminescent material is very high, which means that the lowest energy of the triplet excited state (T₁) of the host materials for the blue devices should be higher. This leads to difficulty in the development of the host materials for the blue devices.

The metal complexes of the disclosure can be customized or tuned to specific applications having particular emission or absorption characteristics. The optical properties of the metal complexes in this disclosure can be tuned by varying the structure of the ligand surrounding the metal center or varying the structure of fluorescent luminophores on the ligands. For example, in emission and absorption spectrum, the metal complexes having a ligand with electron donating substituents or electron withdrawing substituents can generally exhibit different optical properties. The color of the metal complexes can be tuned by modifying the conjugated groups on the fluorescent luminophores and ligands.

The emission of such complexes can be tuned, for example, from the ultraviolet to near-infrared, by, for example, modifying the ligand or fluorescent luminophore structure. A fluorescent luminophore is a group of atoms in an organic molecule, which can absorb energy to generate singlet excited state, and the singlet excitons decay rapidly to yield prompt luminescence. In one aspect, the complexes of the disclosure can provide emission over a majority of the visible spectrum. In a specific example, the complexes of the disclosure can emit light over a range of from about 400 nm to about 700 nm. In another aspect, the complexes of the disclosure have improved stability and efficiency over traditional emission complexes. Moreover, the complexes of the disclosure can be useful as luminescent labels in, for example, bio-applications, anti-cancer agents, emitters in organic luminescent diodes (OLED), or a combination thereof. In another aspect, the complexes of the disclosure can be useful in luminescent devices, such as, compact fluorescent lamps (CFL), luminescent diodes (LED), incandescent lamps, and combinations thereof.

Compounds or compound complexes comprising palladium are disclosed herein. The terms compounds and complexes can be used interchangeably herein.

The complexes disclosed herein can exhibit desirable properties and have emission and/or absorption spectrum that can be tuned via the selection of appropriate ligands. In another aspect, any one or more of the complexes, structures, or portions thereof, specifically recited herein may be excluded.

The complexes described herein can be made using a variety of methods, including, but not limited to those recited in the embodiments provided herein.

The complexes disclosed herein can be delayed fluorescent and/or phosphorescent emitters. In one aspect, the complexes disclosed herein can be delayed fluorescent emitters. In another aspect, the complexes disclosed herein can be phosphorescent emitters. In yet another aspect, the complexes disclosed herein can be delayed fluorescent emitters and phosphorescent emitters.

Some specific embodiments of the present disclosure disclose a tetradentate cyclopalladated palladium complex comprising trisubstituted pyrazole, wherein a structure of the complex is as shown in formula (I):

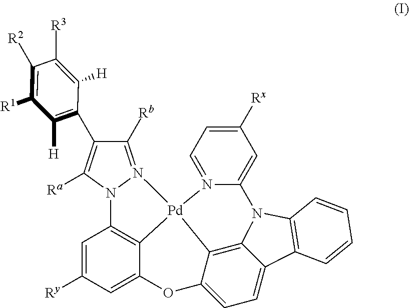

wherein,

R^{a} and R^{b} each are alkyl, alkoxy, cycloalkyl, ether, heterocyclyl, hydroxy, aryl, heteroaryl, aryloxy, monoalkylamino or dialkylamino, monoarylamino or diarylamino, halogen, sulfydryl, cyano independently, or a combination thereof.

R^{x} is alkyl, alkoxy, cycloalkyl, heterocyclyl, ether, monoalkylamino or dialkylamino, monoarylamino or diarylamino, halogen, or a combination thereof.

R^{y} is hydrogen, deuterium, alkyl, alkoxy, cycloalkyl, heterocyclyl, ether, monoalkylamino or dialkylamino, monoarylamino or diarylamino, halogen or a combination thereof; and

R¹, R² and R³ each are hydrogen, deuterium, alkyl, alkoxy, ether, cycloalkyl, heterocyclyl, hydroxy, aryl, heteroaryl, aryloxy, monoalkylamino or dialkylamino, monoarylamino or diarylamino, halogen, sulfydryl, haloalkyl, independently, or a combination thereof.

In some specific embodiments of the present disclosure, the structural unit

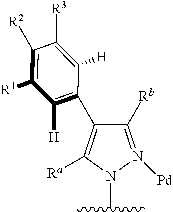

can respectively and independently represent a following structure, but is not limited to the following structure:

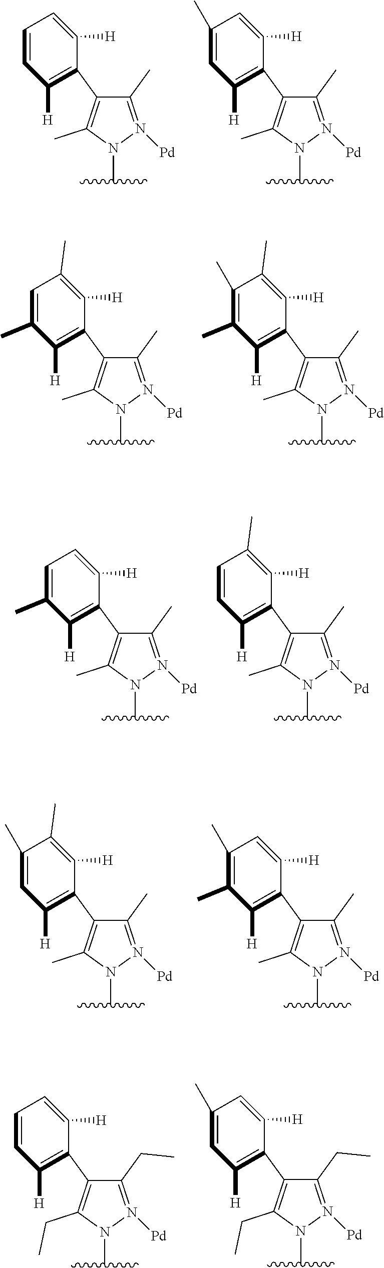

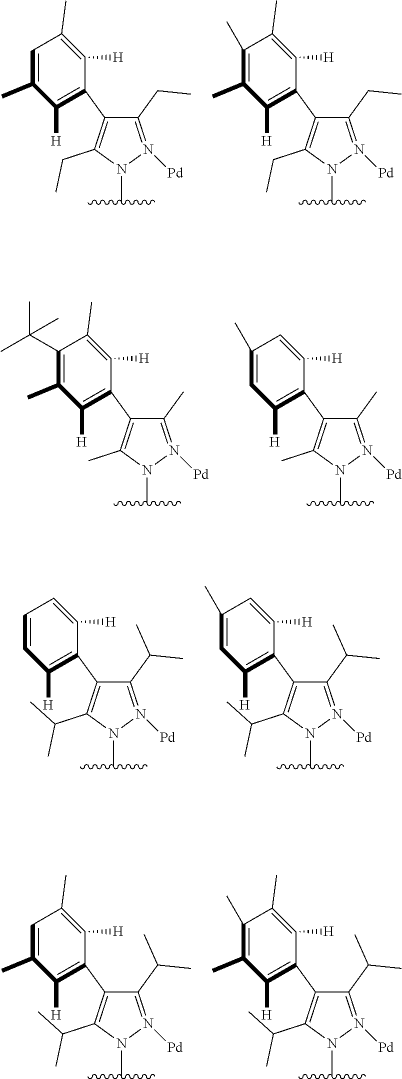

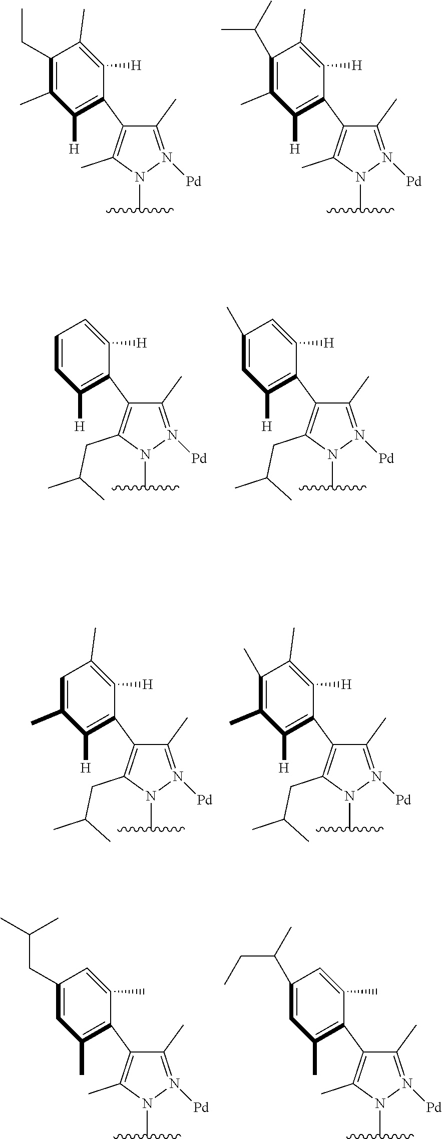

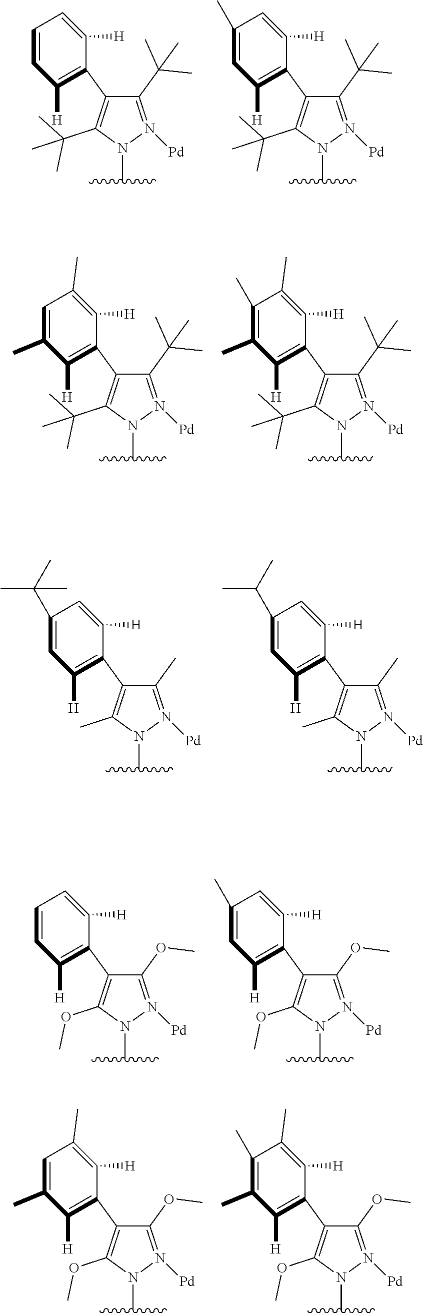

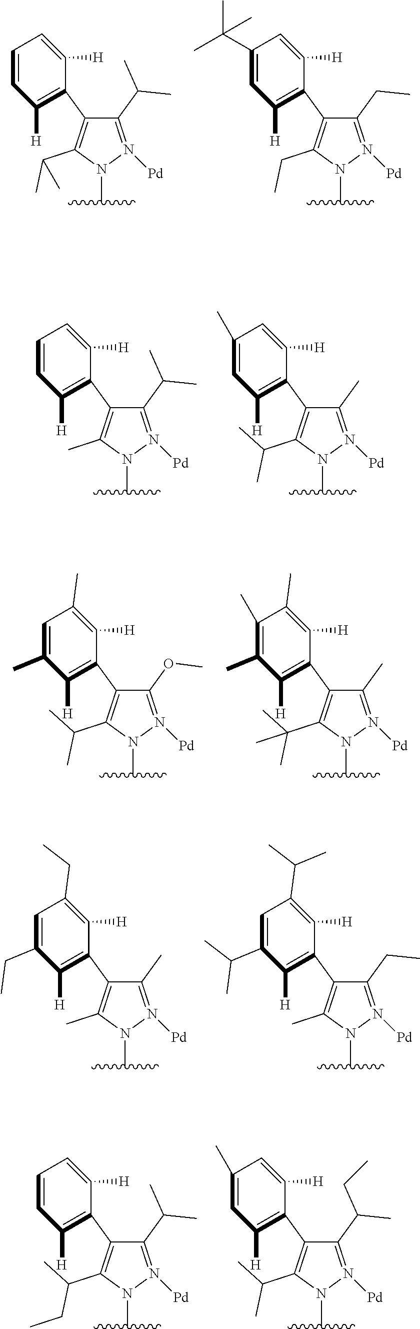

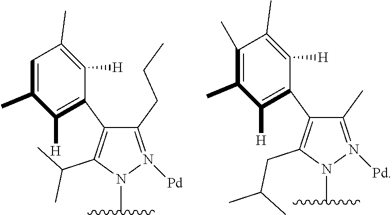

The tetradentate cyclopalladated palladium complex comprising trisubstituted pyrazole disclosed in some specific embodiments of the present disclosure has a structure selected from one of the following:

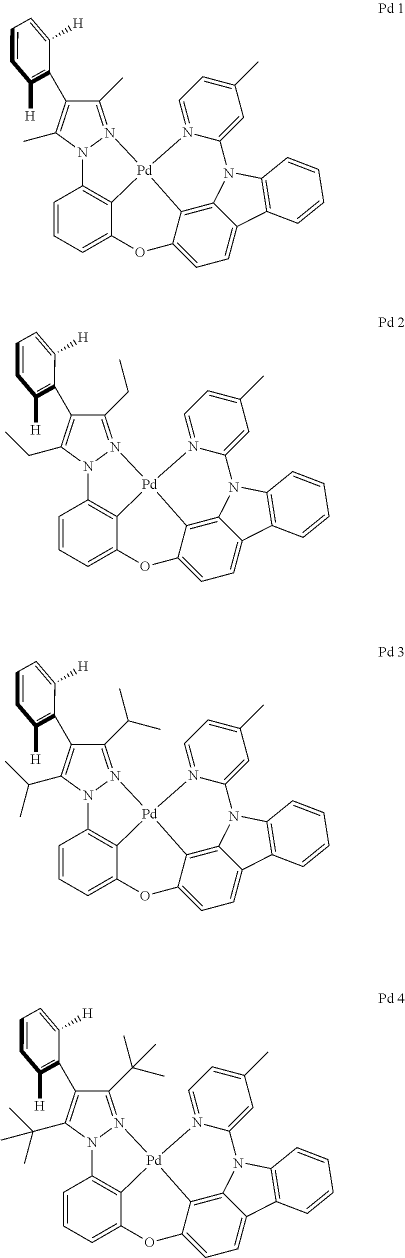

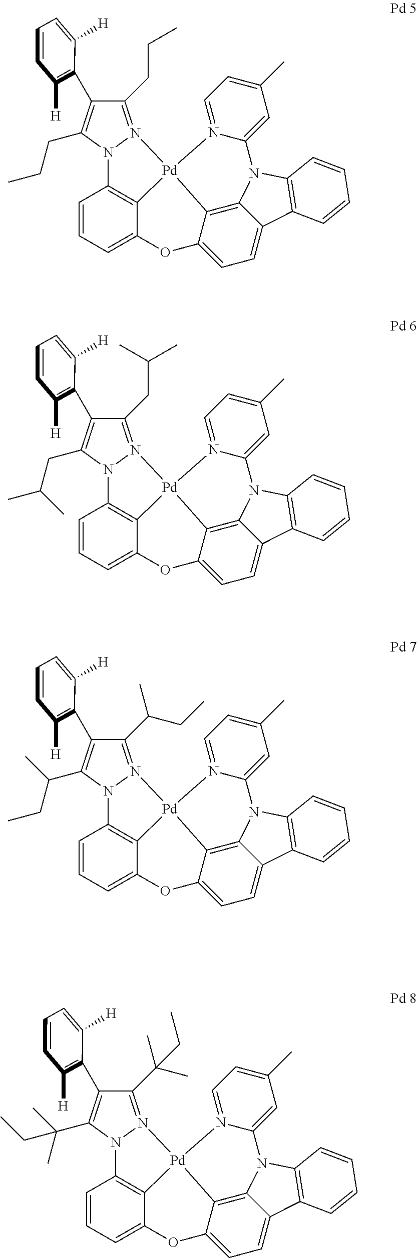

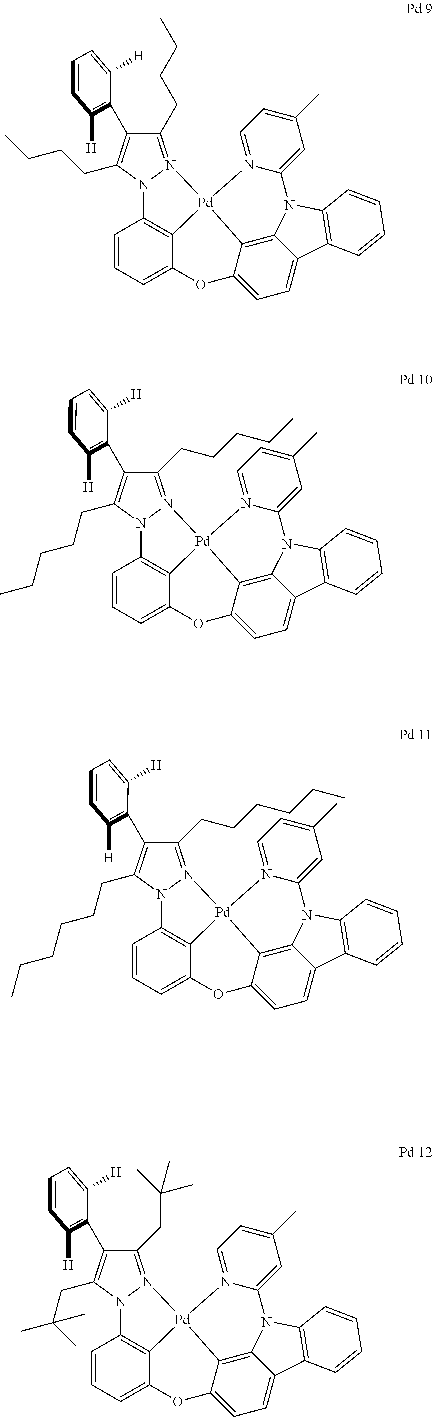

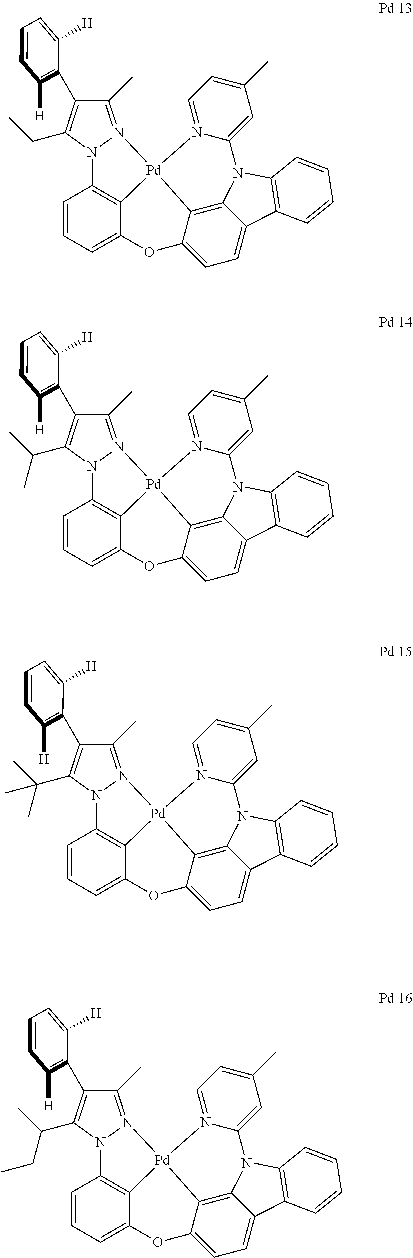

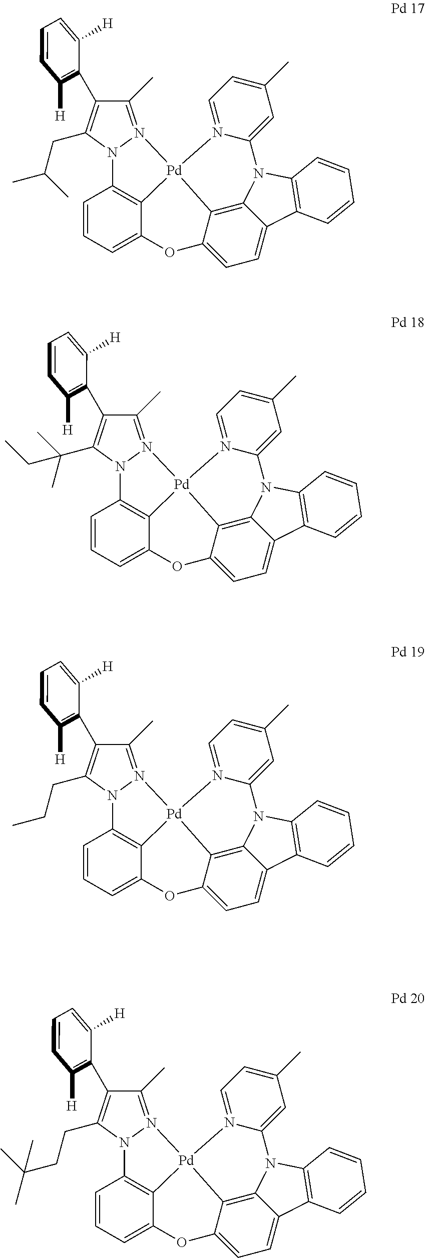

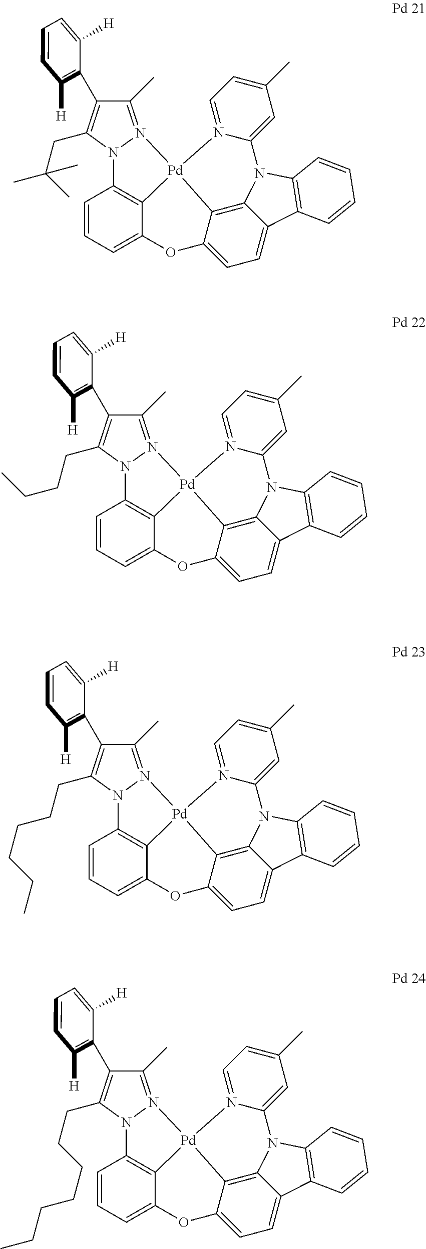

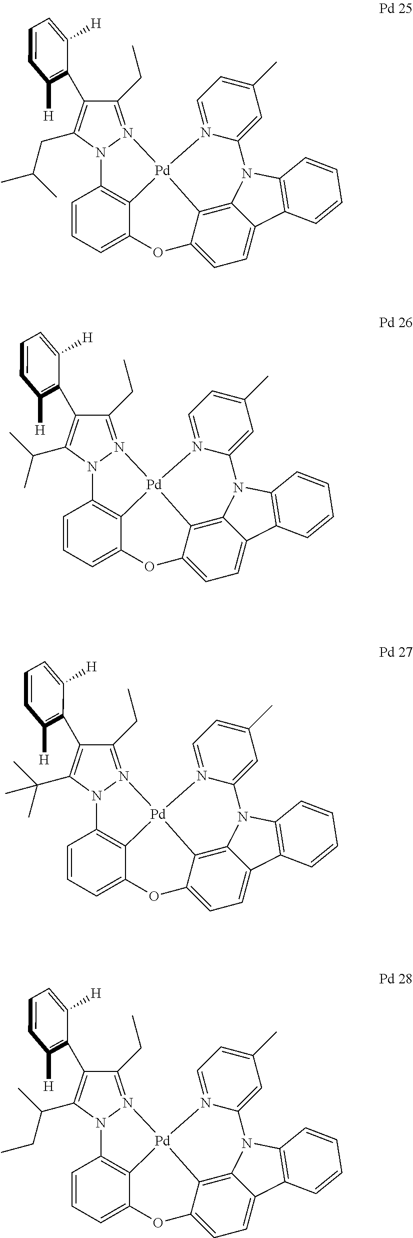

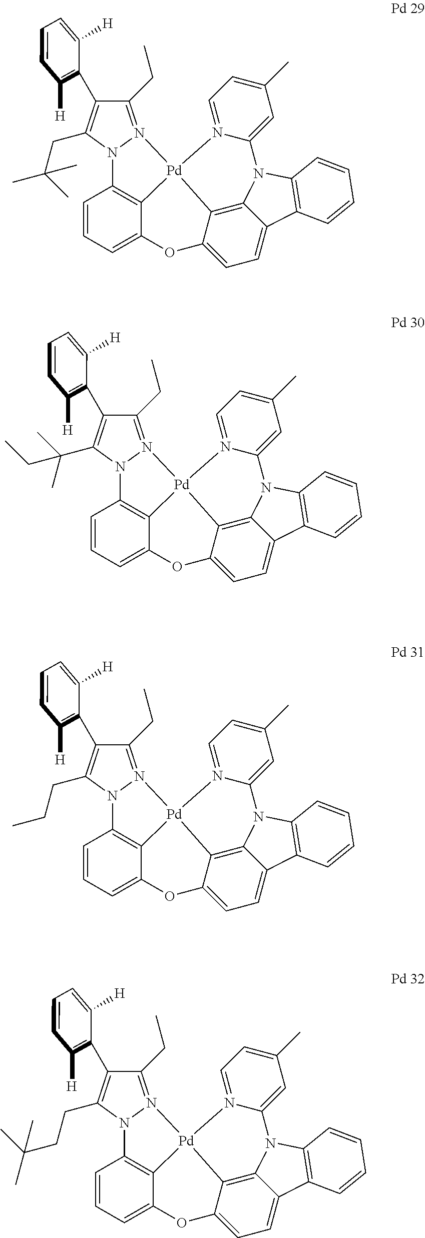

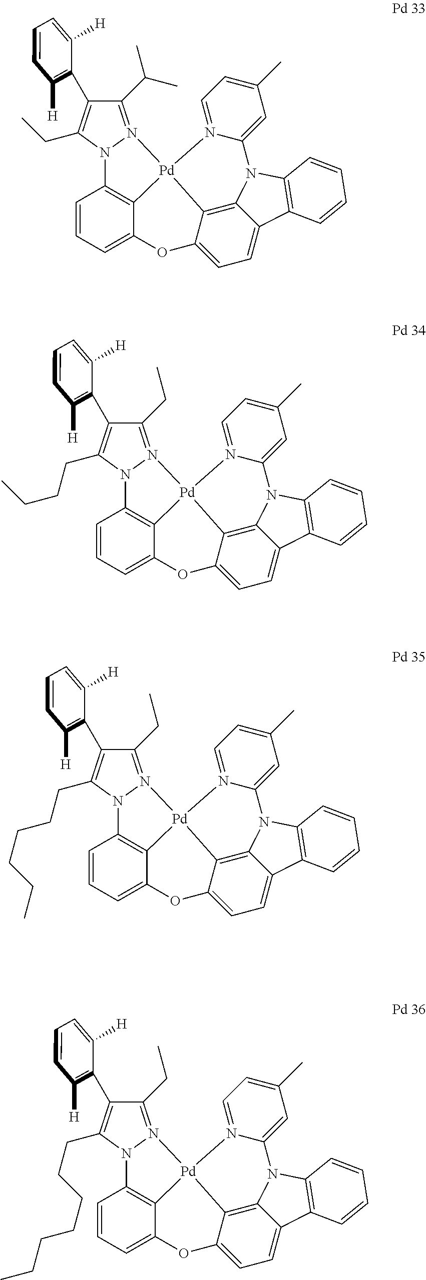

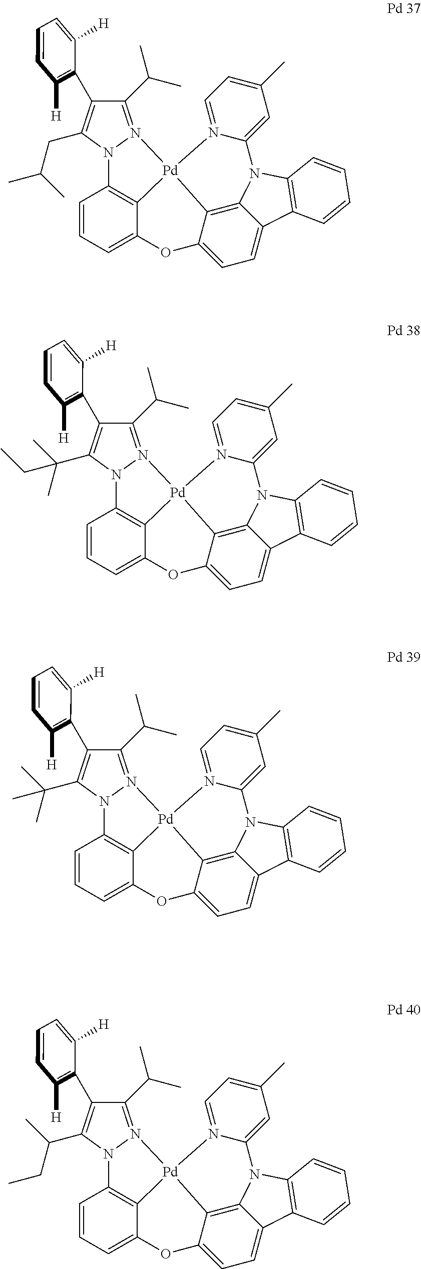

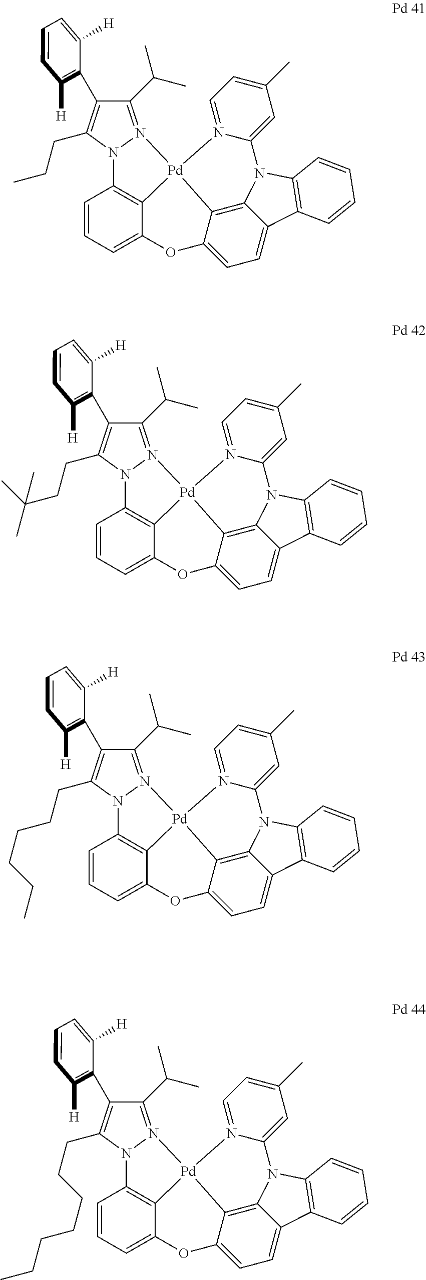

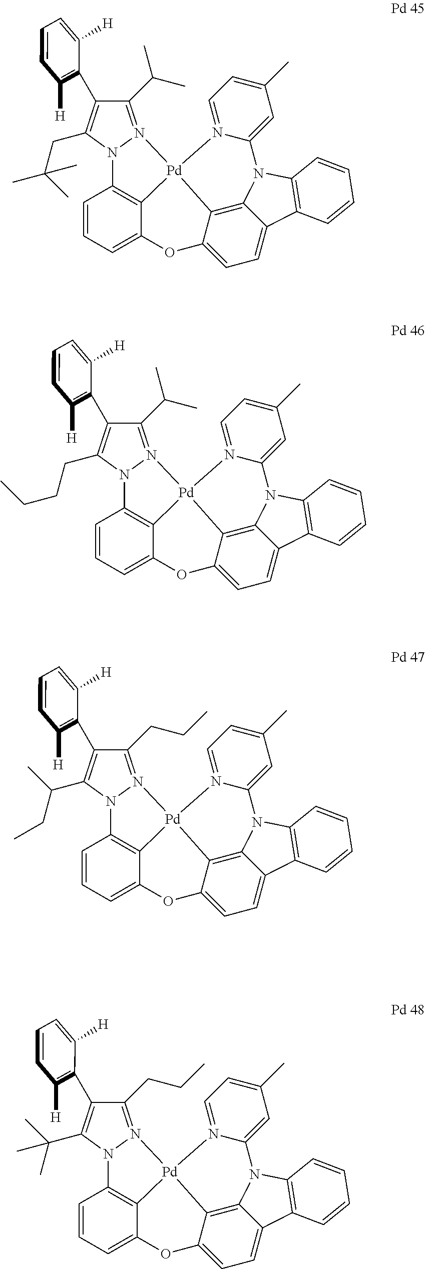

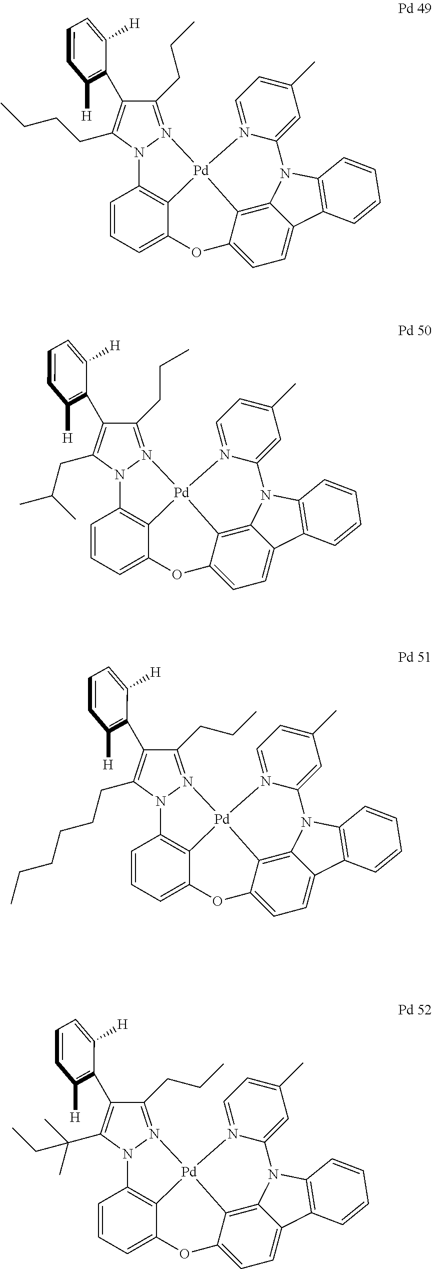

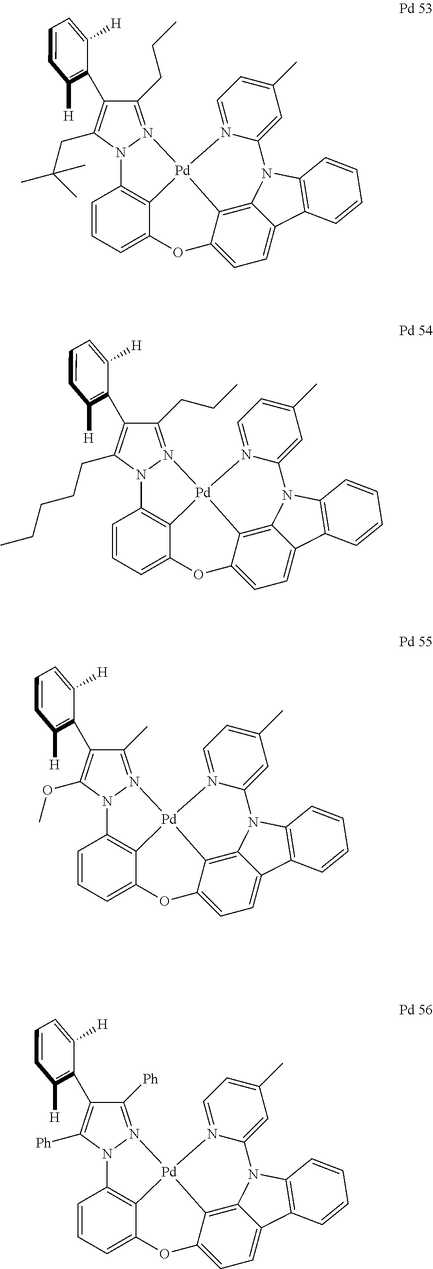

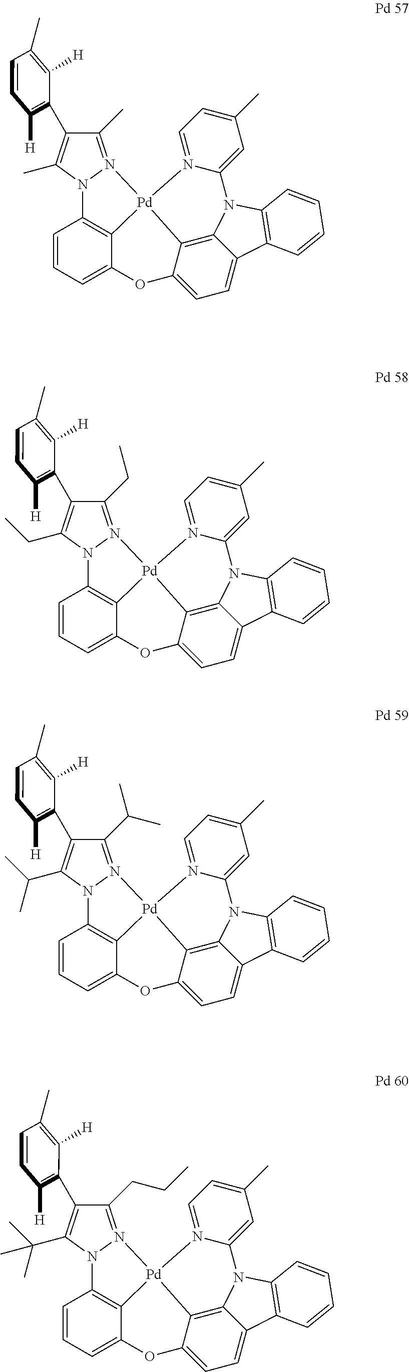

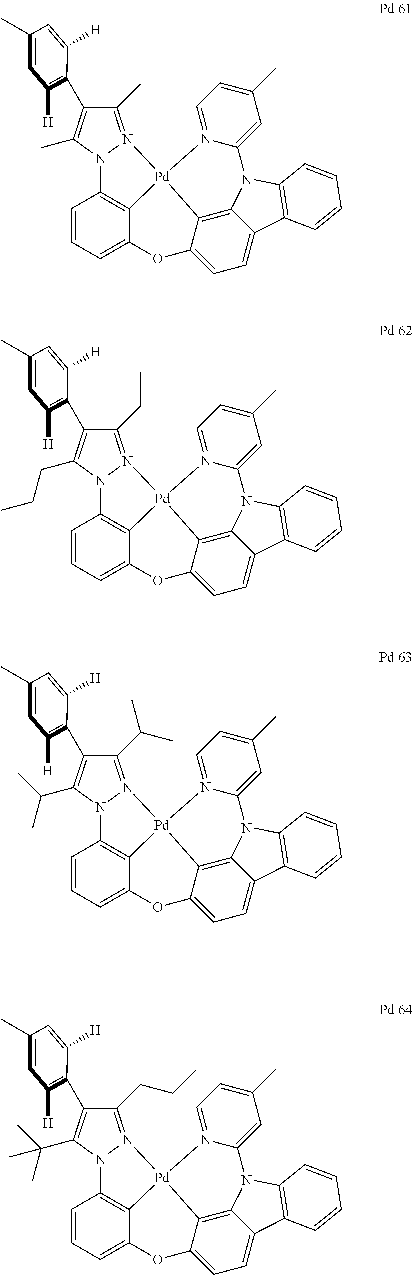

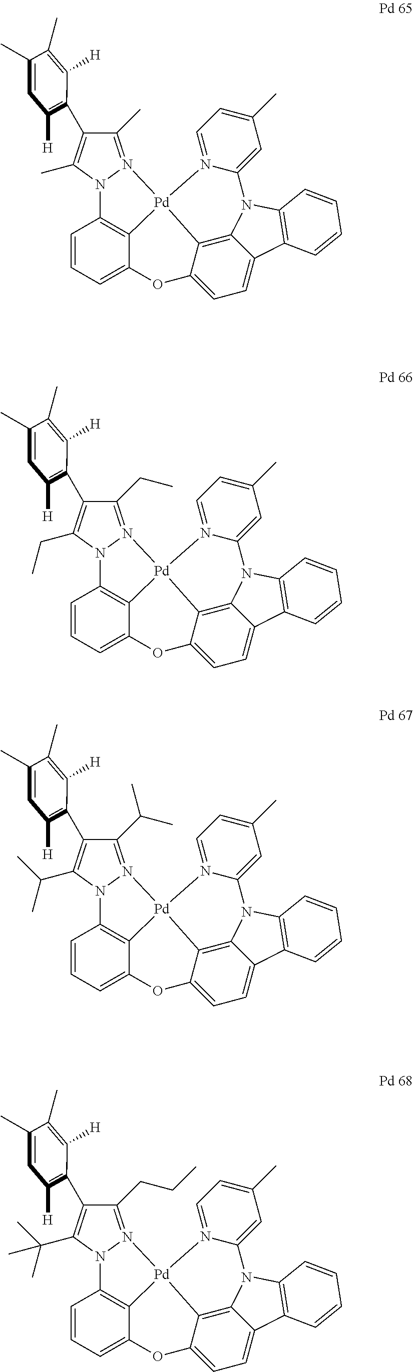

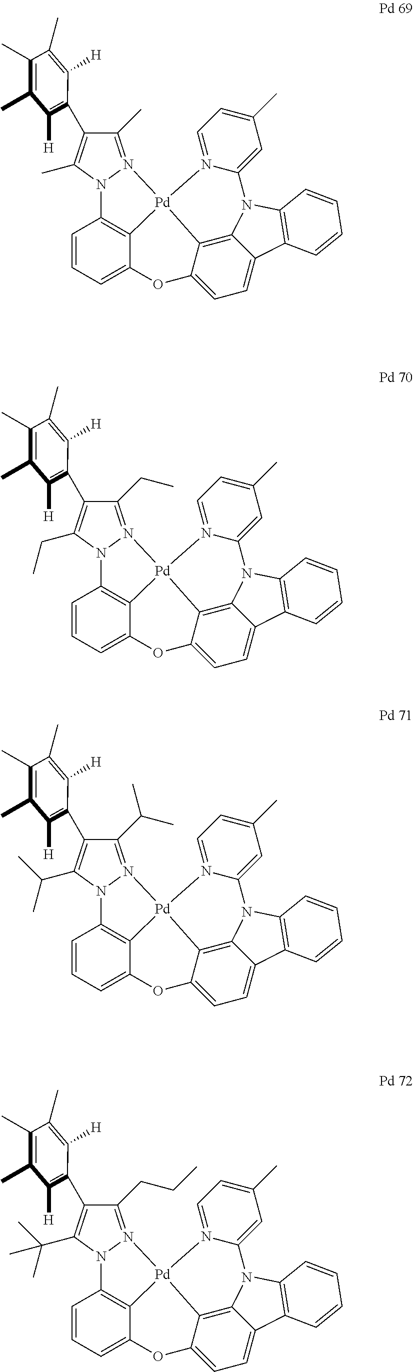

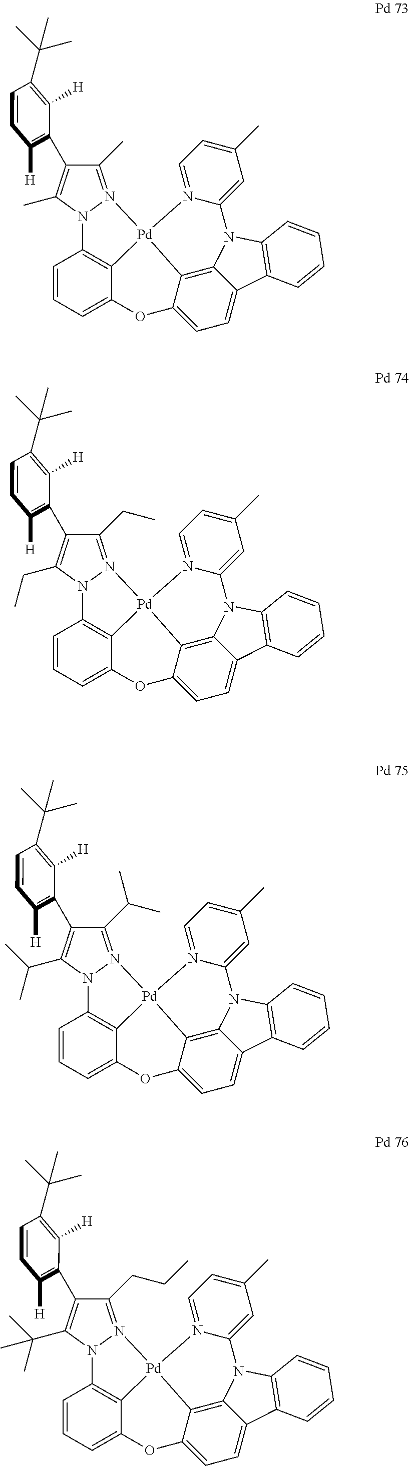

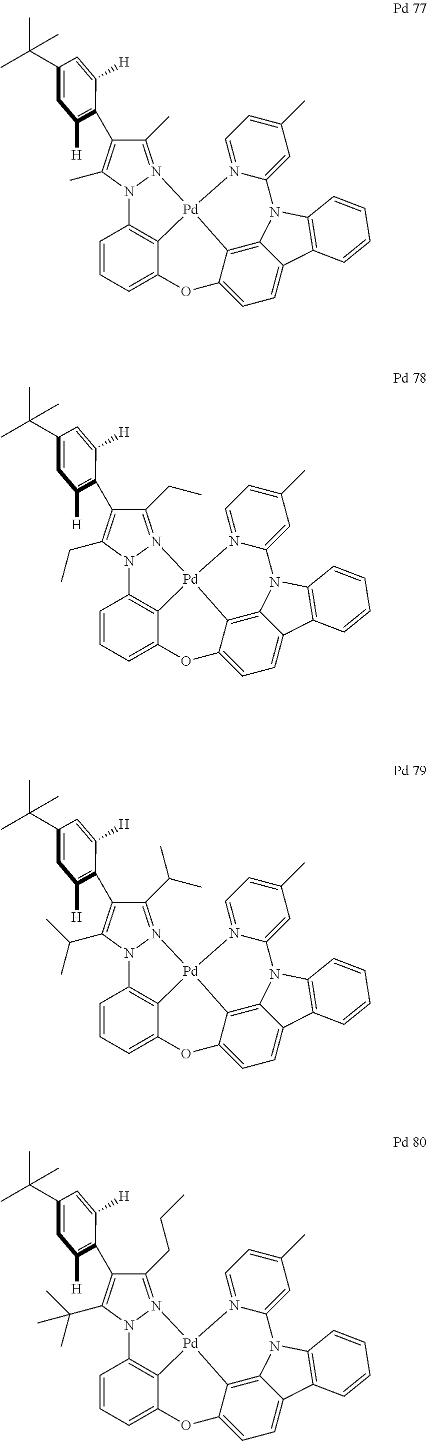

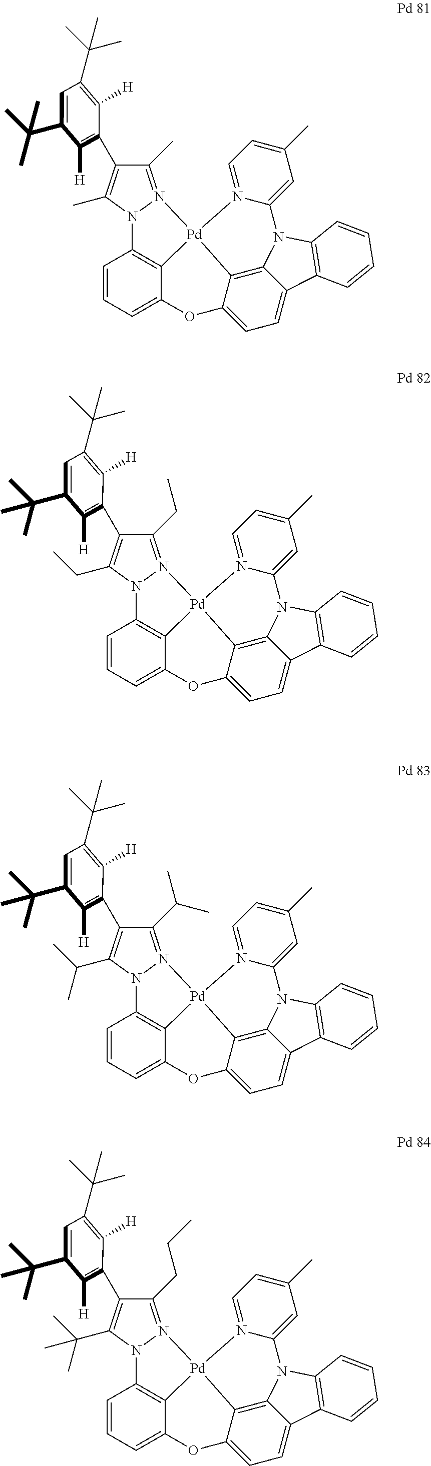

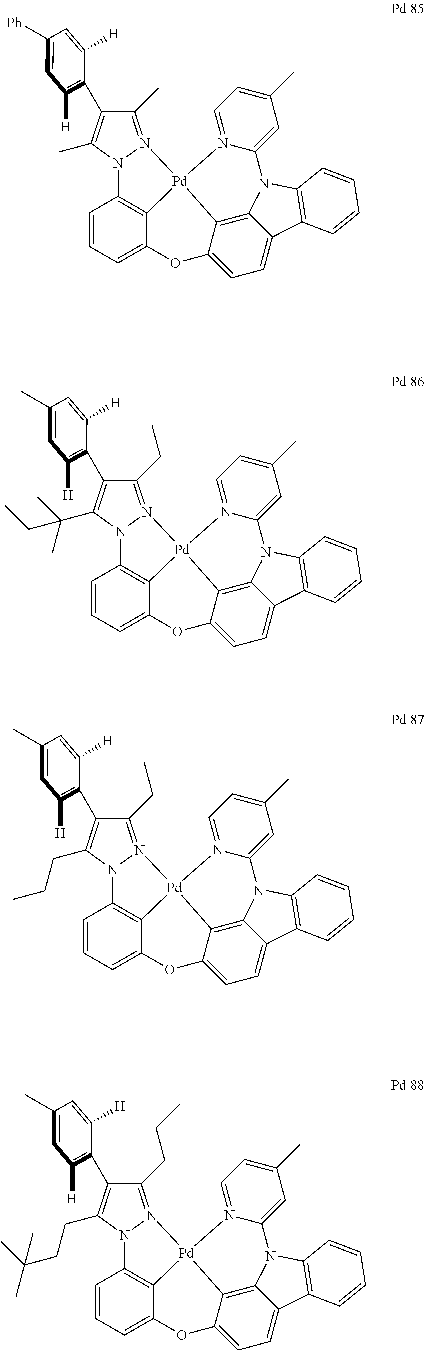

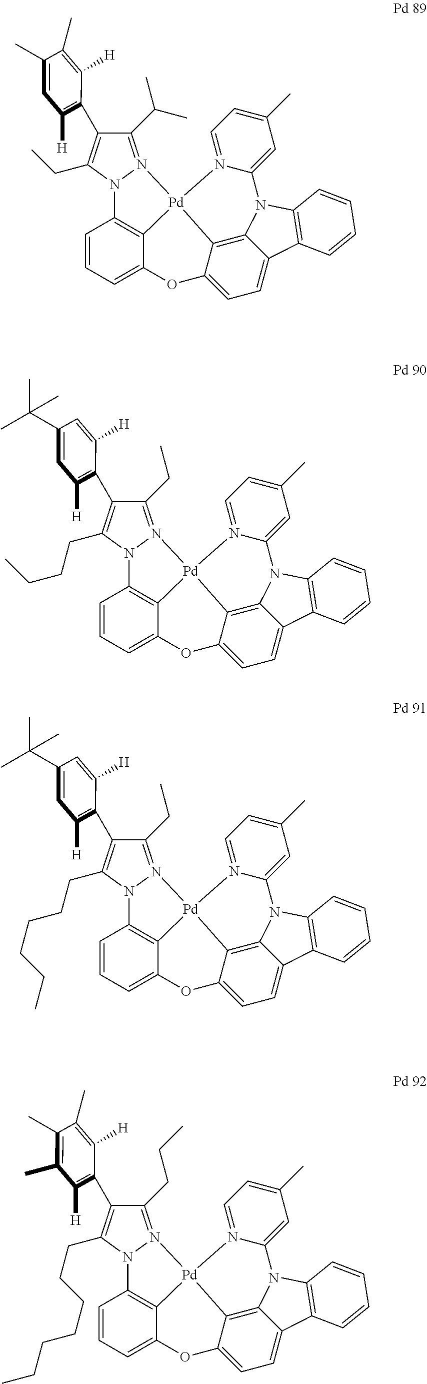

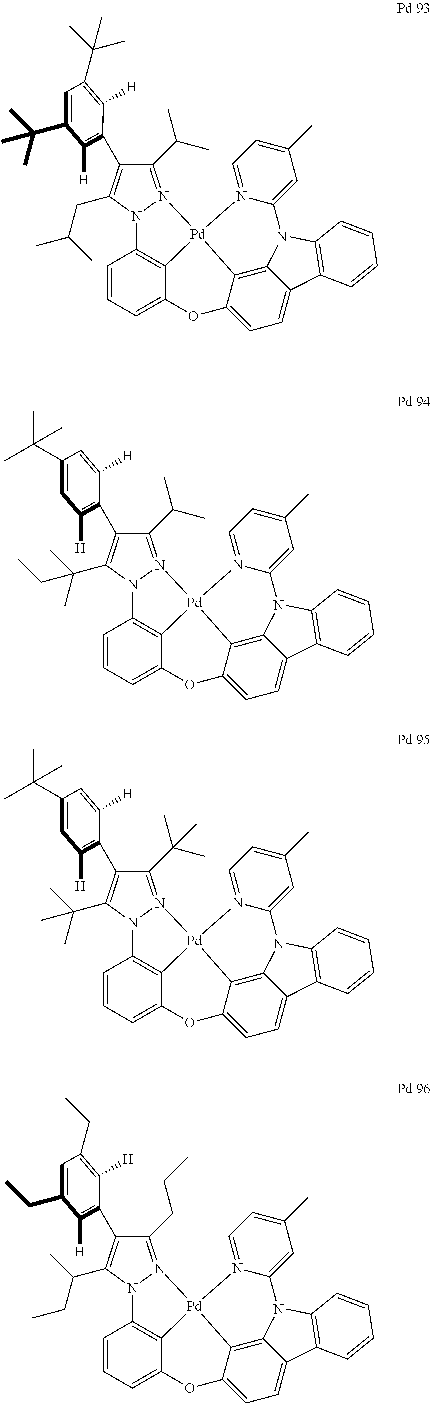

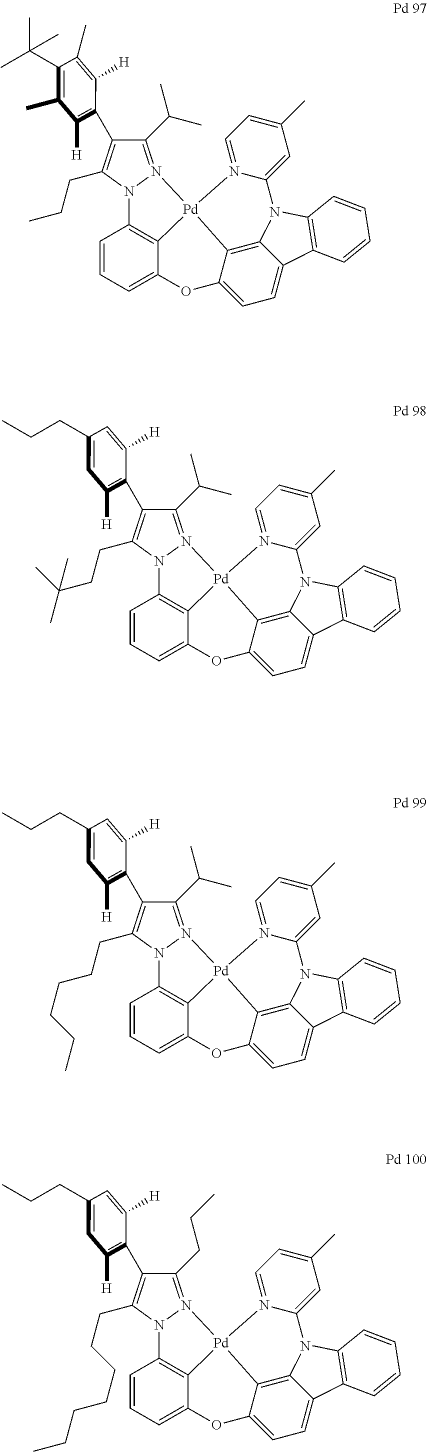

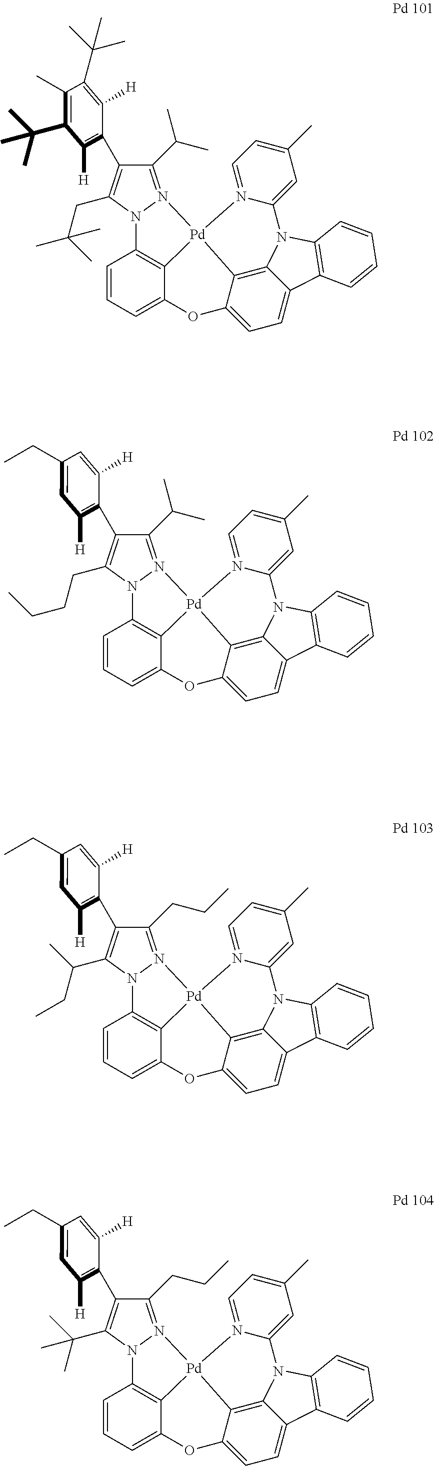

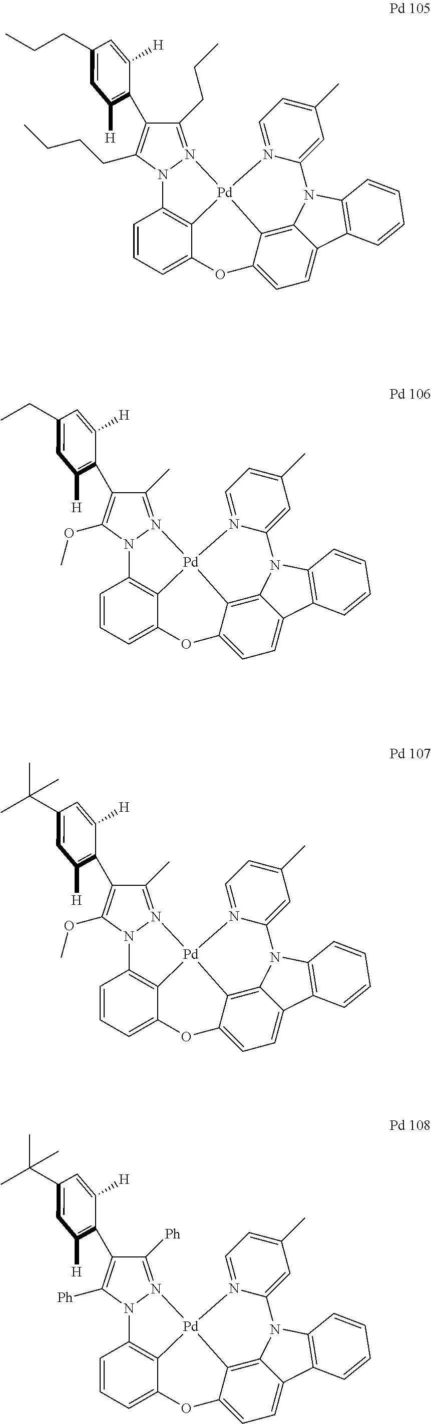

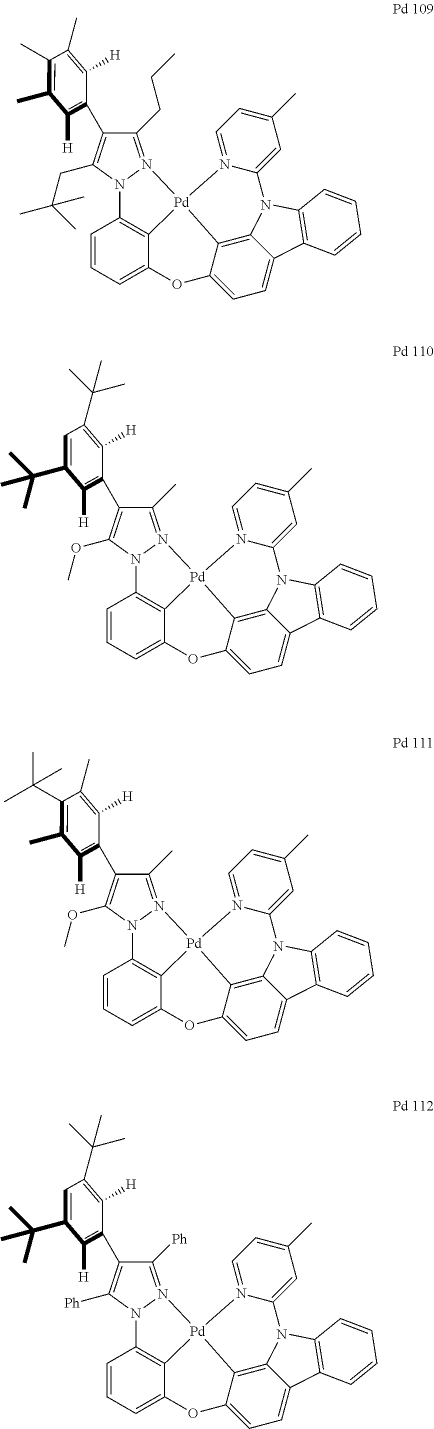

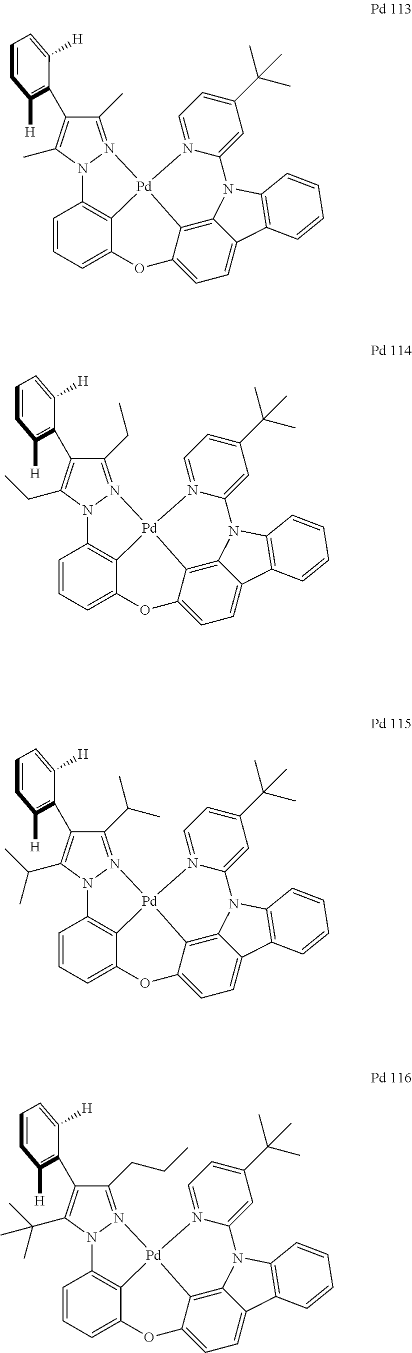

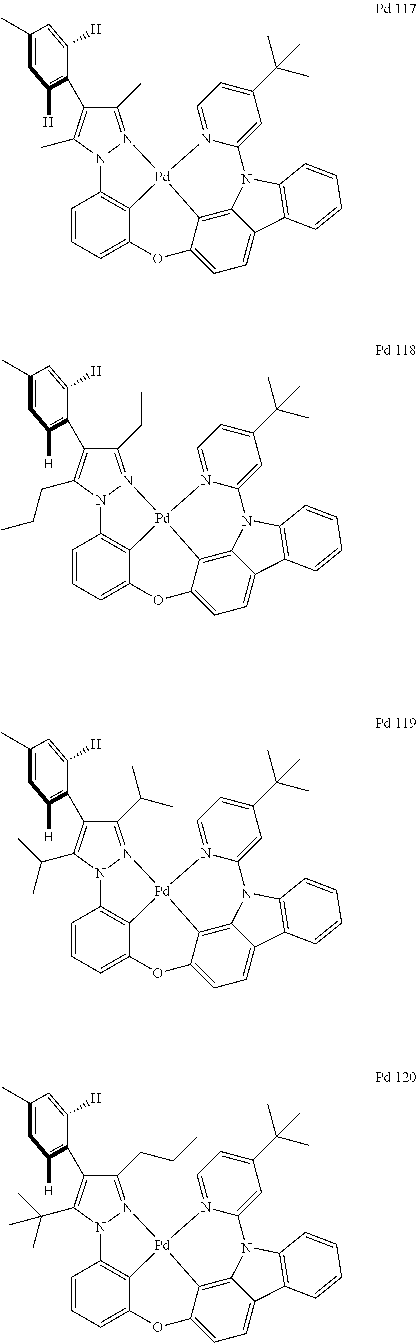

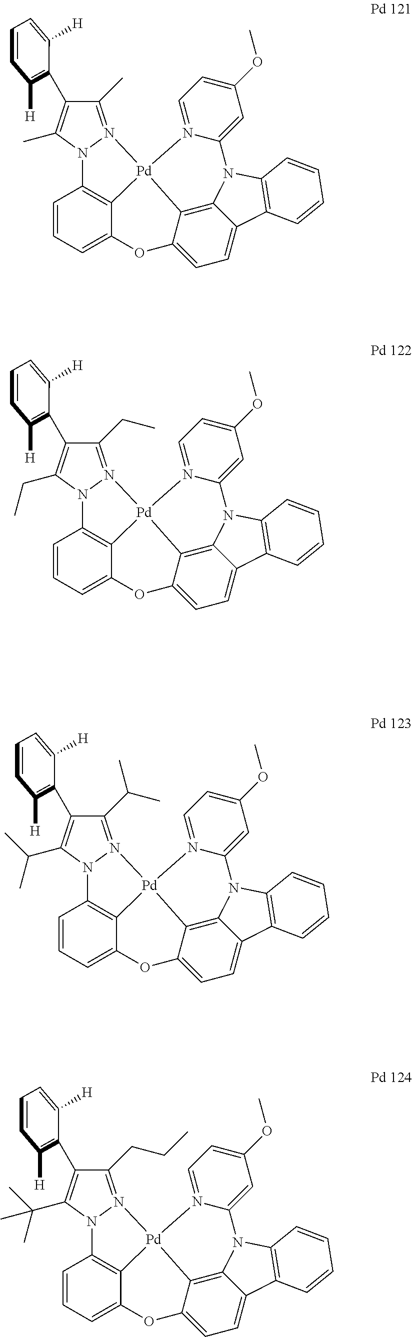

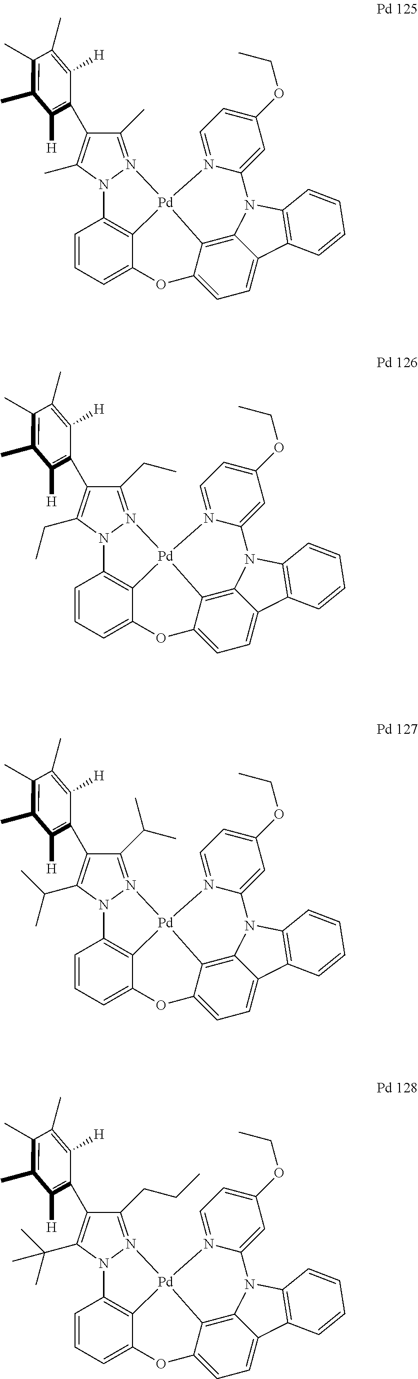

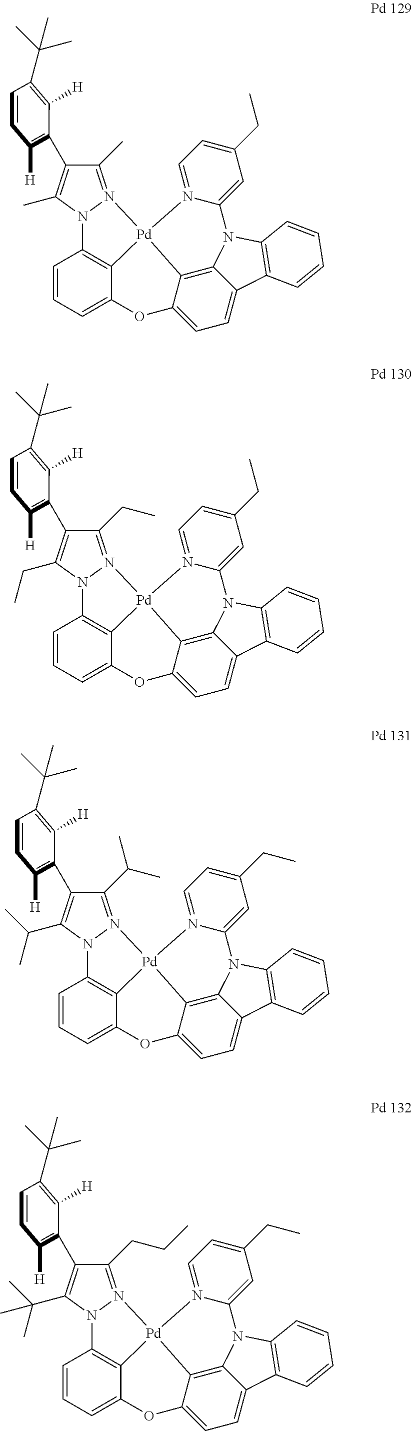

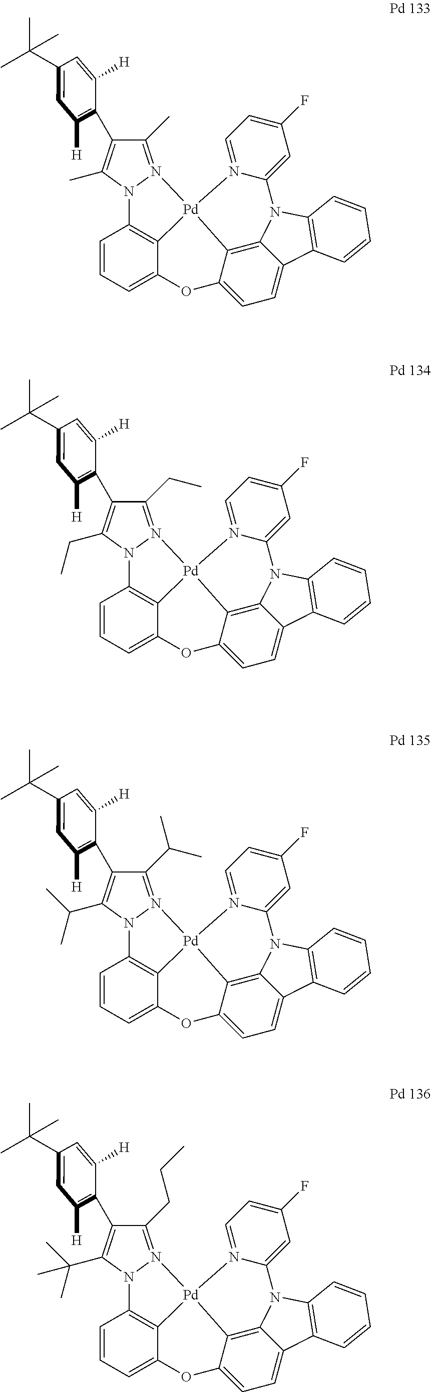

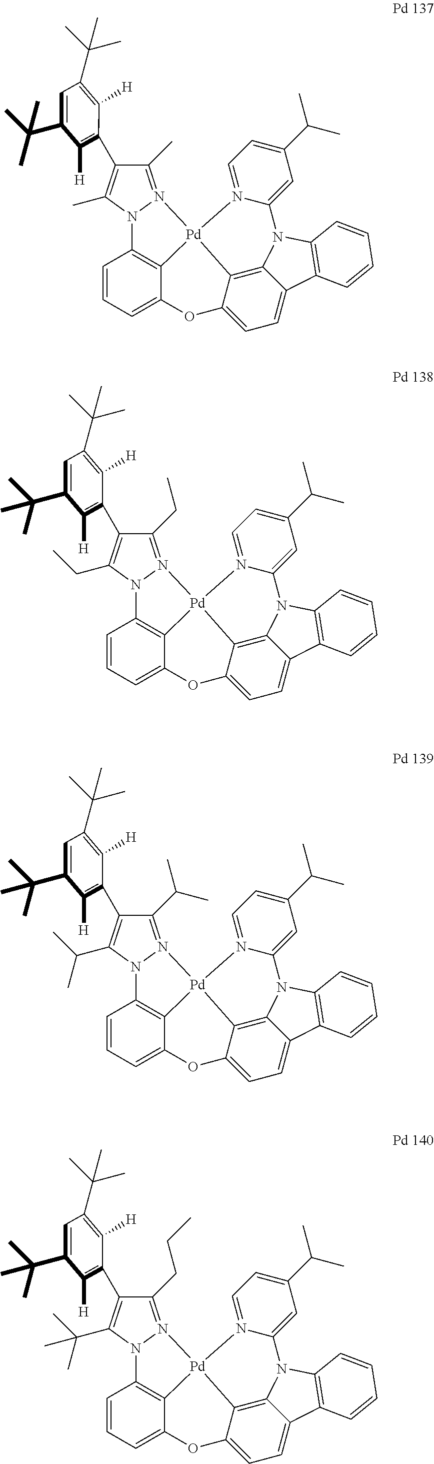

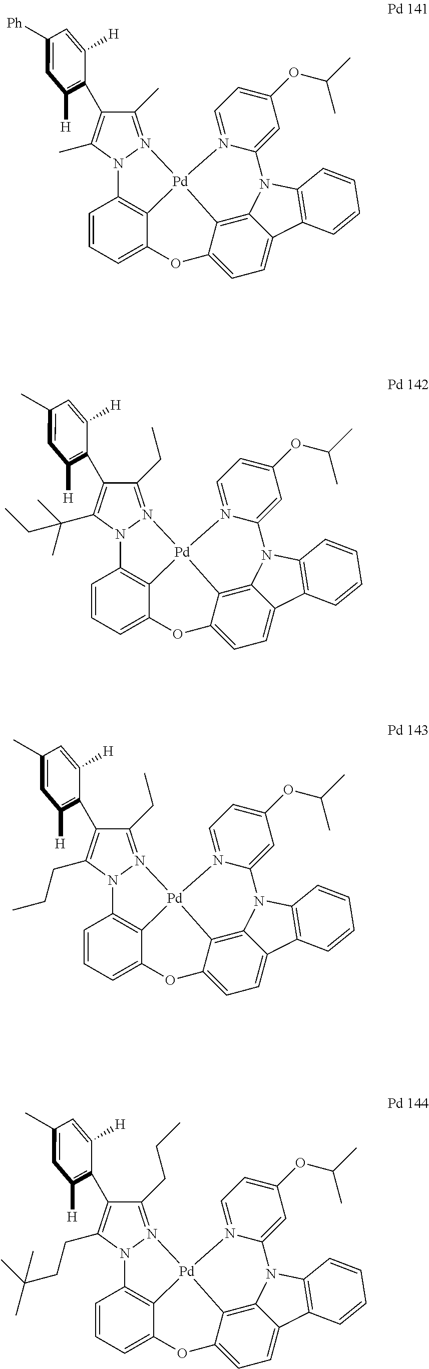

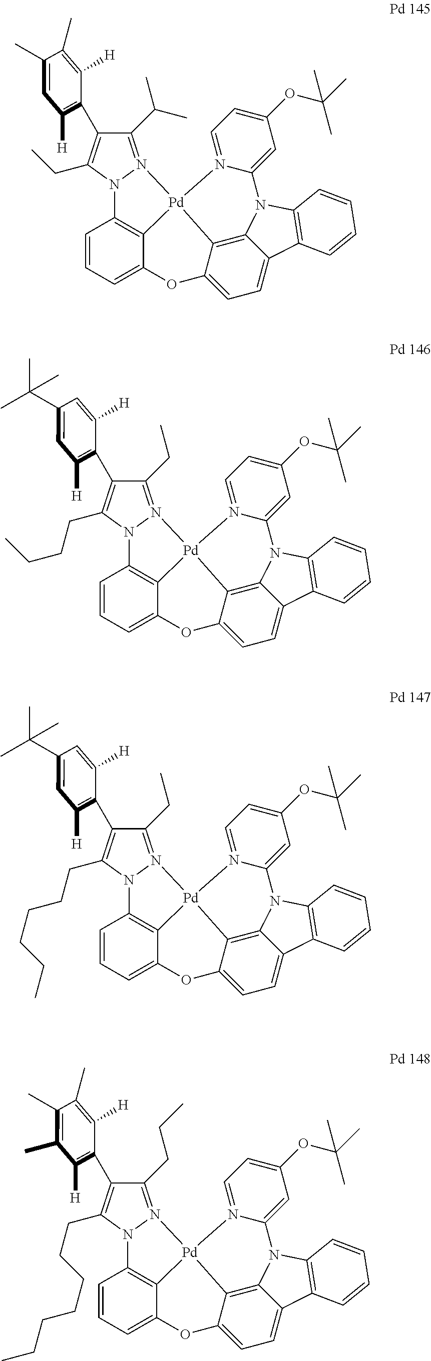

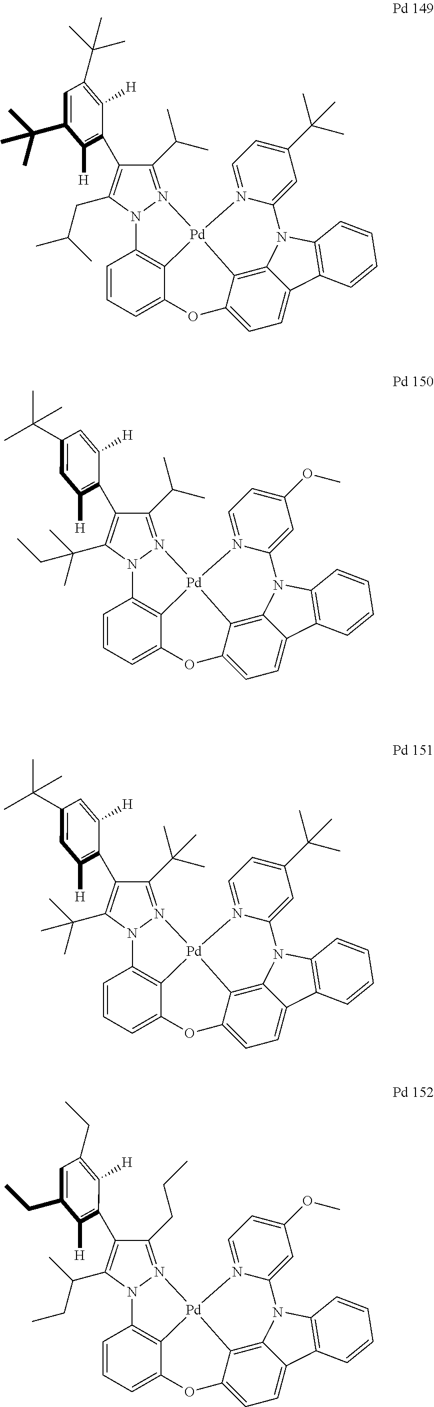

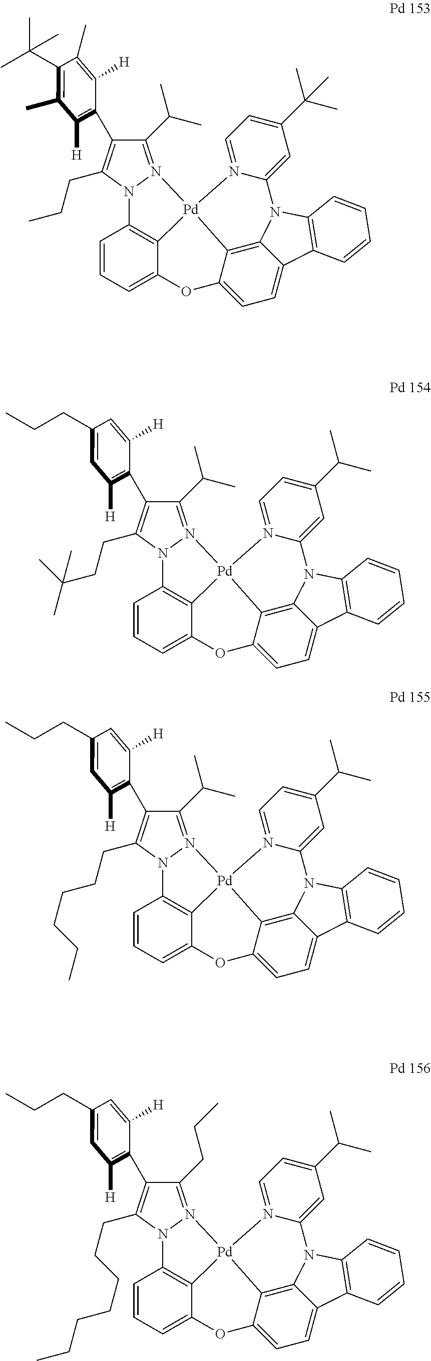

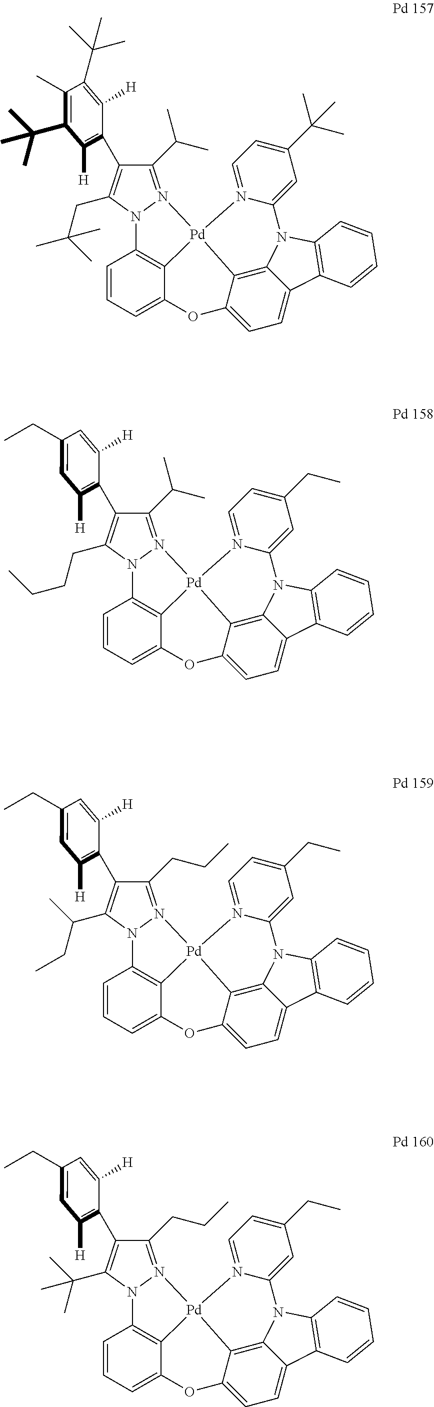

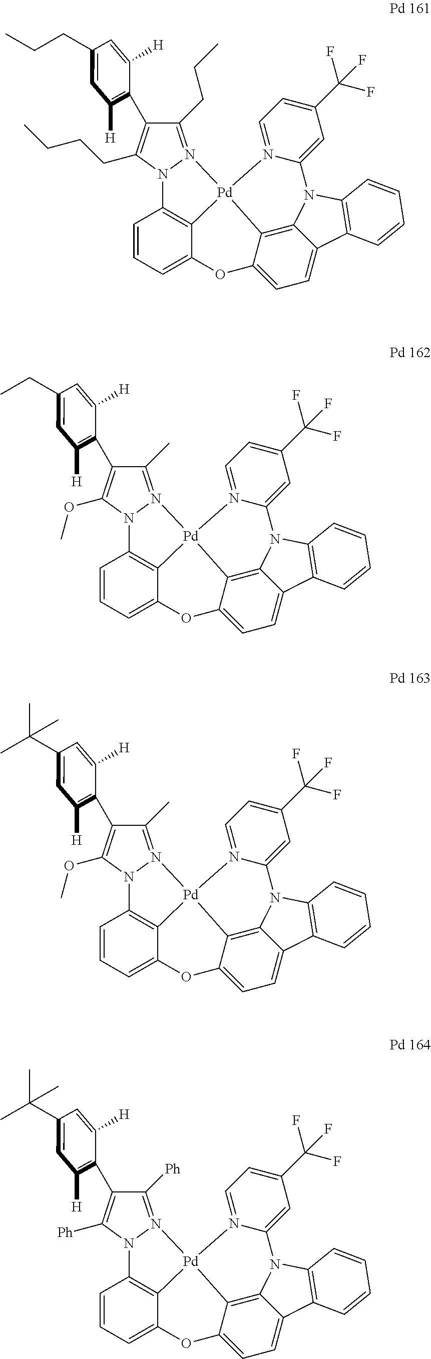

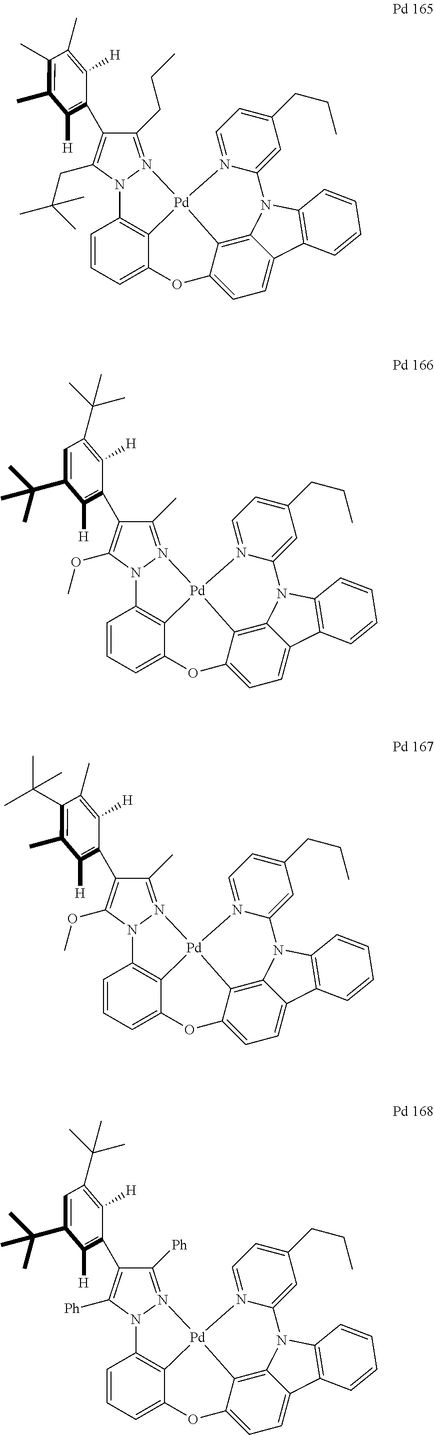

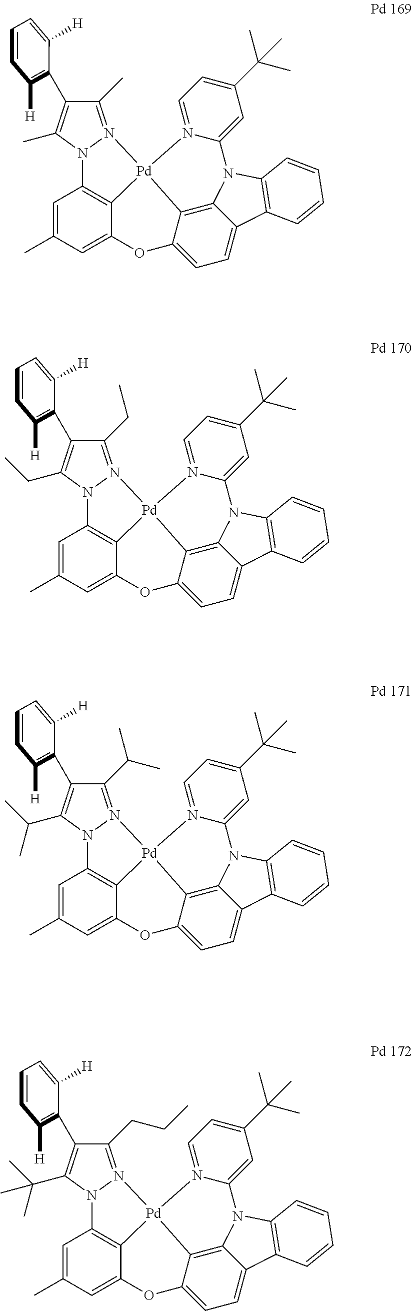

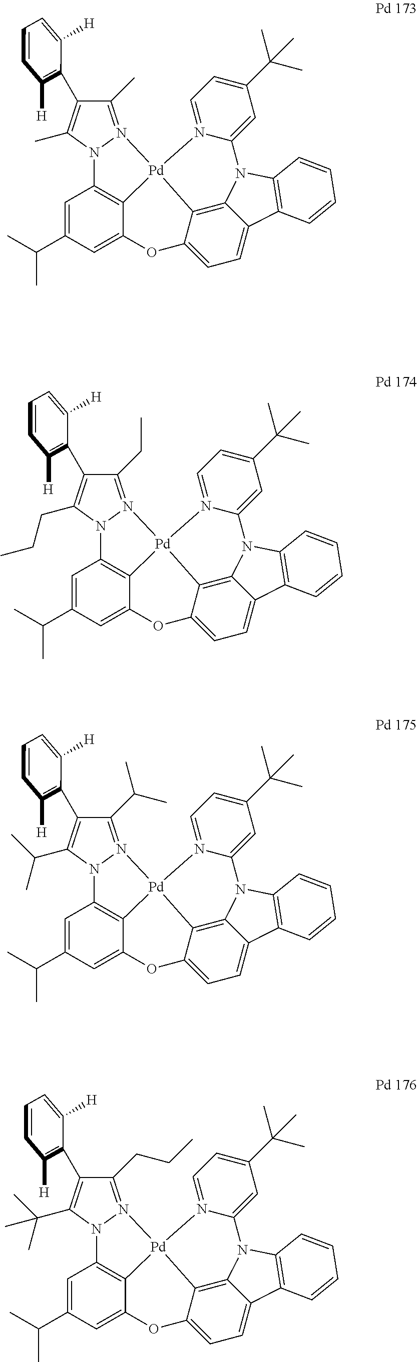

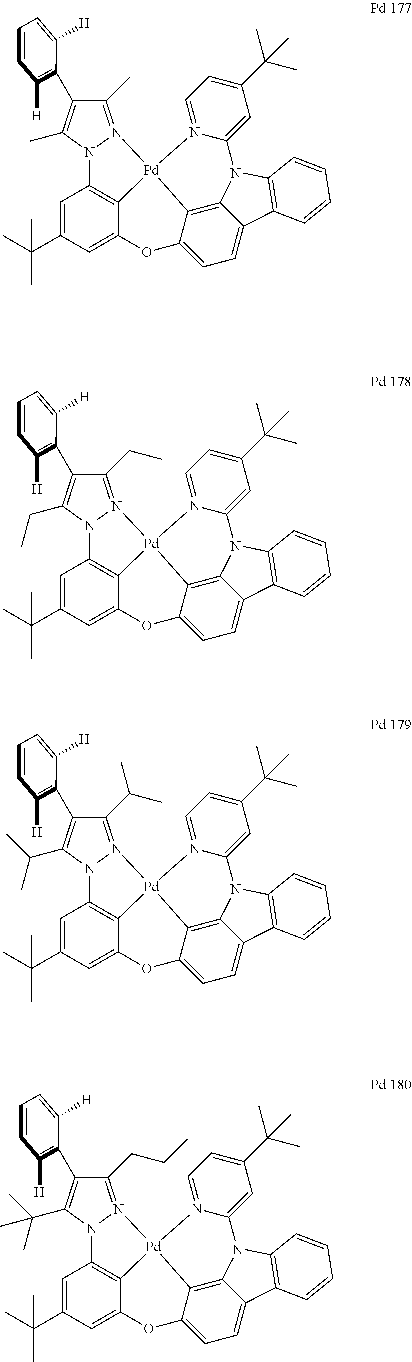

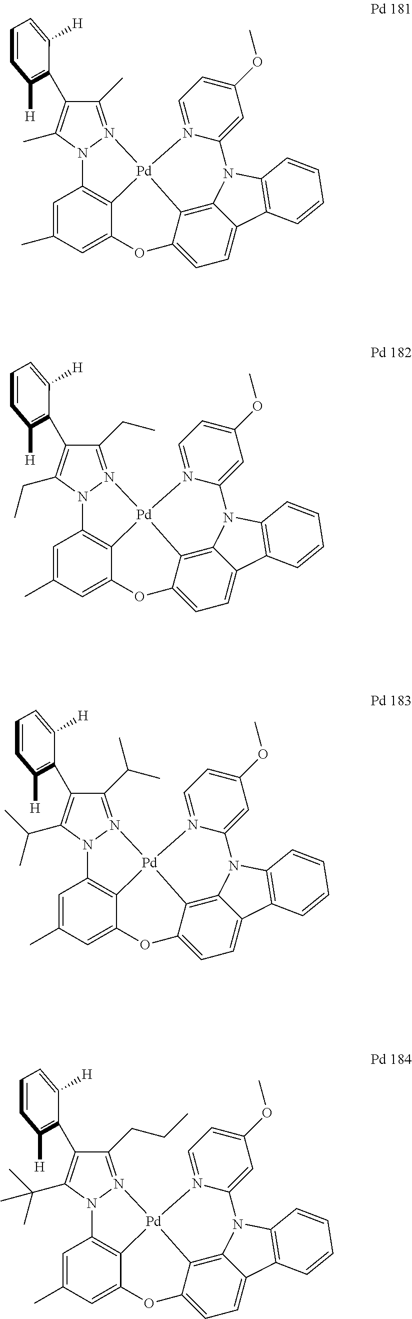

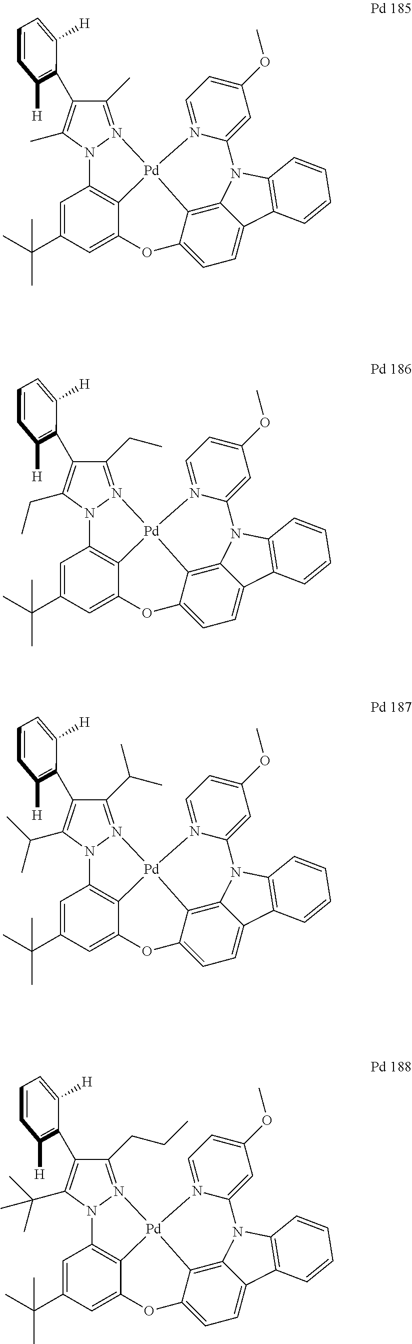

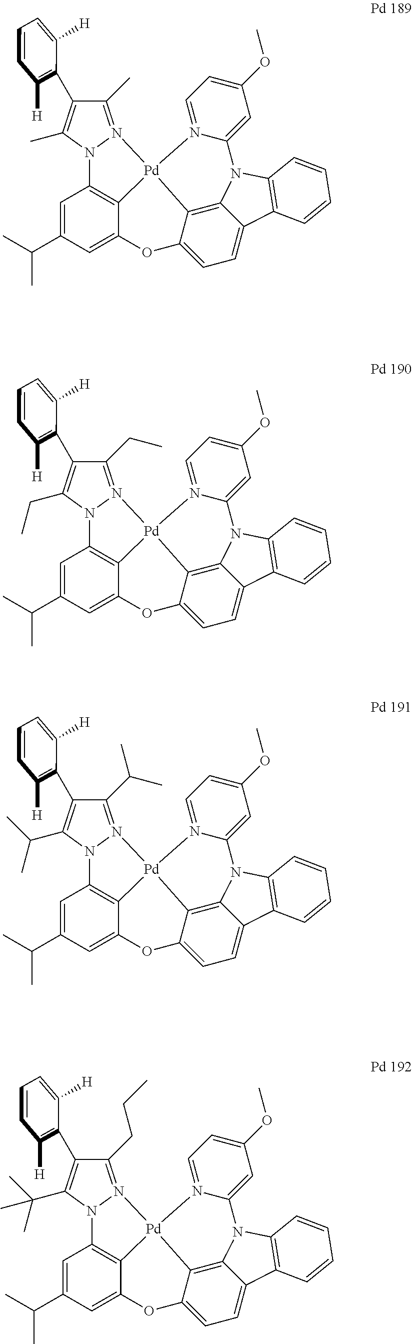

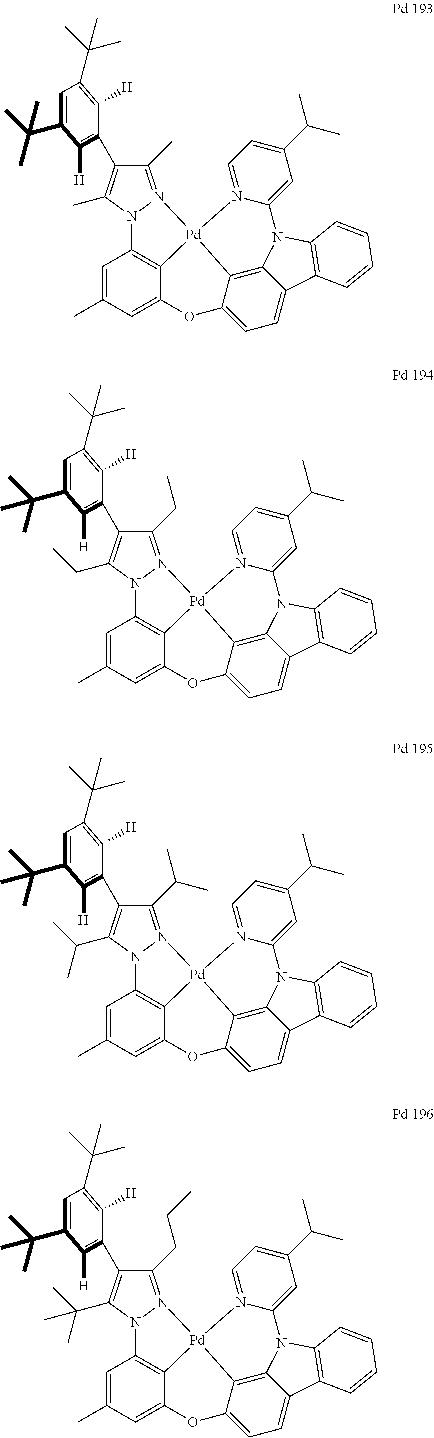

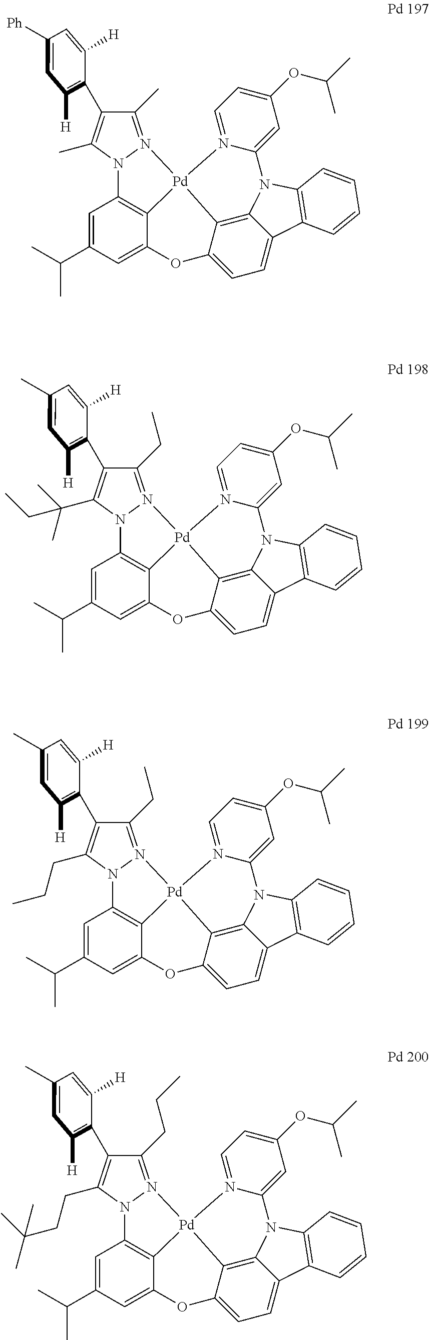

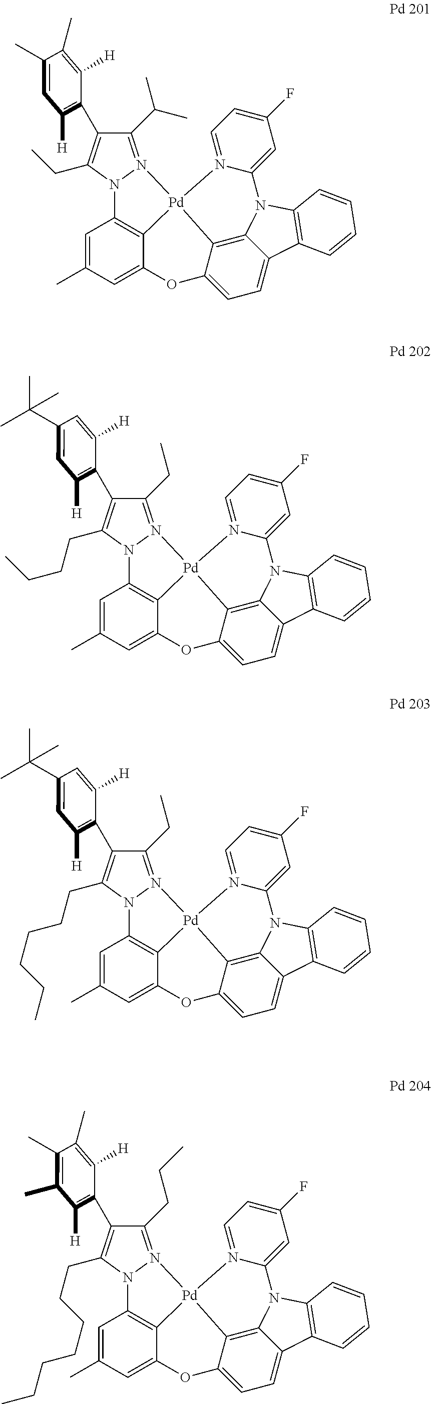

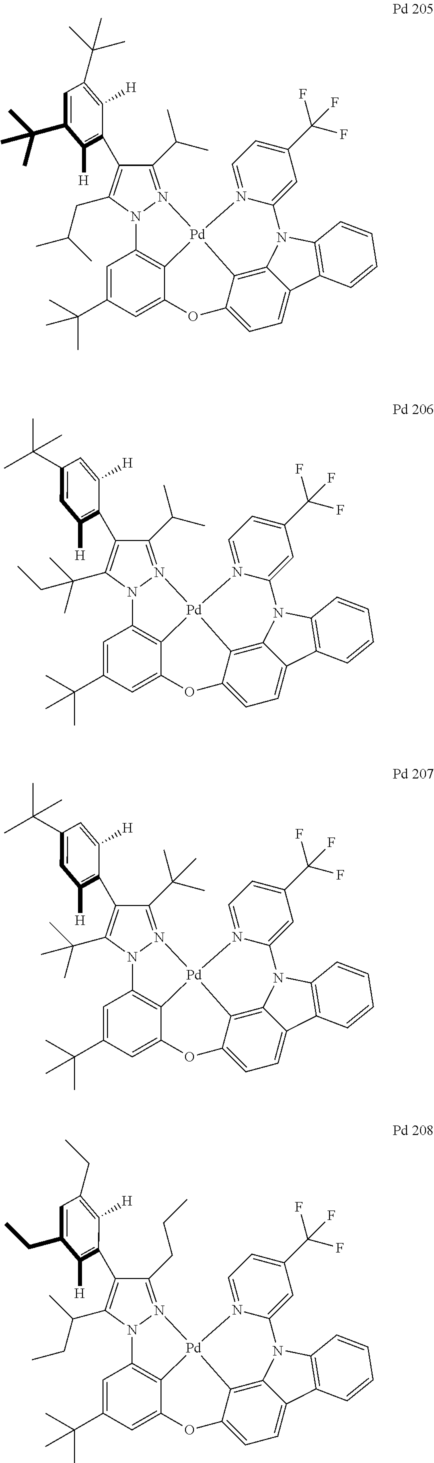

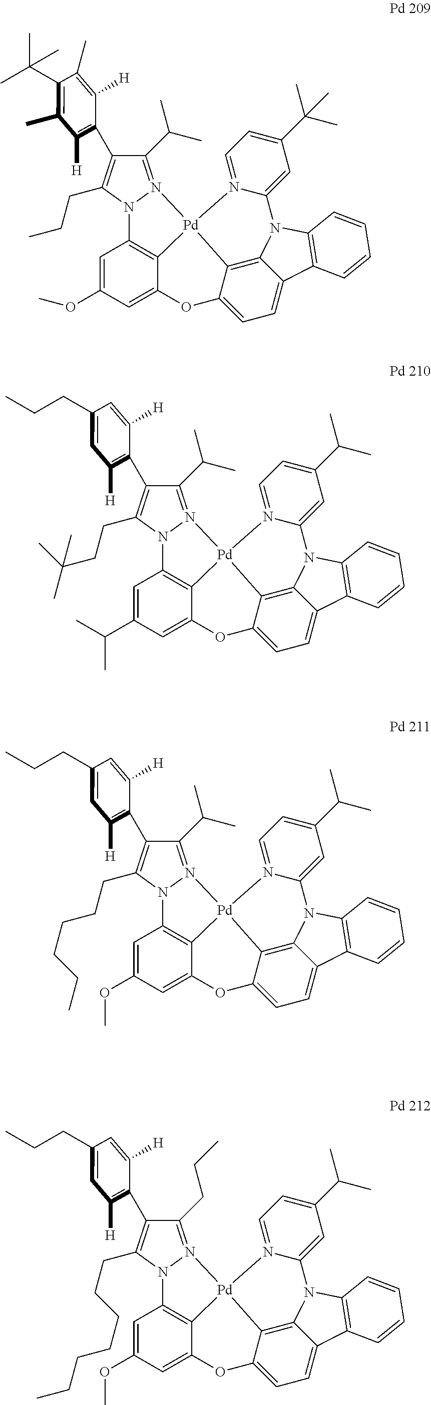

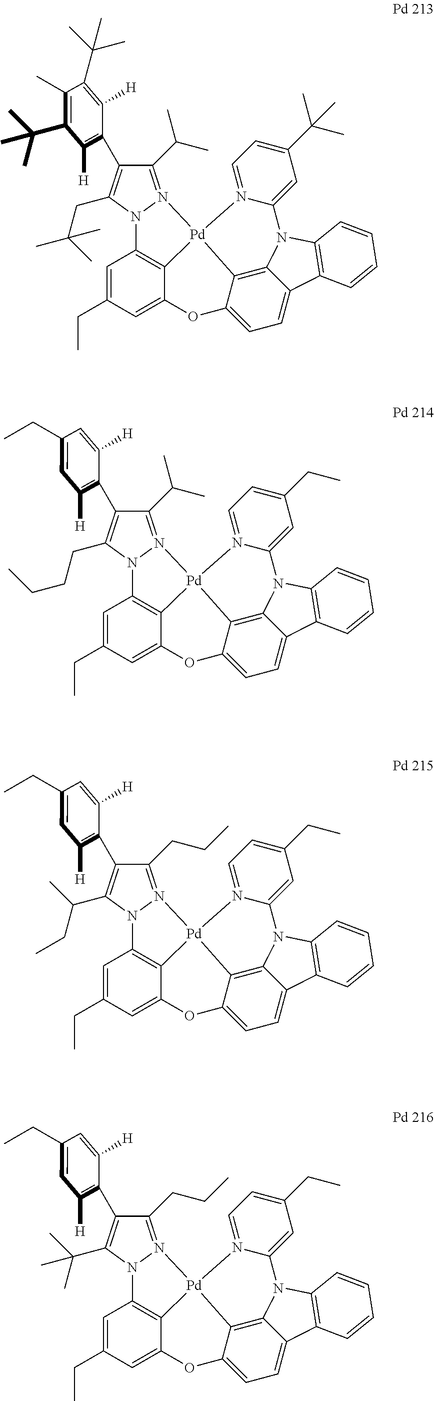

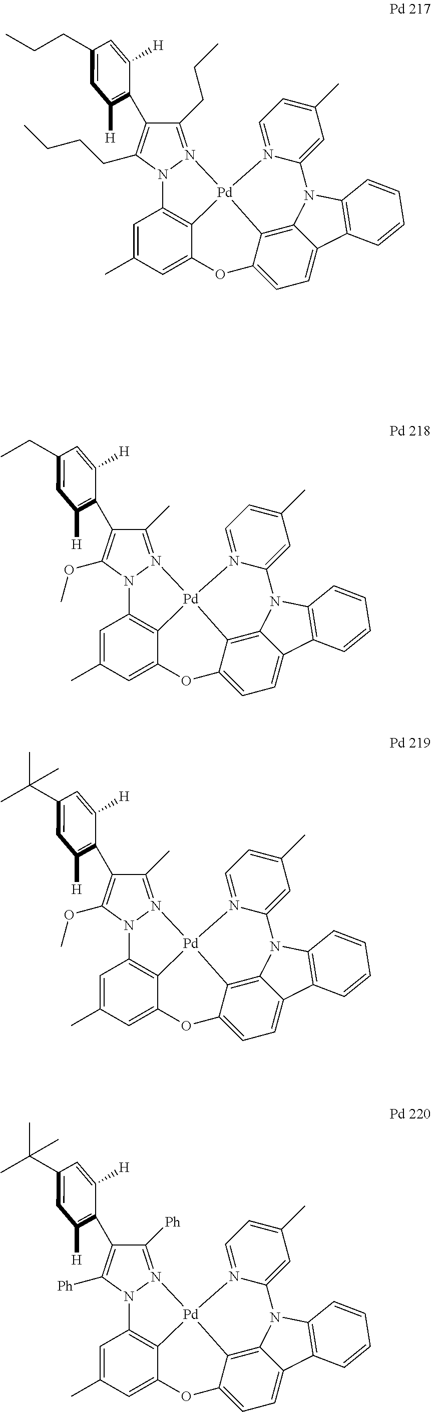

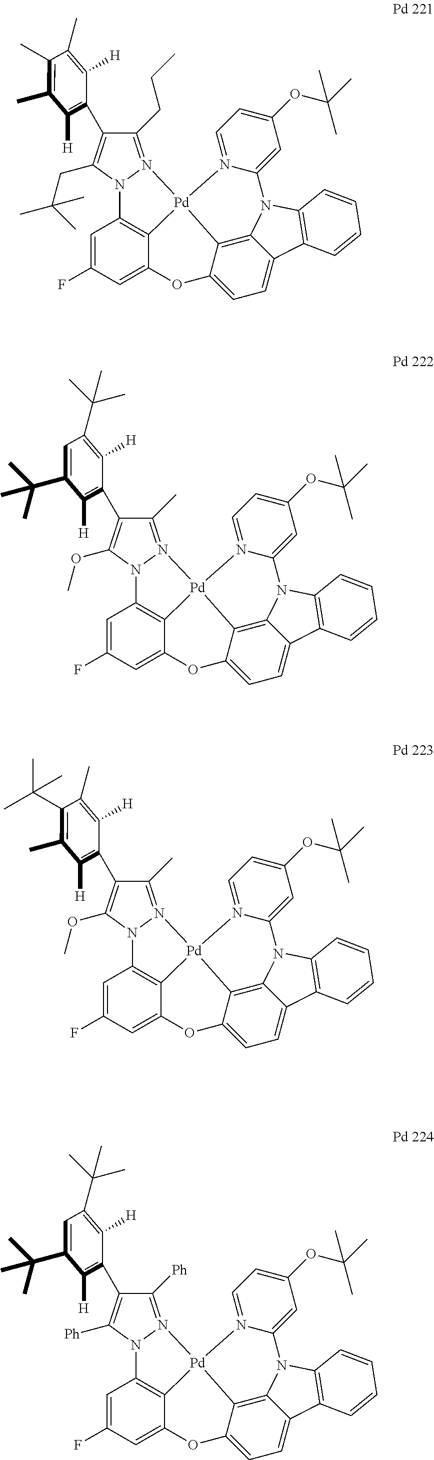

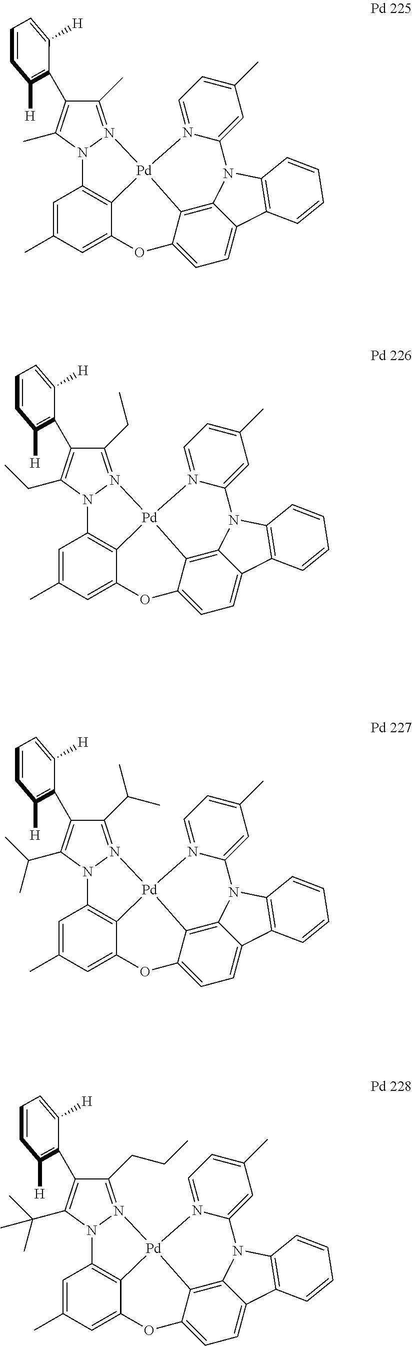

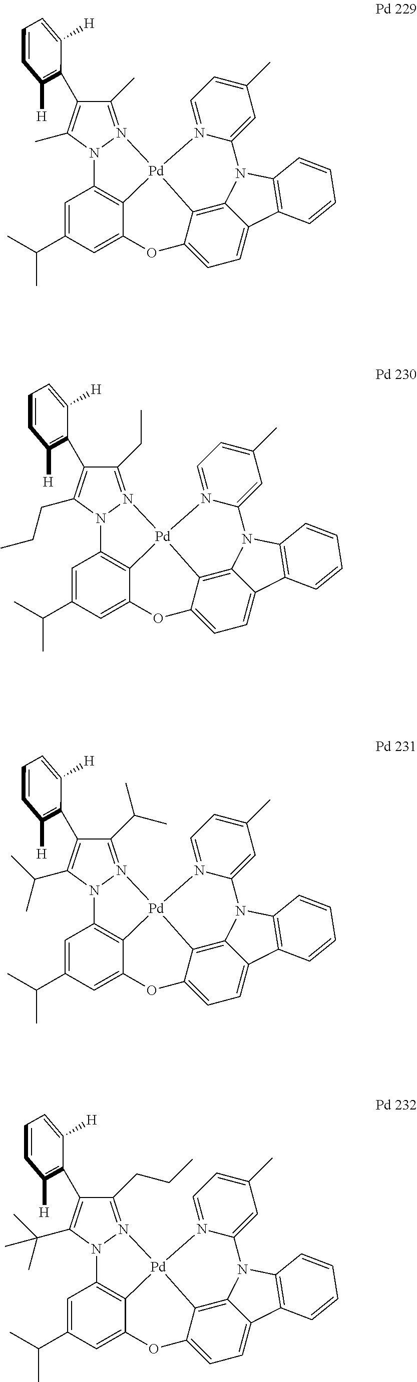

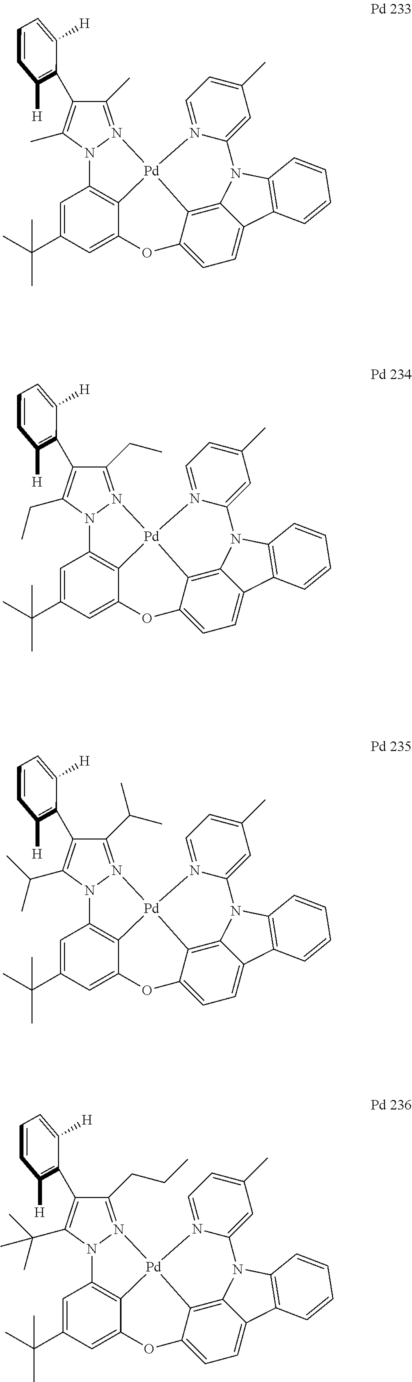

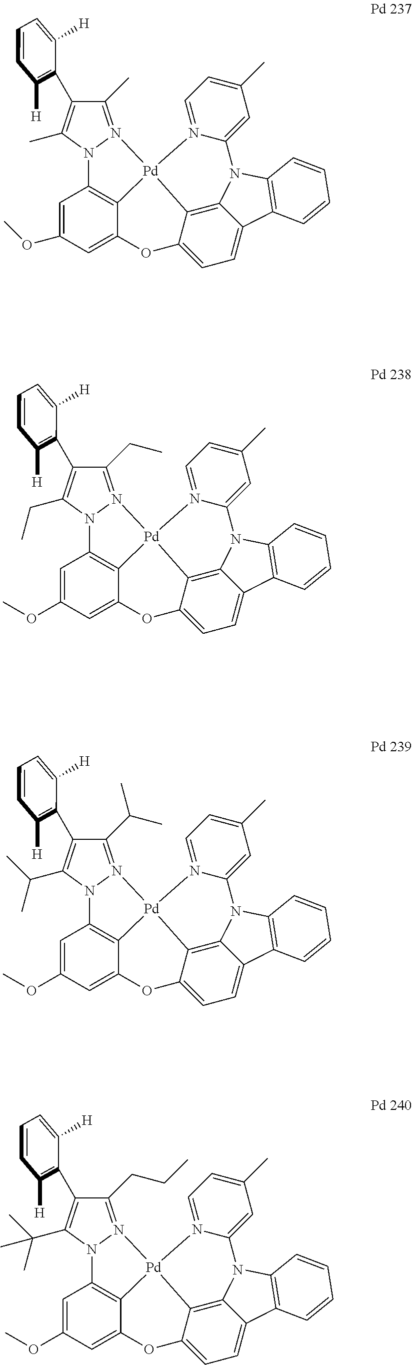

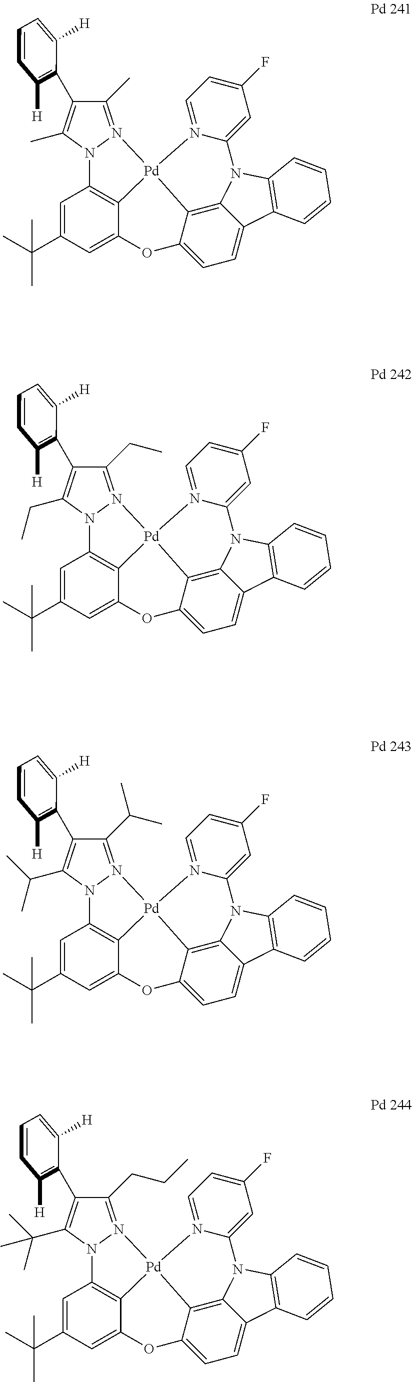

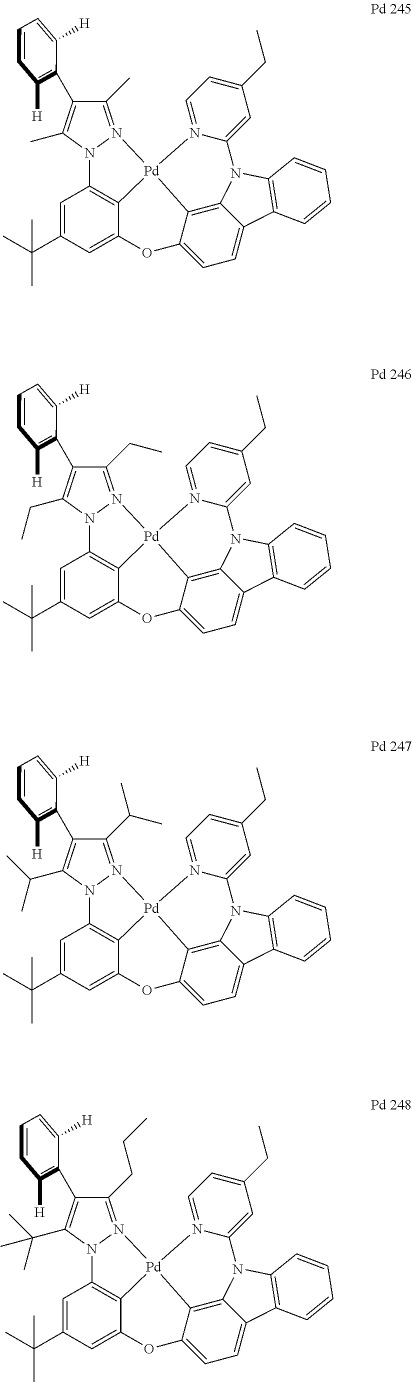

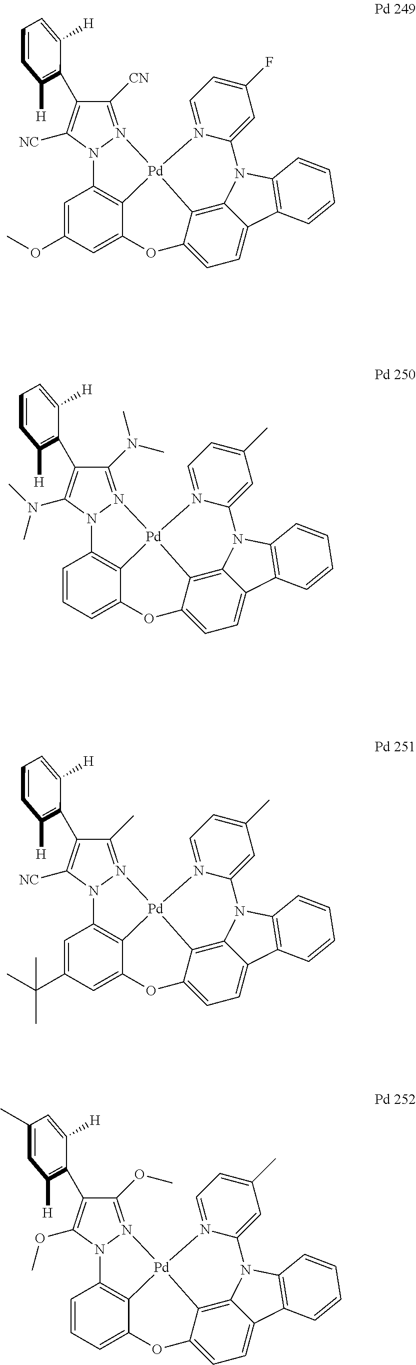

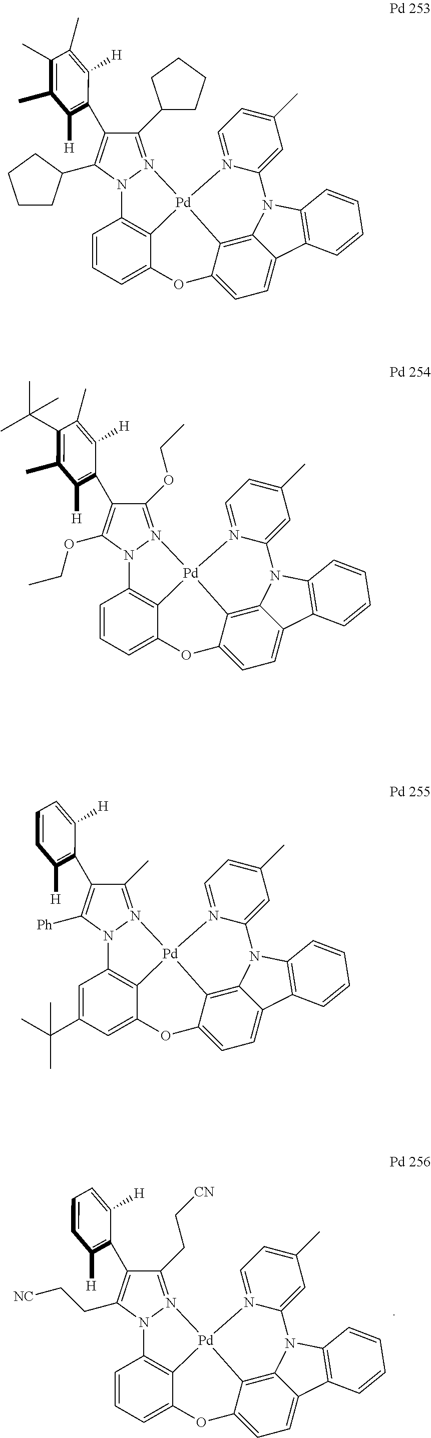

The tetradentate cyclopalladated palladium complex comprising trisubstituted pyrazole provided by some specific embodiments of the present disclosure is electric neutrality.

Some specific embodiments of the present disclosure further provide an optical or electro-optical device which comprises one or more of the above-mentioned tetradentate cyclopalladated palladium complex comprising trisubstituted pyrazole.

The optical or electro-optical device provided by some specific embodiments of the present disclosure comprises a light absorbing device (such as a solar device or a photosensitive device), an organic light emitting diode (OLED), a light emitting device, or a device capable of both light absorption and emission.

The tetradentate cyclopalladated palladium complex comprising trisubstituted pyrazole in some specific embodiments of the present disclosure has 100% of internal quantum efficiency in the optical or electro-optical device.

Some specific embodiments of the present disclosure further provide an OLED device, and a luminescent material or a host material in the OLED device comprises one or more of the above-mentioned tetradentate cyclopalladated palladium complex comprising trisubstituted pyrazole.

The complex provided by some specific embodiments of the present disclosure can either be used as host materials for OLED devices, for example, applied to a full color display; or applied to luminescent materials for the OLED device, such as a light emitting device and a display, etc.

Preparation and Performance Evaluation Examples

The following examples are put forth so as to provide those of ordinary skills in the art with a complete disclosure and description of how the complexes, compositions, articles, devices and/or methods claimed herein are made and evaluated, and are intended to be purely exemplary and are not intended to be limiting in scope. Efforts have been made to ensure accuracy with respect to numbers (e.g., amounts, temperature, etc.), but some errors and deviations should be accounted for. Unless indicated otherwise, parts are parts by weight, temperature is in ° C., or is at ambient temperature, and pressure is at or near atmospheric pressure.

Various methods for preparing of the complexes described herein are recited in the examples. These methods are provided to illustrate various methods of preparation, but are not intended to limit any of the methods recited herein. Accordingly, one of skills in the art in possession of this disclosure could readily modify a recited method or utilize a different method to prepare one or more of the complexes described herein. The following aspects are only exemplary and are not intended to be limiting in scope. Temperatures, catalysts, concentrations, reactant compositions, and other process conditions can vary, and one of skills in the art, in possession of this disclosure, could readily select appropriate reactants and conditions for a desired complex.

¹H spectrum were recorded at 400 MHz, and ¹³C NMR spectrum were recorded at 100 MHz on Varian Liquid State NMR instruments in CDCl₃ or DMSO-d6 solutions and chemical shifts were referenced to residual protiated solvent. If CDCl₃ was used as solvent, ¹H NMR spectrum were recorded with tetramethylsilane (δ=0.00 ppm) as internal reference; and ¹³C NMR spectrum were recorded with DMSO-d₆ (δ=77.00 ppm) as internal reference. If H₂O (δ=3.33 ppm) was used as solvent, ¹H NMR spectrum were recorded with residual H₂O (δ=3.33 ppm) as internal reference; and ¹³C NMR spectrum were recorded with DMSO-d₆ (δ=39.52 ppm) as internal reference. The following abbreviations (or combinations thereof) were used to explain 1H NMR multiplicities: s=singlet, d=doublet, t=triplet, q=quartet, p=quintet, m=multiplet, and br=broad.

General Synthetic Route

The general synthetic route of the complexes disclosed in the present disclosure is as follows:

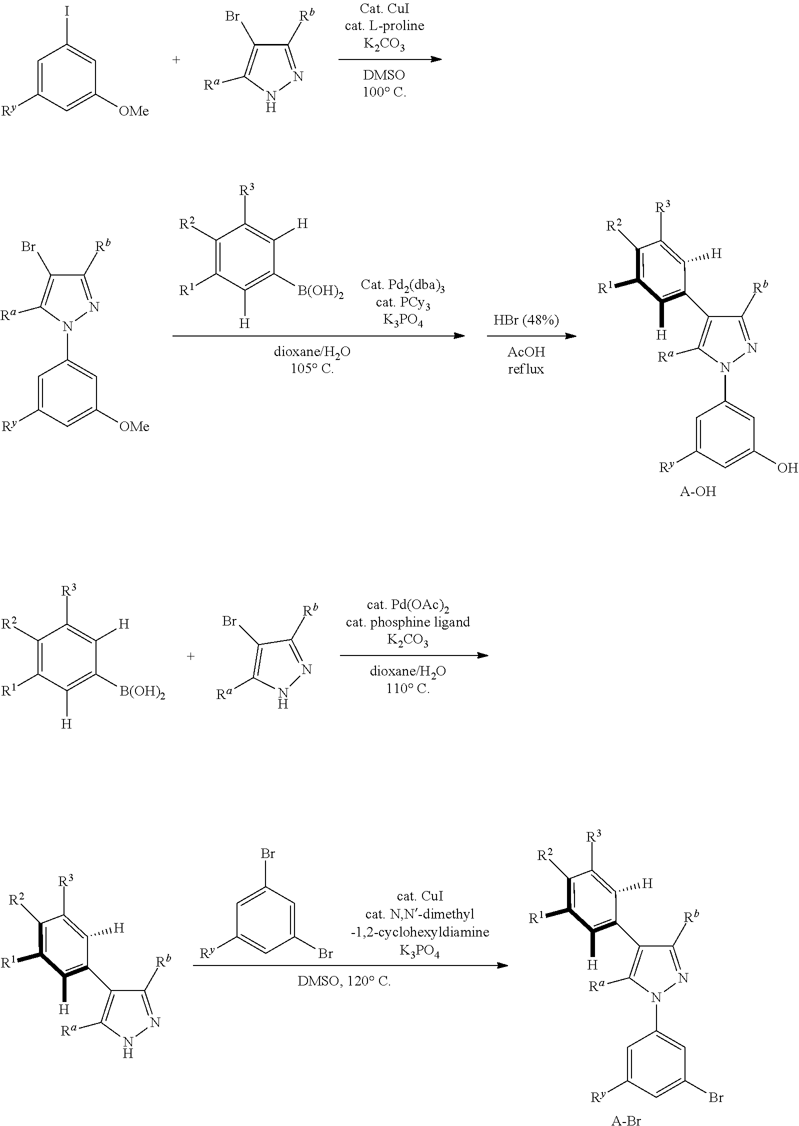

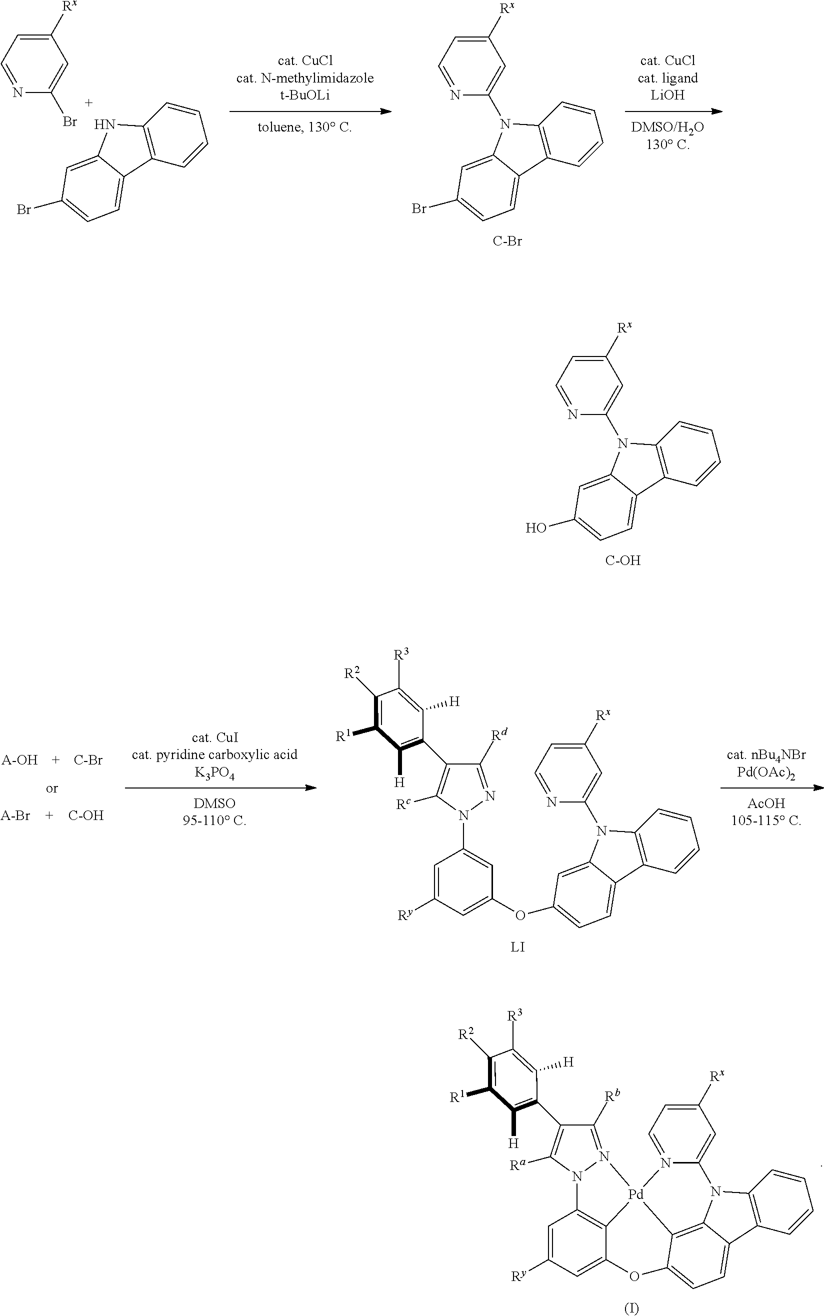

### PREPARATION EXAMPLES

### Example 1: The Complex Pd1 can be Synthesized According to the Following Route

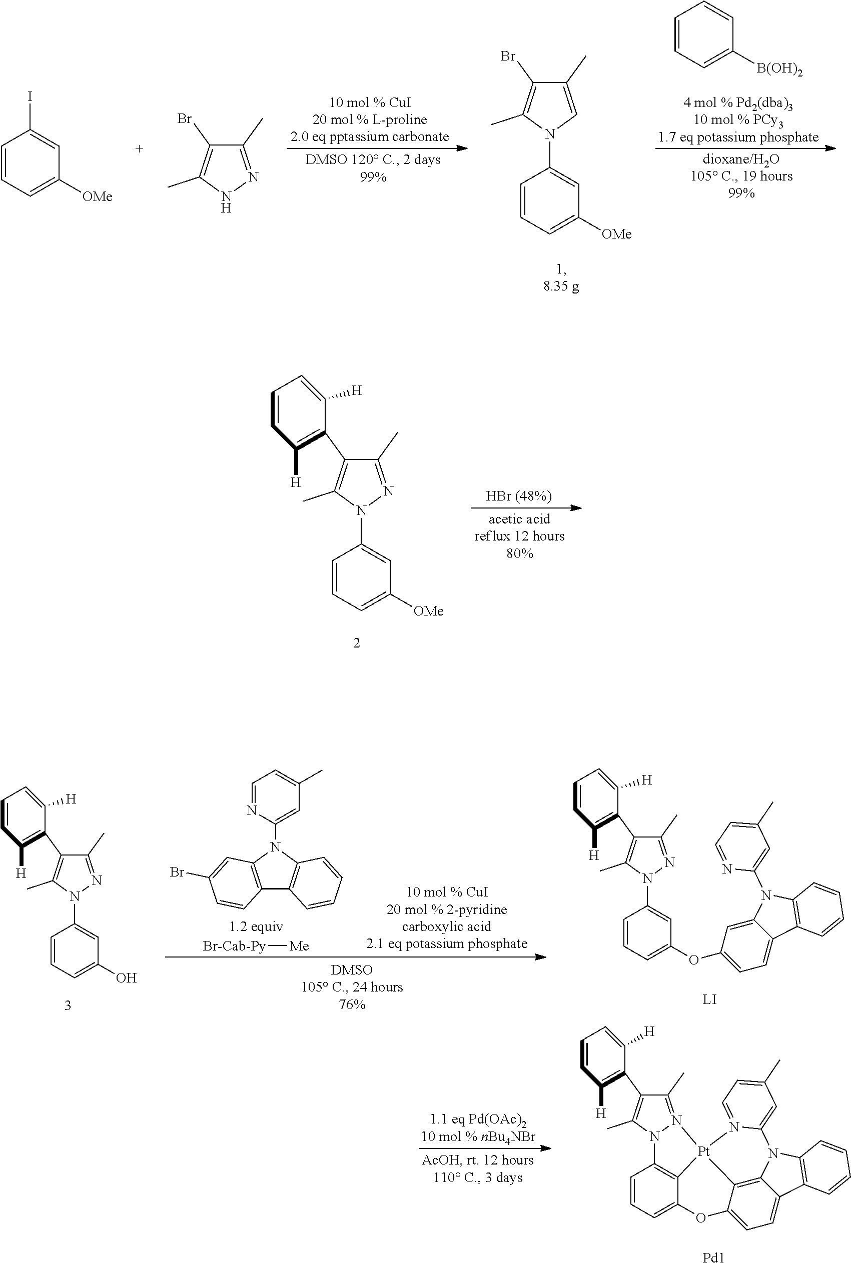

### Synthesis of Intermediate Compound 1

3,5-dimethyl-4-bromopyrazole (5250 mg, 30.00 mmol, 1.00 eq), cuprous iodide (572 mg, 3.00 mmol, 0.10), L-proline (691 mg, 6.00 mmol, 0.20 eq), potassium carbonate (8280 mg, 60.00 mmol, 2.00 eq) were sequentially added into a dry three-necked flask with a reflux condenser and a magnetic rotor, and purged with nitrogen for three times, then m-iodoanisole (10500 mg, 45.00 mmol, 1.50 eg) was added and dimethylsulphoxide (10 mL) was re-distilled. The mixture was stirred at 120° C. for 2 days and monitored by a TLC thin layer chromatography until the raw material 4-bromopyrazole was completely reacted. The mixture was quenched by adding 100 mL water, and was filtered. Insolubles were thoroughly washed with 50 mL ethyl acetate, and an organic phase in a mother liquid was separated, dried over anhydrous sodium sulfate, filtered, and then the solvent was distilled off under reduced pressure. The resulting crude product was separated and purified by silica gel column chromatography with petroleum ether and ethyl acetate (20:1-10:1) as eluent to obtain a compound 1, as a colorless viscous liquid (8350 mg in 99% yield).

¹H NMR (500 MHz, DMSO-d₆): δ 2.20 (s, 3H), 2.30 (s, 3H), 3.81 (s, 3H), 7.01 (ddd, J=8.1, 2.4, 0.6 Hz, 1H), 7.05-7.08 (m, 2H), 7.42 (t, J=8.1 Hz, 1H).

### Synthesis of Intermediate Compound 2

4-bromo-1-(3-metoxybenzene)-3,5-dimethyl-1H-pyrazole 1 (900 mg, 3.20 mmol, 1.00 eq), phenylboronic acid (463 mg, 3.84 mmol, 1.20 eq), Pd₂(dba)₃ (119 mg, 0.13 mmol, 0.04 eq), tripotassium phosphate (1154 mg, 5.44 mmol, 1.70 eq), tricyclohexylphosphine (135 mg, 0.48 mmol, 0.10 eq) were sequentially added into a dry three-necked flask with a magnetic rotor, and purged with nitrogen for three times, then 1,4-dioxane (15 mL) and water (7 mL) were added. The mixture was bubbled with nitrogen for 20 minutes, and stirred and reacted at 105° C. for 2 days. Then the mixture was cooled and 100 mL water was added and the mixture was extracted with ethyl acetate (50 mL×3). Organic phases were combined, dried over anhydrous sodium sulfate, filtered, and the solvent was distilled off under reduced pressure. The resulting crude product was separated and purified by silica gel column chromatography with petroleum ether and ethyl acetate (20:1-15:1) as eluent to obtain compound 2, as an off-white solid (898 mg in 99% yield). ¹H NMR (500 MHz, DMSO-d₆): δ 2.24 (s, 3H), 2.30 (s, 3H), 3.83 (s, 3H), 6.99 (dd, J=8.4, 1.9 Hz, 1H), 7.10-7.13 (m, 2H), 7.31-7.38 (m, 3H), 7.42-7.48 (m, 3H).

### Synthesis of Intermediate Compound 3

1-(3-metoxybenzene)-3,5-dimethyl-4-phenyl-1H-pyrazole (898 mg, 3.23 mmol, 1.00 eq) was dissolved in 23 mL acetic acid and then hydrobromic acid (6.8 mL in 48% concentration) was added thereto. The mixture was stirred and reacted at 120° C. for 15 hours. The mixture was cooled, and the acetic acid was spin out, a small amount of water was added, then a sodium carbonate solution was added, and titration was performed so that no bubbles were generated, an aqueous phase was extracted with ethyl acetate (20 mL×2), organic phases were combined, dried over anhydrous sodium sulfate, filtered, and the solvent was distilled off under reduced pressure. The resulting crude product was separated and purified by silica gel column chromatography with petroleum ether and ethyl acetate (5:1-3:1) as eluent to obtain compound 3, as a pale yellow solid (680 mg in 80% yield).

¹H NMR (500 MHz, DMSO-d₆): δ 2.22 (s, 3H), 2.28 (s, 3H), 6.81 (ddd, J=8.2, 2.2, 0.8 Hz, 1H), 6.93 (t, J=2.2 Hz, 1H), 6.94-6.96 (m, 1H), 7.29-7.37 (m, 4H), 7.44-7.47 (m, 2H), 9.82 (s, 1H).

### Synthesis of ligand L1

Phenol derivative 3 (600 mg, 2.27 mmol, 1.00 eq), 2-bromo-9-(4-methylpyridine-2-)-9H-carbazole Br-Cab-Py-Me (918 mg, 2.72 mmol, 1.20 eq), cuprous iodide (44 mg, 0.23 mmol, 0.10 eq), 2-picolinic acid (56 mg, 0.45 mmol, 0.20 eq) and potassium phosphate (1011 mg, 4.76 mmol, 2.10 eq) were sequentially added into a dry three-necked flask with a magnetic rotor, purged with nitrogen for three times, then DMSO (5 mL) was added. The mixture was stirred and reacted at 105° C. for 24 hours and monitored by a TLC. The mixture was cooled, and added with ethyl acetate (40 mL) and water (40 mL), diluted and then liquid and organic phases were separated, an aqueous phase was extracted with ethyl acetate (20 mL×2), then the organic phases were combined, dried over anhydrous sodium sulfate, filtered, and the solvent was distilled off under reduced pressure. The resulting crude product was separated and purified by silica gel column chromatography with petroleum ether and ethyl acetate (15:1-10:1) as eluent to obtain ligand L1, as a white solid (900 mg in 76% yield).

¹H NMR (500 MHz, DMSO-d₆): δ 2.18 (s, 3H), 2.26 (s, 3H), 2.45 (s, 3H), 7.10-7.13 (m, 2H), 7.17 (t, J=2.2 Hz, 1H), 7.29-7.36 (m, 6H), 7.42-7.47 (m, 3H), 7.53 (t, J=8.1 Hz, 1H), 7.53 (d, J=2.5 Hz, 1H), 7.61 (s, 1H), 7.78 (d, J=8.3 Hz, 1H), 8.24 (d, J=7.7 Hz, 1H), 8.30 (d, J=8.4 Hz, 1H), 8.53 (d, J=5.1 Hz, 1H).

### Synthesis of Metal Complex Pd1

Ligand L1 (200.0 mg, 0.38 mmol, 1.0 eq), Pd(OAc)₂ (95.0 mg, 0.42 mmol, 1.1 eq) and ⁿBu₄NBr (13.0 mg, 0.04 mmol, 0.1 eq) were successively added to a 100 mL three-necked flask with a magnetic rotor and a condenser. The mixture was purged with nitrogen for three times, and a solvent acetic acid (25 mL) was added; then the mixture was bubbled with nitrogen for 10 minutes, stirred at room temperature for 12 hours and then stirred at 110° C. in an oil bath for 3 days. The mixture was cooled to room temperature, and the solvent was distilled off under reduced pressure. The resulting crude product was separated and purified by silica gel column chromatography with petroleum ether and methylene chloride (3:1-1.5:1) as eluent) to obtain Pd1, a white solid (200.6 mg in 84% yield). ¹H NMR (500 MHz, DMSO-d₆): δ 2.33 (s, 3H), 2.44 (s, 3H), 2.67 (s, 3H), 7.02 (dd, J=8.0, 0.5 Hz, 1H), 7.19 (d, J=8.5 Hz, 1H), 7.20 (dd, J=6.5, 0.5 Hz, 1H), 7.28 (t, J=8.0 Hz, 1H), 7.36-7.54 (m, 8H), 7.91 (d, J=8.0 Hz, 1H), 7.92 (s, 1H), 8.11 (d, J=8.0 Hz, 1H), 8.15 (d, J=7.0 Hz, 1H), 8.96 (d, J=6.0 Hz, 1H). ¹³C NMR (100 MHz, DMSO-d₆): δ 13.41, 13.55, 20.98, 108.18, 111.25, 112.00, 112.59, 115.07, 115.56, 116.47, 116.67, 119.87, 120.50, 122.52, 122.67, 124.65, 125.96, 127.44, 127.87, 128.76, 130.14, 131.56, 137.98, 143.14, 147.32, 147.98, 148.62, 151.13, 151.69, 151.75, 152.25. HRMS (DART POSITIVE Ion Mode) for C₃₅H₂₇N₄O¹⁰²Pd [M+H]⁺ calcd 621.1235, found 621.1229.

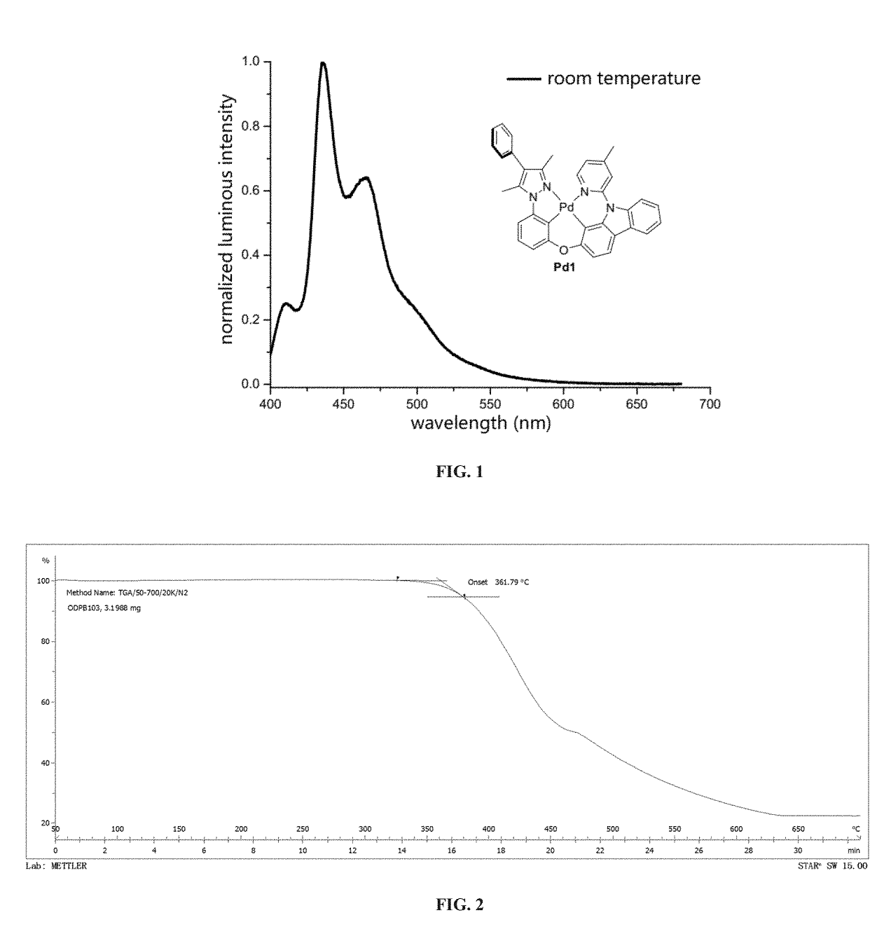

FIG. 1 shows the emission spectrum of the complex Pd1 in dichloromethane solution and at room temperature; and FIG. 2 shows the original spectrum of thermogravimetric analysis (TGA) curve of the complex Pd1.

### Example 2: The Complex Pd113 can be Synthesized According to the Following Route

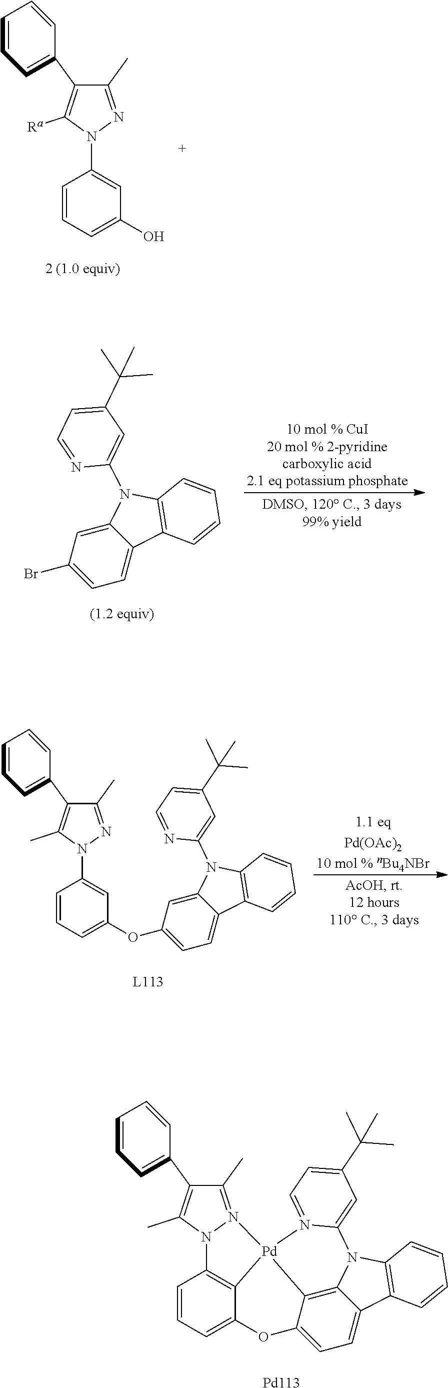

### Synthesis of Ligand L113

1-(3-hydroxyphenyl)-2-5-dimethyl-4-)-phenylpyrazole (793.0 mg, 3.00 mmol, 1.0 eq), 2-bromo-9-(2-(4-tert-butylpyridyl))carbazole (1.37 g, 3.60 mmol, 1.2 eq), cuprous iodide (57.1 mg, 0.30 mmol, 0.1 eq), ligand 2-picolinic acid (73.9 mg, 0.60 mmol, 0.2 eq) and potassium phosphate (1.34 g, 6.30 mmol, 2.1 eq) were successively added into a dry sealed tube with a magnetic rotor. Then the mixture was purged with nitrogen for three times and added with a solvent dimethyl sulfoxide (8 mL). The mixture was then stirred at 120° C. for 3 days, cooled to room temperature, diluted with a large amount of ethyl acetate, filtered and washed with ethyl acetate. The resulting filtrate was washed twice with water and an aqueous phase was extracted twice. Organic phases were combined and dried over anhydrous sodium sulfate. The mixture was filtered, and the solvent was distilled off under reduced pressure. The resulting crude product was separated and purified by silica gel column chromatography with petroleum ether and ethyl acetate (20:1-10:1) as eluent to obtain a target ligand L113, as a white solid (1.67 mg in 99% yield).

¹H NMR (500 MHz, DMSO-d₆): δ 1.29 (s, 9H), 2.18 (s, 3H), 2.21 (s, 3H), 7.13-7.16 (m, 2H), 7.20 (t, J=7.0 Hz, 1H), 7.28-7.35 (m, 5H), 7.41-7.47 (m, 5H), 7.52 (t, J=8.0 Hz, 1H), 7.65 (d, J=1.0 Hz, 1H), 7.75 (d, J=8.0 Hz, 1H), 8.24 (d, J=7.5 Hz, 1H), 8.30 (d, J=8.5 Hz, 1H), 8.57 (d, J=5.5 Hz, 1H).

### Synthesis of Metal Complex Pd113

L113 (281.4 mg, 0.50 mmol, 1.0 eq), Pd(OAc)₂ (123.5 mg, 0.55 mmol, 1.1 eq) and ⁿBu₄NBr (16.1 mg, 0.05 mmol, 0.1 eq) were successively added to a 100 mL three-necked flask with a magnetic rotor and a condenser. The mixture was purged with nitrogen for three times, and a solvent acetic acid (30 mL) was added; then the mixture was bubbled with nitrogen for 10 minutes, stirred at room temperature for 12 hours and then stirred at 110° C. in an oil bath for 3 days. The mixture was cooled to room temperature, and the solvent was distilled off under reduced pressure. The resulting crude product was separated and purified by silica gel column chromatography with petroleum ether and methylene chloride (2:1-1:1) as eluent to obtain Pd113, as a brown solid (198.4 mg in 59% yield). ¹H NMR (500 MHz, DMSO-d₆): δ 1.32 (s, 9H), 2.35 (s, 3H), 2.68 (s, 3H), 7.02 (dd, J=8.0, 1.0 Hz, 1H), 7.19 (d, J=8.0 Hz, 1H), 7.28 (t, J=8.0 Hz, 1H), 7.36-7.54 (m, 9H), 7.92 (d, J=8.0 Hz, 1H), 7.99 (d, J=1.5 Hz, 1H), 8.10 (d, J=8.0 Hz, 1H), 8.17 (dd, J=7.5, 0.5 Hz, 1H), 8.99 (d, J=6.0 Hz, 1H). ¹³C NMR (100 MHz, DMSO-d₆): δ 13.35, 13.63, 29.71, 35.28, 108.07, 111.08, 111.92, 111.95, 112.54, 114.54, 116.38, 116.62, 116.92, 119.97, 122.51, 122.65, 124.63, 125.90, 127.39, 127.88, 128.68, 130.08, 131.50, 137.95, 138.02, 143.16, 147.25, 147.96, 148.84, 151.15, 151.68, 151.79, 164.03. HRMS (DART POSITIVE Ion Mode) for C₃₈H₃₃N₄O¹⁰²Pd [M+H]⁺ calcd 663.1705, found 663.1704.

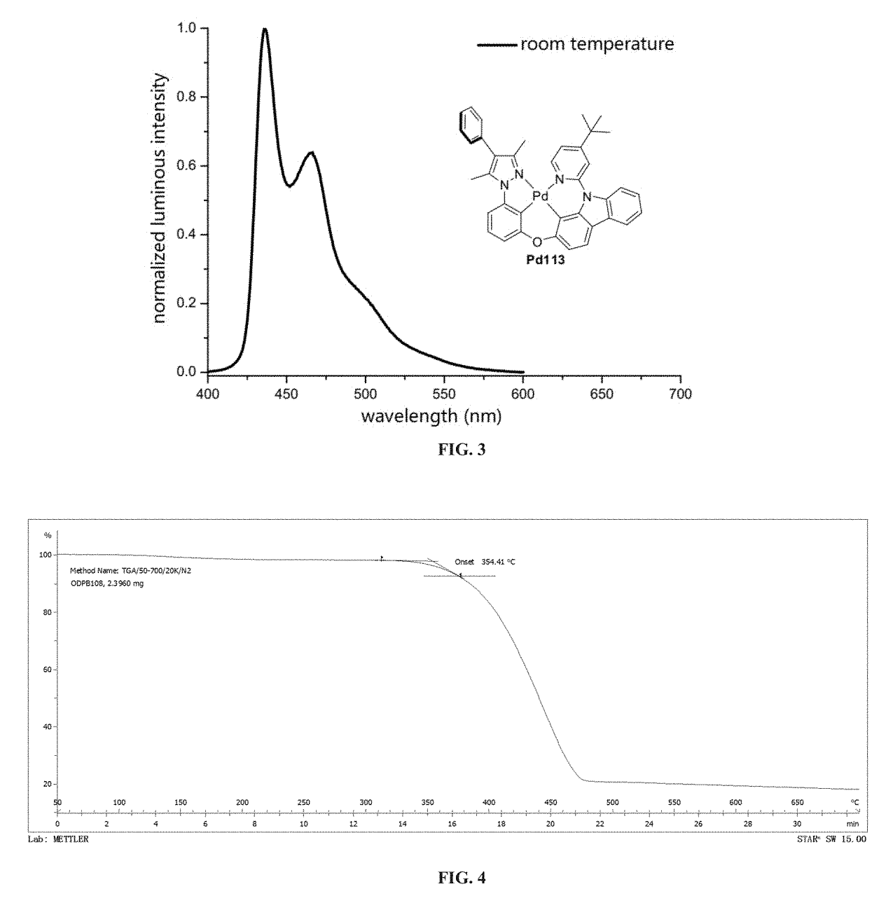

FIG. 3 shows the emission spectrum of the complex Pd113 in dichloromethane solution and at room temperature; and FIG. 4 shows the original spectrum of thermogravimetric analysis (TGA) curve of the complex Pd113.

### Example 3: The Complex Pd229 can be Synthesized According to the Following Route

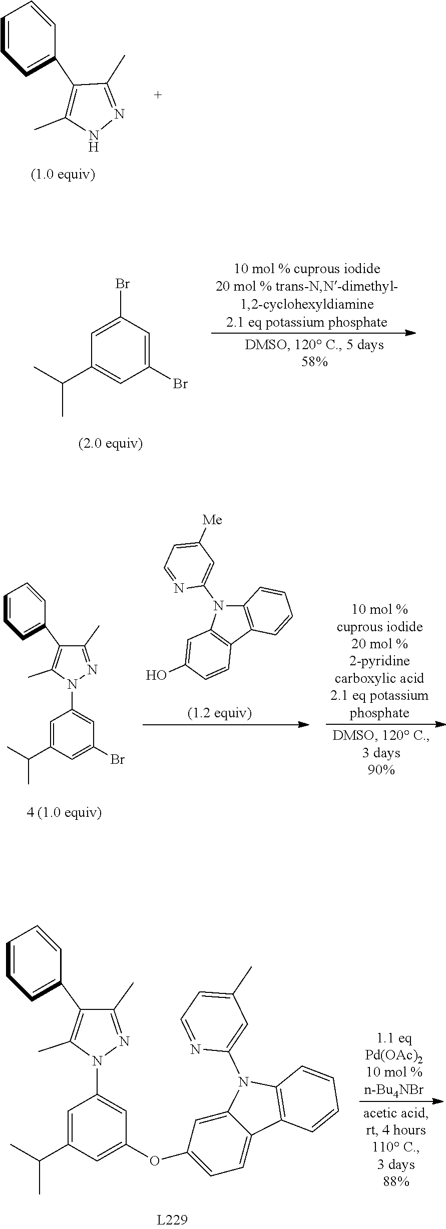

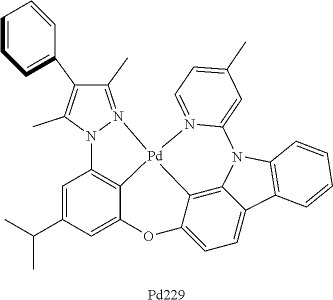

### Synthesis of Intermediate 4

4-phenyl-3,5-dimethylpyrazole (1.0338 g, 6 mmol, 1.0 eq.), 1,3-dibromo-5-isopropylbenzene (3.3360 g, 12 mmol, 2.0 eq), cuprous iodide (0.1143 g, 0.6 mmol, 0.1 eq), potassium phosphate (2.6750 g, 12.6 mmol, 2.1 eq) and trans-N,N′-dimethyl-1,2-cyclohexyldiamine (0.1741 g, 1.2 mmol, 98%, 0.2 eq) were successively added into a dry sealed tube with a magnetic rotor. The mixture was purged with nitrogen for three times and added with a solvent dimethyl sulfoxide (9 mL) under nitrogen protection. The tube was then placed in an oil bath at 120° C. After stirring for 5 days, the mixture was cooled to room temperature and filtered through celite, and the insolubles were washed with thoroughly with ethyl acetate (30 mL×3). A resulting filtrate was washed with brine (20 mL×2) and aqueous phases were combined and extracted with ethyl acetate (10 mL×2). All organic phases are combined and dried over anhydrous sodium sulfate. The mixture was filtered, concentrated, and the crude product was separated and purified by rapid silica gel column chromatography using petroleum ether and ethyl acetate (30:1-15:1) as eluent to obtain intermediate 4, as a light yellow oily matter (1.2831 g in 58% yield).

¹H NMR (500 MHz, DMSO-d₆): δ1.25 (d, J=7.0 Hz, 6H), 2.23 (s, 3H), 2.31 (s, 3H), 3.00 (sep, J=6.8 Hz, 1H), 7.30-7.38 (m, 3H), 7.43-7.52 (m, 4H), 7.58 (t, J=2.0 Hz, 1H).

### Synthesis of Ligand L229

Intermediate 4 (0.7017 g, 1.9 mmol, 1.0 eq.), OH-Cab-Py-Me (0.6254 g, 2.3 mmol, 1.2 eq), cuprous iodide (0.0362 g, 0.19 mmol, 0.1 eq), 2-picolinic acid (0.0473 g, 0.38 mmol, 99%, 0.2 eq) and potassium phosphate (0.8471 g, 12.6 mmol, 2.1 eq) were successively added into a dry sealed tube with a magnetic rotor. The mixture was purged with nitrogen for three times and added with dimethyl sulfoxide (4 mL) under nitrogen protection. The tube was then placed in an oil bath at 120° C. After stirring for 3 days, the reaction was completed by thin layer chromatography monitoring. The mixture was cooled to room temperature, and washed by ethyl acetate (40 mL) and brine (20 mL×2). Aqueous phases were combined and extracted with ethyl acetate (10 mL×2). All organic phases are combined and dried over anhydrous sodium sulfate. The mixture was filtered, concentrated, and the crude product was separated and purified by rapid silica gel column chromatography with petroleum ether and ethyl acetate (10:1) as eluent to obtain ligand L229, as a white solid (0.9571 g in 90% yield).

¹H NMR (500 MHz, DMSO-d₆): δ 1.23 (d, J=7.0 Hz, 6H), 2.17 (s, 3H), 2.23 (s, 3H), 2.44 (s, 3H), 2.98 (sep, J=7.3 Hz, 1H), 6.92 (t, J=2.0 Hz, 1H), 7.03 (t, J=1.8 Hz, 1H), 7.11 (dd, J₁=8.3 Hz, J₂=2.3 Hz, 1H), 7.18 (t, J=1.5 Hz, 1H), 7.27-7.37 (m, 5H), 7.40-7.48 (m, 3H), 7.51 (d, J=2.5 Hz, 1H), 7.60 (s, 1H), 7.76 (d, J=8.0 Hz, 1H), 8.23 (d, J=7.0 Hz, 1H), 8.29 (d, J=8.5 Hz, 1H), 8.52 (d, J=5.0 Hz, 1H).

### Synthesis of the Metal Complex Pd229

L229 (0.1688 g, 0.30 mmol, 1.0 eq), Pd(OAc)₂ (0.0741 g, 0.33 mmol, 1.1 eq) and n-Bu₄NBr (0.0098 g, 0.03 mmol, 0.1 eq) were successively added to a dry sealed tube with a magnetic rotor. The mixture was purged with nitrogen for three times and added with acetic acid (18 mL) under nitrogen protection. The mixture was bubbled with nitrogen for 20 minutes and stirred at room temperature for 4 hours. Then the reaction flask was placed in an oil bath at 110° C. After stirring for 3 days, the mixture was cooled to room temperature and concentrated, and a resulting crude product was separated and purified by rapid silica gel column chromatography using petroleum ether and methylene chloride (2:1-1:1) as eluent to obtain Pd229, as a white solid (0.1764 g in 88% yield). ¹H NMR (400 MHz, DMSO-d₆): δ 1.31 (d, J=6.8 Hz, 6H), 2.33 (s, 3H), 2.44 (s, 3H), 2.69 (s, 3H), 2.95-3.08 (m, 1H), 6.92 (s, 1H), 7.14-7.25 (m, 3H), 7.34-7.48 (m, 5H), 7.48-7.57 (m, 2H), 7.86-7.93 (m, 2H), 8.06-8.18 (m, 2H), 8.94 (d, J=6.0 Hz, 1H).

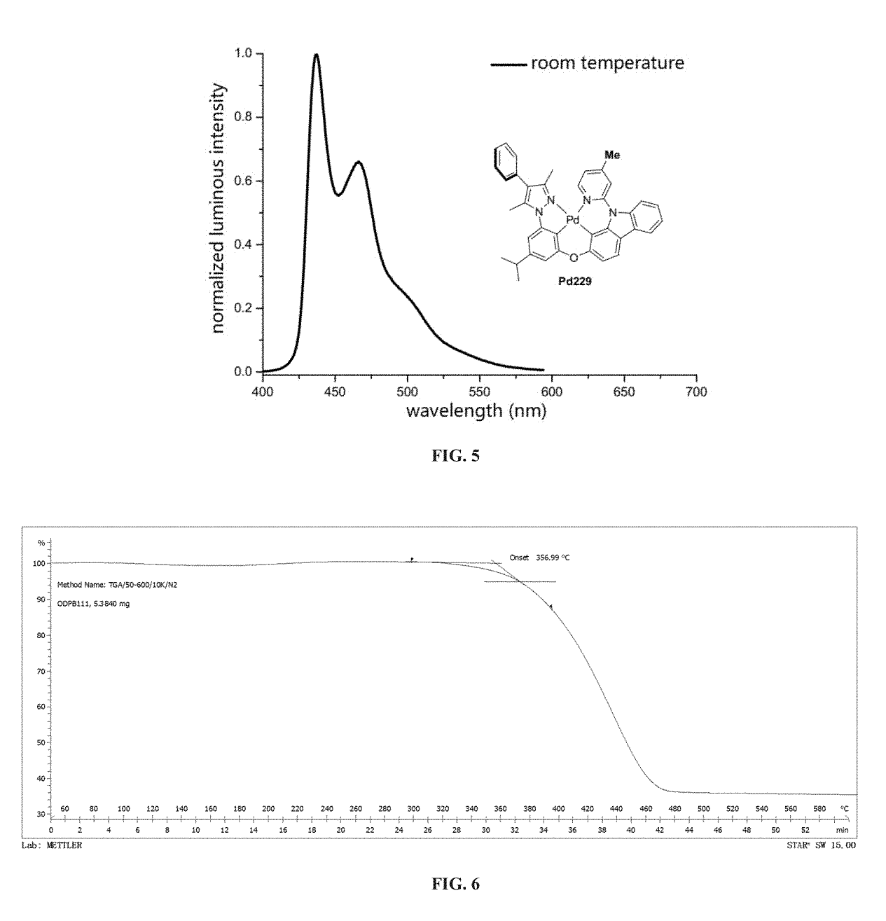

FIG. 5 shows the emission spectrum of the complex Pd229 in dichloromethane solution and at room temperature; and FIG. 6 shows the original spectrum of thermogravimetric analysis (TGA) curve of the complex Pd229.

### Example 4: The Complex Pd233 can be Synthesized According to the Following Route

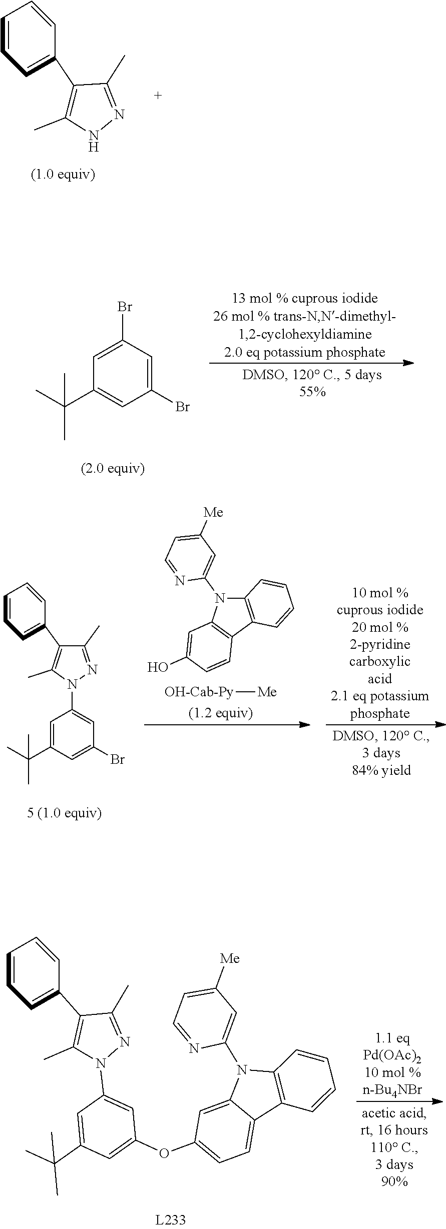

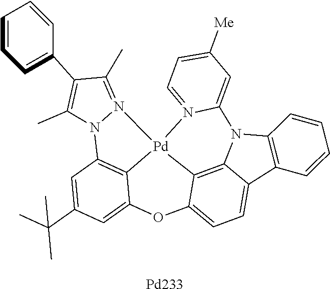

### Synthesis of Intermediate 5

4-phenyl-3,5-dimethylpyrazole (2.0680 g, 12 mmol, 1.0 eq.), 1,3-dibromo-5-t-butylbenzene (7.1513 g, 24 mmol, 98%, 2.0 eq), cuprous iodide (0.2971 g, 1.56 mmol, 0.13 eq), potassium phosphate (5.0945 g, 24 mmol, 2.0 eq) and trans-N,N′-dimethyl-1,2-cyclohexyldiamine (0.4528 g, 3.12 mmol, 98%, 0.26 eq) were successively added into a dry three-necked flask with a magnetic rotor. The mixture was purged with nitrogen for three times and added with dimethyl sulfoxide (18 mL) under nitrogen protection. Then the reaction flask was placed in an oil bath at 120° C. After stirring for 5 days, the mixture was cooled to room temperature and filtered through celite, and the insolubles were washed with thoroughly with ethyl acetate (30 mL×3). A resulting filtrate was washed with brine (20 mL×2) and aqueous phases were combined and extracted with ethyl acetate (10 mL×2). All organic phases are combined and dried over anhydrous sodium sulfate. The mixture was filtered, concentrated, and the resulting crude product was separated and purified by rapid silica gel column chromatography with petroleum ether and ethyl acetate (30:1-15:1) as eluent to obtain intermediate 4, as a light yellow oily matter (2.5293 g in 55% yield).

¹H NMR (500 MHz, DMSO-d₆): δ 1.33 (s, 9H), 2.23 (s, 3H), 2.31 (s, 3H), 7.30-7.40 (m, 3H), 7.44-7.50 (m, 2H), 7.55 (t, J=1.8 Hz, 1H), 7.57-7.60 (m, 2H).

### Synthesis of Ligand L233

Intermediate 5 (1.1499 g, 3.0 mmol, 1.0 eq.), OH-Cab-Py-Me (0.9875 g, 3.6 mmol, 1.2 eq), cuprous iodide (0.0571 g, 0.3 mmol, 0.1 eq), 2-picolinic acid (0.0746 g, 0.6 mmol, 99%, 0.2 eq) and potassium phosphate (1.3375 g, 6.3 mmol, 2.1 eq) were successively added into a dry sealed tube with a magnetic rotor. The mixture was purged with nitrogen for three times and added with dimethyl sulfoxide (6 mL) under nitrogen protection. The tube was then placed in an oil bath at 120° C. After stirring for 3 days, the reaction was completed by thin layer chromatography monitoring. The mixture was cooled to room temperature, and washed by ethyl acetate (60 mL) and brine (20 mL×2). Aqueous phases were combined and extracted with ethyl acetate (10 mL×2). All organic phases are combined and dried over anhydrous sodium sulfate. The mixture was filtered and concentrated, and the resulting crude product was separated and purified by rapid silica gel column chromatography with petroleum ether and ethyl acetate (10:1) as eluent to obtain L233, as a white solid (1.4576 g in 84% yield).

¹H NMR (500 MHz, DMSO-d₆): δ 1.32 (s, 9H), 2.17 (s, 3H), 2.22 (s, 3H), 2.44 (s, 3H), 6.90 (t, J=2.0 Hz, 1H), 7.12 (dd, J₁=8.8 Hz, J₂=2.3 Hz, 1H), 7.18 (t, J=1.8 Hz, 1H), 7.26-7.36 (m, 6H), 7.39-7.48 (m, 3H), 7.52 (d, J=1.5 Hz, 1H), 7.59 (s, 1H), 7.76 (d, J=8.0 Hz, 1H), 8.23 (d, J=7.0 Hz, 1H), 8.29 (d, J=8.5 Hz, 1H), 8.51 (d, J=5.0 Hz, 1H).

### Synthesis of Metal Complex Pd233

L233 (0.1730 g, 0.30 mmol, 1.0 eq), Pd(OAc)₂ (0.0741 g, 0.33 mmol, 1.1 eq) and n-Bu₄NBr (0.0098 g, 0.03 mmol, 0.1 eq) were successively added to a dry sealed tube with a magnetic rotor. The mixture was purged with nitrogen for three times and added with acetic acid (18 mL) under nitrogen protection. The mixture was bubbled with nitrogen for 20 minutes and stirred at room temperature for 16 hours. Then the reaction flask was placed in an oil bath at 110° C. After stirring for 3 days, the mixture was cooled to room temperature and concentrated, and the resulting crude product was separated and purified by rapid silica gel column chromatography with petroleum ether and methylene chloride (2:1-1:1) as eluent to obtain Pd233, as a white solid (0.1843 g in 90% yield). ¹H NMR (400 MHz, DMSO-d₆): δ 1.39 (s, 9H), 2.33 (s, 3H), 2.43 (s, 3H), 2.69 (s, 3H), 6.03 (d, J=1.2 Hz, 1H), 7.15-7.22 (m, 2H), 7.33 (d, J=1.2 Hz, 1H), 7.35-7.48 (m, 5H), 7.48-7.56 (m, 2H), 7.86-7.93 (m, 2H), 8.06-8.17 (m, 2H), 8.92 (d, J=6.0 Hz, 1H).

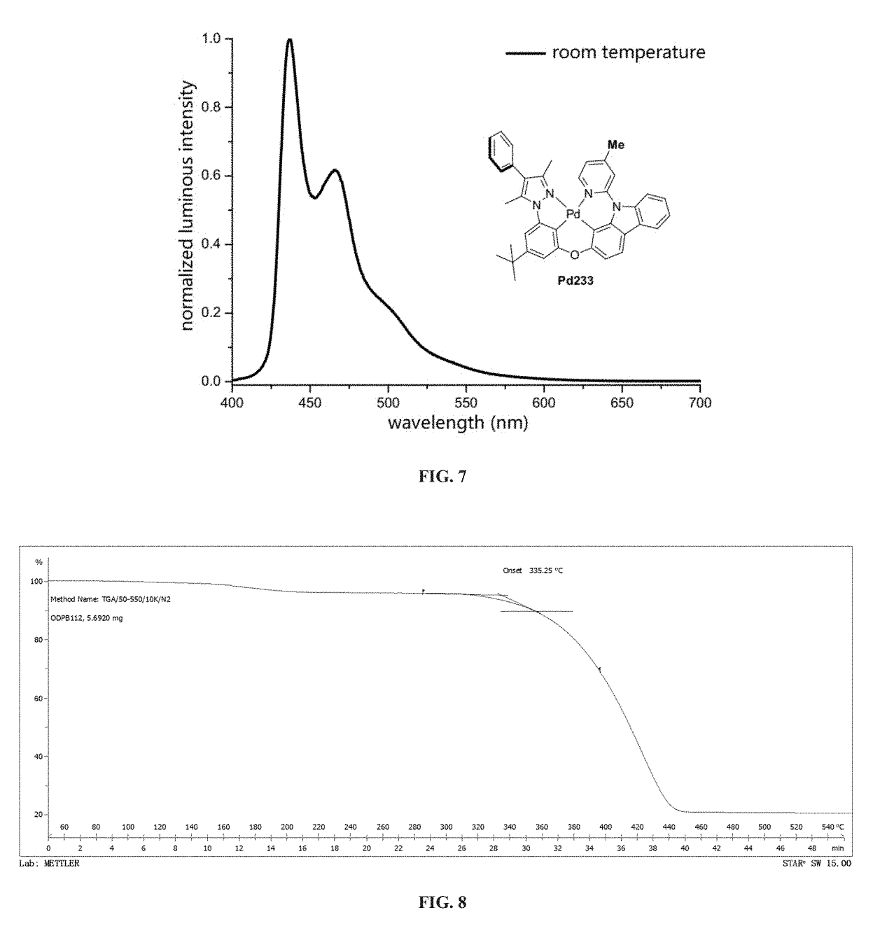

FIG. 7 shows the emission spectrum of the complex Pd233 in dichloromethane solution and at room temperature; FIG. 8 shows the original spectrum of thermogravimetric analysis (TGA) curve of the complex Pd233.

Performance Evaluation Examples

The photophysical, electrochemical and thermogravimetric analysis were conducted on the complexes prepared in the above examples of the present disclosure below:

Photophysical analysis: Phosphorescence emission spectrum and triplet lifetimes were all tested on a HORIBA FL 3-11 spectrometer. Test conditions: in emission spectrum at room temperature, all samples were dilute solutions of methylene chloride (chromatographic grade) (10⁻⁵-10⁻⁶ M), and the samples were all prepared in a glove box and pumped with nitrogen for 5 minutes; the triplet lifetime detection was measured at the strongest peak of the sample emission spectrum. All the quantum efficiencies were the absolute quantum efficiencies measured in an integrating sphere with a dilute solution of methylene chloride (chromatographic grade) (10⁻⁵-10⁻⁶ M) of the samples.

Electrochemical analysis: Cyclic voltammetry was used to test on a CH670E electrochemical workstation. 0.1 M solution of N,N-dimethylacetamide (DMF) solution of tetra-n-butylammonium hexafluorophosphate (ⁿBu₄NPF₆) was used as an electrolyte solution; a metal palladium electrode is a positive electrode; graphite is a negative electrode; metal silver was used as a reference electrode; ferrocene was an internal reference standard and a redox potential thereof was set to zero.

Thermogravimetric analysis: thermogravimetric analysis curves were all performed on TGA2 (SF) thermogravimetric analysis. Thermogravimetric analysis test conditions were: test temperature was 50-700° C.; heating rate was 20K/min; a crucible material was aluminum oxide; the test was accomplished under nitrogen atmosphere; and a sample quality was generally 2-5 mg.

TABLE 1
Photophysical, electrochemical and thermogravimetric analysis of luminescent
materials of the metal complexes

| Pd complex | peak/nm | τ/μs | PLQE/% | CIE | Eₒₓ (V) | E_{red} (V) | Td/° C. |
|---|---|---|---|---|---|---|---|
| Pd1 | 435.9 | 46 | 7 | (0.145, 0.069) | 0.61 | −2.74 | 361 |
| Pd113 | 436.4 | 49 | 9 | (0.144, 0.072) | 0.66 | −2.74 | 354 |
| Pd229 | 437.0 | 58 | 7 | (0.152, 0.097) | — | — | 357 |
| Pd233 | 436.8 | 58 | 10 | (0.142, 0.078) | — | — | 335 |

From the data in Table 1, it can be seen that the palladium metal complexes provided in the specific embodiments of the present disclosure are all deep blue phosphorescent luminescent materials, and the maximum emission peak thereof is 436.0-436.4 nm; the triplet lifetime of the solution is in a microsecond (10⁻⁵ second) level; all the complexes have strong phosphorescent emission; what is more important is that all the thermal decomposition temperatures are above 340° C., which is much higher than the thermal vaporization temperature of the material during the device fabrication (generally not higher than 300° C.); and CIE_{y} is less than 0.1. Therefore, such phosphorescent materials have great application prospects in the field of blue light, especially deep blue phosphorescent materials, and are of great significance for the development and application of deep blue phosphorescent materials.

Those of ordinary skills in the art can understand that the above embodiments are specific embodiments for implementing the disclosure, and in practical applications, various changes in form and detail can be made without departing from the spirit and scope of the disclosure.

What is claimed is:

1. A tetradentate cyclopalladated palladium complex comprising trisubstituted pyrazole, wherein a structure of the complex is as shown in (I): 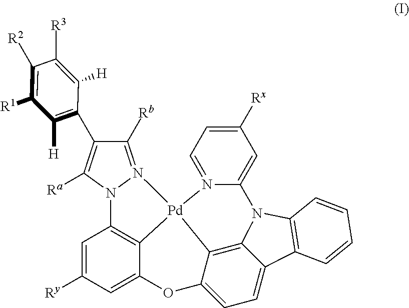
wherein,
R^{a} and R^{b} each are alkyl, alkoxy, cycloalkyl, ether, heterocyclyl, hydroxy, aryl, heteroaryl, aryloxy, monoalkylamino or dialkylamino, monoarylamino or diarylamino, halogen, sulfydryl, cyano, independently, or combination thereof;
R^{x} is alkyl, alkoxy, cycloalkyl, heterocyclyl, ether, monoalkylamino or dialkylamino, monoarylamino or diarylamino, halogen, or combination thereof;
R^{x} is hydrogen, deuterium, alkyl, alkoxy, cycloalkyl, heterocyclyl, ether, monoalkylamino or dialkylamino, monoarylamino or diarylamino, halogen or combination thereof; and
R¹, R² and R³ each are hydrogen, deuterium, alkyl, alkoxy, ether, cycloalkyl, heterocyclyl, hydroxy, aryl, heteroaryl, aryloxy, monoalkylamino or dialkylamino, monoarylamino or diarylamino, halogen, sulfydryl, haloalkyl, independently, or combination thereof.

2. The tetradentate cyclopalladated palladium complex comprising trisubstituted pyrazole according to claim 1, wherein the 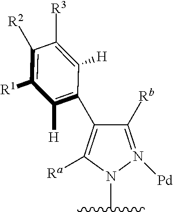
has a structure selected from one of the following structures:

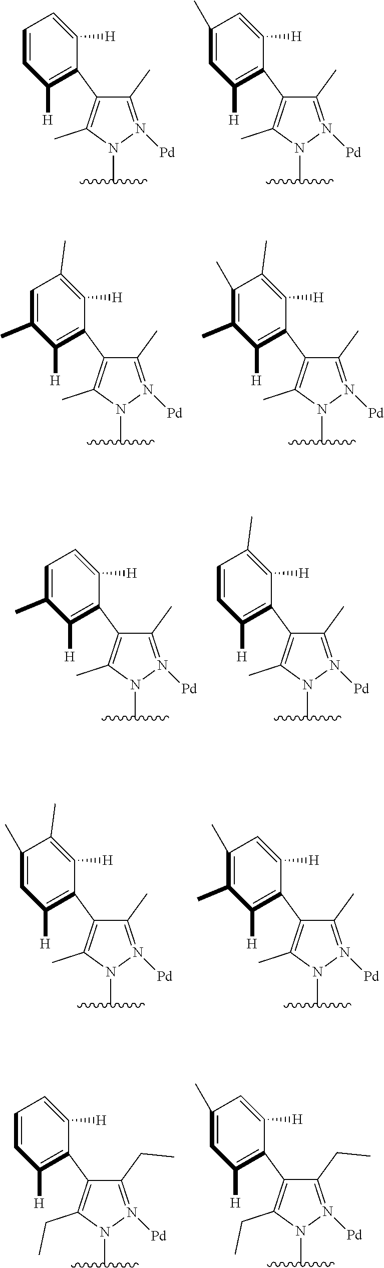

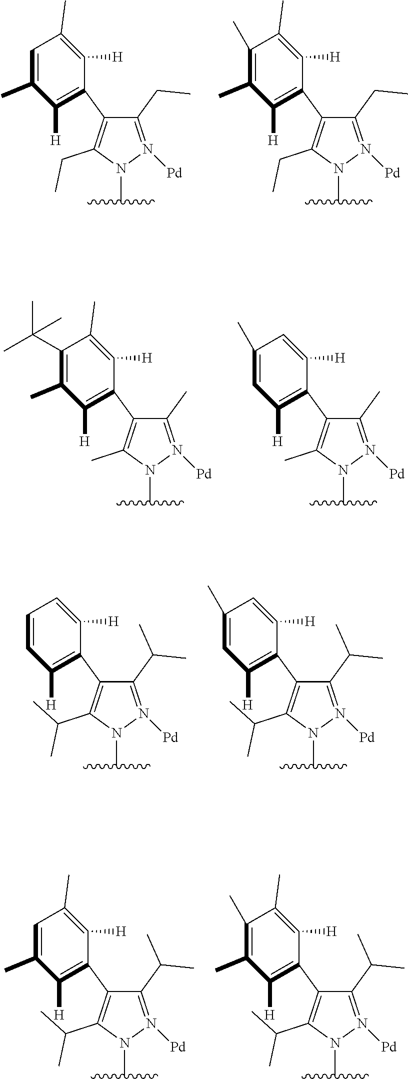

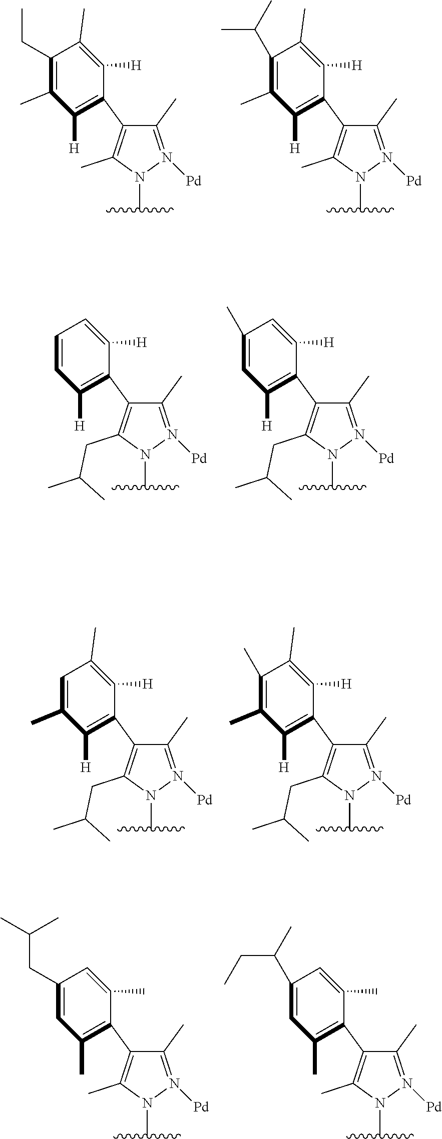

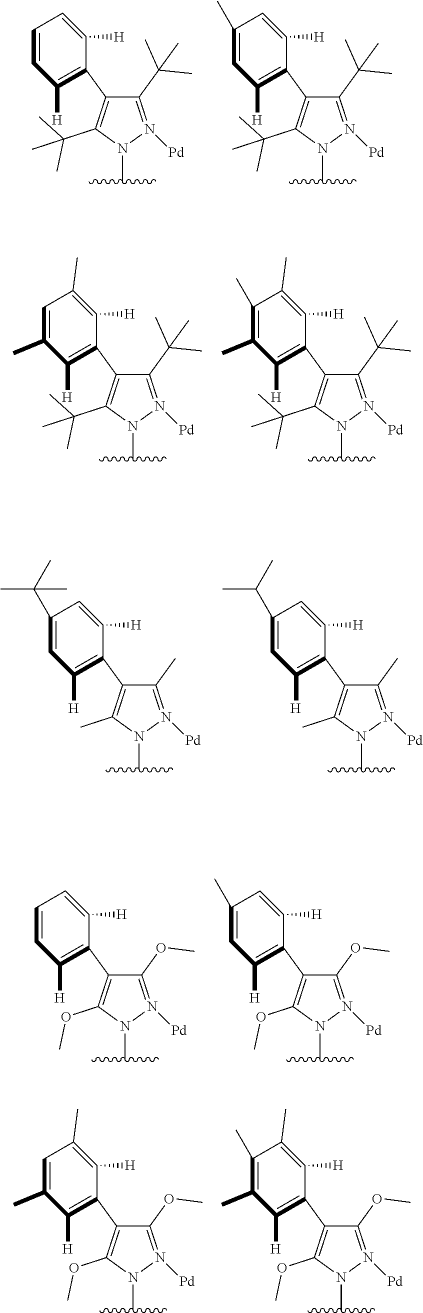

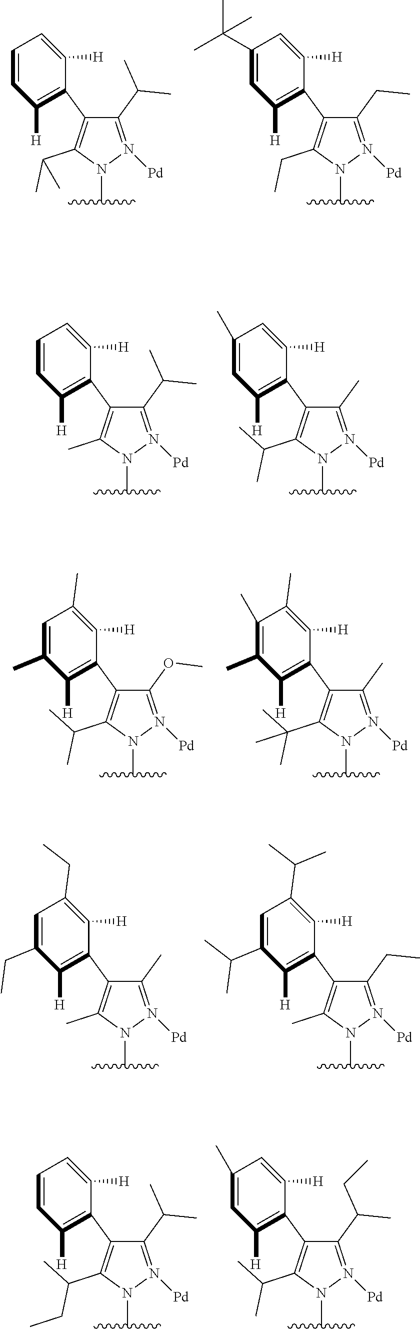

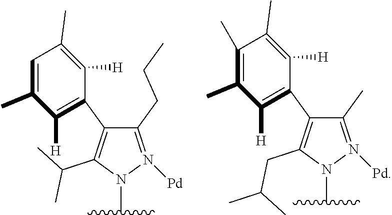

3. The tetradentate cyclopalladated palladium complex comprising trisubstituted pyrazole according to claim 1, wherein the complex has a structure selected from one of the following:

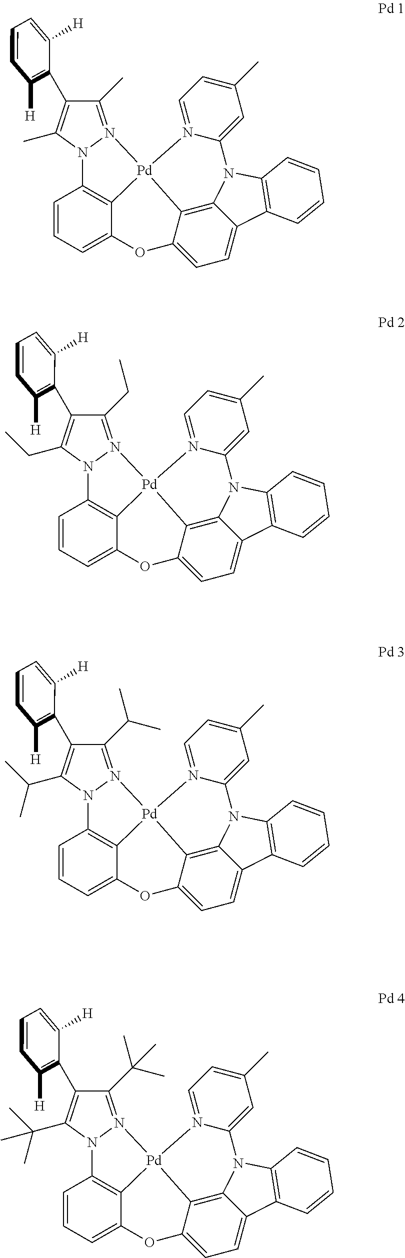

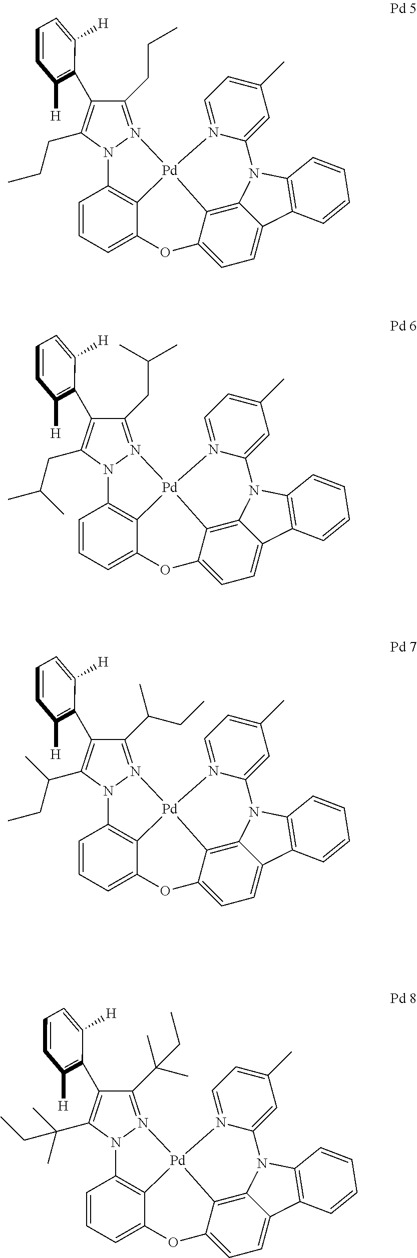

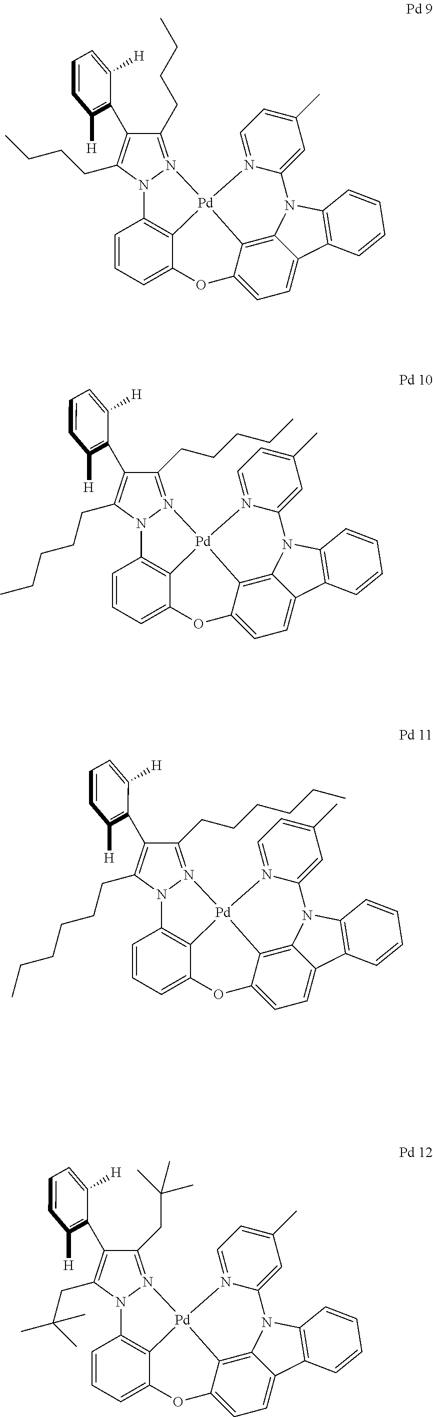

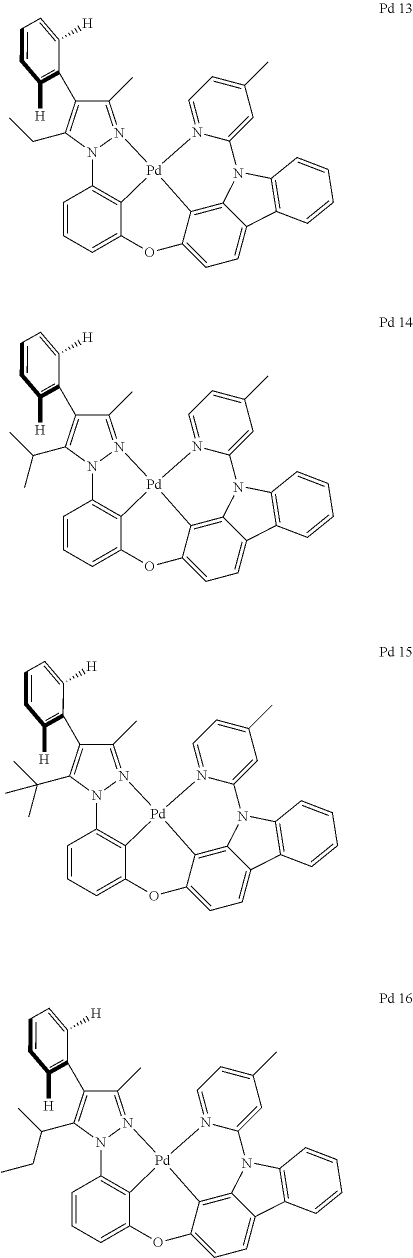

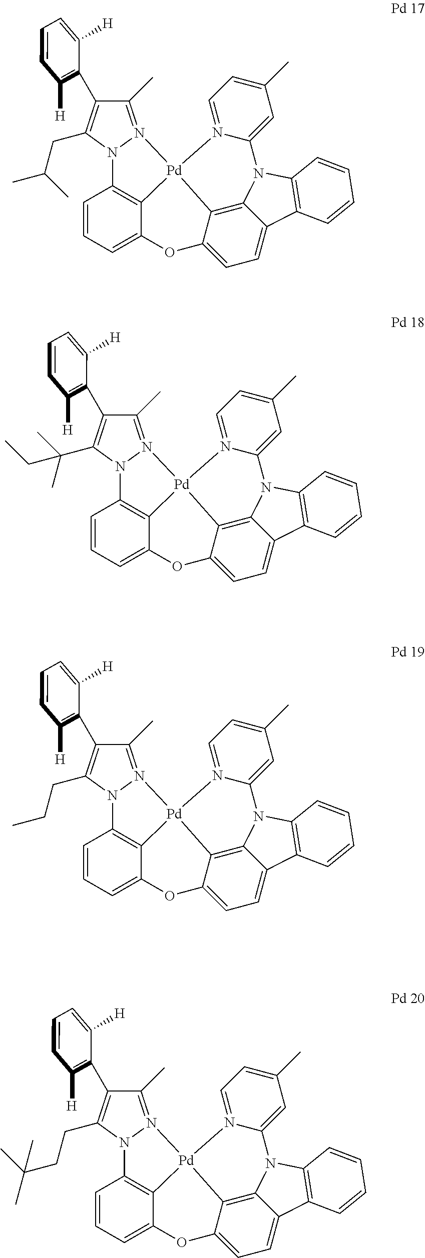

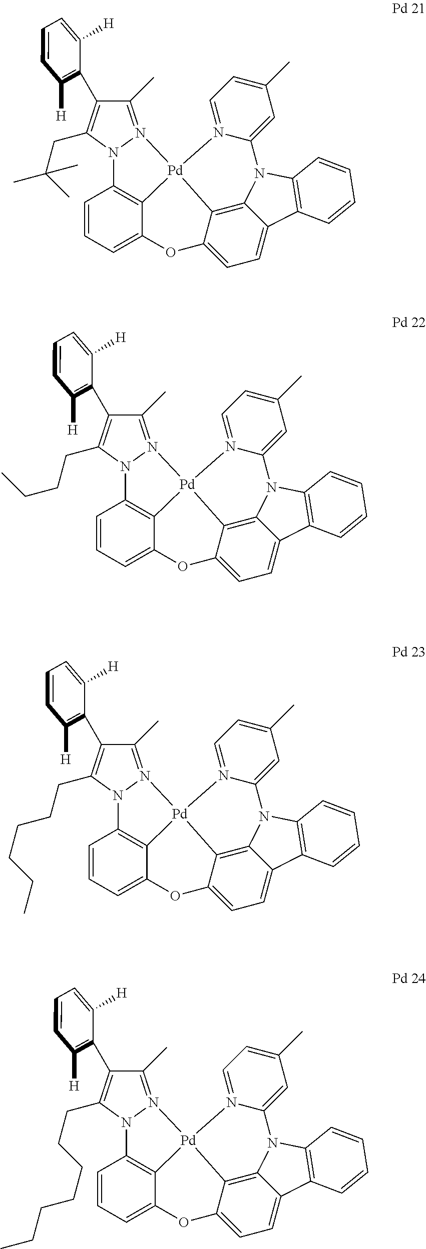

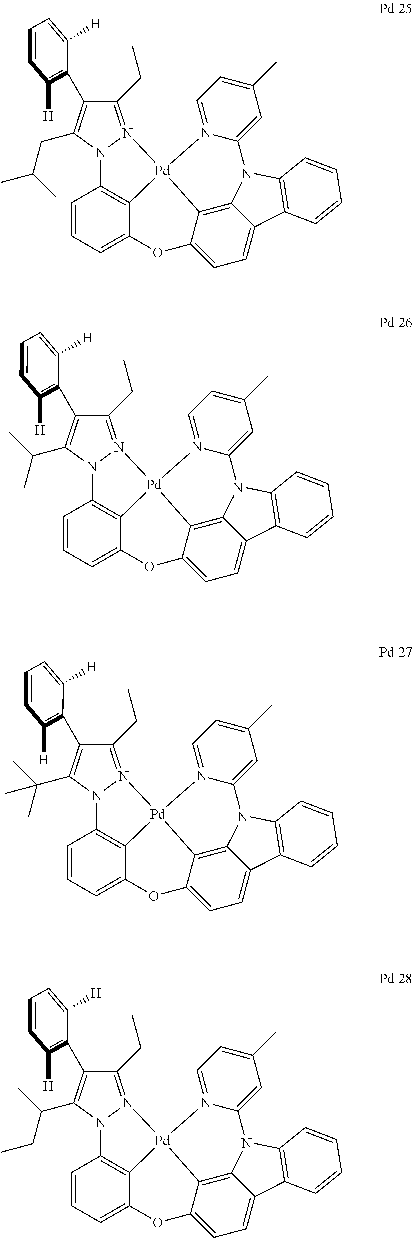

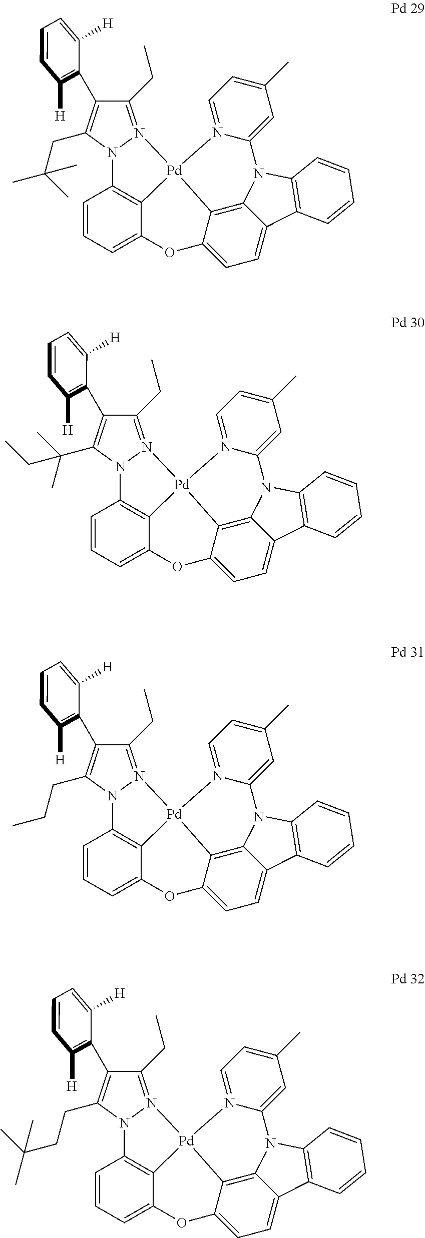

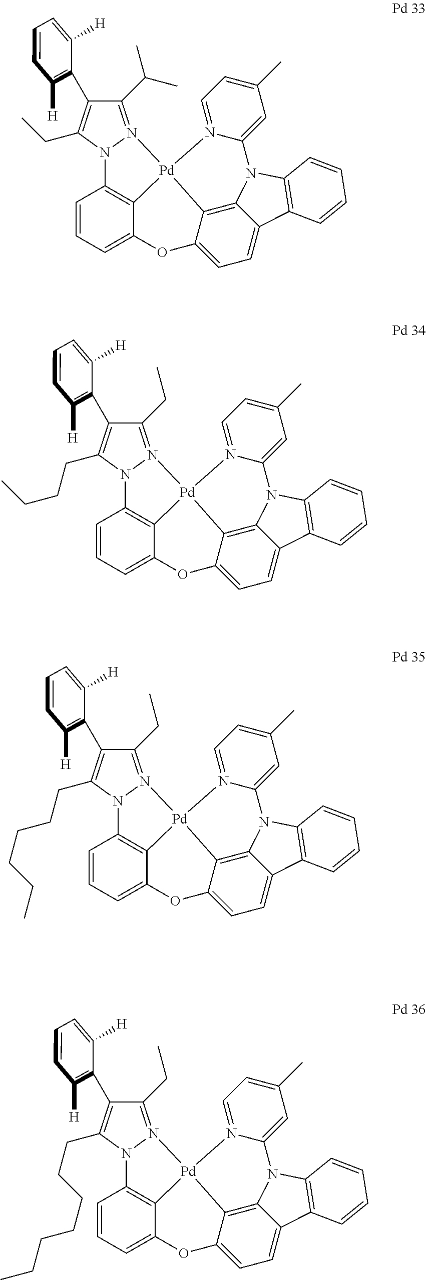

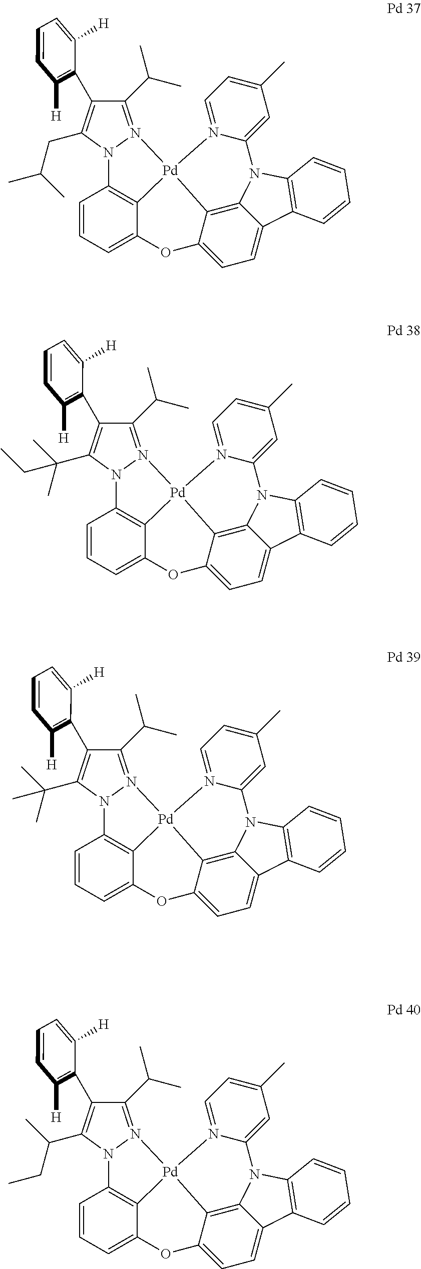

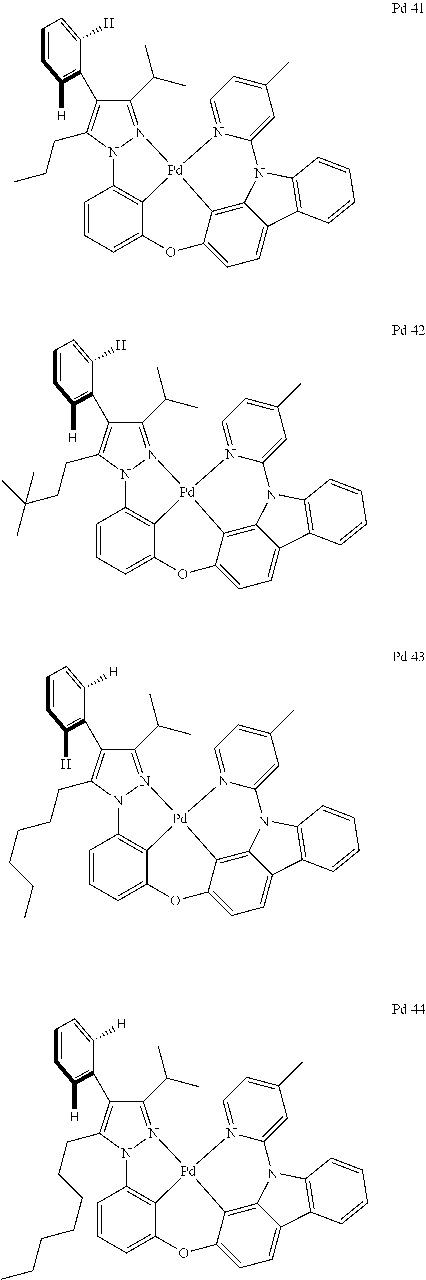

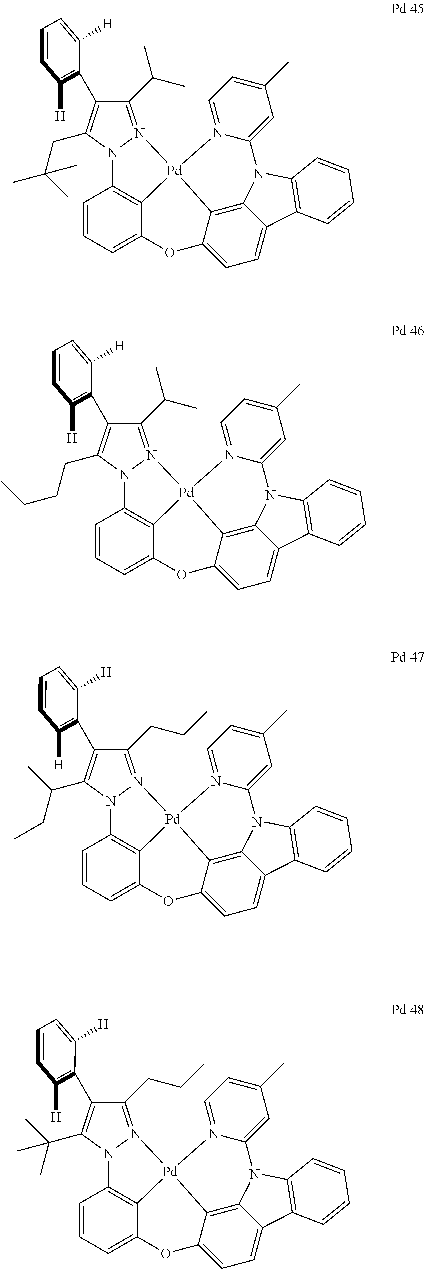

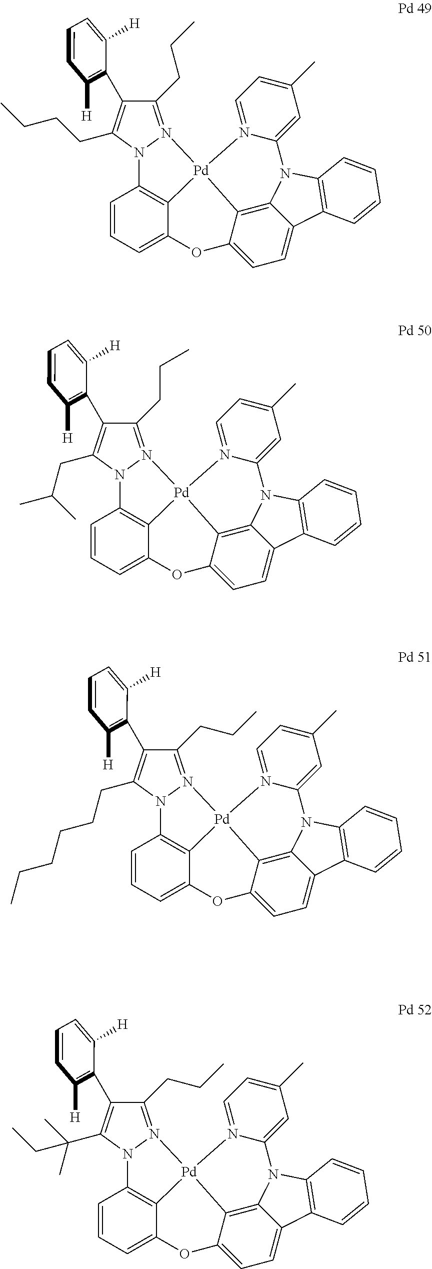

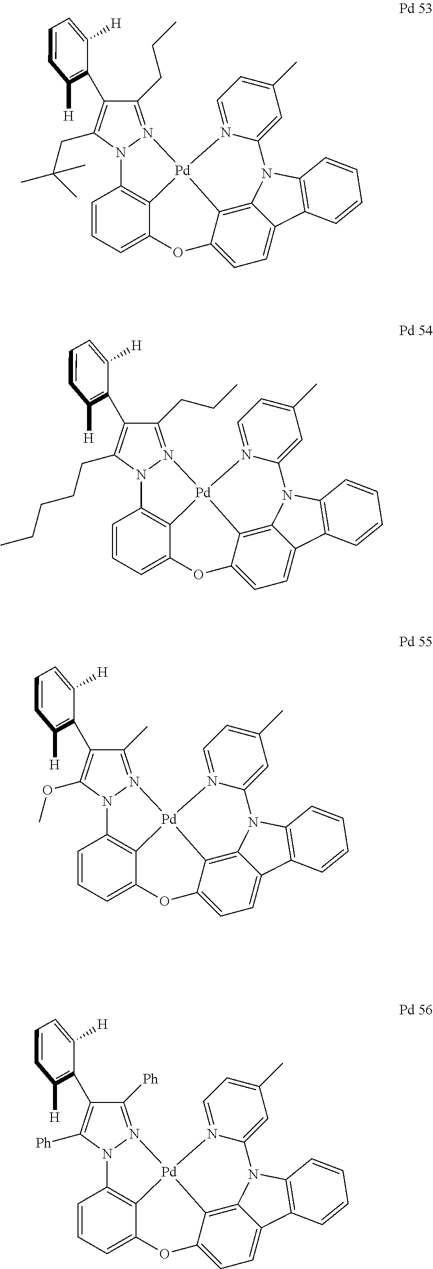

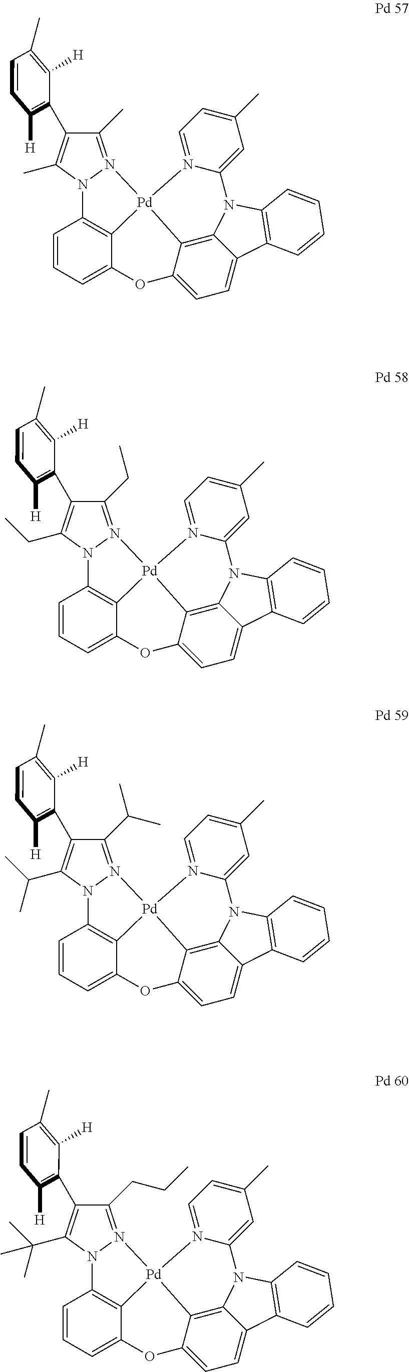

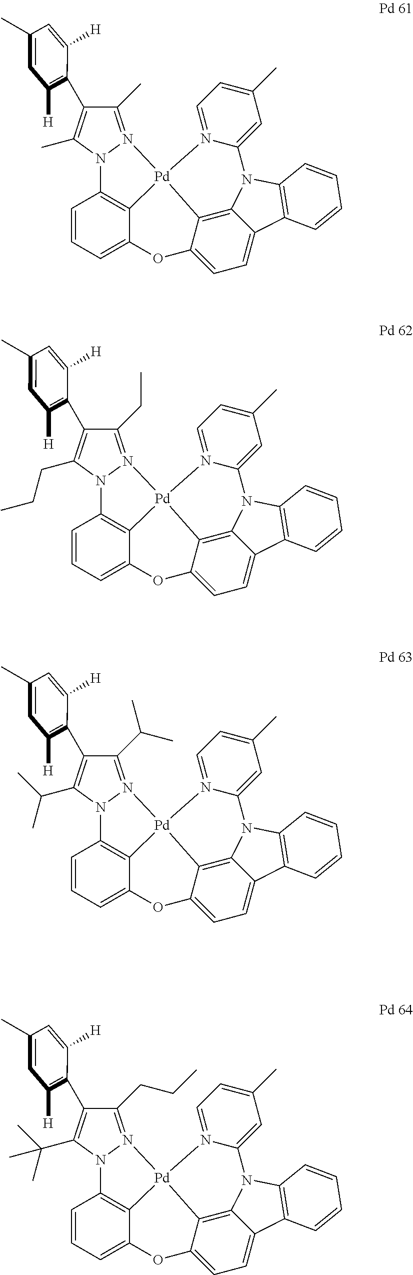

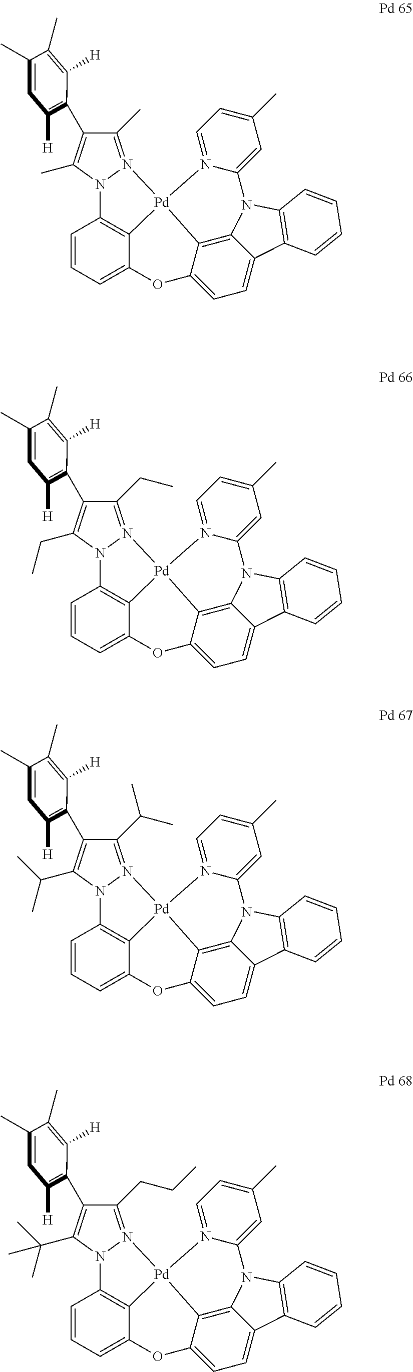

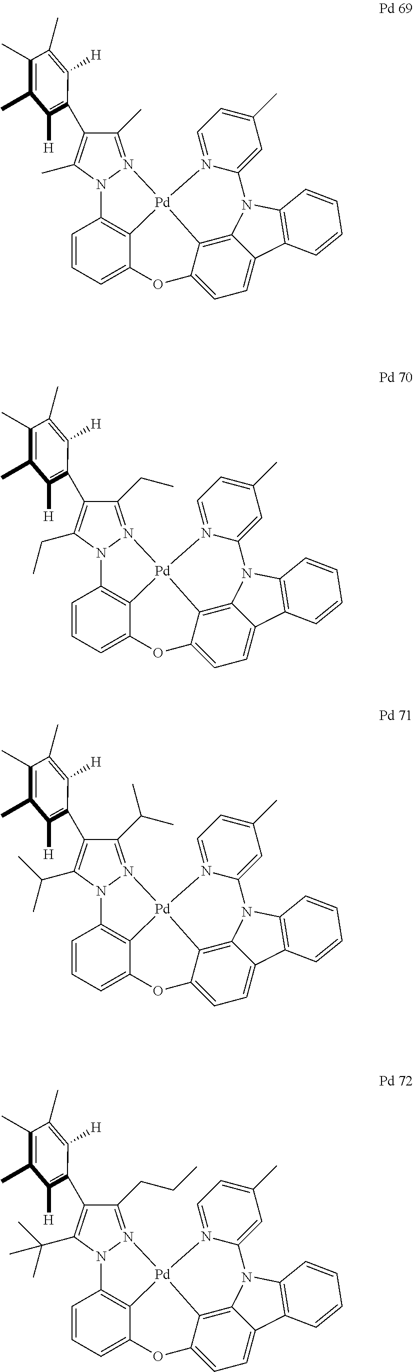

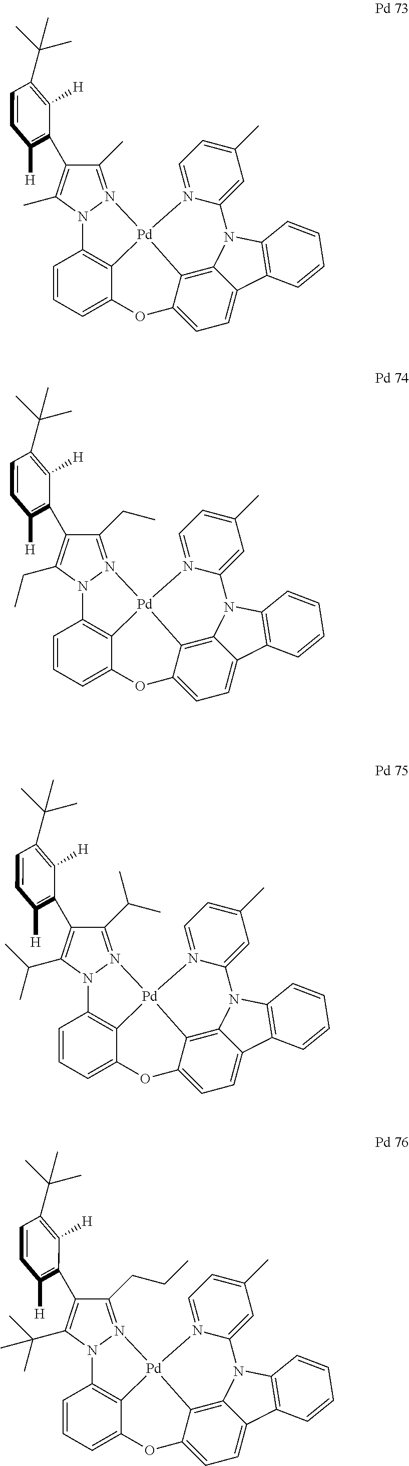

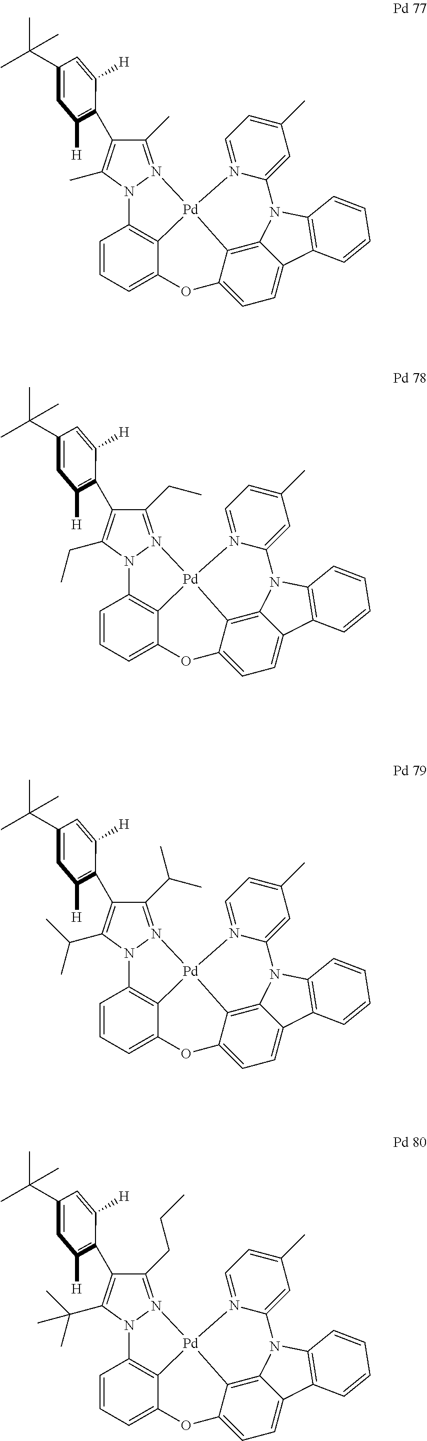

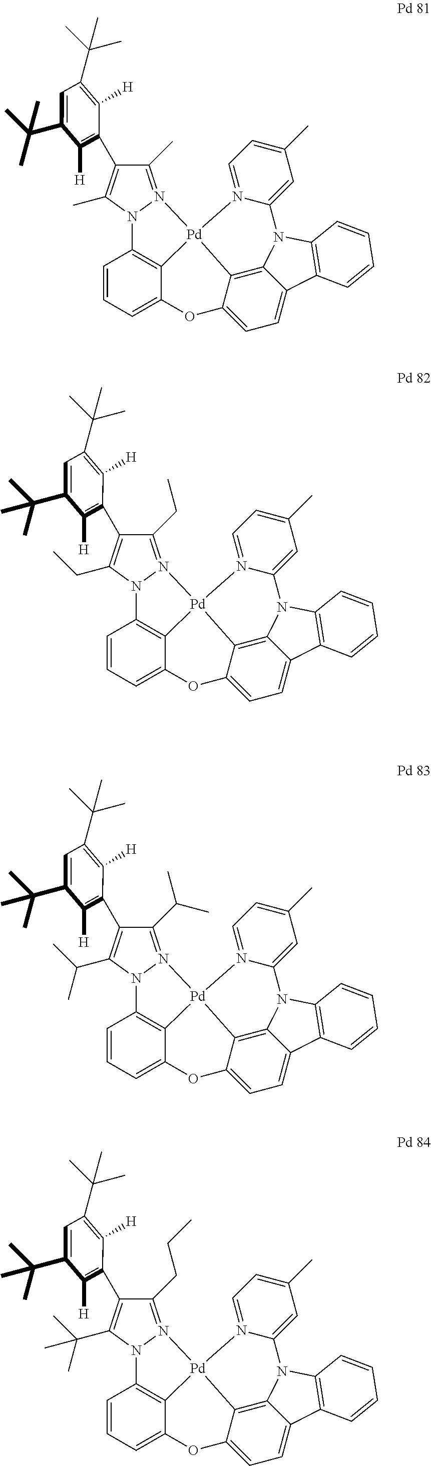

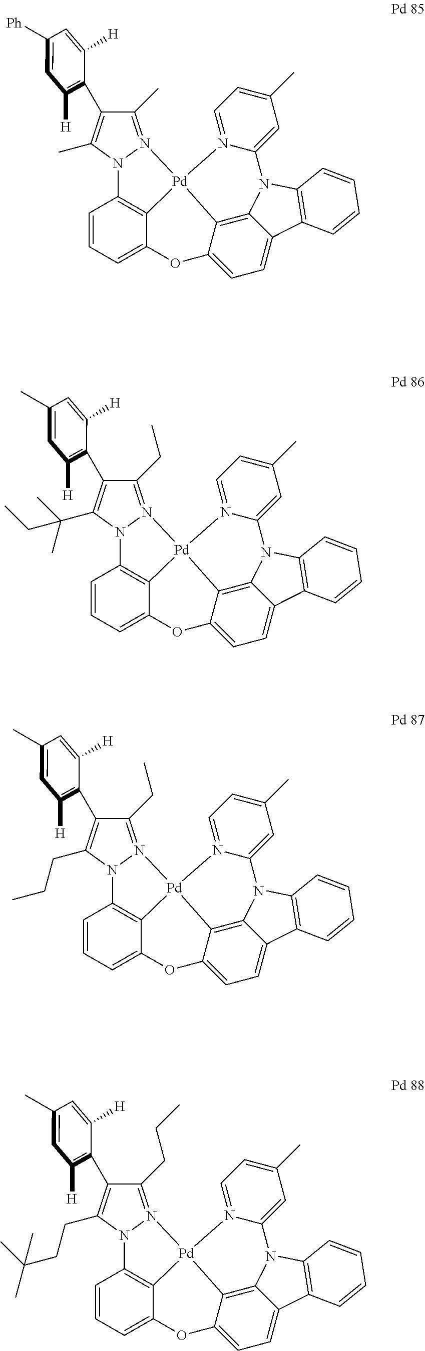

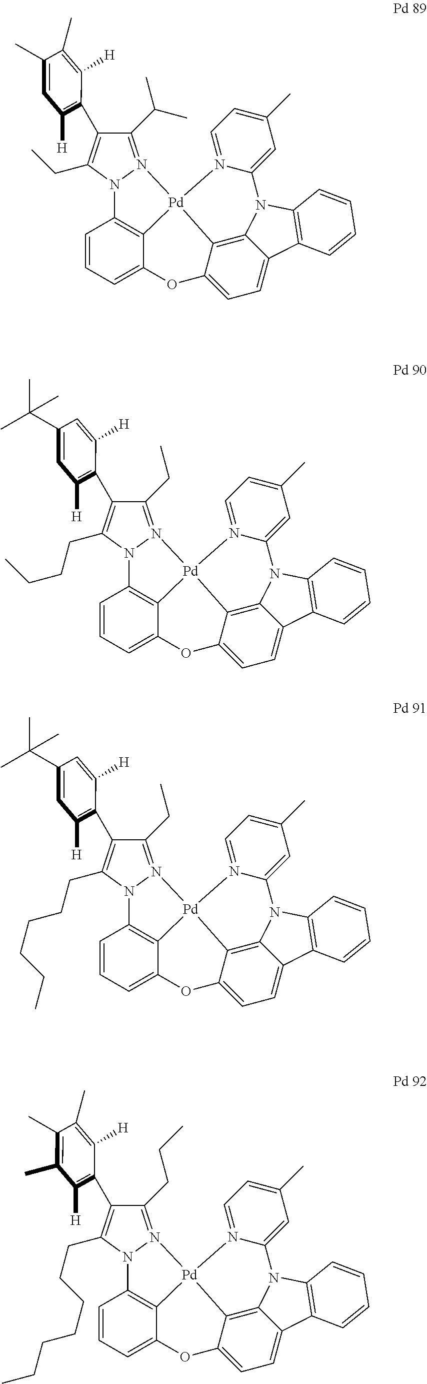

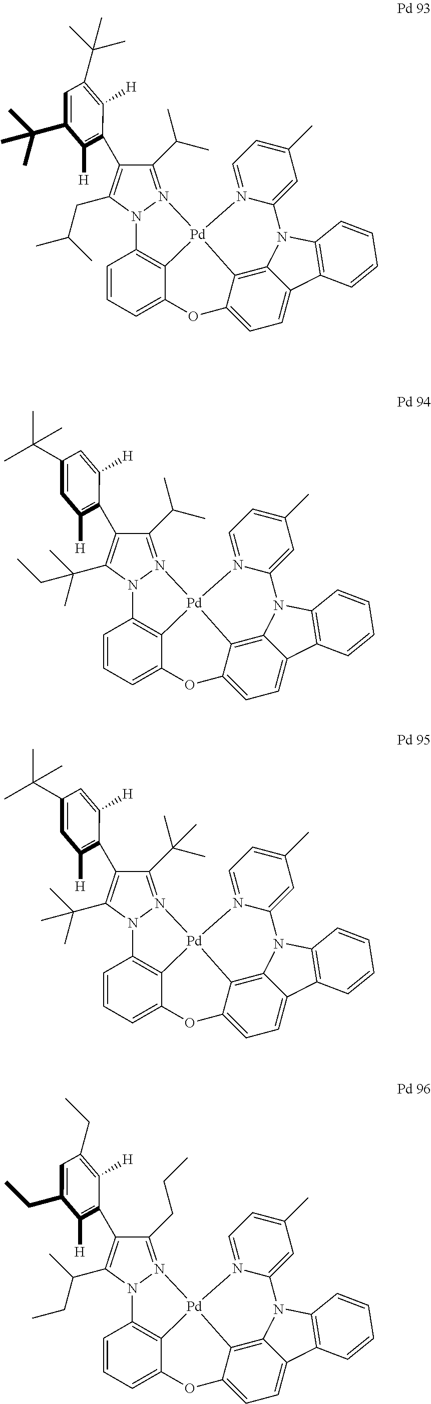

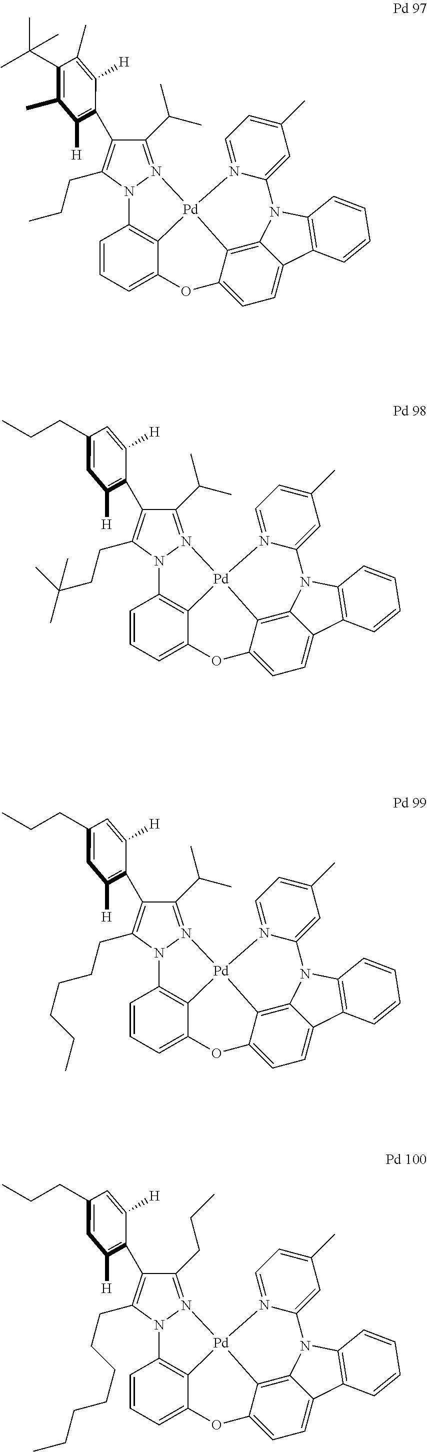

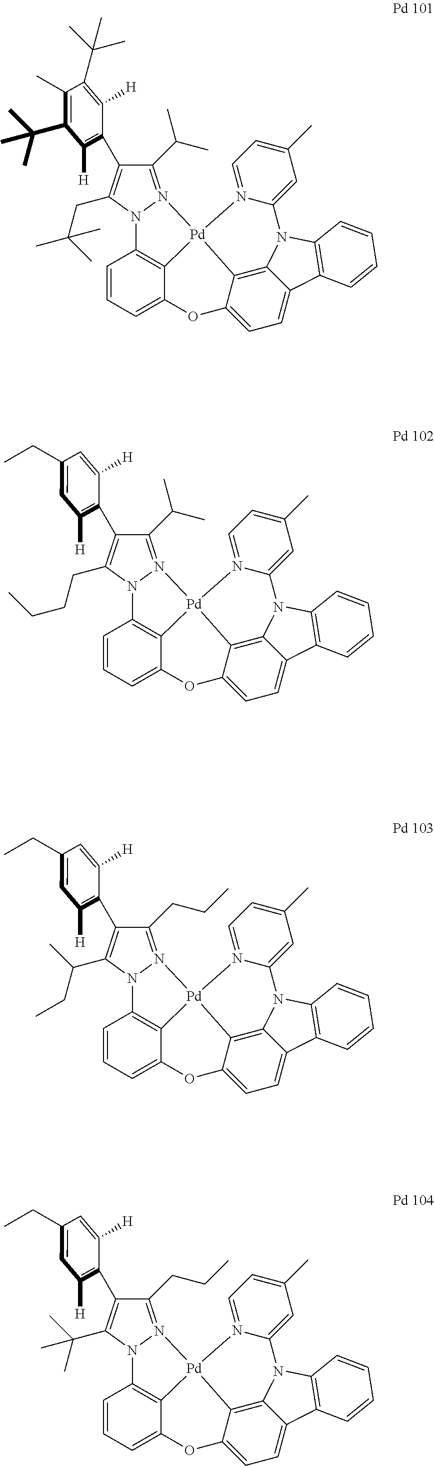

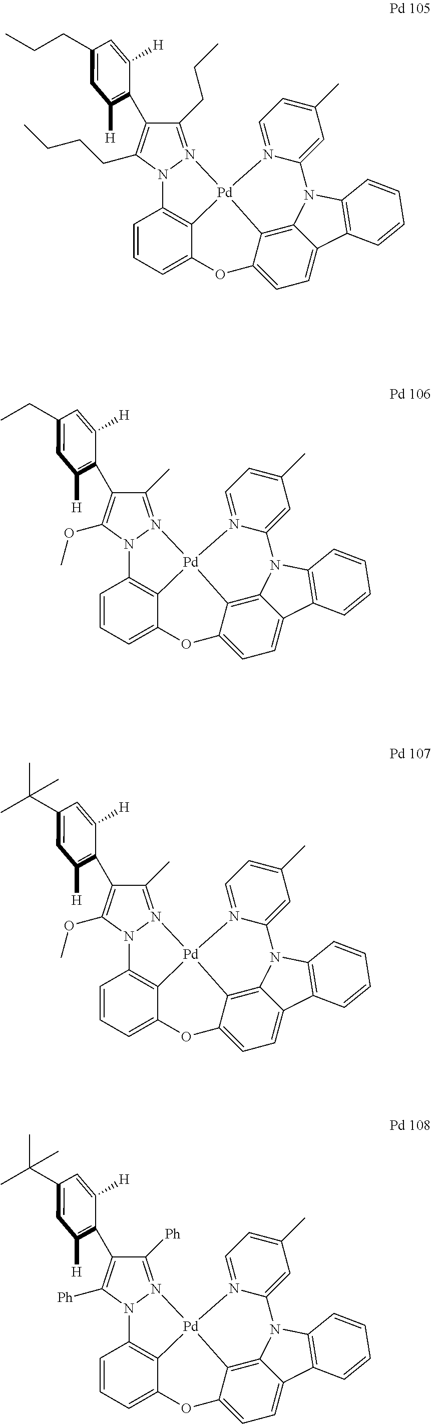

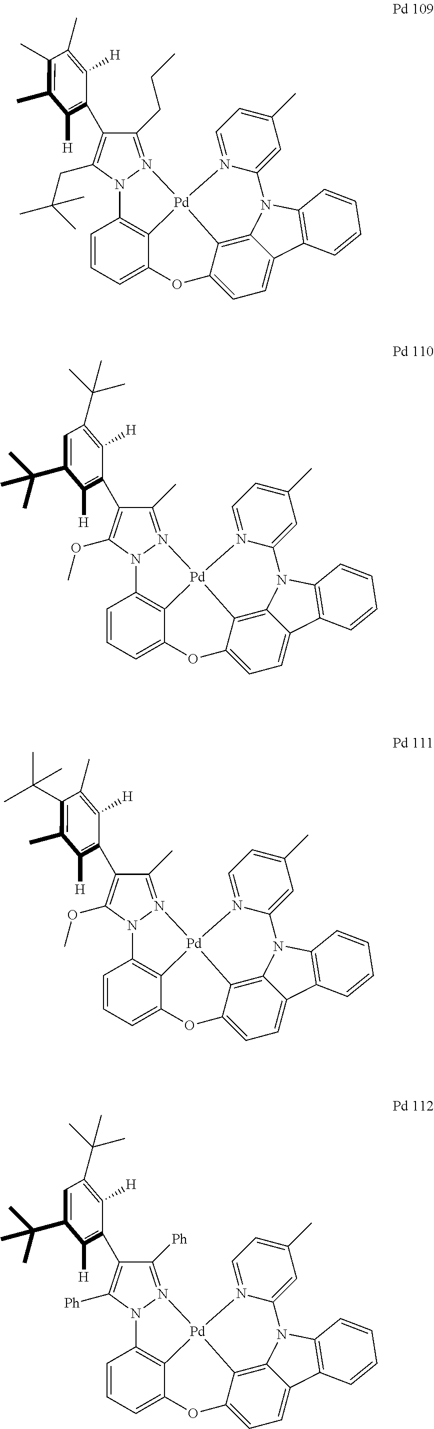

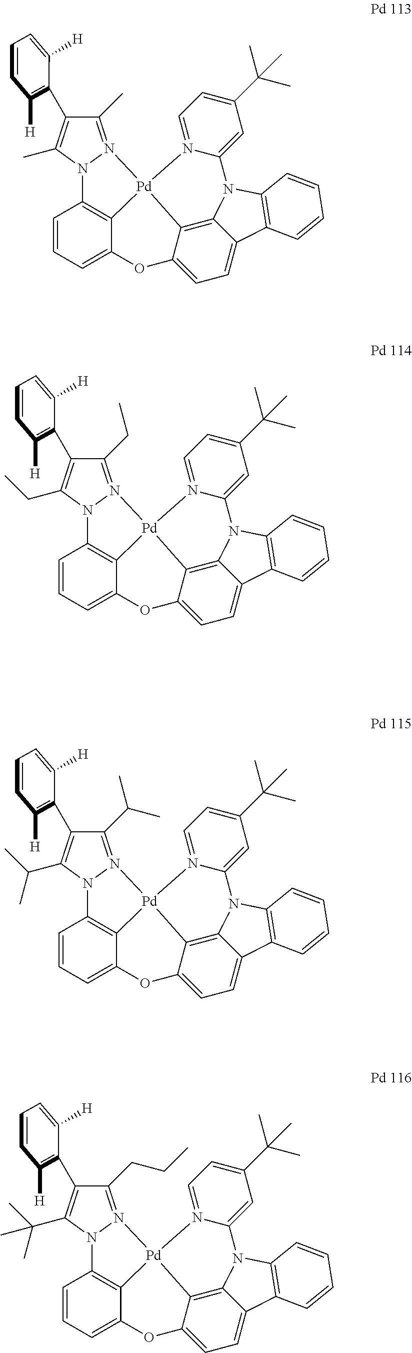

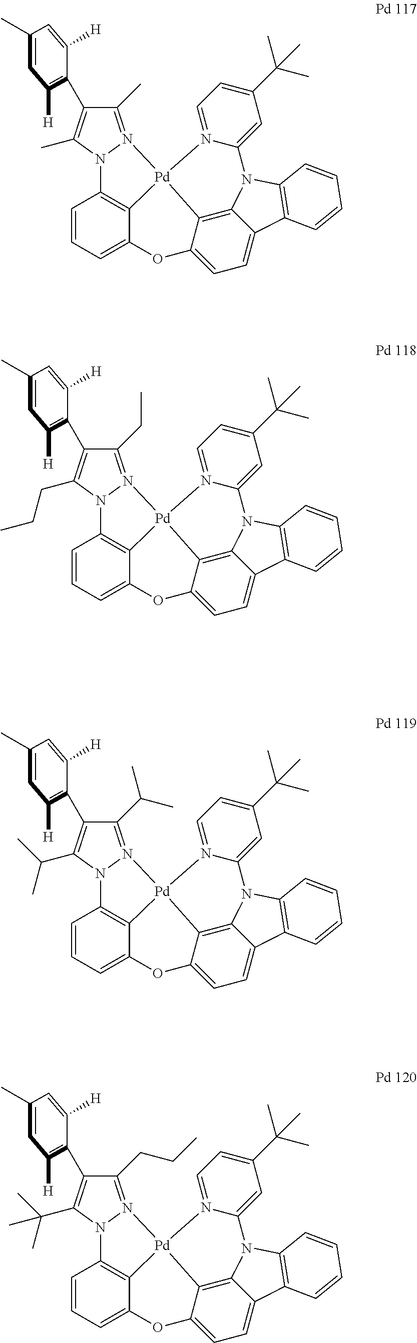

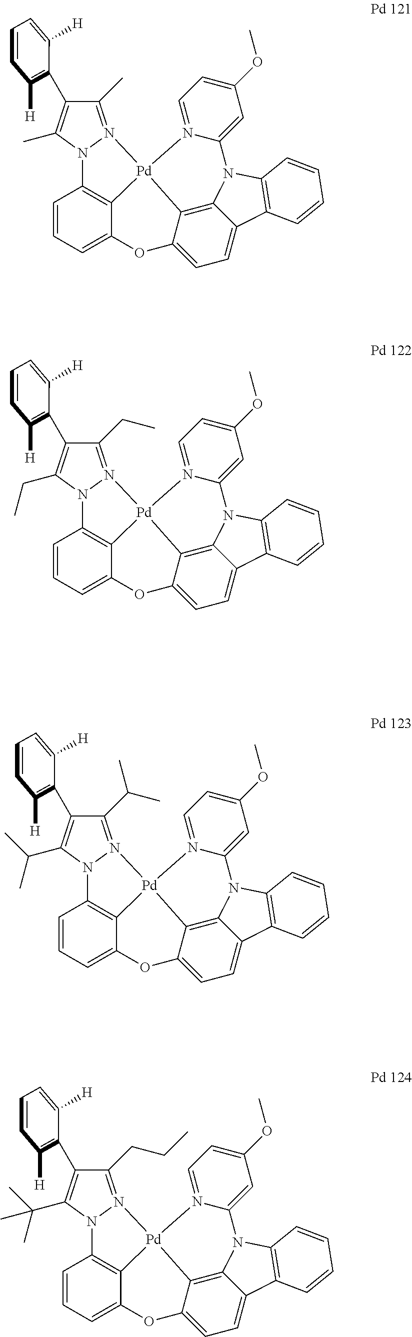

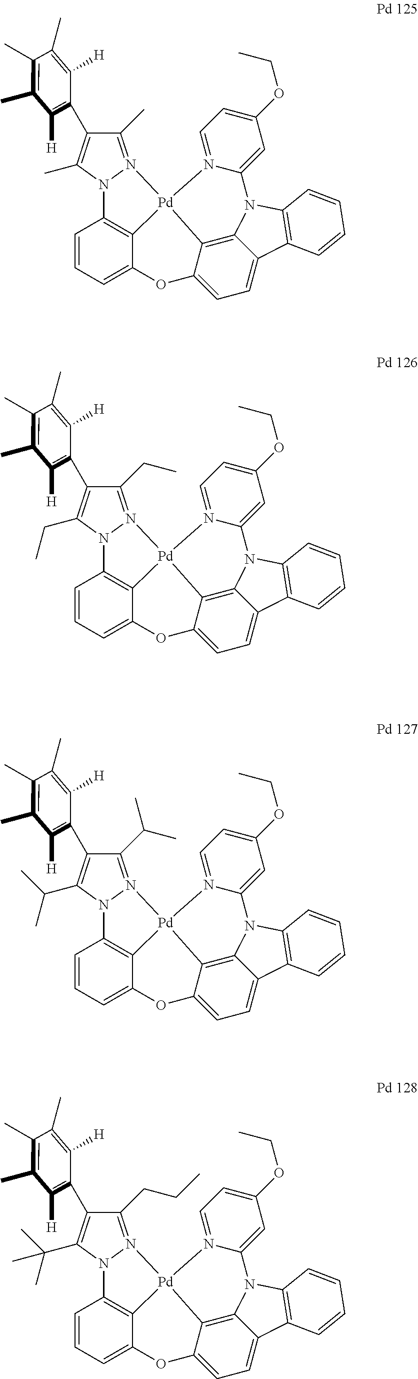

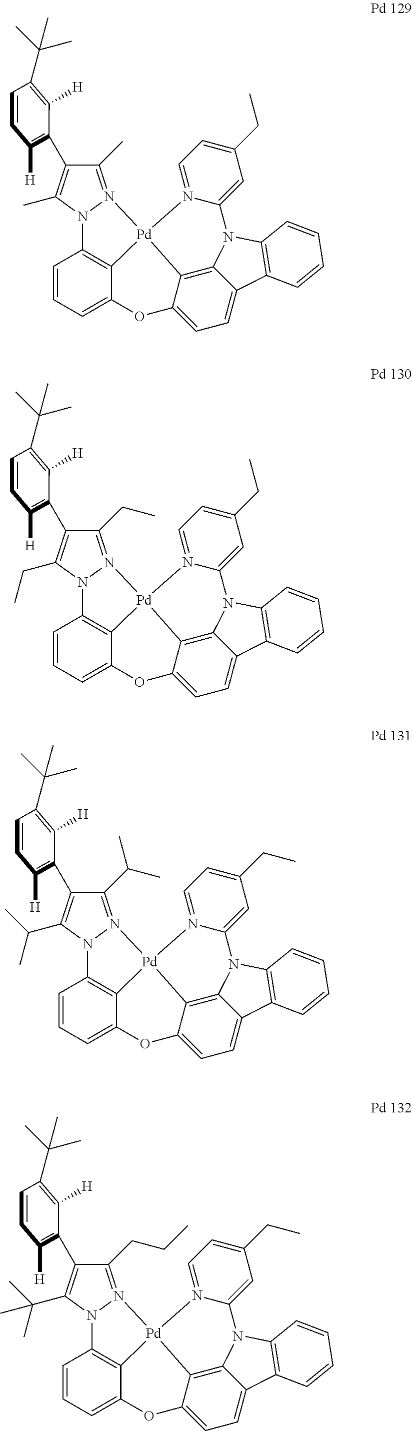

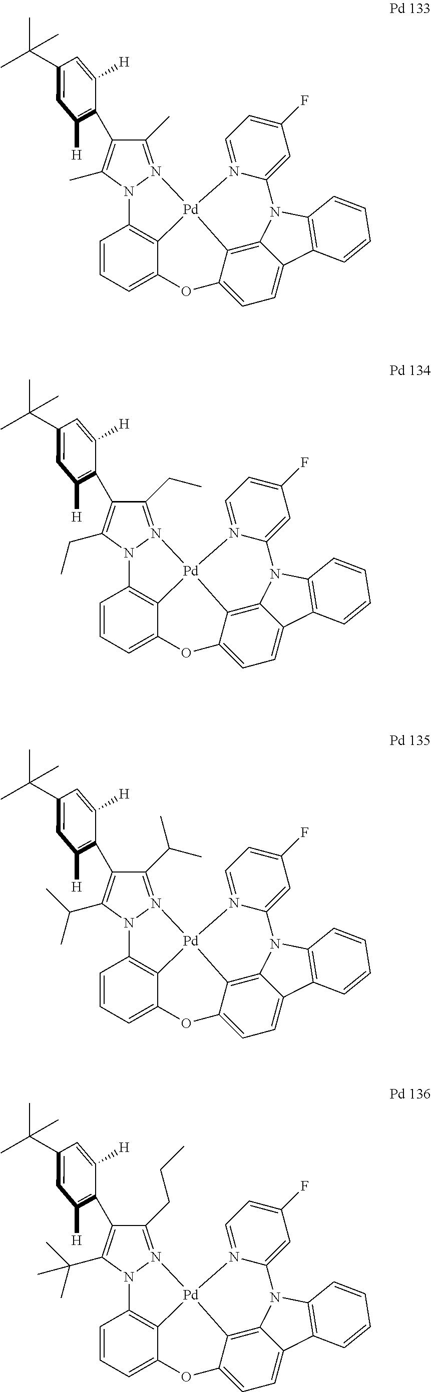

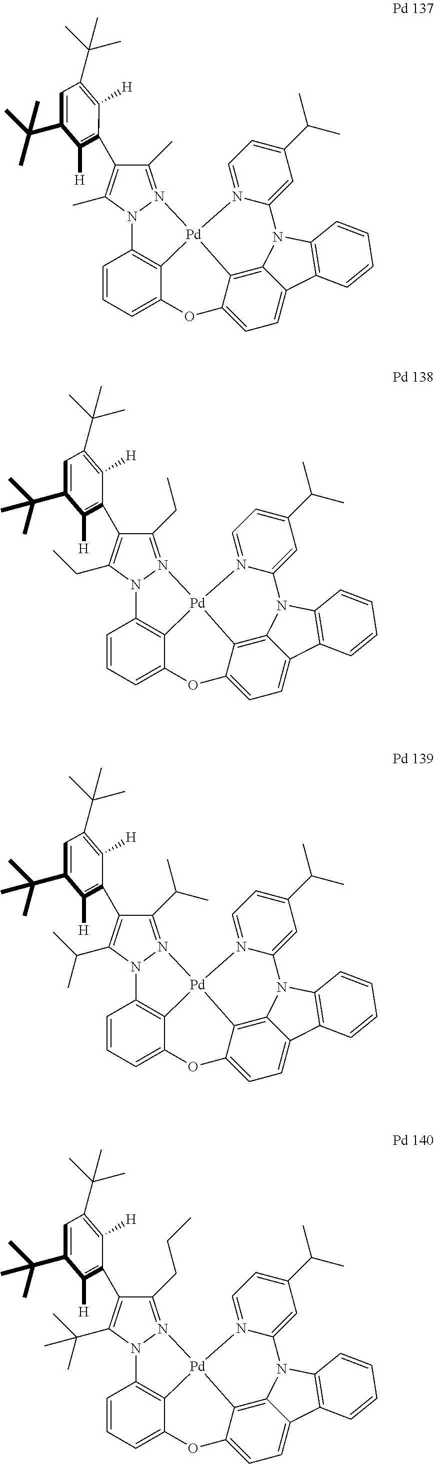

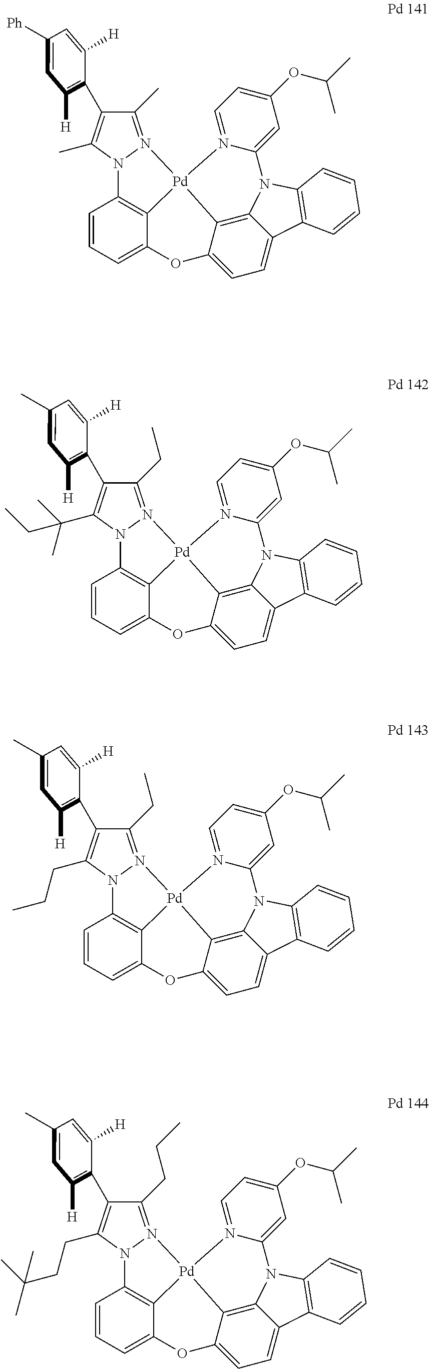

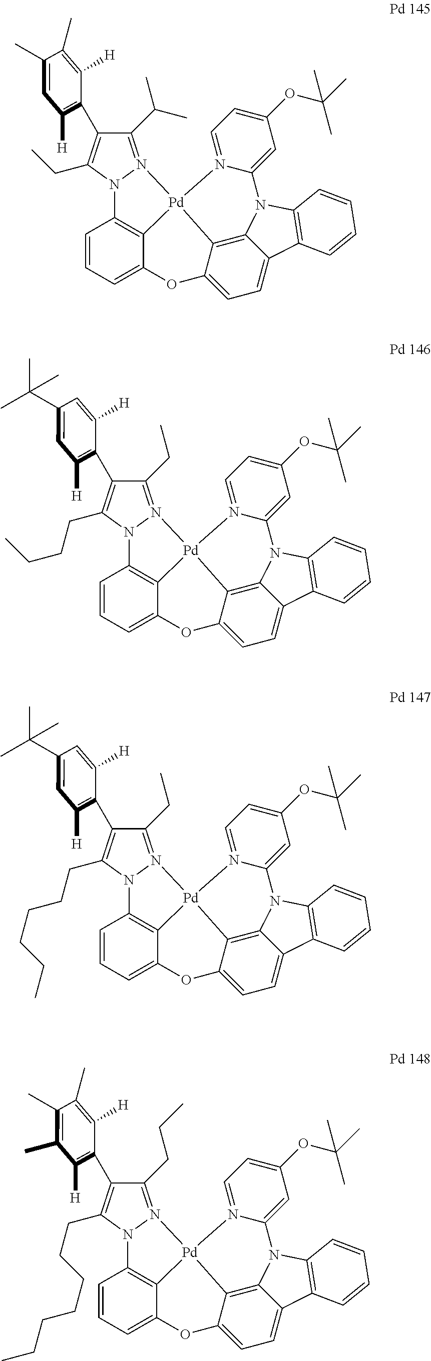

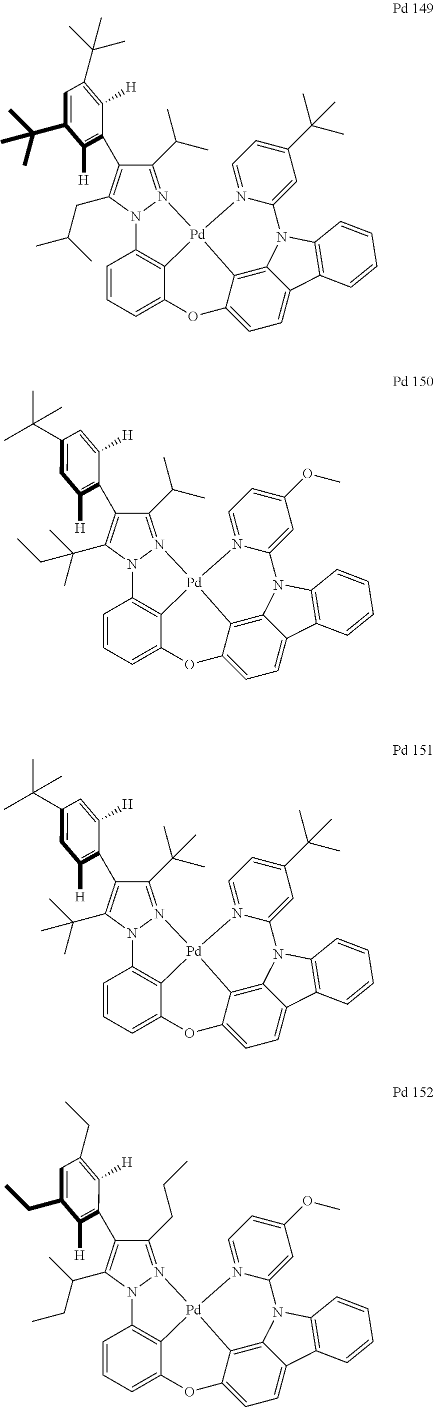

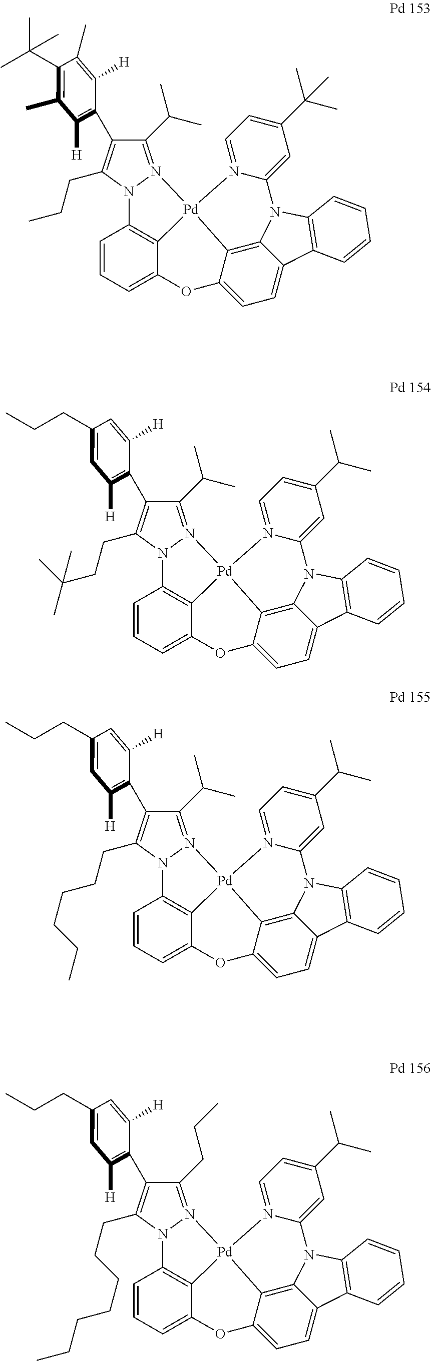

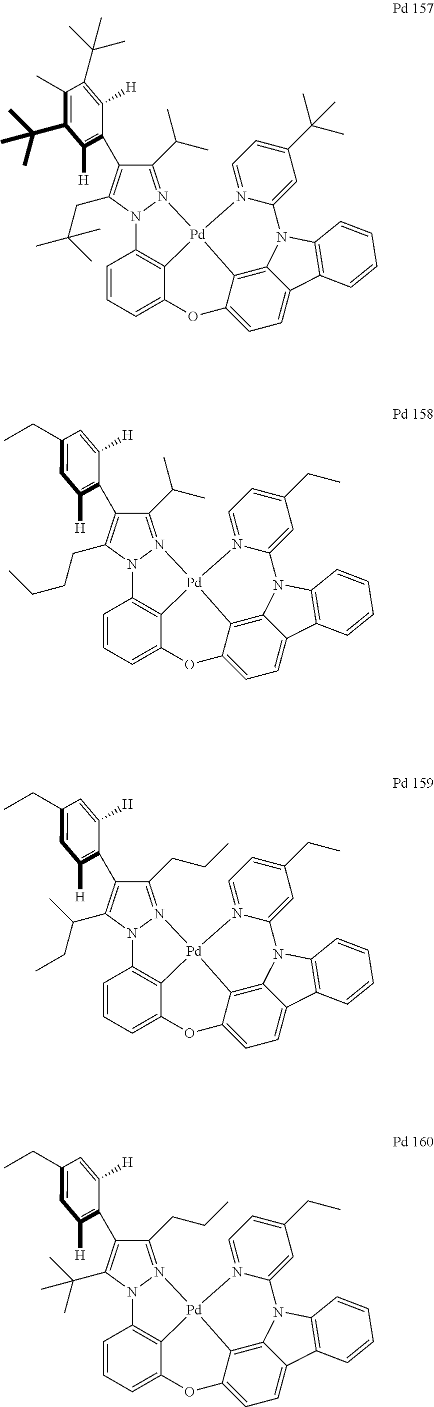

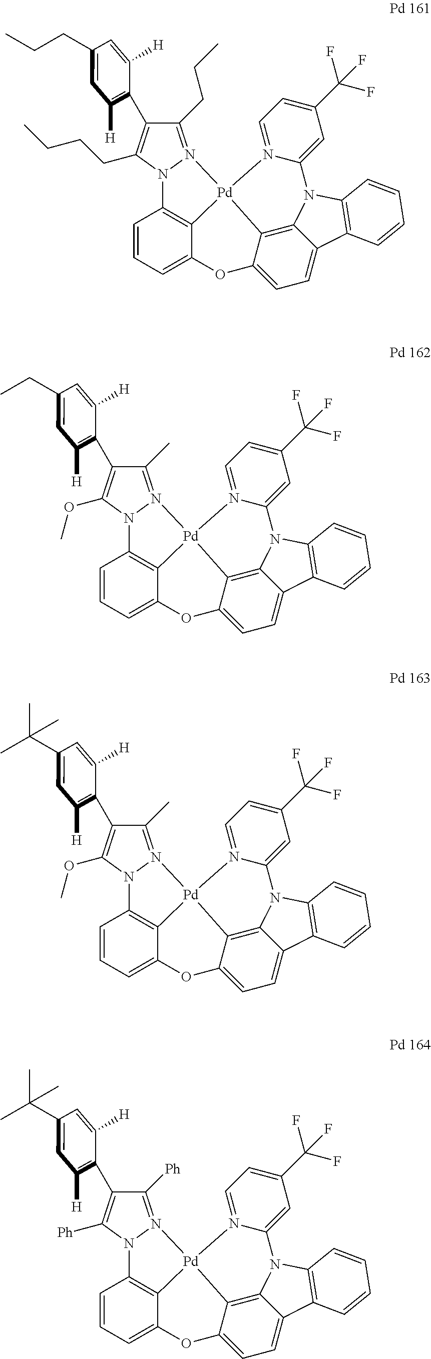

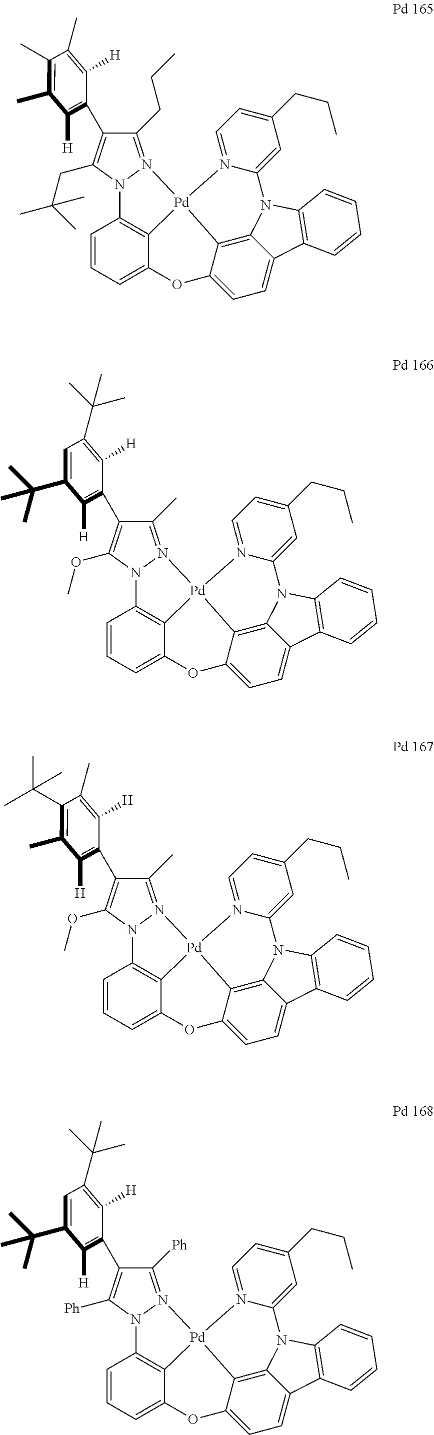

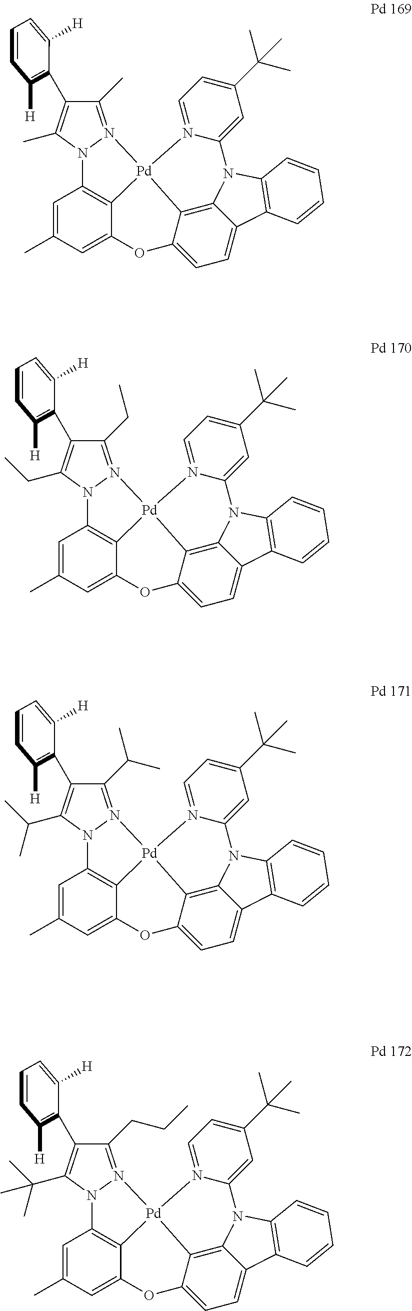

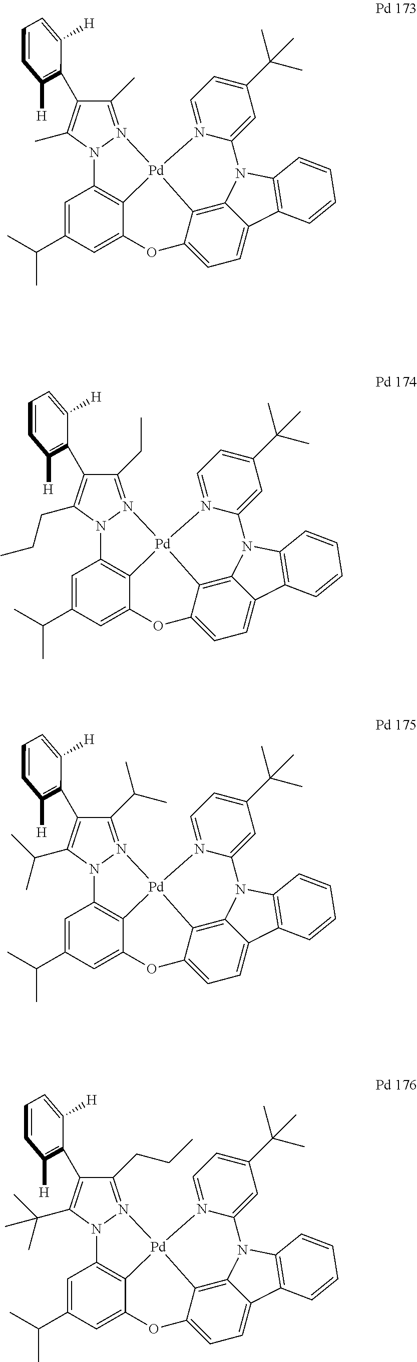

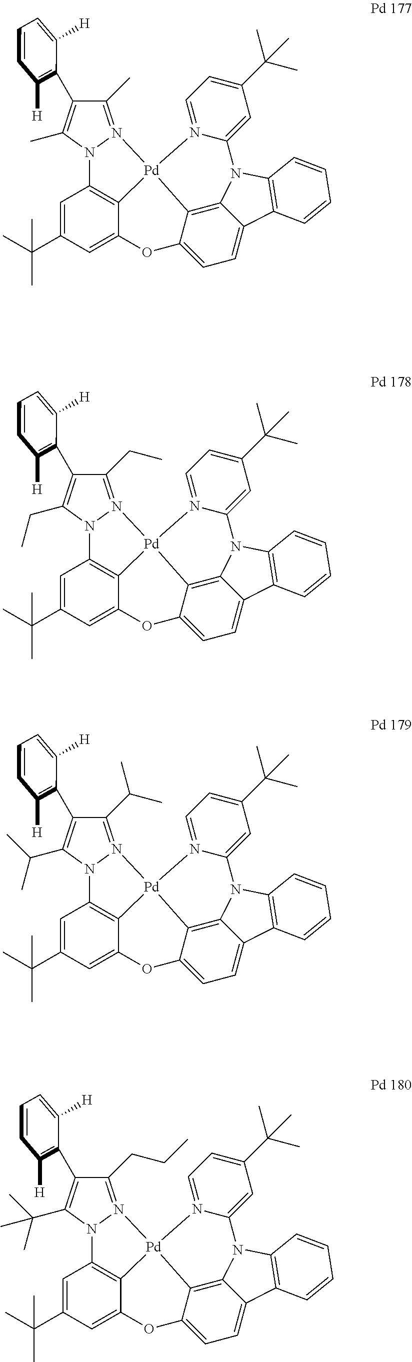

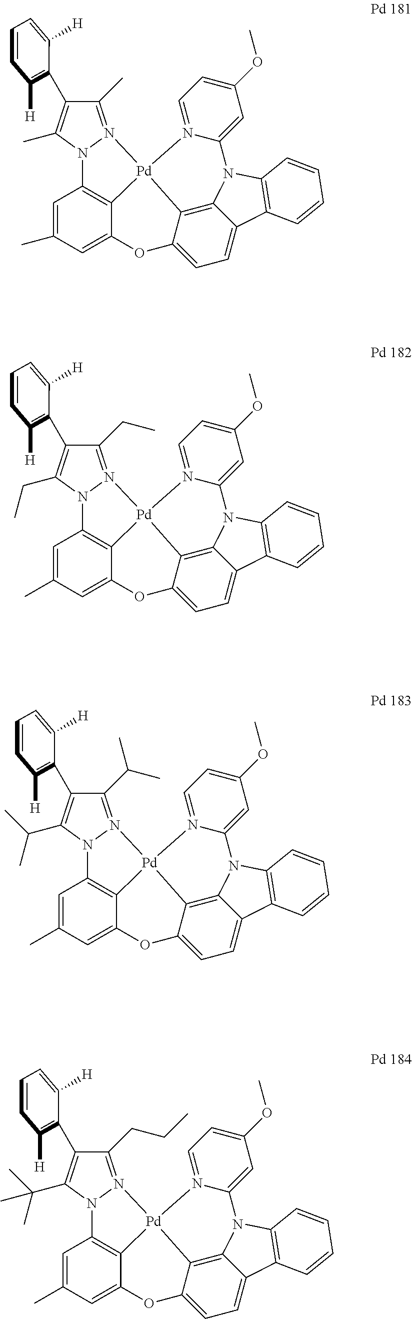

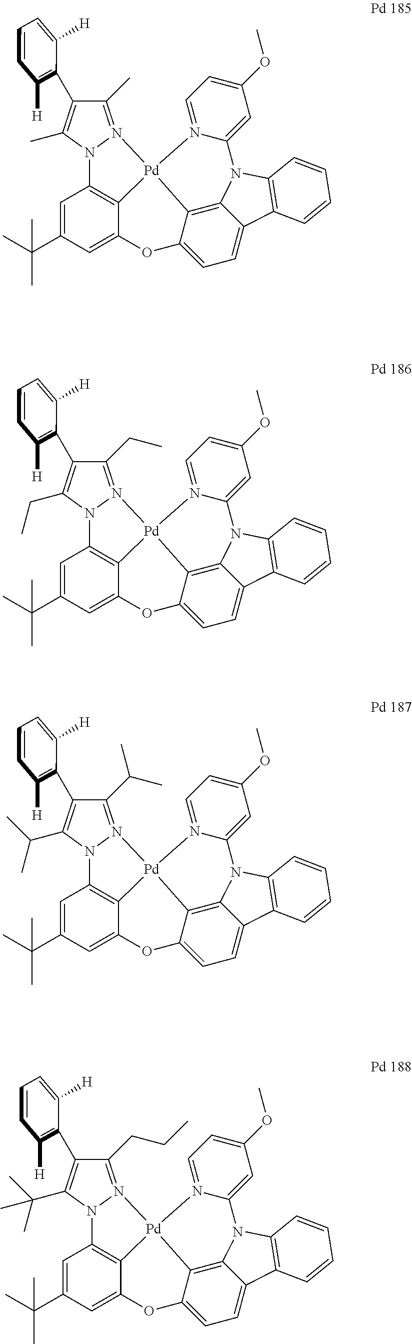

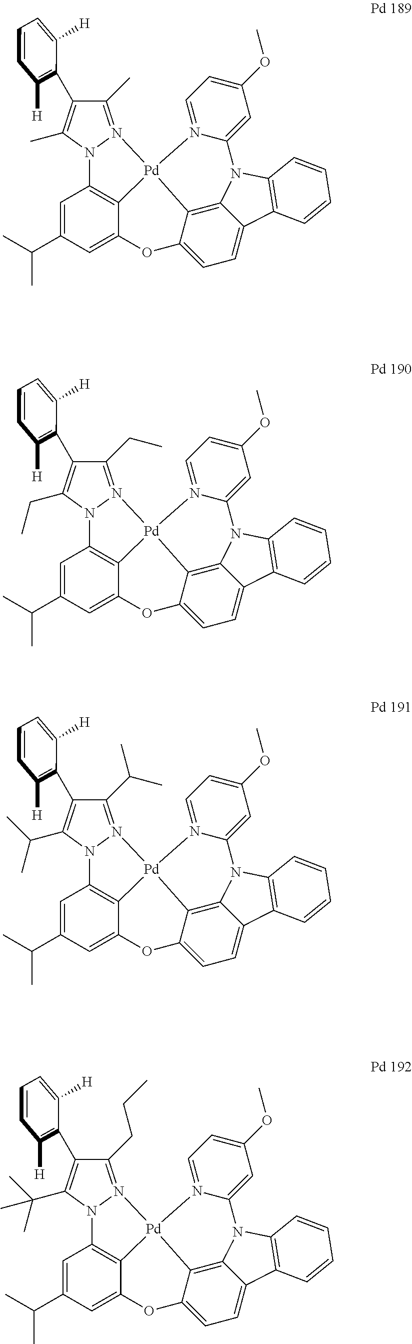

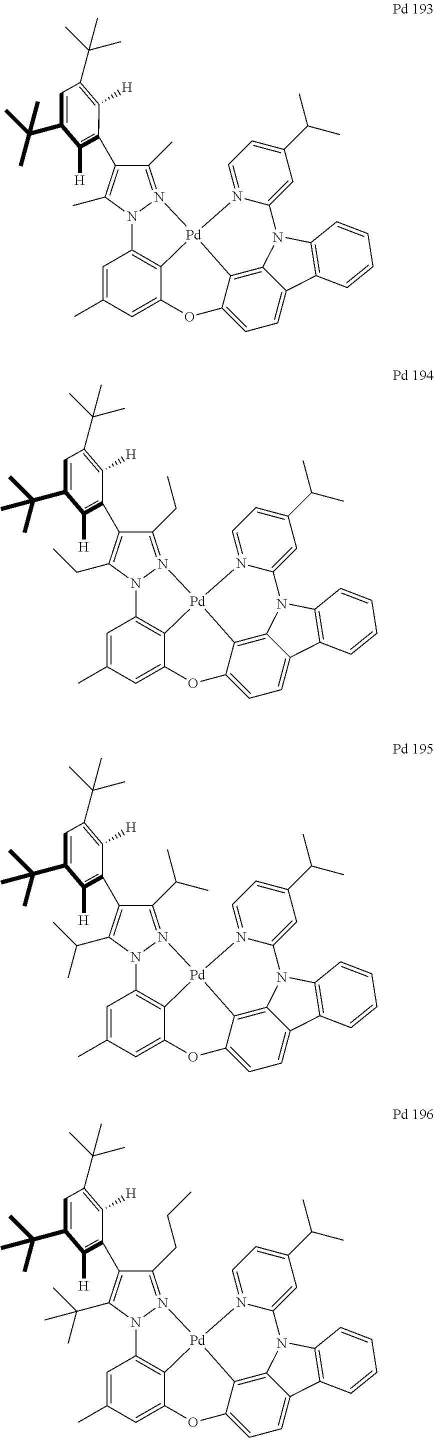

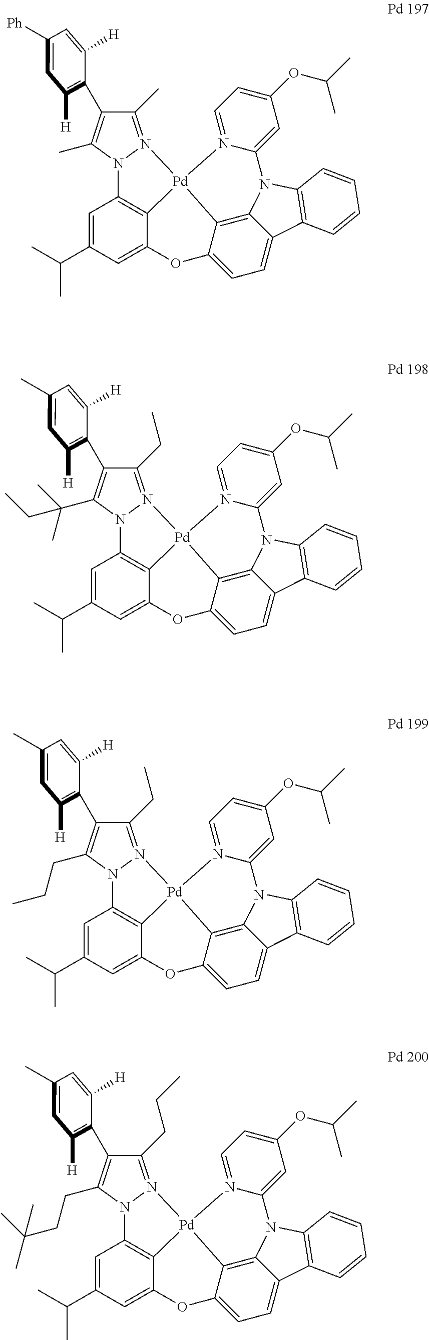

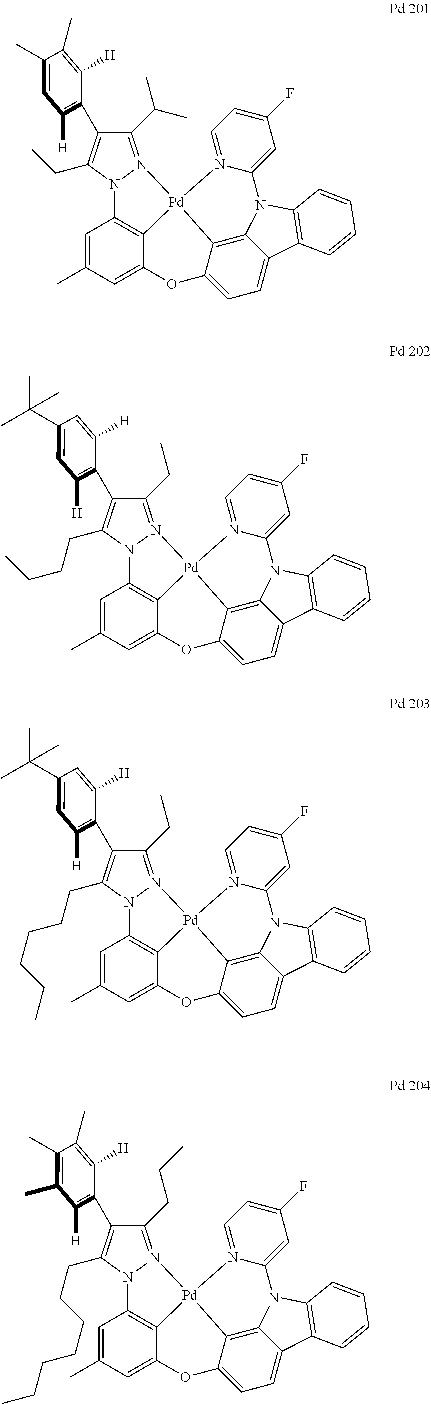

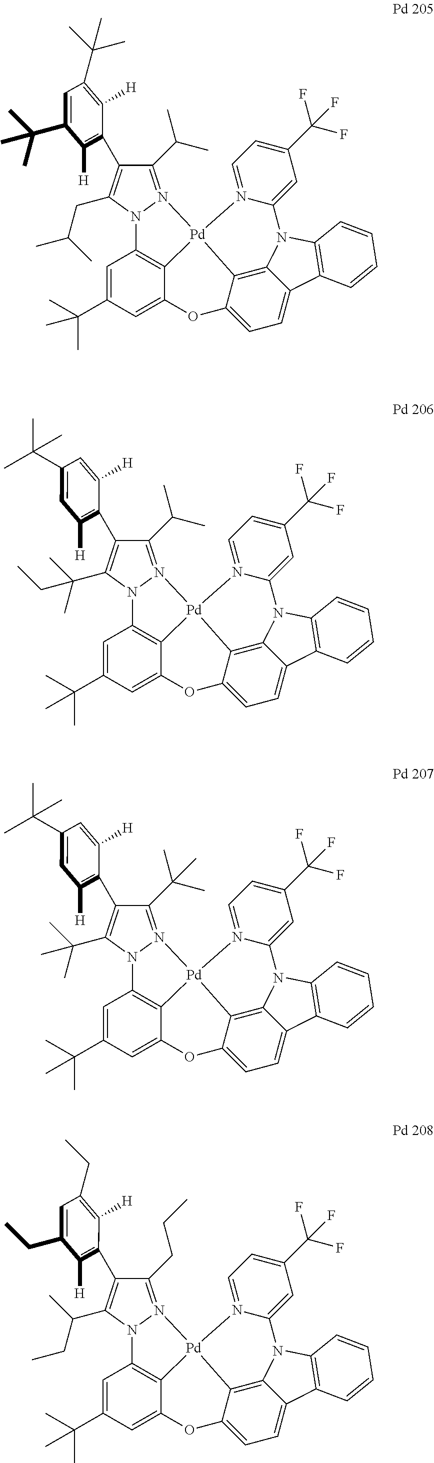

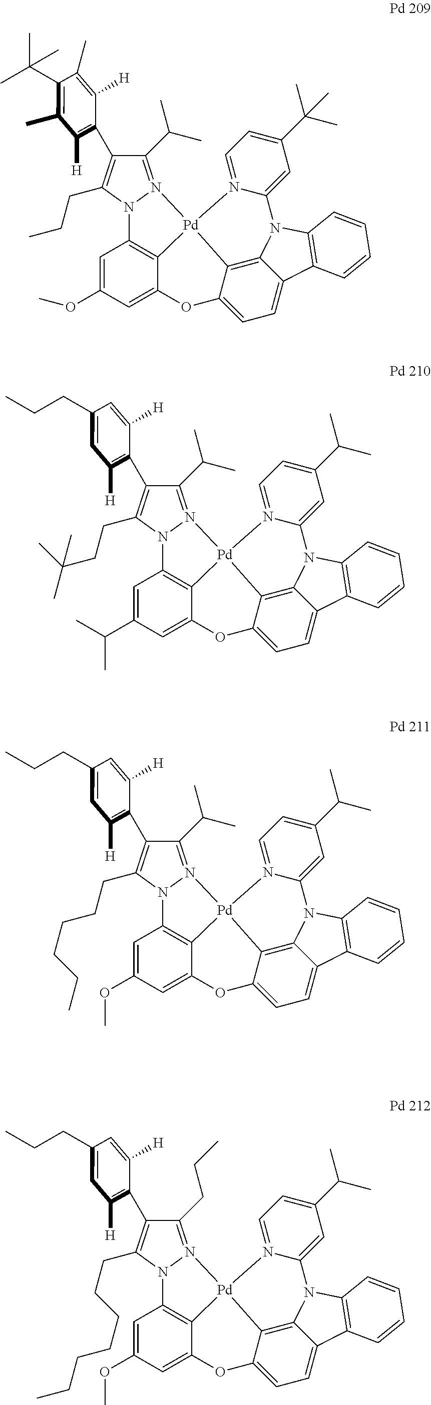

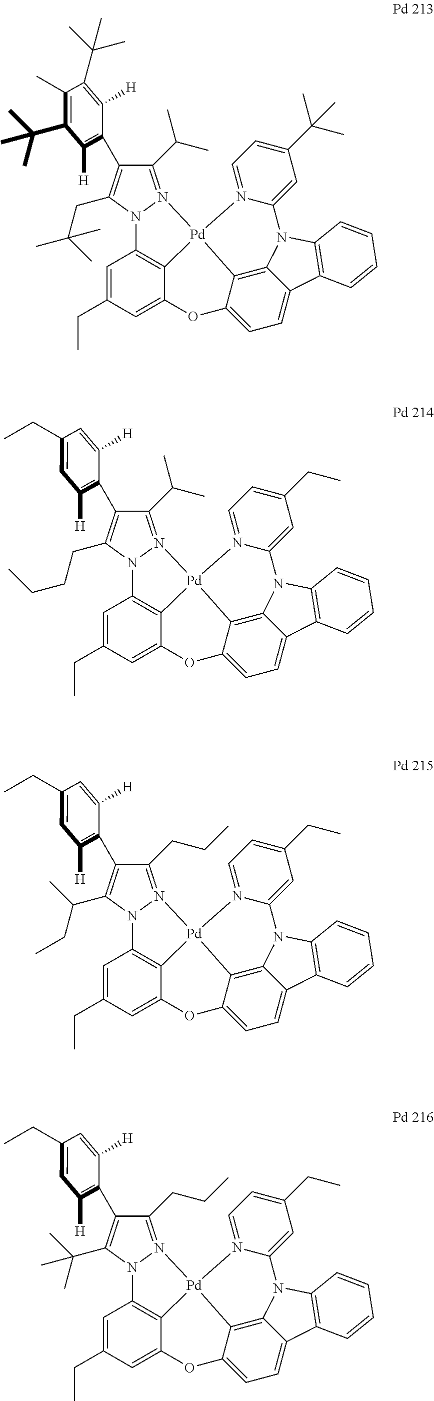

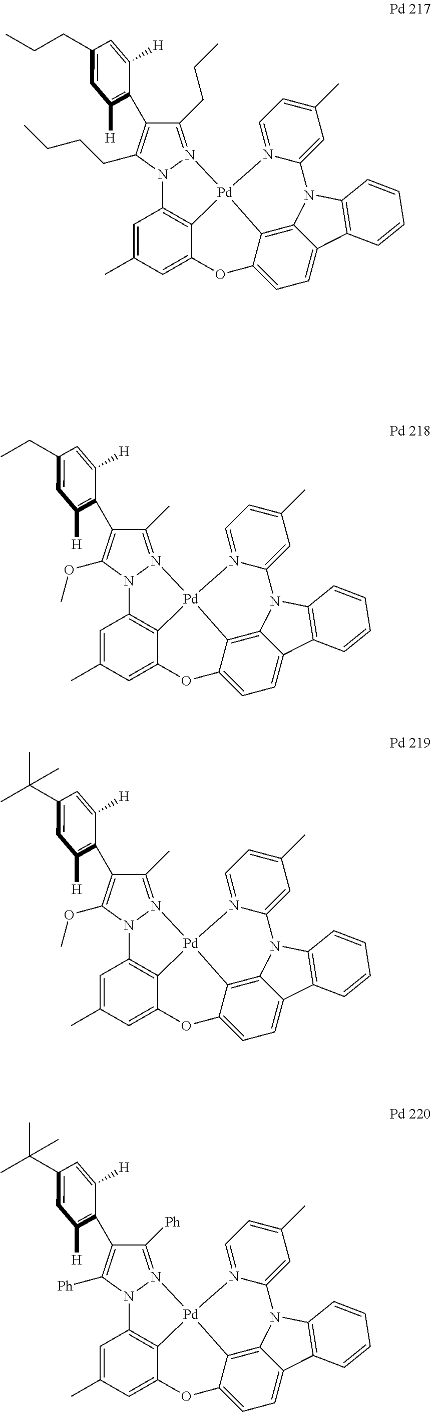

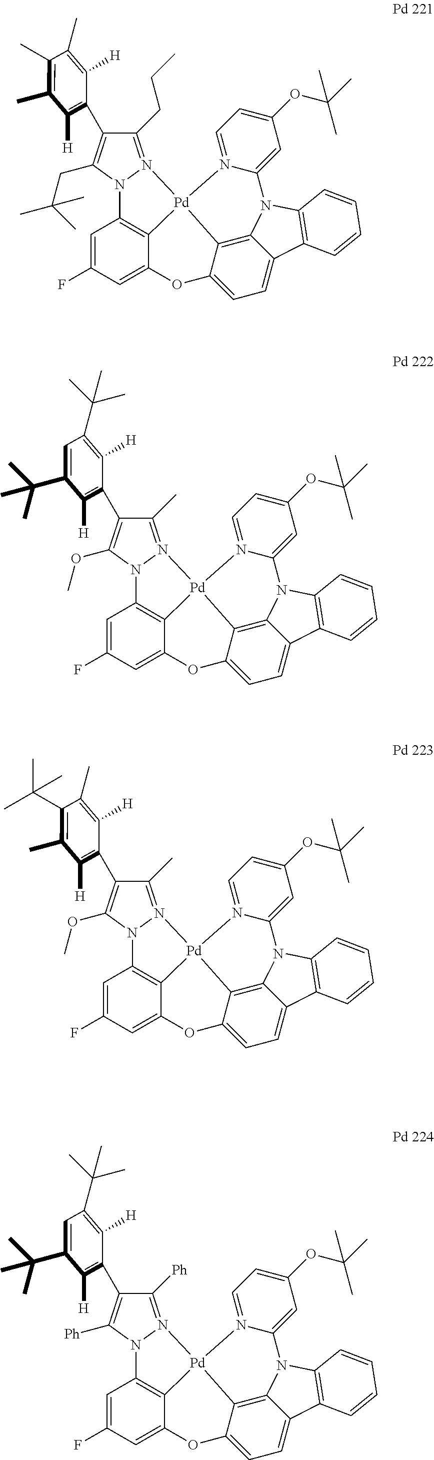

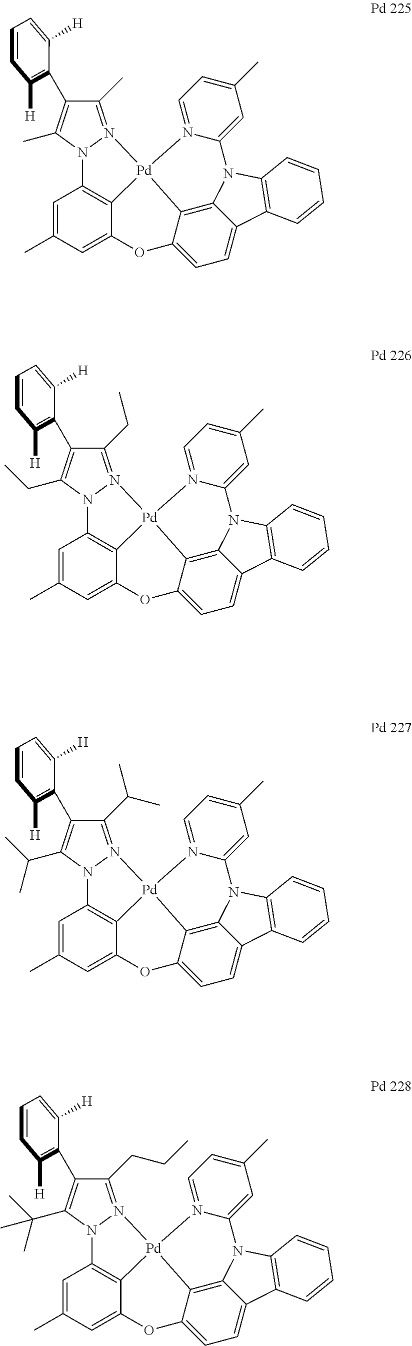

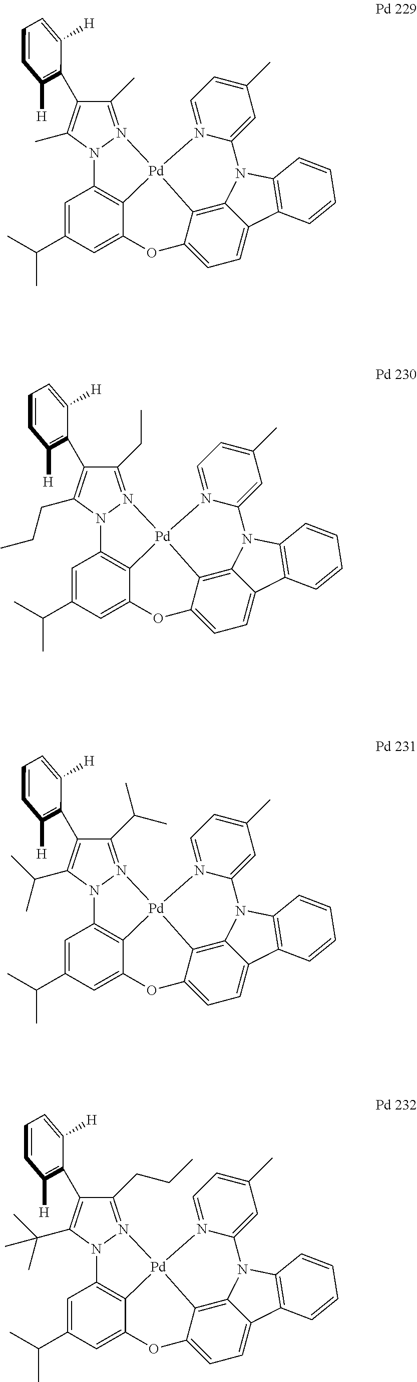

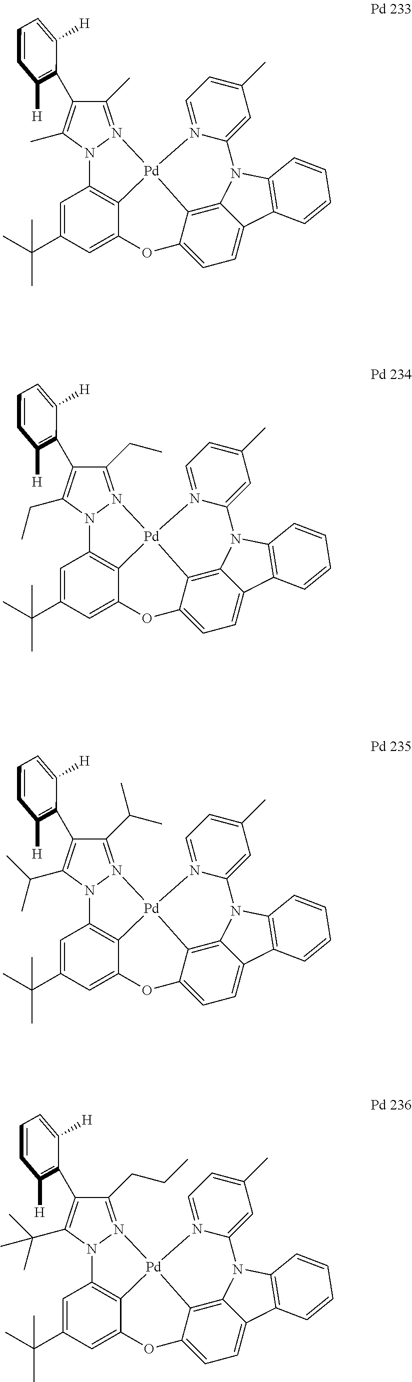

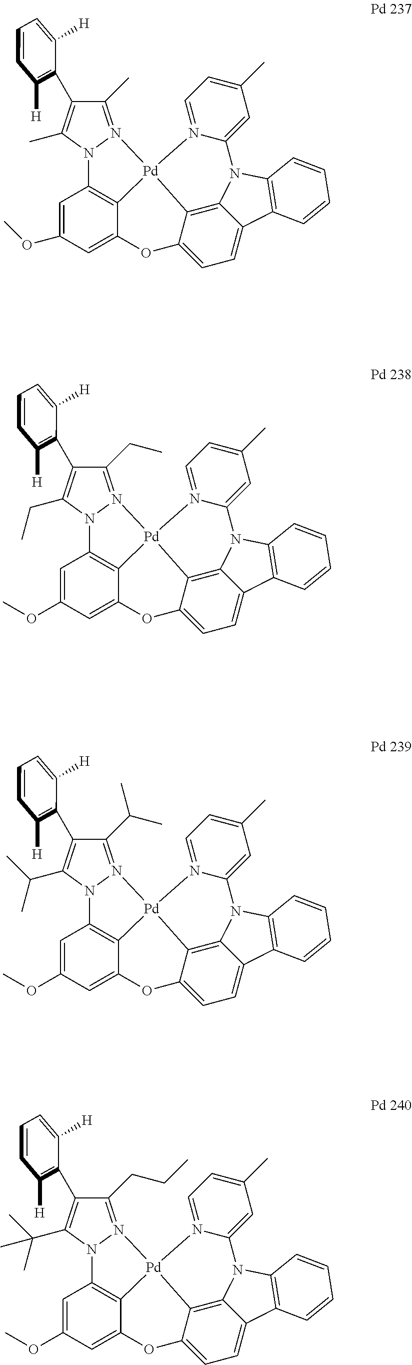

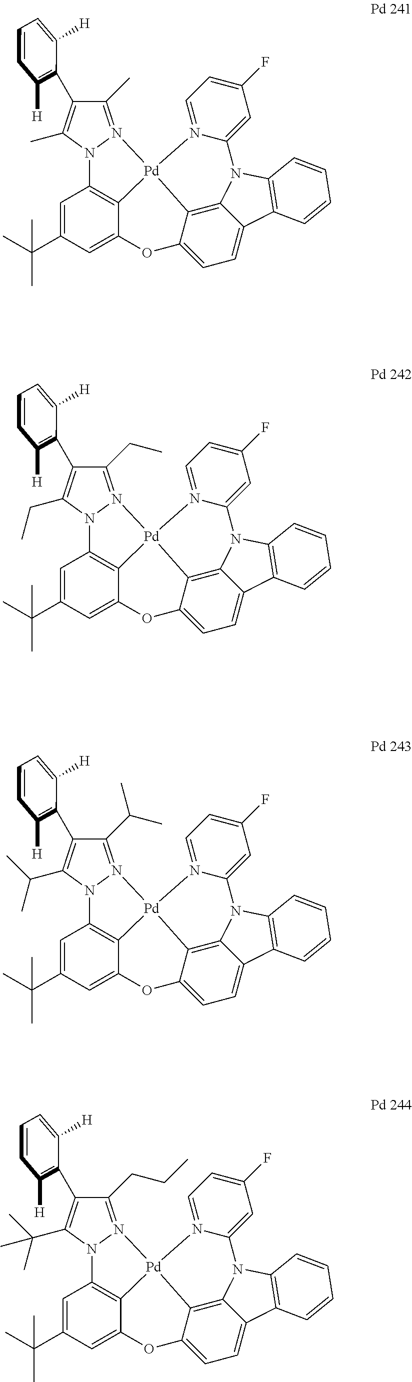

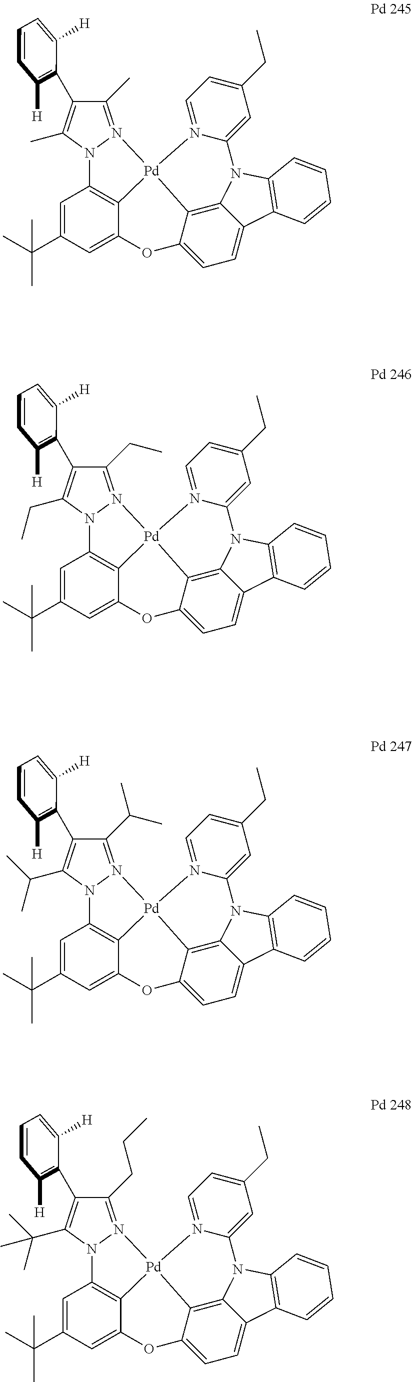

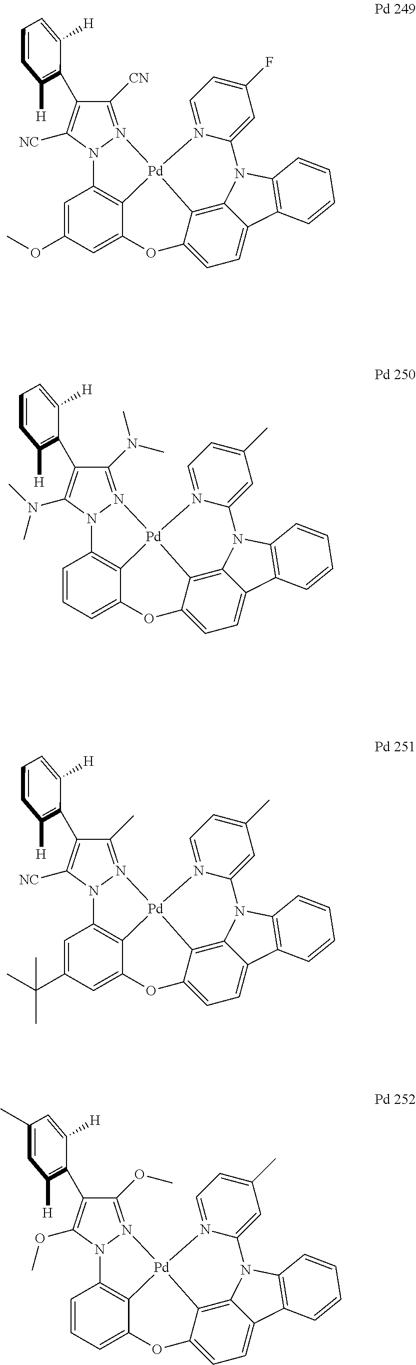

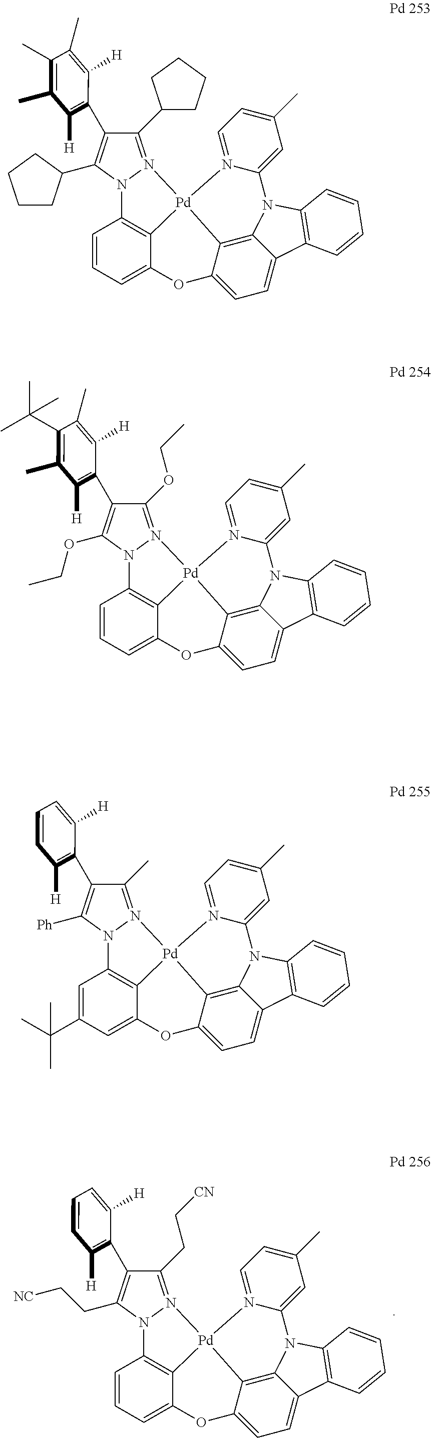

4. The tetradentate cyclopalladated palladium complex comprising trisubstituted pyrazole according to claim 1, wherein the complex is electric neutrality.

5. A method for preparing the tetradentate cyclopalladated palladium complex comprising trisubstituted pyrazole according to claim 1, wherein the complex is synthesized by the following chemical reaction steps:

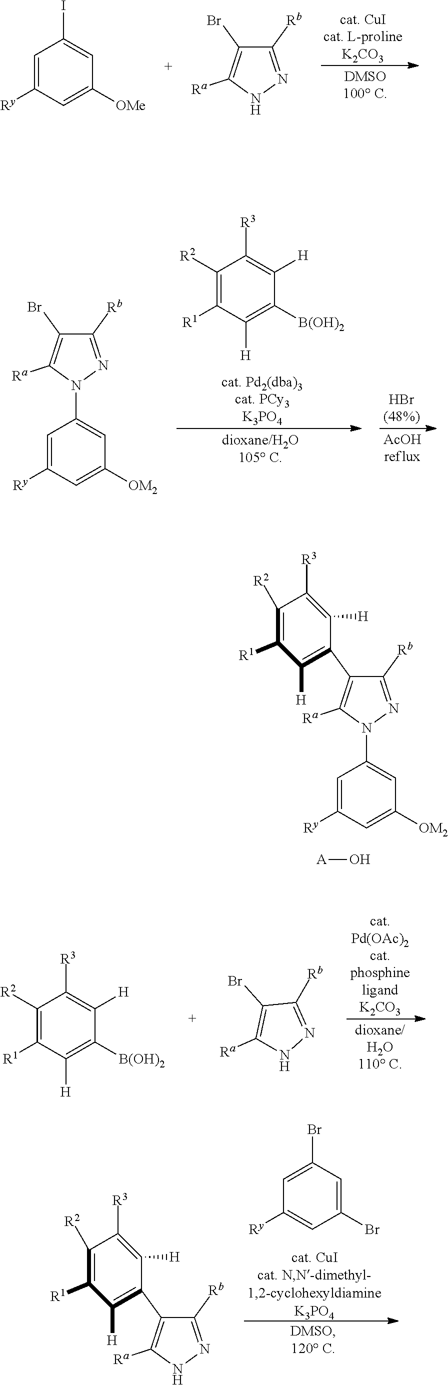

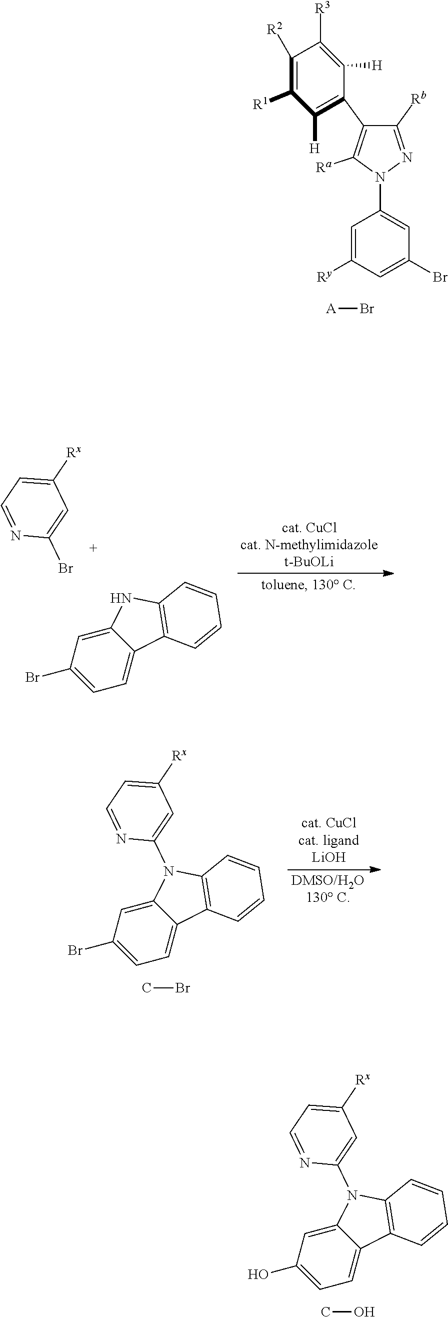

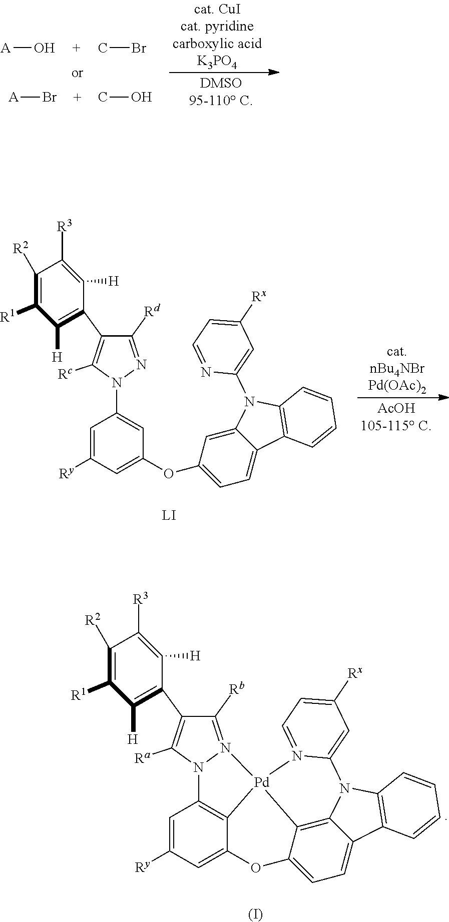

6. Use of the tetradentate cyclopalladated palladium complex comprising trisubstituted pyrazole according to claim 1 in an organic electroluminescent material.

7. An optical or electro-optical device, wherein the device comprises one or more of the tetradentate cyclopalladated palladium complex comprising trisubstituted pyrazole according to claim 1.

8. The optical or electro-optical device according to claim 7, wherein the device comprises a light absorbing device, an organic light emitting diode, a light emitting device, or a device capable of both light-absorbing and light-emitting.

9. The optical or electro-optical device according to claim 7, wherein the complex has 100% of internal quantum efficiency in the device.

10. An OLED device, wherein a luminescent material or a host material in the OLED device comprises one or more of the tetradentate cyclopalladated palladium complex comprising trisubstituted pyrazole according to claim 1.
